(19) United States
(12) Patent Application Publication
(10) Pub. No.: US 2025/0015194 A1
(43) Pub. Date: Jan. 9, 2025

(54) Semiconductor Device

(71) Applicant: Semiconductor Energy Laboratory Co., Ltd., Kanagawa-ken (JP)

(72) Inventors: Shunpei YAMAZAKI, Tokyo (JP); Tsutomu Murakawa, Isehara (JP); Fumito Isaka, Zama (JP); Hitoshi Kunitake, Tokyo (JP); Yasuhiro Jinbo, Isehara (JP)

(73) Assignee: Semiconductor Energy Laboratory Co., Ltd., Kanagawa-ken (JP)

(21) Appl. No.: 18/763,108

(22) Filed: Jul. 3, 2024

(30) Foreign Application Priority Data
Jul. 6, 2023 (JP) 2023-111782
Jul. 6, 2023 (JP) 2023-111783
Jul. 6, 2023 (JP) 2023-111802
Aug. 10, 2023 (JP) 2023-131028

(51) Int. Cl. H01L 29/786; H10B 12/00

(52) U.S. Cl. CPC H01L 29/7869; H01L 29/78696; H10B 12/33

(57) ABSTRACT

A transistor that can be miniaturized is provided. The semiconductor device includes an oxide semiconductor layer, first to fourth conductive layers, and first to fourth insulating layers. Over the first conductive layer including a depressed portion, the first insulating layer, the second conductive layer, the second insulating layer, and the third conductive layer which include a first opening portion overlapping with the depressed portion are provided in this order. The third insulating layer is in contact with at least the side surface of the second conductive layer in the first opening portion. The oxide semiconductor layer is in contact with the top surface of the third conductive layer and the bottom and side surfaces of the depressed portion, and is in contact with the third insulating layer in the first opening portion. The fourth insulating layer is on an inner side of the oxide semiconductor layer in the first opening portion. The fourth conductive layer is on an inner side of the fourth insulating layer in the first opening portion. In a cross-sectional view, the oxide semiconductor layer includes a region overlapping with the second conductive layer with the third insulating layer therebetween and overlapping with the fourth conductive layer with the fourth insulating layer therebetween.

### BACKGROUND OF THE INVENTION

### 1. Field of the Invention

One embodiment of the present invention relates to a semiconductor device, a memory device, a display device, and an electronic device. One embodiment of the present invention also relates to a method for manufacturing the semiconductor device.

One embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), driving methods thereof, and manufacturing methods thereof.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### 2. Description of the Related Art

In recent years, semiconductor devices have been developed; an LSI, a central processing unit (CPU), a memory, and the like have been mainly used for semiconductor devices. A CPU is an aggregation of semiconductor elements; the CPU includes a semiconductor integrated circuit (including at least a transistor and a memory) formed into a chip by processing a semiconductor wafer, and is provided with an electrode that is a connection terminal.

A semiconductor circuit (IC chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit (IC) and a display device. As semiconductor materials usable for the transistor, silicon-based semiconductor materials have been widely used, but oxide semiconductors have been attracting attention as alternative materials.

A transistor including an oxide semiconductor is known to have an extremely low leakage current in an off state. For example, Patent Document 1 discloses a low-power CPU utilizing a characteristic of a low leakage current of the transistor including an oxide semiconductor. Furthermore, for example, Patent Document 2 discloses a memory device that can retain stored data for a long time by utilizing a feature of a low leakage current of the transistor including an oxide semiconductor.

In recent years, demand for an integrated circuit with higher density has risen with reductions in size and weight of electronic devices. In addition, the productivity of a semiconductor device including an integrated circuit is desired to be improved. For example, Patent Document 3 and Non-Patent Document 1 disclose a technique for achieving an integrated circuit with higher density by making a plurality of memory cells overlap with each other by stacking a first transistor including an oxide semiconductor film and a second transistor including an oxide semiconductor film. Patent Document 4 discloses a technique for achieving an integrated circuit with higher density by forming a channel of a transistor including an oxide semiconductor film in the vertical direction.

### REFERENCES

### Patent Documents

[Patent Document 1] Japanese Published Patent Application No. 2012-257187
[Patent Document 2] Japanese Published Patent Application No. 2011-151383
[Patent Document 3] PCT International Publication No. 2021/053473
[Patent Document 4] Japanese Published Patent Application No. 2013-211537

### Non-Patent Document

[Non-Patent Document 1] M. Oota, et al., “3D-Stacked CAAC—In—Ga—Zn Oxide FETs with Gate Length of 72 nm”, IEDM Tech. Dig., 2019, pp. 50-53

### SUMMARY OF THE INVENTION

An object of one embodiment of the present invention is to provide a transistor with favorable electrical characteristics. Another object of one embodiment of the present invention is to provide a transistor with a high on-state current. An object of one embodiment of the present invention is to provide a transistor with small parasitic capacitance. Another object of one embodiment of the present invention is to provide a transistor, a semiconductor device, or a memory device that can be miniaturized or highly integrated. Another object of one embodiment of the present invention is to provide a display device with a high resolution or a high aperture ratio. Another object of one embodiment of the present invention is to provide a transistor, a semiconductor device, a display device, or a memory device with high reliability. Another object of one embodiment of the present invention is to provide a semiconductor device, a display device, or a memory device with low power consumption. Another object of one embodiment of the present invention is to provide a memory device that operates at high speed. Another object of one embodiment of the present invention is to provide a method for manufacturing the transistor, the semiconductor device, the display device, or the memory device.

Note that the description of these objects does not preclude the existence of other objects. One embodiment of the present invention does not necessarily achieve all of these objects. Other objects can be derived from the description of the specification, the drawings, the claims, and the like.

One embodiment of the present invention is a semiconductor device including an oxide semiconductor layer, a first conductive layer, a second conductive layer, a third conductive layer, a fourth conductive layer, a first insulating layer, a second insulating layer, a third insulating layer, and a fourth insulating layer. The first insulating layer is over the first conductive layer. The second conductive layer is over the first insulating layer. The second insulating layer is over the second conductive layer. The third conductive layer is over the second insulating layer. The first conductive layer includes a first depressed portion. The first insulating layer, the second conductive layer, the second insulating layer, and the third conductive layer include a first opening portion in a position overlapping with the first depressed portion. The third insulating layer is in contact with at least a side surface of the second conductive layer in the first opening portion. The oxide semiconductor layer is in contact with a top surface of the third conductive layer and a bottom surface and a side surface of the first depressed portion, and is in contact with the third insulating layer in the first opening portion. The fourth insulating layer is on an inner side of the oxide semiconductor layer in the first opening portion. The fourth conductive layer is on an inner side of the fourth insulating layer in the first opening portion. In a cross-sectional view, the oxide semiconductor layer includes a region overlapping with the second conductive layer with the third insulating layer therebetween and overlapping with the fourth conductive layer with the fourth insulating layer therebetween.

The semiconductor device preferably further includes a fifth insulating layer. In this case, the first conductive layer and the second insulating layer are preferably over the fifth insulating layer, and the shortest distance from a top surface of the fifth insulating layer to a top surface of the first conductive layer in contact with the first insulating layer is preferably longer than the shortest distance from the top surface of the fifth insulating layer to a bottom surface of the fourth insulating layer. Alternatively, the first conductive layer and the fourth conductive layer are preferably over the fifth insulating layer, and the shortest distance from the top surface of the fifth insulating layer to the top surface of the first conductive layer in contact with the first insulating layer is preferably longer than or equal to the shortest distance from the top surface of the fifth insulating layer to a bottom surface of the fourth conductive layer.

The first conductive layer preferably includes a fifth conductive layer and a sixth conductive layer over the fifth conductive layer. The sixth conductive layer preferably includes a second depressed portion. The first opening portion preferably overlaps with the second depressed portion. The oxide semiconductor layer is preferably in contact with a bottom surface and a side surface of the second depressed portion.

The semiconductor device preferably further includes a sixth insulating layer. In this case, the fourth insulating layer preferably covers a top surface and a side surface of the oxide semiconductor layer over the second insulating layer. It is preferable that The sixth insulating layer be over the fourth insulating layer and include a second opening portion in a position overlapping with the first opening portion. The fourth conductive layer preferably includes a portion overlapping with the oxide semiconductor layer with the fourth insulating layer therebetween in the first opening portion, and a portion positioned in the second opening portion. Alternatively, it is preferable that the sixth insulating layer be over the second insulating layer, cover the top surface and the side surface of the oxide semiconductor layer over the second insulating layer, and include the second opening portion in a position overlapping with the first opening portion. The fourth insulating layer preferably includes a portion positioned in the second opening portion. The fourth conductive layer is preferably on an inner side of the fourth insulating layer in the second opening portion.

Another embodiment of the present invention is a semiconductor device including an oxide semiconductor layer, a first conductive layer, a second conductive layer, a third conductive layer, a fourth conductive layer, a fifth conductive layer, a first insulating layer, a second insulating layer, a third insulating layer, a fourth insulating layer, and a fifth insulating layer. The first insulating layer is over the first conductive layer. The second conductive layer is over the first insulating layer. The second insulating layer is over the second conductive layer. The third conductive layer is over the second insulating layer. The first conductive layer includes a first depressed portion. The first insulating layer, the second conductive layer, the second insulating layer, and the third conductive layer include a first opening portion in a position overlapping with the first depressed portion. The third insulating layer is in contact with at least a side surface of the second conductive layer in the first opening portion. The oxide semiconductor layer is in contact with a top surface of the third conductive layer and a bottom surface and a side surface of the first depressed portion, and is in contact with the third insulating layer in the first opening portion. The fourth insulating layer is on an inner side of the oxide semiconductor layer in the first opening portion. The fourth conductive layer is on an inner side of the fourth insulating layer in the first opening portion. The fifth insulating layer is over the fourth insulating layer and includes a second opening portion reaching the fourth conductive layer in a position overlapping with the first opening portion. The fifth conductive layer is in contact with the fourth conductive layer in the second opening portion. In a cross-sectional view, the oxide semiconductor layer includes a region overlapping with the second conductive layer with the third insulating layer therebetween and overlapping with the fourth conductive layer with the fourth insulating layer therebetween.

The semiconductor device preferably further includes a sixth insulating layer. In this case, the first conductive layer and the second insulating layer are preferably over the sixth insulating layer, and the shortest distance from a top surface of the sixth insulating layer to a top surface of the first conductive layer in contact with the first insulating layer is preferably longer than the shortest distance from the top surface of the sixth insulating layer to a bottom surface of the fourth insulating layer. Alternatively, the first conductive layer and the fourth conductive layer are preferably over the sixth insulating layer, and the shortest distance from the top surface of the sixth insulating layer to the top surface of the first conductive layer in contact with the first insulating layer is preferably longer than or equal to the shortest distance from the top surface of the sixth insulating layer to a bottom surface of the fourth conductive layer.

The first conductive layer preferably includes a sixth insulating layer and a seventh conductive layer over the sixth conductive layer. The seventh conductive layer preferably includes a second depressed portion. The first opening portion preferably overlaps with the second depressed portion. The oxide semiconductive layer is preferably in contact with a bottom surface and a side surface of the second depressed portion.

In each of the above semiconductor devices, the third insulating layer preferably includes a seventh insulating layer in contact with the oxide semiconductor layer and an eighth insulating layer positioned on an outer side of the seventh insulating layer in the first opening portion. It is preferable that one of the seventh insulating layer and the eighth insulating layer be an oxide insulating layer and the other be a nitride insulating layer.

Another embodiment of the present invention is a semiconductor device including a first layer and a second layer over the first layer. The second layer includes a first memory cell array and a second memory cell array. The first memory cell array includes a plurality of first memory cells. The second memory cell array includes a plurality of second memory cells. The first layer includes a transistor containing silicon in a channel formation region. The first memory cell and the second memory cell each include a vertical transistor. The vertical transistor includes an oxide semiconductor in a channel formation region. The first memory cell and the second memory cell have different structures.

Another embodiment of the present invention is a semiconductor device including a first layer, a second layer over the first layer, and a third layer over the second layer. The second layer includes a first memory cell array. The third layer includes a second memory cell array. The first memory cell array includes a plurality of first memory cells. The second memory cell array includes a plurality of second memory cells. The first layer includes a transistor containing silicon in a channel formation region. The first memory cell and the second memory cell each include a vertical transistor. The vertical transistor includes an oxide semiconductor in a channel formation region. The first memory cell and the second memory cell have different structures.

One of the first memory cell and the second memory cell preferably retains data without power supply to the memory cell for a longer time than the other.

Another embodiment of the present invention is a semiconductor device including a first layer and a second layer over the first layer. The second layer includes a first memory cell array and a second memory cell array. The first memory cell array includes a plurality of first memory cells. The second memory cell array includes a plurality of second memory cells. The first layer includes a transistor containing silicon in a channel formation region. The first memory cell is composed of one vertical transistor and one capacitor. The second memory cell is composed of two vertical transistors. The vertical transistors included in the first memory cell and the second memory cell each include an oxide semiconductor in a channel formation region.

Another embodiment of the present invention is a semiconductor device including a first layer, a second layer over the first layer, and a third layer over the second layer. The second layer includes a first memory cell array. The third layer includes a second memory cell array. The first memory cell array includes a plurality of first memory cells. The second memory cell array includes a plurality of second memory cells. The first layer includes a transistor containing silicon in a channel formation region. One of the first memory cell and the second memory cell is composed of one vertical transistor and one capacitor, and the other is composed of two vertical transistors. The vertical transistors included in the first memory cell and the second memory cell each include an oxide semiconductor in a channel formation region.

One embodiment of the present invention can provide a transistor with favorable electrical characteristics. Another embodiment of the present invention can provide a transistor with a high on-state current. Another embodiment of the present invention can provide a transistor with small parasitic capacitance. Another embodiment of the present invention can provide a transistor, a semiconductor device, or a memory device that can be miniaturized or highly integrated. Another embodiment of the present invention can provide a display device with a high resolution or a high aperture ratio. Another embodiment of the present invention can provide a transistor, a semiconductor device, a display device, or a memory device with high reliability. Another embodiment of the present invention can provide a semiconductor device, a display device, or a memory device with low power consumption. Another embodiment of the present invention can provide a memory device that operates at high speed. Another embodiment of the present invention can provide a method for manufacturing the transistor, the semiconductor device, the display device, or the memory device.

Note that the description of these effects does not preclude the existence of other effects. One embodiment of the present invention does not necessarily have all of these effects. Other effects can be derived from the description of the specification, the drawings, the claims, and the like.

### BRIEF DESCRIPTION OF THE DRAWINGS

In the accompanying drawings:

FIGS. 1A to 1F are perspective views illustrating structure examples of a semiconductor device;

FIGS. 2A1 and 2A2 are plan views illustrating examples of a semiconductor device, and FIGS. 2B to 2E are cross-sectional views illustrating the example of a semiconductor device;

FIG. 3 is a cross-sectional view illustrating an example of a semiconductor device;

FIGS. 4A and 4B are cross-sectional views illustrating examples of a semiconductor device;

FIGS. 5A and 5B are cross-sectional views illustrating examples of a semiconductor device;

FIGS. 6A to 6D are cross-sectional views illustrating examples of a semiconductor device;

FIGS. 7A to 7C are cross-sectional views illustrating examples of a semiconductor device;

FIG. 8A is a plan view illustrating an example of a semiconductor device, and FIGS. 8B to 8E are cross-sectional views illustrating the example of a semiconductor device;

FIGS. 9A and 9B are cross-sectional views illustrating examples of a semiconductor device;

FIG. 10A is a plan view illustrating an example of a semiconductor device, and FIGS. 10B to 10E are cross-sectional views illustrating the example of a semiconductor device;

FIGS. 11A and 11B are cross-sectional views illustrating examples of a semiconductor device;

FIG. 12A is a plan view illustrating an example of a semiconductor device, and FIGS. 12B to 12E are cross-sectional views illustrating the example of a semiconductor device;

FIGS. 13A and 13B are cross-sectional views illustrating examples of a semiconductor device;

FIGS. 14A to 14C2 are cross-sectional views illustrating examples of a semiconductor device;

FIGS. 15A1 to 15E are cross-sectional views illustrating an example of a method for manufacturing a semiconductor device;

FIGS. 16A to 16C are cross-sectional views illustrating the example of a method for manufacturing a semiconductor device;

FIGS. 17A to 17F are cross-sectional views illustrating the example of a method for manufacturing a semiconductor device;

FIGS. 18A to 18F are cross-sectional views illustrating the example of a method for manufacturing a semiconductor device;

FIGS. 19A to 19D are cross-sectional views illustrating the example of a method for manufacturing a semiconductor device;

FIGS. 20A to 20D are cross-sectional views illustrating a method for forming a metal oxide of one embodiment of the present invention;

FIGS. 21A to 21D are cross-sectional views illustrating the method for forming a metal oxide of one embodiment of the present invention;

FIG. 22A is a plan view illustrating an example of a memory device, and FIGS. 22B and 22C are cross-sectional views illustrating the example of a memory device;

FIGS. 23A and 23B are cross-sectional views illustrating an example of a memory device;

FIGS. 24A and 24B are cross-sectional views illustrating an example of a memory device;

FIG. 25A is a plan view illustrating an example of a memory device, and FIGS. 25B and 25C are cross-sectional views illustrating the example of a memory device;

FIGS. 26A and 26B are cross-sectional views illustrating an example of a memory device;

FIGS. 27A and 27B are cross-sectional views illustrating examples of a memory device;

FIG. 28 is a cross-sectional view illustrating an example of a memory device;

FIG. 29 is a cross-sectional view illustrating an example of a memory device;

FIG. 30 is a cross-sectional view illustrating an example of a memory device;

FIG. 31 is a cross-sectional view illustrating an example of a memory device;

FIG. 32 is a cross-sectional view illustrating an example of a memory device;

FIG. 33A is a plan view illustrating an example of a memory device, and FIG. 33B is a cross-sectional view illustrating the example of a memory device;

FIG. 34 is a cross-sectional view illustrating an example of a memory device;

FIG. 35 is a cross-sectional view illustrating an example of a memory device;

FIG. 36A is a plan view illustrating an example of a memory device, and FIG. 36B is a cross-sectional view illustrating the example of a memory device;

FIG. 37 is a cross-sectional view illustrating an example of a memory device;

FIG. 38 is a cross-sectional view illustrating an example of a memory device;

FIG. 39 is a block diagram illustrating a structure example of a semiconductor device;

FIGS. 40A to 40G each illustrate a circuit structure example of a memory cell;

FIGS. 41A and 41B are perspective views illustrating structure examples of a semiconductor device;

FIG. 42 is a block diagram illustrating a CPU;

FIGS. 43A and 43B are perspective views illustrating a structure example of a semiconductor device;

FIGS. 44A and 44B are perspective views of a semiconductor device;

FIGS. 45A and 45B each illustrate a hierarchy of various kinds of memory devices;

FIGS. 46A and 46B are perspective views illustrating an example of a display device;

FIG. 47 is a cross-sectional view illustrating an example of a display device;

FIG. 48 is a cross-sectional view illustrating an example of a display device;

FIG. 49 is a cross-sectional view illustrating an example of a display device;

FIG. 50 is a cross-sectional view illustrating an example of a display device;

FIGS. 51A to 51C illustrate structure examples of a display device;

FIGS. 52A and 52B illustrate examples of electronic components;

FIGS. 53A to 53C illustrate examples of a large computer, FIG. 53D illustrates an example of space equipment, and FIG. 53E illustrates an example of a storage system that can be used in a data center;

FIGS. 54A to 54F illustrate examples of electronic devices;

FIGS. 55A to 55G illustrate examples of electronic devices;

FIGS. 56A to 56F illustrate examples of electronic devices;

FIG. 57A is a circuit diagram of an example, and FIG. 57B is a timing chart of the example; and

FIGS. 58A and 58B show measurement results of reading currents in an example;

### DETAILED DESCRIPTION OF THE INVENTION

Embodiments will be described in detail with reference to the drawings. Note that the embodiments of the present invention are not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the structures of the invention described below, the same portions or portions having similar functions are denoted by the same reference numerals in different drawings, and description of such portions is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of a current or a voltage, switching operation for controlling conduction or non-conduction, and the like. A transistor in this specification includes, in its category, an insulated-gate field effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an OS transistor. In addition, a transistor containing silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration of lower than 0.1 atomic % is an impurity. When a semiconductor contains an impurity, an increase in density of defect states or a reduction in crystallinity of the semiconductor might occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity might cause oxygen vacancies (also referred to as V_{O}) in an oxide semiconductor, for example.

Note that in this specification and the like, an oxynitride refers to a material in which an oxygen content is higher than a nitrogen content. A nitride oxide refers to a material in which a nitrogen content is higher than an oxygen content.

The contents of elements such as hydrogen, oxygen, carbon, and nitrogen in a film can be analyzed by secondary ion mass spectrometry (SIMS) or X-ray photoelectron spectroscopy (XPS), for example. Note that XPS is suitable when the content percentage of a target element is high (e.g., 0.5 atomic % or higher, or 1 atomic % or higher). By contrast, SIMS is suitable when the content percentage of a target element is low (e.g., 0.5 atomic % or lower, or 1 atomic % or lower). To compare the contents of elements, analysis with a combination of SIMS and XPS is preferably used.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −20° and less than or equal to 20°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 70° and less than or equal to 110°.

In this specification and the like, the term “electrically connected” includes the case where components are connected to each other through an “object having any electric action”. There is no particular limitation on an “object having any electric function” as long as electric signals can be transmitted and received between components that are connected through the object. Examples of the “object having any electric function” are a switching element such as a transistor, a resistor, a coil, a capacitor, and an element with a variety of functions as well as an electrode and a wiring.

Unless otherwise specified, an off-state current in this specification and the like refers to a leakage current between a source and a drain generated when a transistor is in an off state (also referred to as a non-conducting state or a cutoff state). Unless otherwise specified, the off state of an n-channel transistor means that a gate-source voltage V_{gs} is lower than a threshold voltage Vₜₕ, and the off state of a p-channel transistor means that V_{gs} is higher than Vₜₕ.

Note that “normally on” in this specification and the like means a state where a channel exists without application of a voltage to a gate and a current flows through a transistor. Furthermore, “normally off” means a state where a current does not flow through a transistor when no potential or a ground potential is applied to a gate.

In this specification and the like, a tapered shape refers to a shape such that at least part of a side surface of a component is inclined to a substrate surface or a formation surface of the component. For example, a tapered shape preferably includes a region where the angle between the inclined side surface and the substrate surface or the formation surface (such an angle is also referred to as a taper angle) is greater than 0° and less than 90°. Note that the side surface of the component, the substrate surface, and the formation surface are not necessarily completely flat and may be substantially flat with a slight curvature or with slight unevenness.

In this specification and the like, when the expression “A is positioned over B” is used, at least part of A is positioned over B. In other words, A includes a region positioned over B, for example. Similarly, when the expression “A is in contact with B” or “A overlaps with B” is used, at least part of A is in contact with or overlaps with B. In other words, A includes a region in contact with B or A includes a region overlapping with B, for example. Similarly, in this specification and the like, when the expression “A covers B” is used, at least part of A covers B. In other words, A includes a region covering B, for example.

In this specification and the like, a device formed using a metal mask or a fine metal mask (FMM) may be referred to as a device having a metal mask (MM) structure. In this specification and the like, a device formed without using a metal mask or an FMM may be referred to as a device having a metal maskless (MML) structure.

In this specification and the like, a structure where light-emitting layers of light-emitting elements (also referred to as light-emitting devices) having different emission wavelengths are separately formed may be referred to as a side-by-side (SBS) structure. The SBS structure can optimize materials and structures of light-emitting elements and thus can extend freedom of choice of materials and structures, whereby the luminance and the reliability can be easily improved.

In this specification and the like, a hole or an electron is sometimes referred to as a carrier. Specifically, a hole-injection layer or an electron-injection layer may be referred to as a carrier-injection layer, a hole-transport layer or an electron-transport layer may be referred to as a carrier-transport layer, and a hole-blocking layer or an electron-blocking layer may be referred to as a carrier-blocking layer. Note that in some cases, the above-described carrier-injection layer, carrier-transport layer, and carrier-blocking layer cannot be distinguished from each other. One layer may have two or three functions of the carrier-injection layer, the carrier-transport layer, and the carrier-blocking layer in some cases.

In this specification and the like, a light-emitting element includes an EL layer between a pair of electrodes. The EL layer includes at least a light-emitting layer. Examples of layers (also referred to as functional layers) in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, one of the pair of electrodes may be referred to as a pixel electrode and the other may be referred to as a common electrode.

In this specification and the like, a sacrificial layer (which may also be referred to as a mask layer) refers to a layer that is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is divided because of the shape of its formation surface (e.g., a step).

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

### Embodiment 1

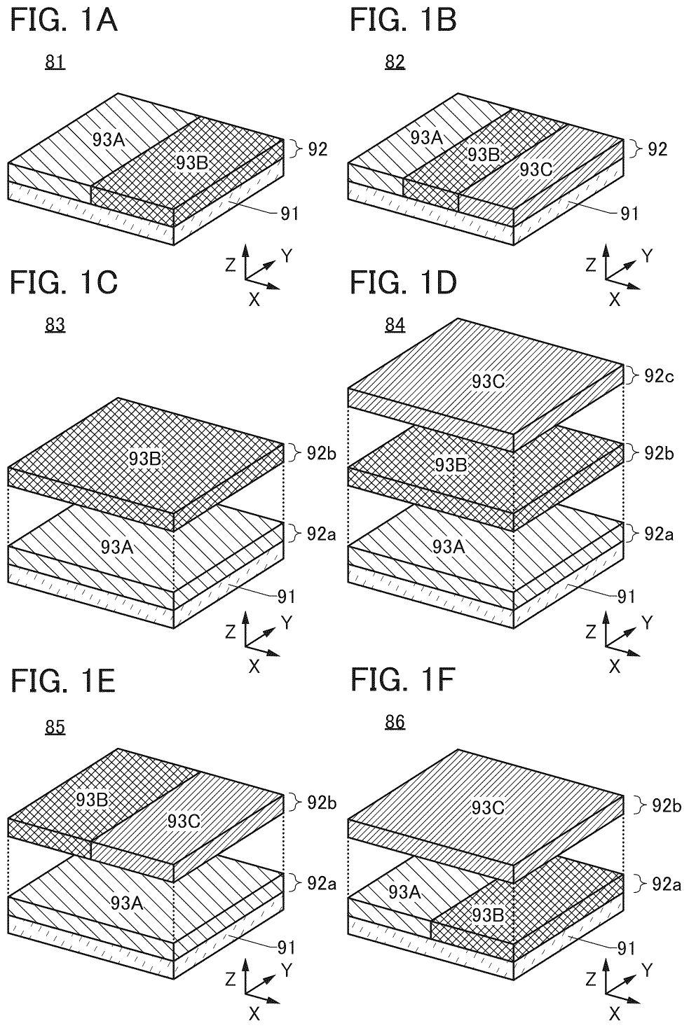

In this embodiment, semiconductor devices of embodiments of the present invention will be described with reference to FIGS. 1A to 1F. The semiconductor devices of this embodiment can each function as a memory device.

FIGS. 1A to 1F are schematic perspective views illustrating the semiconductor devices. The semiconductor devices illustrated in FIGS. 1A to 1F each include a layer 91 and one or more layers 92 over the layer 91.

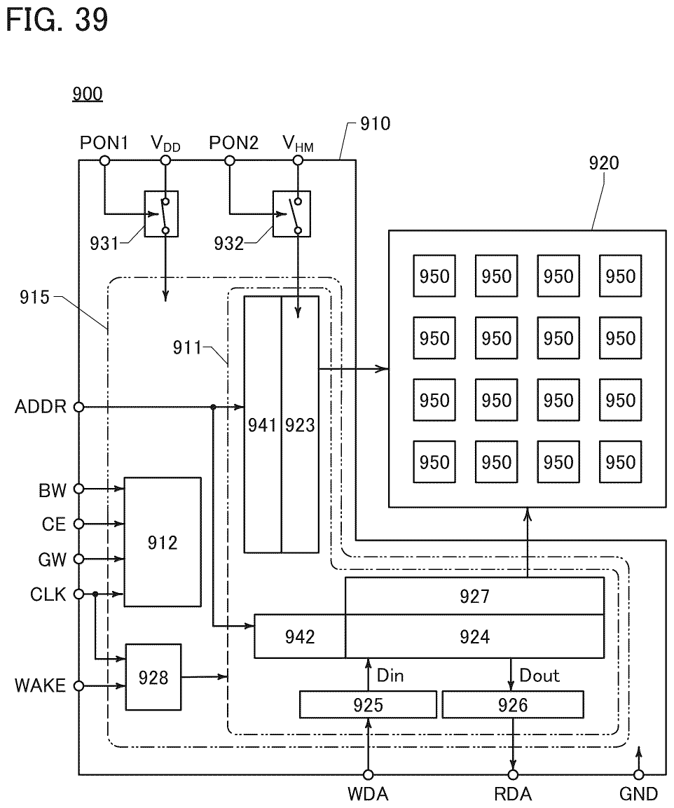

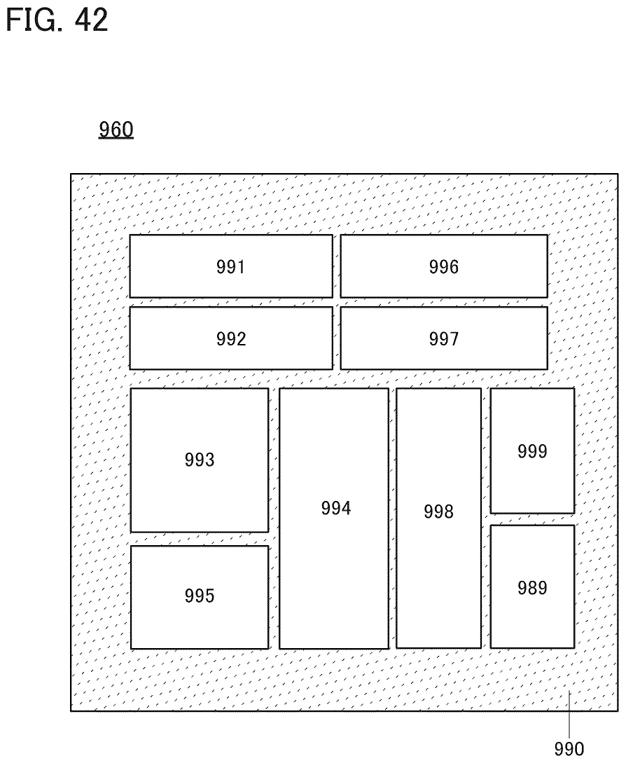

The layer 91 can have, for example, a structure usable for a driver circuit 910 (FIG. 39) to be described later or a structure usable for an arithmetic device 960 (FIG. 42) to be described later. Specifically, the layer 91 includes a reading circuit, for example. The layer 91 preferably includes a transistor containing silicon in its channel formation region.

One layer 92 includes at least one kind of memory cell array 93. Description is made below on the assumption that one memory cell array 93 includes one kind of memory cell. The memory cell array 93 includes one or more memory cells. For example, the memory cell array 93 includes a plurality of memory cells arranged in a matrix. In the memory cell array 93, a plurality of memory cells can be arranged in at least one of the X direction, the Y direction, and the Z direction.

The semiconductor device of one embodiment of the present invention includes at least two kinds of memory cell arrays 93. Examples of a memory cell usable for each memory cell array 93 include a memory cell composed of one transistor and one capacitor (hereinafter referred to as a 1Tr1C memory cell), a memory cell composed of two transistors and one capacitor (hereinafter referred to as a 2Tr1C memory cell), and a memory cell composed of two transistors (hereinafter referred to as a 2Tr0C memory cell). Note that the structure of the memory cell is not limited thereto; two or more transistors (typically, two to six transistors) and one or more capacitors (typically, one to five capacitors) can be used in combination.

When the semiconductor device includes two or more kinds of memory cells, a memory cell to be used can be selected depending on the intended use. This allows the memory device to achieve all of high-speed writing, high-speed reading, and low power consumption.

For example, in a 1Tr1C memory cell, stored data is erased in reading (also referred to as destructive reading). Meanwhile, in 2Tr0C and 2Tr1C memory cells, stored data is not erased in reading (also referred to as non-destructive reading). The semiconductor device of one embodiment of the present invention preferably includes a plurality of kinds of such memory cells that perform different operations.

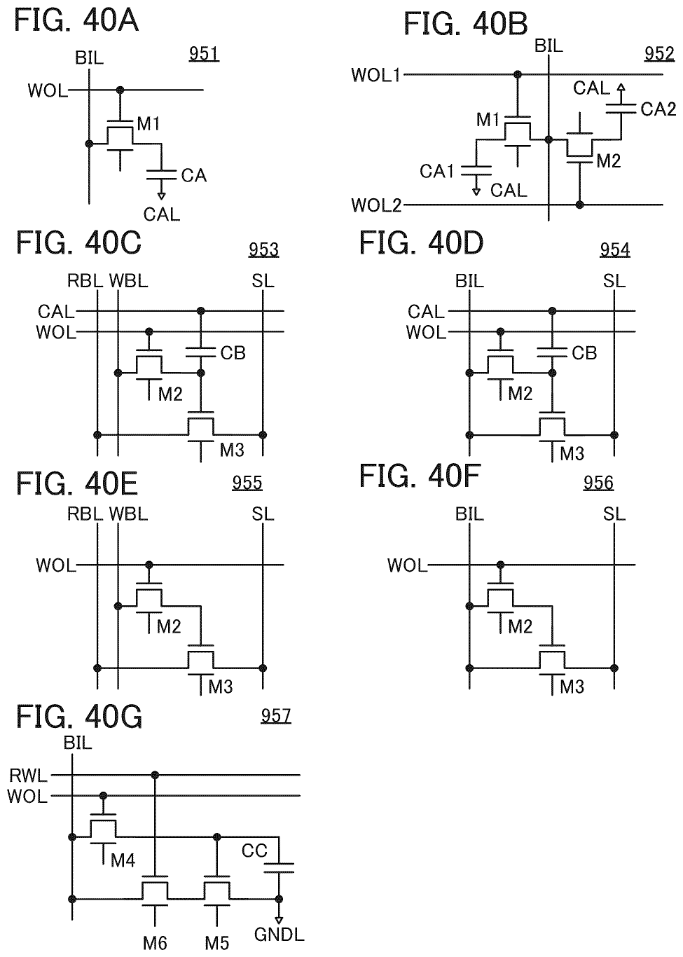

The semiconductor device of one embodiment of the present invention preferably includes at least one of memory cells illustrated in FIGS. 40A to 40G. Here, a memory cell 951 illustrated in FIG. 40A is an example of the 1Tr1C memory cell. A memory cell 953 illustrated in FIG. 40C and a memory cell 954 illustrated in FIG. 40D are examples of the 2Tr1C memory cell. A memory cell 955 illustrated in FIG. 40E and a memory cell 956 illustrated in FIG. 40F are examples of the 2Tr0C memory cell. The details of the memory cells will be described later.

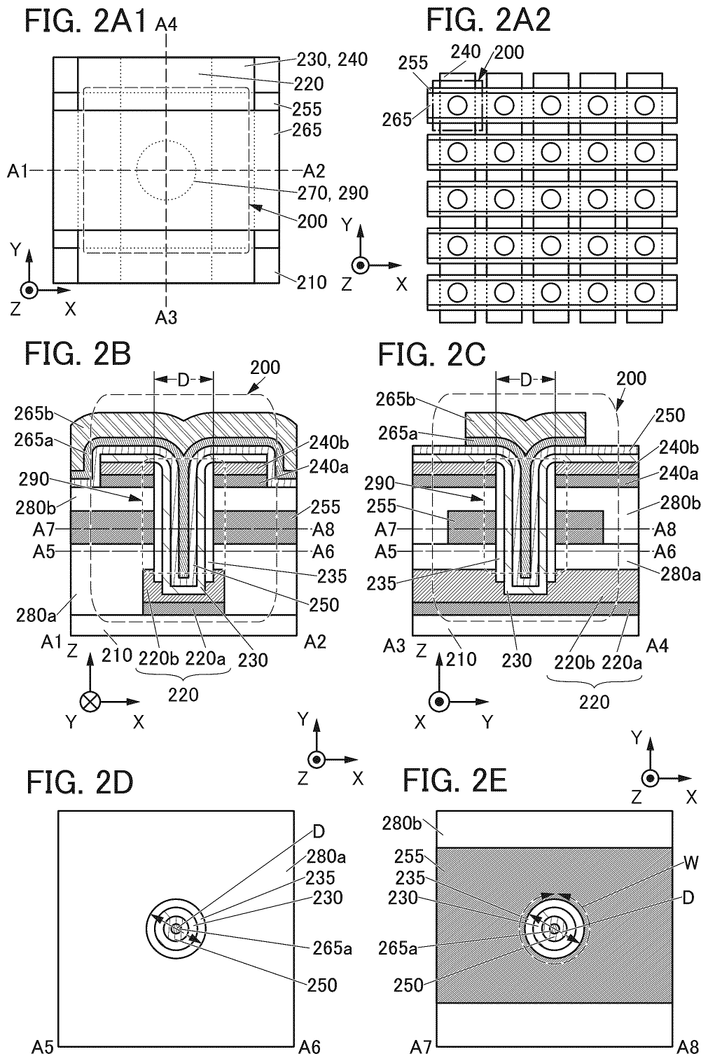

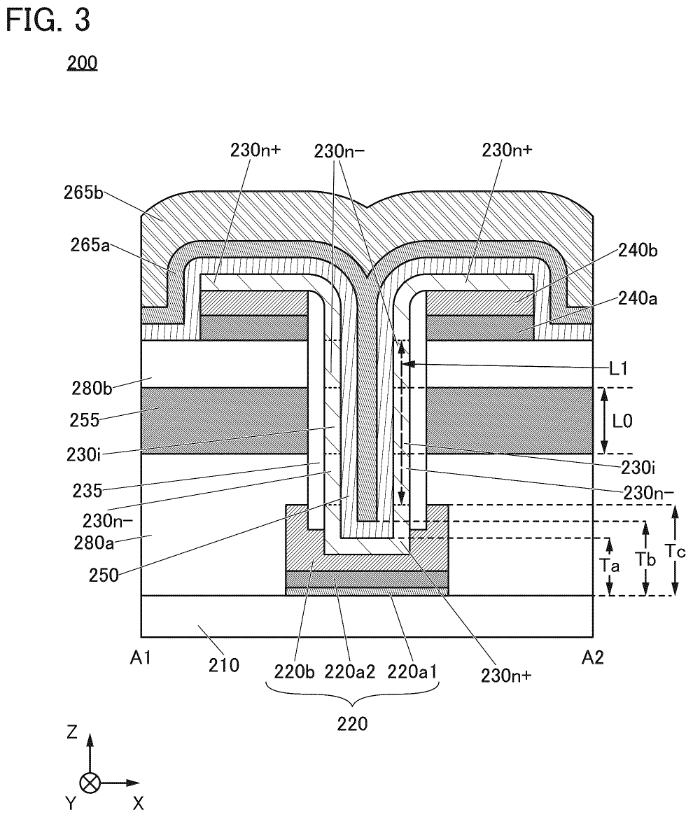

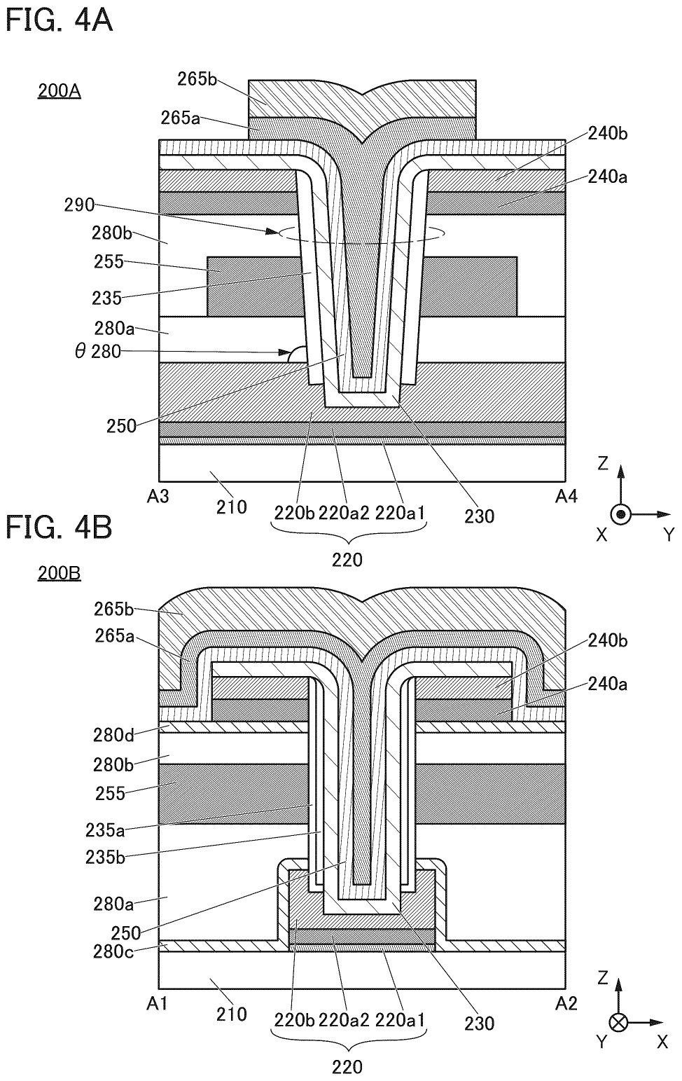

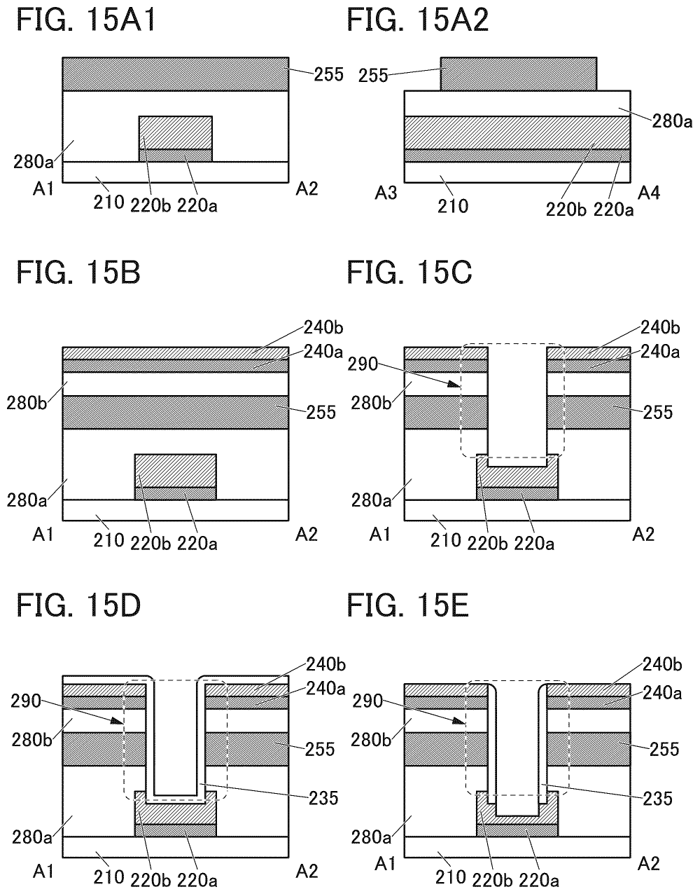

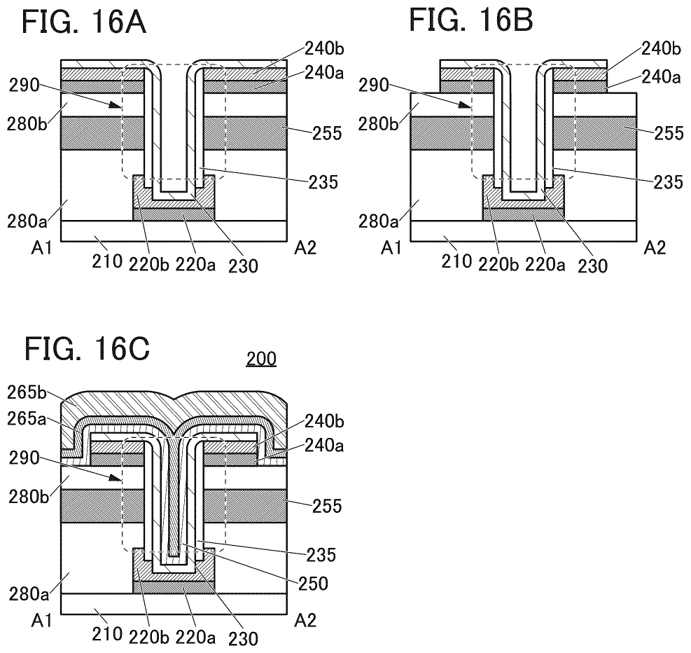

The layer 92 preferably includes a transistor including an oxide semiconductor in its channel formation region. The transistor of one embodiment of the present invention, which includes an oxide semiconductor in its channel formation region and has a low off-state current, is suitable for a memory cell. Thus, the memory cell is substantially nonvolatile. In addition, the transistor of one embodiment of the present invention has a high on-state current and a low off-state current, and thus enables high-speed writing and non-destructive reading. The details of the transistor including an oxide semiconductor in its channel formation region will be described later (see FIGS. 2A1 to 2E, FIG. 3, FIGS. 4A and 4B, FIGS. 5A and 5B, FIGS. 6A to 6D, FIGS. 7A to 7C, FIGS. 8A to 8E, FIGS. 9A and 9B, FIGS. 10A to 10E, FIGS. 11A and 11B, FIGS. 12A to 12E, FIGS. 13A and 13B, FIGS. 14A to 14C2, FIGS. 15A1 to 15E, FIGS. 16A to 16C, FIGS. 17A to 17F, FIGS. 18A to 18F, FIGS. 19A to 19D, and the like).

Note that in this specification and the like, a nonvolatile memory refers to a memory capable of retaining stored data for at least 1 day, preferably 1 or more months, further preferably 1 or more years, still further preferably 10 or more years, without power supply to the memory at 85° C. In this specification and the like, a volatile memory refers to a memory other than the nonvolatile memory.

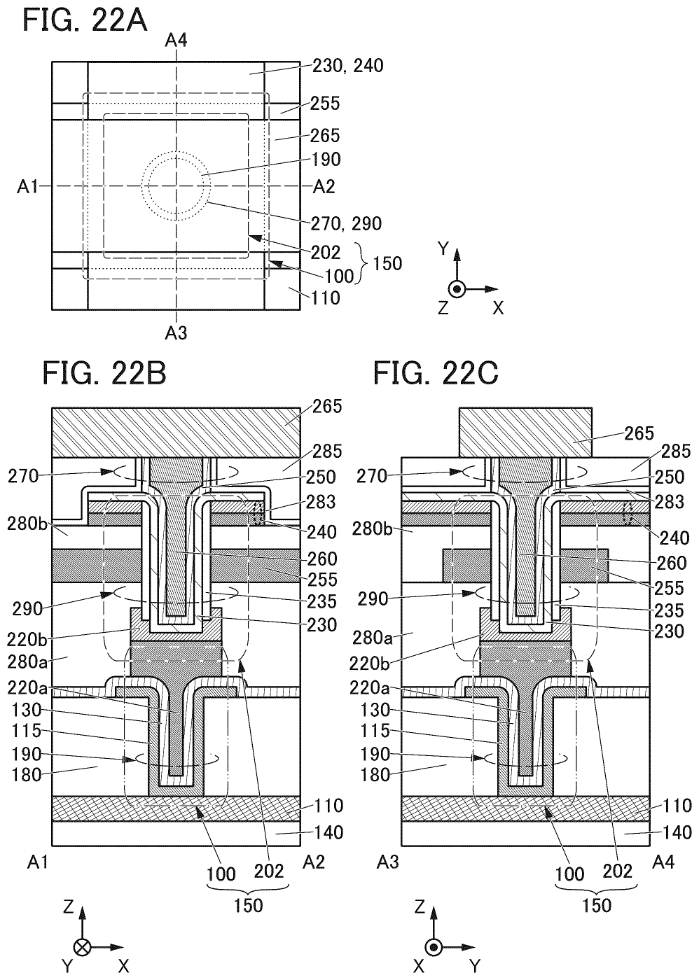

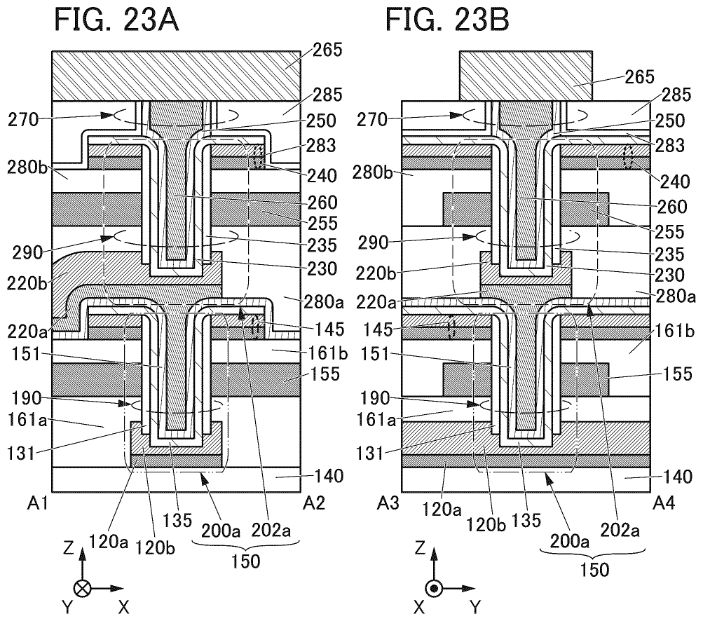

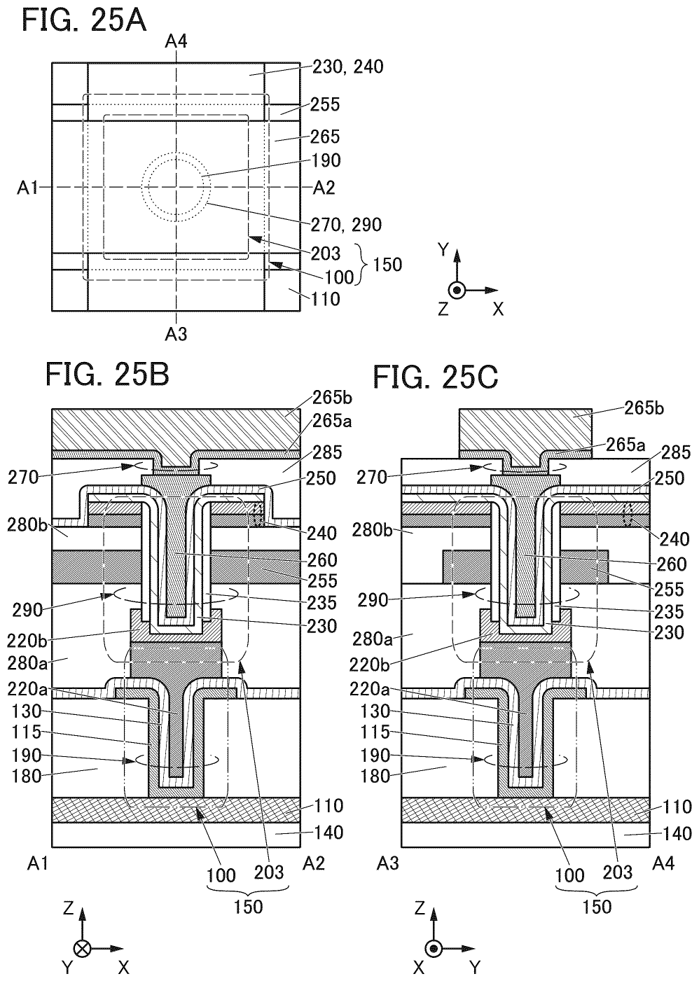

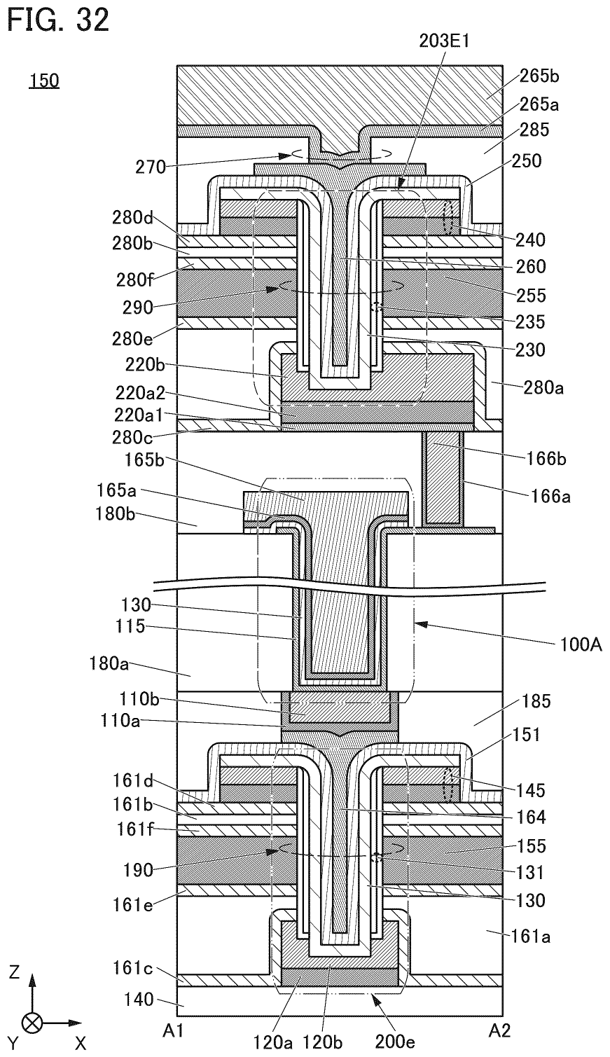

For specific cross-sectional structure examples of the memory cell including the transistor of one embodiment of the present invention, FIGS. 22A to 22C, FIGS. 23A and 23B, FIGS. 24A and 24B, FIGS. 25A to 25C, FIGS. 26A and 26B, FIGS. 27A and 27B, FIG. 28, FIG. 29, FIG. 30, FIG. 31, FIG. 32, and the like can be referred to. Here, memory cells illustrated in FIGS. 22A to 22C and FIGS. 25A to 25C are examples of the 1Tr1C memory cell. Memory cells illustrated in FIGS. 23A and 23B, FIGS. 24A and 24B, FIGS. 26A and 26B, FIGS. 27A and 27B, FIG. 28, FIG. 29, FIG. 30, and FIG. 31 are examples of the 2Tr0C memory cell. The 2Tr0C memory cell can be used as a high-speed writing memory or a write mostly memory, for example. A memory cell illustrated in FIG. 32 is an example of the 2Tr1C memory cell. When OS transistors are used for the 2Tr1C memory cell, a nonvolatile function can be given to a dynamic random access memory (DRAM) or a static random access memory (SRAM), for example. Note that the 1Tr1C and 2Tr1C memory cells can each be used as a random access memory (RAM). The details of these cross-sectional structures will be described later.

The memory cells illustrated in FIGS. 22A to 32 each include a vertical transistor including an oxide semiconductor in its semiconductor layer. The vertical transistor has high on-state current characteristics, high frequency characteristics, and low off-state current characteristics, and thus enables the memory cell to have a substantially nonvolatile function and perform high-speed writing and non-destructive reading.

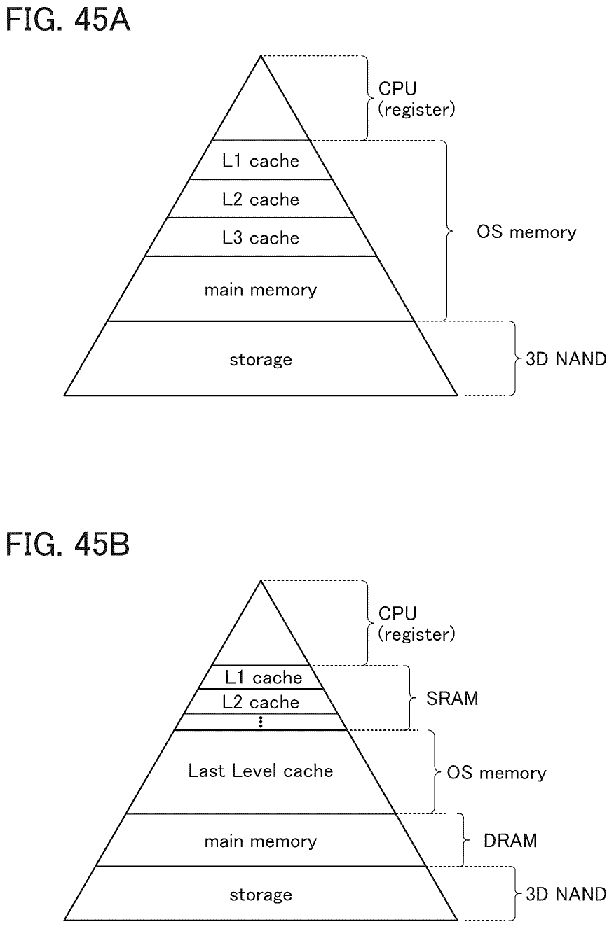

Note that the semiconductor device of one embodiment of the present invention has a function of reading and writing data from and to a storage (typically, a high-capacity nonvolatile memory device such as a 3D NAND memory device) retaining data that needs to be stored for a long time, programs used in an arithmetic processing device, or the like (for the details, refer to Embodiment 6 and FIG. 45 to be described later). The 3D NAND memory device functions as a read mostly memory because of its characteristics.

A semiconductor device 81 illustrated in FIG. 1A and a semiconductor device 82 illustrated in FIG. 1B each include one layer 92 over the layer 91. The layer 92 of the semiconductor device 81 includes a memory cell array 93A and a memory cell array 93B. The layer 92 of the semiconductor device 82 includes the memory cell array 93A, the memory cell array 93B, and a memory cell array 93C.

The memory cell arrays 93A and 93B preferably include memory cells with different circuit structures. For example, the memory cell array 93A preferably includes any one of the 1Tr1C, 2Tr0C, and 2Tr1C memory cells, and the memory cell array 93B preferably includes another one of the 1Tr1C, 2Tr0C, and 2Tr1C memory cells. Specifically, the 1Tr1C memory cell is preferably used for one of the memory cell arrays 93A and 93B, and the 2Tr0C memory cell is preferably used for the other.

The memory cell arrays 93A, 93B, and 93C preferably include memory cells with different circuit structures. For example, the memory cell array 93A preferably includes any one of the 1Tr1C, 2Tr0C, and 2Tr1C memory cells, the memory cell array 93B preferably includes another one of the 1Tr1C, 2Tr0C, and 2Tr1C memory cells, and the memory cell array 93C preferably includes the remaining one of the 1Tr1C, 2Tr0C, and 2Tr1C memory cells.

Alternatively, two or more of the memory cell arrays 93A, 93B, and 93C may include memory cells with the same circuit structure. For example, two or more of the memory cell arrays 93A, 93B, and 93C may include memory cells with the same circuit structure (1Tr1C, 2Tr0C, 2Tr1C, or the like), and the number, size, and the like of the memory cells may be different from each other. Using a plurality of memory cell arrays different in performance, specifications, and the like in this manner enables a multifunctional semiconductor device, even when the memory cells have the same circuit structure.

When two or more kinds of memory cell arrays 93 are provided in one layer 92 in this manner, a semiconductor device with a combination of a plurality of kinds of memory cells can be obtained. The combination of a plurality of kinds of memory cells enables the semiconductor device to have a function between a write mostly memory and a read mostly memory.

Note that the semiconductor device of one embodiment of the present invention is suitable for an arithmetic processing device typified by a CPU, a graphics processing unit (GPU), or the like. A CPU, a GPU, a memory, and the like has been required to have higher performance with progress of artificial intelligence (AI) technology. Meanwhile, in the AI technology, the same data or similar data is repeatedly used in some cases. Thus, a memory to be used is selected depending on data to be stored. For example, important data not to be erased is stored in a memory having a long data retention time, and the same data, similar data, or data to be retained temporarily is stored in a memory having a relatively short data retention time. As described above, the semiconductor device of one embodiment of the present invention can use different memory cells depending on the intended use.

As a method for stacking the layer 92 including the memory cell array and the layer 91, a method in which the layer 92 is stacked directly over the layer 91 (also referred to as a monolithic stacking method) can be used. The monolithic stacking method is suitable for miniaturization because alignment or attachment of the layers 91 and 92 for connecting the layers is unnecessary. Note that in the case of using the monolithic stacking method, on the assumption that the layer 91 is a processor and the layer 92 is a memory, for example, what is called an on-chip memory structure where a memory is formed directly over a processor can be obtained. The on-chip memory structure allows an interface portion between the processor and the memory to operate at high speed. With the on-chip memory structure, the sizes of a connection wiring and the like can be small; thus, the number of connection pins can be increased. The increase in the number of connection pins enables parallel operations, which can improve the bandwidth of the memory (also referred to as a memory bandwidth).

Alternatively, an attaching method or a bonding method may be employed where the layers 91 and 92 are formed over different substrates, and the different substrates are attached and electrically connected to each other with a through electrode technique such as a through silicon via (TSV) or a bonding method using a conductive film (Cu—Cu bonding or the like). The memory cell arrays 93A and 93B may be formed over the same substrate or different substrates. The same applies to the case where three or more kinds of memory cell arrays 93 are provided.

In the case where a plurality of kinds of memory cell arrays 93 are provided in one layer 92, the memory cell arrays 93 have equally divided regions in the examples illustrated in FIG. 1A and the like; however, the present invention is not limited thereto. For example, one of the memory cell arrays 93A and 93B may occupy a larger area on the top surface of the layer 91 than the other. The same applies to the case where three or more kinds of memory cell arrays 93 are provided. The external shapes of the layers 91 and 92 may be the same or different from each other.

A semiconductor device 83 illustrated in FIG. 1C includes two layers 92 over the layer 91. Specifically, the semiconductor device 83 includes the layer 91, a layer 92a over the layer 91, and a layer 92b over the layer 92a. The layer 92a includes the memory cell array 93A, and the layer 92b includes the memory cell array 93B.

A semiconductor device 84 illustrated in FIG. 1D includes three layers 92 over the layer 91. Specifically, the semiconductor device 84 includes the layer 91, the layer 92a over the layer 91, the layer 92b over the layer 92a, and a layer 92c over the layer 92b. The layer 92a includes the memory cell array 93A, the layer 92b includes the memory cell array 93B, and the layer 92c includes the memory cell array 93C.

With such a stack of the layers 92 including different memory cell arrays 93, a semiconductor device with a combination of a plurality of kinds of memory cells can be obtained.

A semiconductor device 85 illustrated in FIG. 1E and a semiconductor device 86 illustrated in FIG. 1F each include two layers 92 over the layer 91. Specifically, the semiconductor devices 85 and 86 each include the layer 91, the layer 92a over the layer 91, and the layer 92b over the layer 92a. In the semiconductor device 85, the layer 92a includes the memory cell array 93A, and the layer 92b includes the memory cell arrays 93B and 93C. In the semiconductor device 86, the layer 92a includes the memory cell arrays 93A and 93B, and the layer 92b includes the memory cell array 93C.

Note that in the semiconductor devices 83, 85, and 86 illustrated in FIGS. 1C, 1E, and 1F, the layers can be stacked by a variety of methods. For example, the layer 92a can be formed over the layer 91 by the monolithic stacking method, and the layer 92b can be formed over the layer 92a by an attaching method. Note that the present invention is not limited to this example, and the layers 91, 92a, and 92b may be formed by the same stacking method. Note that the above structure can also be employed for the semiconductor device 84 illustrated in FIG. 1D. Specifically, the layers 91, 92a, 92b, and 92c may be formed by the same stacking method or different stacking methods.

In this manner, two or more kinds of memory cell arrays 93 are provided in one layer 92 and a plurality of layers 92 including different memory cell arrays 93 are stacked, whereby a semiconductor device with a combination of a plurality of kinds of memory cells can be obtained. Using the structure of the memory cell of one embodiment of the present invention is expected to reduce the power consumption to 1/1000 of that of a conventional memory cell (e.g., DRAM).

This embodiment can be combined with any of the other embodiments as appropriate. In this specification, in the case where a plurality of structure examples are shown in one embodiment, the structure examples can be combined as appropriate.

### Embodiment 2

In this embodiment, semiconductor devices of embodiments of the present invention and a manufacturing method thereof will be described with reference to FIGS. 2A1 to 2E, FIG. 3, FIGS. 4A and 4B, FIGS. 5A and 5B, FIGS. 6A to 6D, FIGS. 7A to 7C, FIGS. 8A to 8E, FIGS. 9A and 9B, FIGS. 10A to 10E, FIGS. 11A and 11B, FIGS. 12A to 12E, FIGS. 13A and 13B, FIGS. 14A to 14C2, FIGS. 15A1 to 15E, FIGS. 16A to 16C, FIGS. 17A to 17F, FIGS. 18A to 18F, and FIGS. 19A to 19D.

The semiconductor device of one embodiment of the present invention includes an oxide semiconductor layer, first to fourth conductive layers, and first to fourth insulating layers.

The oxide semiconductor layer functions as a semiconductor layer of a transistor, the first conductive layer functions as one of a source electrode and a drain electrode of the transistor, the third conductive layer functions as the other of the source electrode and the drain electrode of the transistor, and the fourth conductive layer functions as a first gate electrode of the transistor. The fourth insulating layer functions as a first gate insulating layer of the transistor. The second conductive layer functions as a second gate electrode, and the third insulating layer functions as a second gate insulating layer.

The first insulating layer is positioned over the first conductive layer. The second conductive layer is positioned over the first insulating layer. The second insulating layer is positioned over the second conductive layer. The third conductive layer is positioned over the second insulating layer. The first conductive layer includes a first depressed portion. The first insulating layer, the second conductive layer, the second insulating layer, and the third conductive layer include a first opening portion in a position overlapping with the first depressed portion. The third insulating layer is in contact with the first conductive layer and is in contact with at least the side surface of the first insulating layer, the side surface of the second conductive layer, and the side surface of the second insulating layer in the first opening portion. The oxide semiconductor layer is in contact with the top surface of the third conductive layer and the bottom and side surfaces of the first depressed portion, and is in contact with the third insulating layer in the first opening portion. The fourth insulating layer is positioned on an inner side of the oxide semiconductor layer in the first opening portion. The fourth conductive layer is positioned on an inner side of the fourth insulating layer in the first opening portion.

In the transistor of one embodiment of the present invention, the first depressed portion is provided in the first conductive layer. Thus, as compared with the case where the first depressed portion is not provided, the levels of the bottom surfaces of the fourth insulating layer and the fourth conductive layer in the first opening portion can be made low. Accordingly, a gate electric field is easily applied to the oxide semiconductor layer, leading to favorable electrical characteristics of the transistor. Here, the levels of the surfaces can be determined using a formation surface of the transistor as a reference, for example.

In a cross-sectional view, the oxide semiconductor layer included in the transistor of one embodiment of the present invention includes a region overlapping with the second conductive layer with the third insulating layer therebetween and overlapping with the fourth conductive layer with the fourth insulating layer therebetween. One of the second conductive layer and the fourth conductive layer functions as a gate, and the other functions as a back gate. When the transistor includes the back gate, the threshold voltage can be easily controlled and a change in the threshold voltage can be inhibited, so that the electrical characteristics and reliability of the transistor can be improved.

Large capacitance generated between a gate wiring and the source electrode or the drain electrode might slow the transistor operation and degrade the frequency characteristics of a circuit including the transistor.

In view of the above, in the transistor of one embodiment of the present invention, parasitic capacitance generated between the third conductive layer and the fourth conductive layer is preferably reduced. In this case, high-speed operation of the transistor can be achieved. A semiconductor device with favorable electrical characteristics can be provided.

For example, it is preferable that the semiconductor device of one embodiment of the present invention further include a fifth insulating layer. In this case, it is preferable that the fourth insulating layer cover the top and side surfaces of the oxide semiconductor layer over the second insulating layer, the fifth insulating layer be positioned over the fourth insulating layer and include a second opening portion in a position overlapping with the first opening portion, and the fourth conductive layer include a portion overlapping with the oxide semiconductor layer with the fourth insulating layer therebetween in the first opening portion and a portion positioned in the second opening portion. Alternatively, it is preferable that the fifth insulating layer be positioned over the second insulating layer, cover the top and side surfaces of the oxide semiconductor layer over the second insulating layer, and include the second opening portion in a position overlapping with the first opening portion. It is preferable that the fourth insulating layer include a portion positioned in the second opening portion, and the fourth conductive layer be positioned on an inner side of the fourth insulating layer in the second opening portion.

The fourth conductive layer includes a portion overlapping with the oxide semiconductor layer with the fourth insulating layer therebetween in the first opening portion and a portion positioned in the second opening portion. In this case, a gate wiring is placed over the fifth insulating layer, so that the physical distance between the third conductive layer and the gate wiring can be increased. Thus, parasitic capacitance generated between the third conductive layer and the gate wiring can be reduced. Note that part of the fourth conductive layer (a portion positioned over the fifth insulating layer) may function as the gate wiring, and another gate wiring may be provided over the fifth insulating layer separately from the fourth conductive layer.

Alternatively, in the transistor of one embodiment of the present invention, parasitic capacitance generated between the third conductive layer and the gate wiring is preferably reduced. In this case, high-speed operation of the transistor can be achieved. A semiconductor device with favorable electrical characteristics can be provided.

For example, the semiconductor device of one embodiment of the present invention preferably includes a fifth conductive layer and a sixth insulating layer in addition to the oxide semiconductor layer, the first to fourth conductive layers, and the first to fourth insulating layers described above. In this case, it is preferable that the sixth insulating layer be positioned over the fourth insulating layer and include the second opening portion reaching the fourth conductive layer in a position overlapping with the first opening portion, and the fifth conductive layer be in contact with the fourth conductive layer in the second opening portion.

The fifth conductive layer functions as a gate wiring. Since the fifth conductive layer is placed over the sixth insulating layer, the physical distance between the third conductive layer and the gate wiring can be increased. Thus, parasitic capacitance generated between the third conductive layer and the gate wiring can be reduced.

Note that a groove (slit) may be provided instead of the opening portion.

In the transistor of one embodiment of the present invention, the source electrode and the drain electrode are positioned at different heights, so that a current flows in the semiconductor layer in the height direction. In other words, the channel length direction includes a height (vertical) component, so that the transistor of one embodiment of the present invention can also be referred to as a vertical field effect transistor (VFET), a vertical transistor, a vertical-channel transistor, or the like.

In the transistor of one embodiment of the present invention, the source electrode, the semiconductor layer, and the drain electrode can be provided to overlap with each other. Thus, the area occupied by the transistor can be significantly smaller than the area occupied by what is called a planar transistor in which a planar semiconductor layer is provided.

The channel length of the transistor of one embodiment of the present invention can be controlled by the thicknesses of the first insulating layer, the second conductive layer, the second insulating layer, and the like. Thus, a transistor with an extremely small channel length, which is difficult to achieve in a planar transistor, can be achieved. Accordingly, a transistor with a small occupation area and a high on-state current can be provided.

When a transistor has a small channel length, the transistor is likely to be normally on due to the influence of what is called short-channel effect (SCE). In contrast, as described above, the transistor of one embodiment of the present invention includes a back gate. Thus, by controlling the threshold voltage, a normally-off transistor is easily achieved. That is, the transistor of one embodiment of the present invention can have a high on-state current, normally-off characteristics, and high reliability even when being miniaturized.

The transistor including an oxide semiconductor has a low off-state current, and thus enables long-term retention of stored contents when used for a memory device, for example. In other words, such a memory device does not require refresh operation or has an extremely low frequency of refresh operation, leading to a sufficient reduction in power consumption. When the transistor of one embodiment of the present invention is used for a memory device, the memory device can be highly integrated and reduced in power consumption.

### Structure Example 1 of Semiconductor Device

A structure of the semiconductor device of one embodiment of the present invention will be described with reference to FIGS. 2A1 to 2E and FIG. 3.

### [Transistor 200]

FIG. 2A1 is a plan view of a semiconductor device including a transistor 200. FIG. 2A2 is a plan view illustrating an example where a plurality of transistors 200 are arranged. FIGS. 2B and 3 are each a cross-sectional view taken along dashed-dotted line A1-A2 in FIG. 2A. FIG. 3 corresponds to an example of an enlarged view of FIG. 2B, and illustrates more details of the structure example of each layer. FIG. 2C is a cross-sectional view taken along dashed-dotted line A3-A4 in FIG. 2A. FIG. 2D is a cross-sectional view taken along dashed-dotted line A5-A6 in FIGS. 2B and 2C. FIG. 2D can also be regarded as a cross-sectional view along an XY plane including an insulating layer 280a. FIG. 2E is a cross-sectional view taken along dashed-dotted line A7-A8 in FIGS. 2B and 2C. FIG. 2E can also be regarded as a cross-sectional view along the XY plane including a conductive layer 255. Note that for simplification, some components are not illustrated in the plan view in FIG. 2A1. Some components are omitted also in the following plan views in some cases.

The semiconductor device illustrated in FIGS. 2A1, 2B to 2E, and 3 includes an insulating layer 210 over a substrate (not illustrated), the transistor 200 over the insulating layer 210, the insulating layer 280a over the insulating layer 210, and an insulating layer 280b over the insulating layer 280a. The insulating layers 210, the insulating layer 280a, and the insulating layer 280b function as interlayer films.

The transistor 200 includes a conductive layer 220a, a conductive layer 220b over the conductive layer 220a, the conductive layer 255 over the insulating layer 280a, a conductive layer 240a over the insulating layer 280b, a conductive layer 240b over the conductive layer 240a, an insulating layer 235, an oxide semiconductor layer 230, an insulating layer 250 over the oxide semiconductor layer 230, a conductive layer 265a over the insulating layer 250, and a conductive layer 265b over the conductive layer 265a.

Hereinafter, the conductive layer 220a and the conductive layer 220b are collectively referred to as a conductive layer 220 in some cases. Furthermore, the conductive layer 240a and the conductive layer 240b are collectively referred to as a conductive layer 240 in some cases. Furthermore, the conductive layer 265a and the conductive layer 265b are collectively referred to as a conductive layer 265 in some cases.

In the transistor 200, the oxide semiconductor layer 230 functions as a semiconductor layer, the conductive layer 265 functions as a first gate electrode, the insulating layer 250 functions as a first gate insulating layer, the conductive layer 220 functions as one of a source electrode and a drain electrode, the conductive layer 240 functions as the other of the source electrode and the drain electrode, the conductive layer 255 functions as a second gate electrode, and the insulating layer 235 functions as a second gate insulating layer. The conductive layer 265 functions also as a gate wiring. As illustrated in FIG. 2A2, the conductive layer 240 and the conductive layer 255 can each function as a wiring.

It is preferable that the conductive layer 265 function as a gate electrode and the conductive layer 255 function as a back gate electrode. In this case, the insulating layer 250 functions as a gate insulating layer, and the insulating layer 235 functions as a back gate insulating layer. Note that the conductive layer 265 may function as the back gate electrode and the conductive layer 255 may function as the gate electrode.

The oxide semiconductor layer 230 includes a region overlapping with the conductive layer 255 with the insulating layer 235 therebetween and overlapping with the conductive layer 265a with the insulating layer 250 therebetween. At least part of the region functions as the channel formation region of the transistor 200. One of a region of the oxide semiconductor layer 230 which is in contact with the conductive layer 220 and a region of the oxide semiconductor layer 230 which is in contact with the conductive layer 240 functions as a source region, and the other functions as a drain region. That is, the channel formation region is interposed between the source region and the drain region.

As illustrated in FIGS. 2B and 2C, an opening portion 290 reaching the conductive layer 220 is provided in the insulating layer 280a, the conductive layer 255, the insulating layer 280b, the conductive layer 240a, and the conductive layer 240b.

The conductive layer 220 includes the conductive layer 220a and the conductive layer 220b over the conductive layer 220a, and a depressed portion is provided in the conductive layer 220b. In other words, the conductive layer 220 includes a depressed portion, the bottom surface of the depressed portion corresponds to the bottom surface of the depressed portion of the conductive layer 220b, and the side surface of the depressed portion corresponds to the side surface of the depressed portion of the conductive layer 220b. Specifically, the conductive layer 220b includes a first depressed portion and a second depressed portion positioned on an outer side of the first depressed portion. The depth of the first depressed portion is greater than that of the second depressed portion. The second depressed portion is provided in the conductive layer 220b at the time of forming the opening portion 290, and then the first depressed portion is provided in the conductive layer 220b at the time of processing the insulating layer 235. Thus, in FIG. 2B and the like, the side surface of the first depressed portion is aligned with a surface of the insulating layer 235 on the oxide semiconductor layer 230 side, and the side surface of the second depressed portion is aligned with surfaces of the insulating layer 280a and the like on the opening portion 290 side. Hereinafter, the first depressed portion and the second depressed portion are collectively referred to as a depressed portion in some cases.

The opening portion 290 overlaps with the depressed portion of the conductive layer 220b. Here, the bottom portion of the opening portion 290 includes the bottom surface of the depressed portion of the conductive layer 220b, and the sidewall of the opening portion 290 includes the side surface of the depressed portion of the conductive layer 220b, the side surface of the insulating layer 280a, the side surface of the conductive layer 255, the side surface of the insulating layer 280b, the side surface of the conductive layer 240a, and the side surface of the conductive layer 240b.

The opening portion 290 includes an opening portion included in the insulating layer 280a, an opening portion included in the conductive layer 255, an opening portion included in the conductive layer 280b, an opening portion included in the conductive layer 240a, and an opening portion included in the conductive layer 240b. In other words, the opening portion included in a region where the insulating layer 280a overlaps with the conductive layer 220a is part of the opening portion 290, the opening portion included in a region where the conductive layer 255 overlaps with the conductive layer 220a is another part of the opening portion 290, the opening portion included in a region where the insulating layer 280b overlaps with the conductive layer 220a is another part of the opening portion 290, the opening portion included in a region where the conductive layer 240a overlaps with the conductive layer 220a is another part of the opening portion 290, and the opening portion included in a region where the conductive layer 240b overlaps with the conductive layer 220a is another part of the opening portion 290. The shape and the size of the opening portion 290 in the plan view may differ from layer to layer. When the opening portion 290 has a circular top-view shape, the opening portions included in the layers may be, but not necessarily concentrically arranged.

At least part of the components of the transistor 200 is placed in the opening portion 290. Specifically, the insulating layer 235, the oxide semiconductor layer 230, the insulating layer 250, and the conductive layer 265 are placed to be positioned in the opening portion 290 at least partly.

The insulating layer 235 includes at least a region positioned between the oxide semiconductor layer 230 and the conductive layer 255. The oxide semiconductor layer 230 is in contact with the insulating layer 235 in the opening portion 290.

In FIG. 2B and the like, the insulating layer 235 is in contact with the bottom and side surfaces of the depressed portion (specifically, the second depressed portion) of the conductive layer 220, and is in contact with the side surfaces of the insulating layer 280a, the conductive layer 255, the insulating layer 280b, the conductive layer 240a, and the conductive layer 240b in the opening portion 290. The oxide semiconductor layer 230 is in contact with the bottom and side surfaces of the depressed portion (specifically, the first depressed portion) of the conductive layer 220, the insulating layer 235, and the top surface of the conductive layer 240b. The insulating layer 250 is positioned on an inner side of the oxide semiconductor layer 230 in the opening portion 290, and the conductive layer 265a is positioned on an inner side of the insulating layer 250 in the opening portion 290.

The insulating layer 235 is provided along at least part of the sidewall of the opening portion 290. Portions of the oxide semiconductor layer 230 and the insulating layer 250 which are placed in the opening portion 290 reflect the shape of the opening portion 290. Specifically, the oxide semiconductor layer 230 is provided to cover the bottom portion and the sidewall of the opening portion 290, and the insulating layer 250 is provided to cover the oxide semiconductor layer 230. Then, the conductive layer 265a is provided to fill at least part of a depressed portion of the insulating layer 250 reflecting the shape of the opening portion 290.

In the transistor of one embodiment of the present invention, at least one layer included in the conductive layer 265 is provided in the opening portion 290. In the case where the conductive layer 265 has a stacked-layer structure, it becomes more difficult to place all the layers included in the conductive layer 265 in the opening portion 290 as the diameter of the opening portion 290 becomes smaller with progress of miniaturization of the transistor 200. FIGS. 2B and 2C illustrate an example where the conductive layer 265 has a two-layer structure, only the conductive layer 265a is provided in the opening portion 290, and the conductive layer 265b over the conductive layer 265a is provided in a position overlapping with the opening portion 290. Note that both of the conductive layers 265a and 265b are positioned in the opening portion 290 in some cases depending on the diameter of the opening portion 290, the thickness of the conductive layer 265a, and the like.

When the conductive layer 220b includes the depressed portion in a position overlapping with the opening portion 290, unlike in the case where the depressed portion is not provided, the levels of the bottom surfaces of the insulating layer 250 and the conductive layer 265a in the opening portion 290 can be lower than the level of the top surface of the conductive layer 220b which is in contact with the insulating layer 280a, with the top surface of the insulating layer 210 used as a reference. Here, the levels of the surfaces can be determined using the formation surface of the transistor as a reference. Here, the top surface of the insulating layer 210 is used as the reference. The surface used as the reference is not limited to the formation surface of the transistor. For example, the top surface of the substrate where the transistor or the semiconductor device is provided may be used as the reference.

As illustrated in FIG. 3, a shortest distance Tc from the top surface of the insulating layer 210 to the top surface of the conductive layer 220b which is in contact with the insulating layer 280a is preferably longer than a shortest distance Ta from the top surface of the insulating layer 210 to the bottom surface of the insulating layer 250. Accordingly, the contact area between the side surface of the conductive layer 220b and the oxide semiconductor layer 230 can be increased, so that the contact resistance therebetween can be reduced. This can inhibit a decrease in on-state current of the transistor 200 due to the contact resistance between the conductive layer 220b and the oxide semiconductor layer 230. Note that the shortest distance Ta can be determined on the basis of the bottom surface of the insulating layer 250 in the opening portion 290.

As illustrated in FIG. 3, the shortest distance Te is preferably longer than or equal to a shortest distance Tb from the top surface of the insulating layer 210 to the bottom surface of the conductive layer 265a, further preferably longer than the shortest distance Tb. Thus, a gate electric field is easily applied to the channel formation region of the oxide semiconductor layer 230, so that the electrical characteristics of the transistor 200 can be improved. Furthermore, a gate electric field is easily applied to a region of the oxide semiconductor layer 230 which is in contact with the conductive layer 220b, so that the on-state current of the transistor 200 can be increased. The electrical characteristics of the transistor 200 can be improved when either the conductive layer 220 or the conductive layer 240 is used as the drain electrode. Note that the shortest distance Tb can be determined on the basis of the bottom surface of the conductive layer 265a in the opening portion 290.

The oxide semiconductor layer 230 is in contact with the bottom and side surfaces of the depressed portion of the conductive layer 220b and the top surface of the conductive layer 240b. When the conductive layer 220b includes a depressed portion, the contact area between the oxide semiconductor layer 230 and the conductive layer 220b can be increased. Thus, the contact resistance between the oxide semiconductor layer 230 and the conductive layer 220b can be reduced.

A conductive material containing oxygen is preferably used for the conductive layer 220b. Accordingly, the contact resistance between the oxide semiconductor layer 230 and the conductive layer 220b can be reduced.

In the case where the conductive layer 220 and the conductive layer 240 each have a stacked-layer structure, a conductive material containing oxygen is preferably used for a layer having the largest contact area with the oxide semiconductor layer 230 in the stacked-layer structure, in which case the contact resistance with the oxide semiconductor layer 230 can be reduced. Thus, for example, a conductive material containing oxygen is preferably used for the conductive layer 220b and the conductive layer 240b.

Alternatively, in the case where the conductive layer 220 and the conductive layer 240 each have a stacked-layer structure, the use of a conductive material containing oxygen for the layer closest to the channel formation region in the stacked-layer structure can reduce the contact resistance with the oxide semiconductor layer 230, which allows a short current path between the source and the drain and thus can increase the on-state current of the transistor. Therefore, a conductive material containing oxygen is preferably used for the conductive layer 220b and the conductive layer 240a, for example.

As a conductive material containing oxygen, a metal oxide having conductivity (also referred to as an oxide conductor) is preferably used.

FIG. 2B illustrates a structure where an end portion of the conductive layer 240a, an end portion of the conductive layer 240b, and an end portion of the oxide semiconductor layer 230 are aligned with each other outside the opening portion 290. As in a manufacturing method example described later, the conductive layer 240a, the conductive layer 240b, and the oxide semiconductor layer 230 can be formed by processing with the use of the same mask. This is preferable because the number of masks required for manufacturing the semiconductor device can be reduced. Note that the present invention is not limited thereto. For example, in the X direction or the Y direction, any one of the end portion of the oxide semiconductor layer 230, the end portion of the conductive layer 240a, and the end portion of the conductive layer 240b may be positioned inward or outward from the others.

The conductive layer 240 includes the opening portion 290 in a region overlapping with the conductive layer 220. The conductive layer 240 is preferably not positioned in the opening portion 290 included in the insulating layer 280b and the like. That is, the conductive layer 240 preferably does not include a region in contact with the side surface of the insulating layer 280b in the opening portion 290. With such a structure, the opening portion 290 can be formed in the conductive layer 240, the insulating layer 280b, the conductive layer 255, and the insulating layer 280a at once. Furthermore, when the side surfaces of the conductive layer 240, the insulating layer 280b, the conductive layer 255, and the insulating layer 280a are aligned with each other in the opening portion 290, the thickness distributions of the insulating layer 235, the oxide semiconductor layer 230, and the like provided in the opening portion 290 can be uniform. In addition, the insulating layer 235, the oxide semiconductor layer 230, and the like can be inhibited from being divided by a step formed by the conductive layer 240 and the insulating layer 280b, for example.

Although FIGS. 2B and 2C illustrate the structure where the side surface of the conductive layer 240 in the opening portion 290 and the side surface of the insulating layer 280b in the opening portion 290 are on the same plane (also referred to as being aligned or substantially aligned with other), the present invention is not limited thereto. For example, the side surface of the conductive layer 240 in the opening portion 290 and the side surface of the insulating layer 280b in the opening portion 290 may be discontinuous. The inclination of the side surface of the conductive layer 240 in the opening portion 290 and the inclination of the side surface of the insulating layer 280b in the opening portion 290 may be different from each other. At this time, for example, the taper angle of the side surface of the conductive layer 240 in the opening portion 290 is preferably smaller than that of the side surface of the insulating layer 280b in the opening portion 290. With such a structure, the coverage of the side surface of the conductive layer 240 with the oxide semiconductor layer 230 in the opening portion 290 is improved, so that defects such as voids can be reduced. In the case where the insulating layers 280a and 280b each have a stacked-layer structure, the inclinations of the side surfaces of the layers in the opening portion 290 may be different from each other. Similarly, in the case where the conductive layer 240 has a stacked-layer structure, the inclinations of the side surfaces of the layers in the opening portion 290 may be different from each other.

The transistor 200 includes a metal oxide functioning as a semiconductor (also referred to as an oxide semiconductor) in the oxide semiconductor layer 230 including a channel formation region. That is, the transistor 200 can be regarded as an OS transistor.

When oxygen vacancies (V_{O}) and impurities are in a channel formation region of an oxide semiconductor in an OS transistor, electrical characteristics of the OS transistor easily vary and the reliability thereof might worsen. In some cases, hydrogen in the vicinity of an oxygen vacancy forms a defect that is an oxygen vacancy into which hydrogen enters (hereinafter sometimes referred to as V_{O}H), which generates an electron serving as a carrier. Thus, when the channel formation region of the oxide semiconductor includes oxygen vacancies, the OS transistor is likely to be normally on. Therefore, the oxygen vacancies and the impurities are preferably reduced as much as possible in the channel formation region of the oxide semiconductor. In other words, the oxide semiconductor preferably includes an i-type (intrinsic) or substantially i-type channel formation region with a low carrier concentration.

Meanwhile, preferably, the source region and the drain region of the OS transistor include more oxygen vacancies, include more V_{O}H, or have a higher concentration of an impurity such as hydrogen, nitrogen, or a metal element than the channel formation region, and thus are low-resistance regions with high carrier concentrations. In other words, the source region and the drain region of the OS transistor are preferably n-type regions having higher carrier concentrations and lower resistances than the channel formation region.

As described above, the oxide semiconductor layer 230 is provided in the opening portion 290. The transistor 200 has a structure where one of the source electrode and the drain electrode (here, the conductive layer 220) is in a lower position and the other of the source electrode and the drain electrode (here, the conductive layer 240) is in an upper position, and thus a current flows in the vertical direction. That is, a channel is formed along the side surface of the opening portion 290.

The positional relationship of the layers in the opening portion 290 is described with reference to FIGS. 2D and 2E. The insulating layer 235 is in contact with the outer surface of the oxide semiconductor layer 230. The conductive layer 255 surrounds all the perimeter of the oxide semiconductor layer 230 with the insulating layer 235 therebetween. The insulating layer 250 is in contact with the outer surface of the conductive layer 265a. The oxide semiconductor layer 230 surrounds all the perimeter of the conductive layer 265a with the insulating layer 250 therebetween. Thus, the channel formation region of the transistor 200 can be formed in a region of the oxide semiconductor layer 230 along its entire surface on the insulating layer 235 side in the opening portion 290 (the entire region in contact with the insulating layer 235). Note that FIG. 2E can be regarded as a cross-sectional view along the XY plane including the channel formation region of the oxide semiconductor layer 230.

The channel length of the transistor 200 can be regarded as a distance between the source region and the drain region. That is, the channel length of the transistor 200 is determined by the thicknesses of the insulating layer 280a, the conductive layer 255, the insulating layer 280b, and the like over the conductive layer 220.

Since the transistor 200 includes the conductive layer 255 functioning as the back gate, the threshold voltage of the transistor 200 can be controlled by a potential supplied to the conductive layer 255. At this time, a portion of the oxide semiconductor layer 230 overlapping with the conductive layer 255 with the insulating layer 235 therebetween is most likely to be affected by the conductive layer 255. Thus, in FIG. 3, the oxide semiconductor layer 230 is divided into three regions: a region 230n⁺, a region 230n⁻, and a region 230i. The region 230i corresponds to the portion of the oxide semiconductor layer 230 overlapping with the conductive layer 255 with the insulating layer 235 therebetween.

The region 230n⁺ is formed in and around a region of the oxide semiconductor layer 230 which is in contact with the conductive layer 240b or the conductive layer 220b, and can be referred to as the source region or the drain region. The source and drain regions are n-type regions (low-resistance regions) having a higher carrier concentration than the channel formation region.

The region 230i is a region of the oxide semiconductor layer 230 overlapping with the conductive layer 255 with the insulating layer 235 therebetween and overlapping with the conductive layer 265a with the insulating layer 250 therebetween, and can be referred to as a channel formation region. The channel formation region is preferably controlled to be an i-type (intrinsic) or substantially i-type region with a potential supplied to the conductive layer 255.

The region 230n⁻ is preferably a region having higher resistance than the region 230n⁺ and lower resistance than the region 230i. When there is a high-resistance region between the region 230i and the region 230n⁺, the on-state current of the transistor 200 might decrease. When the region 230n⁻ has relatively low resistance, the on-state current of the transistor 200 can be increased in some cases. Note that the region 230n⁻ also functions as the channel formation region in some cases.

As described above, in the case where the channel length of the transistor 200 is regarded as the distance between the source region and the drain region, the channel length of the transistor 200 can be referred to as a length L1. Meanwhile, since the region 230n⁻ has lower resistance than the region 230i, the channel formation region of the transistor 200 can be regarded as the region 230i that is controlled so as to be a high-resistance region by the conductive layer 255. In that case, the channel length of the transistor 200 can be regarded as a length L0 of the region 230i that is shorter than the length L1. At this time, the length L0 can also be referred as an effective channel length of the transistor 200.

When the region 230n″ has low resistance and the effective channel length of the transistor is small, the transistor is likely to be normally on. Meanwhile, the transistor of one embodiment of the present invention includes a back gate. When a potential lower than or equal to a source potential or a potential lower than or equal to 0 V (preferably a negative potential) is supplied to the back gate, the threshold voltage of the transistor can be shifted positively and the transistor can be normally off. Accordingly, the transistor of one embodiment of the present invention can have both a high on-state current and normally-off characteristics.

Note that in the transistor of one embodiment of the present invention, one of the conductive layer 255 and the conductive layer 265 may be used as the gate and the other may be used as the back gate. In the transistor of one embodiment of the present invention, it is particularly suitable to use the conductive layer 265 as the gate and use the conductive layer 255 as the back gate in some cases. When the conductive layer 265 whose region facing the oxide semiconductor layer 230 is larger than that of the conductive layer 255 is used as the gate, a gate electric field is applied to the oxide semiconductor layer 230 more effectively, and thus the electrical characteristics of the transistor can be improved in some cases.

In a planar transistor, the channel length is determined by the light exposure limit of photolithography. In one embodiment of the present invention, the channel length can be determined by the thicknesses of the insulating layer 280a and the insulating layer 280b. Thus, the transistor 200 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm). Accordingly, the transistor 200 can have a higher on-state current and higher frequency characteristics.

In addition, as described above, the channel formation region, the source region, and the drain region can be formed in the opening portion 290. Thus, the area occupied by the transistor 200 can be reduced as compared with a planar transistor in which the channel formation region, the source region, and the drain region are provided separately on the XY plane. Thus, the semiconductor device can be highly integrated. In the case where the semiconductor device of one embodiment of the present invention is used for a memory device, the storage capacity per unit area can be increased.

FIG. 2A2 illustrates an example where a plurality of transistors 200 are arranged in a matrix. Specifically, FIG. 2A2 illustrates an example where 5×5 transistors are arranged in the X direction and the Y direction. As illustrated in FIG. 2A2, the transistor 200 is provided in an intersection portion of the conductive layer 265 extending in the X direction and the conductive layer 240 extending in the Y direction. As illustrated in FIG. 2A2, the opening portion 290 can have a diameter smaller than the short-side widths of the conductive layers 240, 255, and 265. Thus, it can be said that the transistor 200 can be highly integrated and miniaturized.

As illustrated in FIG. 2D, the insulating layer 235, the oxide semiconductor layer 230, the insulating layer 250, and the conductive layer 265a are provided concentrically. Therefore, the side surface of the conductive layer 265a provided at the center faces the side surface of the oxide semiconductor layer 230 with the insulating layer 250 therebetween. That is, in the plan view, all the perimeter of the oxide semiconductor layer 230 serves as the channel formation region. In this case, for example, the channel width of the transistor 200 is determined by the length of the perimeter of the oxide semiconductor layer 230. In other words, the channel width of the transistor 200 is determined by the width of the opening portion 290 (the diameter in the case where the opening portion 290 is circular in the plan view). FIGS. 2B to 2E each show a width D of the opening portion 290, and FIG. 2E shows a channel width W of the transistor 200. By increasing the width D of the opening portion 290, the channel width per unit area can be increased and the on-state current can be increased.

Note that the width D of the opening portion 290 changes in the depth direction in some cases. Here, the shortest distance between two side surfaces of the conductive layer 255 on the opening portion 290 side in a cross-sectional view is particularly used as the width D. In other words, the minimum width of the opening portion 290 in the conductive layer 255 is used as the width D of the opening portion 290. The width of the opening portion 290 at the highest position, the width of the opening portion 290 at the lowest position, or the width of the opening portion 290 at the midpoint therebetween in the conductive layer 255, or the average value of these three widths may be used as the width D. Although the example where the width D is determined using the width of the opening portion 290 in the conductive layer 255 is described here, there is no particular limitation on the method for determining the width D. For example, as the width D, the shortest distance between two side surfaces of the insulating layer 280a, the insulating layer 280b, the conductive layer 240a, or the conductive layer 240b on the opening portion 290 side can be used. Alternatively, the width of the opening portion 290 at the highest position, the width of the opening portion 290 at the lowest position, or the width of the opening portion 290 at the midpoint therebetween in the insulating layer 280a, the insulating layer 280b, the conductive layer 240a, or the conductive layer 240b, or the average value of these three widths may be used as the width D.

In the case where the opening portion 290 is formed by a photolithography method, the width D of the opening portion 290 is determined by the light exposure limit of photolithography. In addition, the width D of the opening portion 290 is determined by the thicknesses of the insulating layer 235, the oxide semiconductor layer 230, the insulating layer 250, and the conductive layer 265a provided in the opening portion 290. The width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in the plan view, the width D of the opening portion 290 corresponds to the diameter of the opening portion 290, and the channel width W can be “D×π”.

The channel length L of the transistor 200 is preferably smaller than at least the channel width W of the transistor 200. The channel length L of the transistor 200 is preferably greater than or equal to 0.1 times and less than or equal to 0.99 times, further preferably greater than or equal to 0.5 times and less than or equal to 0.8 times the channel width W of the transistor 200. This structure enables the transistor to have favorable electrical characteristics and high reliability.

As described above, when the opening portion 290 is formed to be substantially circular in the plan view, the insulating layer 235, the oxide semiconductor layer 230, the insulating layer 250, and the conductive layer 265a are formed concentrically. This makes each of the distance between the conductive layer 255 and the oxide semiconductor layer 230 and the distance between the conductive layer 265a and the oxide semiconductor layer 230 substantially uniform, so that a gate electric field can be substantially uniformly applied to the oxide semiconductor layer 230.

Although this embodiment describes the example where the opening portion 290 has a circular shape in the plan view, the present invention is not limited thereto. The opening portion 290 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. Note that the polygonal shape may be a concave polygonal shape (a polygonal shape at least one of the interior angles of which is greater than) 180° or a convex polygonal shape (a polygonal shape all the interior angles of which are less than or equal to) 180°. As illustrated in FIG. 2A1 and the like, the opening portion 290 preferably has a circular shape in the plan view. When the opening portion has a circular shape in the plan view, processing accuracy in forming the opening portions can be high, whereby the opening portions can be formed to have minute sizes. Note that in this specification and the like, a circular shape is not necessarily a perfect circular shape.

### <Materials for Semiconductor Device>

Materials that can be used for the semiconductor device of this embodiment are described below. Note that the layers included in the semiconductor device of this embodiment may have a single-layer structure or a stacked-layer structure. FIGS. 2B and 2C illustrate an example where the conductive layer 220a has a single-layer structure. FIG. 3 illustrates an example where the conductive layer 220a has a stacked-layer structure.

### [Oxide Semiconductor Layer 230]

As described above, the oxide semiconductor layer 230 includes the channel formation region. The oxide semiconductor layer 230 further includes the source region and the drain region. The source and drain regions are n-type regions (low-resistance regions) having a higher carrier concentration than the channel formation region. The oxide semiconductor layer 230 may have a stacked-layer structure of two or more layers.

There is no particular limitation on the crystallinity of the semiconductor material used for the oxide semiconductor layer 230, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. A single crystal semiconductor or a semiconductor having crystallinity is preferably used, in which case degradation of the transistor characteristics can be inhibited.

The band gap of the metal oxide functioning as a semiconductor is preferably greater than or equal to 2.0 eV, further preferably greater than or equal to 2.5 eV. The use of such a metal oxide having a large band gap can reduce the off-state current of the transistor. The off-state current of the OS transistor is small, so that power consumption of the semiconductor device can be sufficiently reduced. The OS transistor has high frequency characteristics, which enables the semiconductor device to operate at high speed.

For the oxide semiconductor layer that can be used as the semiconductor layer of the transistor of one embodiment of the present invention, the description in Embodiment 3 can be referred to. The details are not described here.

Note that for the semiconductor device of this embodiment, a transistor containing another semiconductor material in a channel formation region may be used. Examples of another semiconductor material include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also one kind of the compound semiconductor. These semiconductor materials may contain an impurity as a dopant.

Examples of silicon that can be used as a semiconductor material of a transistor include single crystal silicon, polycrystalline silicon, microcrystalline silicon, and amorphous silicon. An example of polycrystalline silicon is low-temperature polysilicon (LTPS).

Alternatively, a semiconductor layer of a transistor may include a layered material functioning as a semiconductor. The layered material generally refers to a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSc₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### [Insulating Layer]

An inorganic insulating film is preferably used for each of the insulating layers (the insulating layer 210, the insulating layer 250, the insulating layer 235, the insulating layer 280a, the insulating layer 280b, and the like) included in the semiconductor device. Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

With miniaturization and high integration of a transistor, for example, a problem such as generation of a leakage current may arise because of a thin gate insulating layer. When a high-k material is used for the gate insulating layer, the voltage at the time of operation of the transistor can be reduced while the physical thickness is maintained. In addition, the equivalent oxide thickness (EOT) of the gate insulating layer can be reduced. By contrast, when a material with a low dielectric constant is used for an insulating layer functioning as an interlayer film, parasitic capacitance generated between wirings can be reduced. Thus, a material is preferably selected depending on the function of an insulating layer. Note that a material with a low dielectric constant is a material with high dielectric strength.

Examples of a material with a high dielectric constant (a high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a material with a low dielectric constant include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of an inorganic insulating material with a low dielectric constant include silicon oxide to which fluorine is added, silicon oxide to which carbon is added, and silicon oxide to which carbon and nitrogen are added. Another example is porous silicon oxide. Note that these silicon oxides can contain nitrogen.

A material that can have ferroelectricity may be used for the insulating layer included in the semiconductor device. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or the neighborhood thereof. Examples of the material that can have ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, curopium, titanium, zirconium, hafnium, vanadium, niobium, tantalum, chromium, and the like. Note that the atomic ratio of the element M1 to the element M2 can be set as appropriate. A metal oxide containing the element M1 and nitrogen has ferroelectricity in some cases even though the metal oxide does not contain the element M2. Examples of the material that can have ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can have ferroelectricity also include perovskite-type oxynitrides such as SrTaO₂N and BaTaO₂N, and GaFcO₃ with a K-alumina-type structure.

Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, an insulating layer can have a stacked-layer structure of a plurality of materials selected from the above-listed materials. Since the above-listed materials and the like may change their crystal structures (characteristics) according to a variety of processes and the like as well as film formation conditions, a material that exhibits ferroelectricity is referred to not only as a ferroelectric but also as a material that can have ferroelectricity in this specification and the like.

A metal oxide containing one or both of hafnium and zirconium is preferable because the metal oxide can have ferroelectricity even when being a thin film of several nanometers. A metal oxide containing one or both of hafnium and zirconium is preferable because the metal oxide can have ferroelectricity even with a minute area. Accordingly, the use of a metal oxide containing one or both of hafnium and zirconium enables miniaturization of the semiconductor device.

Note that in this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that the insulating layer can exhibit ferroelectricity, the insulating layer needs to include a crystal. It is particularly preferable that the insulating layer include a crystal having an orthorhombic crystal structure, in which case ferroelectricity is exhibited. A crystal included in the insulating layer may have one or more of crystal structures selected from cubic, tetragonal, orthorhombic, monoclinic, and hexagonal crystal structures. Alternatively, the insulating layer may have an amorphous structure. In that case, the insulating layer may have a composite structure including an amorphous structure and a crystal structure.

Addition of a Group 3 element (also referred to as IIIa element) in the periodic table to an oxide containing one or both of hafnium and zirconium increases the oxygen vacancy concentration in the oxide and facilitates formation of a crystal having an orthorhombic crystal structure. This is preferable because the proportion of the crystal having an orthorhombic crystal structure is increased and the amount of remanent polarization can be increased. On the other hand, too much addition of the Group 3 element might decrease the crystallinity of the oxide and hinder the exhibition of ferroelectricity. Thus, the content percentage of the Group 3 element in the oxide containing one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of the Group 3 element atoms in the number of all metal element atoms contained in the layer. The Group 3 element is preferably one or more selected from scandium, lanthanum, and yttrium, further preferably one or both of lanthanum and yttrium.

A transistor including a metal oxide can have stable electrical characteristics when surrounded by an insulating layer having a function of inhibiting passage of impurities and oxygen. The insulating layer having a function of inhibiting passage of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting passage of impurities and oxygen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

Specifically, as the insulating layer having a function of inhibiting passage of oxygen and impurities such as water and hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide can be used. Other examples of the insulating layer having a function of inhibiting passage of oxygen and impurities such as water and hydrogen include oxides containing aluminum and hafnium (hafnium aluminate). Other examples of the insulating layer having a function of inhibiting passage of oxygen and impurities such as water and hydrogen include metal nitrides such as aluminum nitride, aluminum titanium nitride, titanium nitride, silicon nitride oxide, and silicon nitride.

In addition, an insulating layer in contact with an oxide semiconductor layer, such as a gate insulating layer, or an insulating layer provided in the vicinity of the oxide semiconductor layer preferably includes a region containing oxygen (hereinafter, sometimes referred to as excess oxygen) that is released by heating. For example, when an insulating layer including a region containing excess oxygen is in contact with an oxide semiconductor layer or positioned in the vicinity of the oxide semiconductor layer, the number of oxygen vacancies in the oxide semiconductor layer can be reduced. Examples of an insulating layer in which a region containing excess oxygen is easily formed include silicon oxide, silicon oxynitride, and porous silicon oxide.

The insulating layer 210 functions as an interlayer film and preferably has a low dielectric constant. In the case where a material with a low dielectric constant is used for an interlayer film, parasitic capacitance generated between wirings can be reduced. Silicon oxide and silicon oxynitride are thermally stable, and thus are suitable for the insulating layer 210.

The concentration of impurities such as water and hydrogen in the insulating layer 210 is preferably reduced. This can inhibit entry of impurities such as water and hydrogen into the channel formation region of the oxide semiconductor layer 230.

As the insulating layer 210, a barrier insulating layer against hydrogen is preferably used. When the insulating layer 210 provided outside the oxide semiconductor layer 230 has a barrier property against hydrogen, diffusion of hydrogen into the oxide semiconductor layer 230 can be inhibited.

Examples of a material for the barrier insulating layer against hydrogen include aluminum oxide, magnesium oxide, hafnium oxide, gallium oxide, silicon nitride, and silicon nitride oxide.

Note that in this specification and the like, a barrier insulating layer refers to an insulating layer having a barrier property. In addition, the barrier property refers to a property that does not easily allow diffusion of a target substance (also referred to as a property that does not easily allow passage of a target substance, a property with low permeability of a target substance, or a function of inhibiting diffusion of a target substance). Note that hydrogen described as a target substance refers to at least one of a hydrogen atom, a hydrogen molecule, substances bonded to hydrogen, such as a water molecule and OH⁻, and the like. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom, an oxygen molecule, and the like.

For example, a silicon nitride film is preferably used for the insulating layer 210.

The insulating layer 280a and the insulating layer 280b each preferably include the above-described barrier insulating layer against hydrogen. The insulating layer 280a and the insulating layer 280b are provided to surround the oxide semiconductor layer 230. When the insulating layer 280a and the insulating layer 280b provided outside the oxide semiconductor layer 230 has a barrier property against hydrogen, diffusion of hydrogen into the oxide semiconductor layer 230 can be inhibited. For example, the insulating layer 280a and the insulating layer 280b each preferably include one or both of an aluminum oxide film and a silicon nitride film.

Note that silicon nitride also has a barrier property against oxygen. Thus, using silicon nitride for the insulating layer 280a and the insulating layer 280b can inhibit extraction of oxygen from the oxide semiconductor layer 230, and accordingly can inhibit formation of an excess amount of oxygen vacancies in the oxide semiconductor layer 230.

Furthermore, when silicon nitride is used for the insulating layer 280a and the insulating layer 280b, excess oxygen can be prevented from being supplied to the oxide semiconductor layer 230. Thus, the channel formation region of the oxide semiconductor layer 230 can be prevented from containing excess oxygen, whereby the reliability of the transistor 200 can be improved.

The insulating layer 280a and the insulating layer 280b each preferably include any of an oxide insulating film, an oxynitride film, and an insulating layer including a region containing excess oxygen, which are described above.

For example, the insulating layer including a region containing excess oxygen can be formed by deposition by a sputtering method in an atmosphere containing oxygen. Since a molecule containing hydrogen is not used as a deposition gas in the sputtering method, the hydrogen concentration in the insulating layer 280a and the insulating layer 280b can be reduced. When at least one layer in each of the insulating layers 280a and 280b is formed in this manner, oxygen can be supplied from the insulating layer 280a and the insulating layer 280b to the channel formation region of the oxide semiconductor layer 230, so that oxygen vacancies and V_{O}H therein can be reduced.

The concentration of impurities such as water and hydrogen in the insulating layer 280a and the insulating layer 280b is preferably reduced. This can inhibit entry of impurities such as water and hydrogen into the channel formation region of the oxide semiconductor layer 230.

Since the thicknesses of the insulating layers 280a and 280b over the conductive layer 220 affect the channel length of the transistor 200, the thicknesses of the insulating layers 280a and 280b are set as appropriate in accordance with a designed channel length of the transistor 200.

For example, a single-layer structure of a silicon nitride film, a silicon nitride oxide film, or an aluminum oxide film is preferably used for each of the insulating layers 280a and 280b. Alternatively, for example, a three-layer structure where a silicon nitride film, a silicon oxide film, and a silicon nitride film are stacked in this order is preferably used for each of the insulating layers 280a and 280b. For example, a three-layer structure where an aluminum oxide film, a silicon oxide film, and an aluminum oxide film are stacked in this order is preferably used for each of the insulating layers 280a and 280b.

The insulating layer 250 preferably has a function of trapping and fixing hydrogen. In this case, the hydrogen concentration in the oxide semiconductor layer 230 (in particular, the hydrogen concentration in the channel formation region of the transistor) can be reduced. Accordingly, V_{O}H in the channel formation region can be reduced, so that the channel formation region can be an i-type or substantially i-type region.

Examples of a material for an insulating layer having a function of capturing or fixing hydrogen include metal oxides such as an oxide containing hafnium, an oxide containing magnesium, an oxide containing aluminum, and an oxide containing aluminum and hafnium (hafnium aluminate). Furthermore, these metal oxides may further contain zirconium, and an example of such a metal oxide is an oxide containing hafnium and zirconium. Note that in a metal oxide having an amorphous structure, some oxygen atoms have a dangling bond, which allows the metal oxide to have a high property of capturing or fixing hydrogen. Thus, these metal oxides preferably have an amorphous structure. For example, these oxides may have an amorphous structure by containing silicon. For example, an oxide containing hafnium and silicon (hafnium silicate) is preferably used. Note that the metal oxide may partly include one or both of a crystal region and a crystal grain boundary.

Note that a function of capturing or fixing a target substance can also be referred to as a property that does not easily allow diffusion of a target substance. Thus, a function of capturing or fixing a target substance can be rephrased as a barrier property.

In the case where the gate insulating layer has a stacked-layer structure, a layer in contact with the oxide semiconductor layer 230 preferably has a function of capturing or fixing hydrogen. In this case, hydrogen contained in the oxide semiconductor layer 230 can be captured or fixed more effectively. Thus, the hydrogen concentration in the oxide semiconductor layer 230 can be reduced. For a layer of the insulating layer 250 which is in contact with the oxide semiconductor layer 230, hafnium silicate or the like is preferably used, for example. The layer preferably has an amorphous structure.

When the layer has an amorphous structure, formation of a crystal grain boundary can be inhibited. Inhibiting formation of a crystal grain boundary can increase the planarity of the layer. This enables the insulating layer 250 to have uniform thickness distribution and a reduced number of extremely thin portions, so that the withstand voltage of the insulating layer 250 can be increased. Furthermore, the thickness distribution of the film provided over the insulating layer 250 can be uniform.

Furthermore, inhibiting formation of a crystal grain boundary in the layer can reduce a leakage current due to the defect states in the crystal grain boundary. Thus, the insulating layer 250 can function as an insulating film with a small leakage current.

Since hafnium oxide is a high dielectric constant (high-k) material, hafnium silicate becomes a high dielectric constant (high-k) material depending on the content of silicon. Thus, in the case where hafnium oxide or hafnium silicate is used for the gate insulating layer, a gate potential applied at the time of operation of the transistor can be reduced while the physical thickness of the gate insulating layer is maintained. In addition, the equivalent oxide thickness (EOT) of the gate insulating layer can be reduced.

As described above, for the insulating layer 250, an oxide containing one or both of aluminum and hafnium is preferably used, more preferably, an oxide containing one or both of aluminum and hafnium and having an amorphous structure is used, and further preferably, aluminum oxide having an amorphous structure is used.

As the insulating layer 250, the above-described barrier insulating layer against hydrogen is preferably used. When a barrier insulating layer against hydrogen is used as the insulating layer 250, diffusion of impurities contained in the conductive layer 265 into the oxide semiconductor layer 230 can be inhibited. For example, silicon nitride is suitable for the insulating layer 250 because of its high barrier property against hydrogen. Furthermore, the insulating layer 250 may include a thermally stable insulating layer such as silicon oxide or silicon oxynitride.

With such a structure, a semiconductor device having favorable electrical characteristics can be provided. A highly reliable semiconductor device can be provided. A semiconductor device with a small variation in transistor electrical characteristics can be provided. A semiconductor device having a high on-state current can be provided.

Furthermore, the insulating layer 250 may include a thermally stable insulating layer such as silicon oxide or silicon oxynitride.

The insulating layer 250 may include, between a pair of insulating layers having a function of capturing and fixing hydrogen, a thermally stable insulating layer.

The insulating layer 250 preferably includes a barrier insulating layer against oxygen. In this case, oxidation of the conductive layer 240, the conductive layer 265, and the like can be inhibited. In the case where the insulating layer 250 has a stacked-layer structure, a layer in contact with the conductive layer 240 or the conductive layer 265 is preferably a barrier insulating layer against oxygen. In particular, the layer in contact with the conductive layer 240 and a layer in contact with the conductive layer 265, which are included in the insulating layer 250, are preferably barrier insulating layers against oxygen.

When a barrier insulating layer against hydrogen and oxygen is used as the layer of the insulating layer 250 which is in contact with the conductive layer 265, oxidation of the conductive layer 265 can be inhibited. Furthermore, diffusion of oxygen contained in the oxide semiconductor layer 230 into the conductive layer 265 can be inhibited, and accordingly formation of oxygen vacancies in the oxide semiconductor layer 230 can be inhibited.

Examples of a barrier insulating layer against oxygen include an oxide containing one or both of aluminum and hafnium, magnesium oxide, gallium oxide, gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

The layer of the insulating layer 250 which is in contact with the conductive layer 240 is preferably less likely to transmit oxygen than at least the insulating layer 280b. When the layer has a barrier property against oxygen, oxidation of the side surface of the conductive layer 240 can be inhibited, and accordingly formation of an oxide film on the side surface can be inhibited. It is thus possible to inhibit a reduction in the on-state current or field-effect mobility of the transistor 200.

Each layer included in the insulating layer 250 is preferably a thin film. For example, when the insulating layer 250 has a thickness greater than or equal to 1 nm and less than or equal to 20 nm, preferably greater than or equal to 3 nm and less than or equal to 10 nm, the subthreshold swing value (also referred to as S value), which is one of transistor characteristics, can be reduced. Note that the S value means the amount of change in gate voltage in the subthreshold region when the drain voltage is constant and the drain current is changed by one order of magnitude.

The thickness of each layer included in the insulating layer 250 is preferably greater than or equal to 0.1 nm and less than or equal to 10 nm, further preferably greater than or equal to 0.1 nm and less than or equal to 5.0 nm, further preferably greater than or equal to 0.5 nm and less than or equal to 5.0 nm, further preferably greater than or equal to 1.0 nm and less than 5.0 nm, further preferably greater than or equal to 1.0 nm and less than or equal to 3.0 nm. Note that each layer included in the insulating layer 250 at least partly includes a region with the above thickness.

The insulating layer 250 preferably has a three-layer structure where a first insulating layer containing a material with a low dielectric constant, a second insulating layer having a function of capturing or fixing hydrogen, and a third insulating layer having a barrier property against hydrogen and oxygen are stacked in this order from the oxide semiconductor layer 230 side. As the material with a low dielectric constant contained in the first insulating layer, silicon oxide or silicon oxynitride is preferably used. The first insulating layer is in contact with the oxide semiconductor layer 230. When an oxide is used for the first insulating layer, oxygen can be supplied to the oxide semiconductor layer 230. Providing the third insulating layer can inhibit diffusion of oxygen contained in the first insulating layer into the conductive layer 265 and inhibit oxidation of the conductive layer 265. Furthermore, a reduction in the amount of oxygen supplied from the first insulating layer to the oxide semiconductor layer 230 can be inhibited.

The insulating layer 250 preferably has a four-layer structure where a fourth insulating layer having a barrier property against oxygen, a first insulating layer containing a material with a low dielectric constant, a second insulating layer having a function of capturing or fixing hydrogen, and a third insulating layer having a barrier property against hydrogen and oxygen are stacked in this order from the oxide semiconductor layer 230 side. The first insulating layer to the third insulating layer can have a structure similar to that of the layers used in the above three-layer structure. The fourth insulating layer is in contact with the oxide semiconductor layer 230. When the fourth insulating layer has a barrier property against oxygen, release of oxygen from the oxide semiconductor layer 230 can be inhibited. For the fourth insulating layer, aluminum oxide is preferably used, for example. Aluminum oxide has a function of capturing or fixing hydrogen, and thus is suitably used for the fourth insulating layer in contact with the oxide semiconductor layer 230. Specifically, it is preferable to employ a four-layer structure where an aluminum oxide film, a silicon oxide film, a hafnium oxide film, and a silicon nitride film are stacked in this order from the oxide semiconductor layer 230 side.

Typically, the thicknesses of the fourth, first, second, and third insulating layers are 1 nm, 2 nm, 2 nm, and 1 nm, respectively. Such a structure enables a transistor to have favorable electrical characteristics even when the transistor is miniaturized or highly integrated.

Alternatively, the insulating layer 250 preferably has a three-layer structure where a fourth insulating layer having a barrier property against oxygen, a first insulating layer containing a material with a low dielectric constant, and a second insulating layer having a function of capturing or fixing hydrogen are stacked in this order from the oxide semiconductor layer 230 side. Specifically, it is preferable to employ a three-layer structure where an aluminum oxide film, a silicon oxide film, and a hafnium oxide film are stacked in this order from the oxide semiconductor layer 230 side.

The silicon oxide film included in the insulating layer 250 is preferably formed by a PEALD method. The thickness of the silicon oxide film included in the insulating layer 250 is preferably greater than or equal to 0.7 nm and less than or equal to 3.0 nm. An ALD method enables one atomic layer to be formed at a time, and has various advantages such as formation of an extremely thin film, deposition on a component with a high aspect ratio or a surface with a large step, formation of a film with few defects such as pinholes, deposition with excellent coverage, and low-temperature deposition. Thus, by an ALD method, the coverage of the sidewall and bottom surface of the opening portion 290 with the insulating layer 250 can be increased in the transistor of one embodiment of the present invention, so that the insulating layer 250 with a uniform thickness can be formed. A PEALD method utilizing plasma is preferable, because deposition at lower temperature is possible. Furthermore, when plasma is utilized, the deposition rate can be increased and the productivity can be increased.

The insulating layer 250 is preferably formed of two or more kinds of films. When the insulating layer 250 is formed of two or more kinds of films, the insulating layer 250 can have a plurality of functions. Examples of the functions of the insulating layer 250 include a function of extracting hydrogen from the oxide semiconductor layer 230 and a function of inhibiting diffusion of hydrogen into the oxide semiconductor layer 230. Note that in the formation of the insulating layer 250, an ALD process is preferably used twice or more. For example, the insulating layer 250 preferably has a stacked-layer structure of a plurality of insulating films, and two or more of the plurality of insulating films are preferably formed through an ALD process. When at least two insulating films are formed through an ALD process, the coverage with the insulating layer 250 and the thickness uniformity of the insulating layer 250 can be improved. When two or more kinds of films, e.g., two or more kinds of insulating films are successively formed through an ALD process, the productivity can be increased.

As the insulating layer 210, the above-described insulating layer having a function of capturing or fixing hydrogen may be used. Accordingly, hydrogen in the oxide semiconductor layer 230 diffusing into the insulating layer 210 through the conductive layers 220a and 220b can be captured or fixed. Thus, the hydrogen concentration in the oxide semiconductor layer 230 can be reduced. For example, the insulating layer 210 may have a two-layer structure of a silicon nitride film and a hafnium silicate film over the silicon nitride film.

The insulating layer 235 can be referred to as a sidewall, a sidewall insulating layer, a sidewall protective layer, or the like.

The insulating layer 235 preferably includes an insulating layer including a region containing oxygen that is released by heating. Thus, oxygen can be supplied from the insulating layer 235 to the oxide semiconductor layer 230. For example, for the insulating layer 235, silicon oxide or silicon oxynitride is preferably used.

The insulating layer 235 preferably includes a barrier insulating layer against hydrogen. Accordingly, diffusion of hydrogen into the oxide semiconductor layer 230 can be inhibited, and the reliability of the transistor 200 can be improved. For example, aluminum oxide, hafnium oxide, silicon nitride, or silicon nitride oxide is preferably used for the insulating layer 235.

A silicon nitride film included in the insulating layer 235 is preferably formed by a PEALD method. This can improve the coverage of the sidewall of the opening portion 290 with the insulating layer 235, so that the insulating layer 235 with a uniform thickness can be formed.

Alternatively, it is also possible to use any of the above-described materials that can have ferroelectricity for the insulating layer 235.

For example, the insulating layer 235 can have a single-layer structure of a silicon oxide film; a single-layer structure of a silicon nitride film; a two-layer structure of a silicon oxide film and a silicon nitride film; a three-layer structure of a silicon oxide film, a silicon nitride film, and a silicon oxide film; or a three-layer structure of a silicon nitride film, a silicon oxide film, and a silicon nitride film, for example. In the case of the two-layer structure of a silicon oxide film and a silicon nitride film, for example, it is preferable that the silicon oxide film be provided on the oxide semiconductor layer 230 side and the silicon nitride film be provided on the conductive layer 255 side. Accordingly, oxygen can be efficiently supplied to the oxide semiconductor layer 230 and diffusion of impurities such as hydrogen into the oxide semiconductor layer 230 can be inhibited. Alternatively, the silicon nitride film may be provided on the oxide semiconductor layer 230 side, and the silicon oxide film may be provided on the conductive layer 255 side.

### [Conductive Layer]

For each of the conductive layers (the conductive layer 220, the conductive layer 240, the conductive layer 255, the conductive layer 265, and the like) included in the semiconductor device, it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As an alloy containing any of the above metal elements, a nitride of the alloy or an oxide of the alloy may be used. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electric conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include an indium oxide containing tungsten oxide, an indium oxide containing titanium oxide, an indium tin oxide (also referred to as ITO), an indium tin oxide containing titanium oxide, an indium tin oxide to which silicon is added (also referred to as ITSO), an indium zinc oxide (also referred to as IZO (registered trademark)), and an indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

Each of the conductive layers 220 and 240 is in contact with the oxide semiconductor layer 230, and thus is preferably formed using a conductive material that is not easily oxidized, a conductive material that maintains its low electric resistance even after being oxidized, a metal oxide that has conductivity (also referred to as an oxide conductor), or a conductive material that has a function of inhibiting diffusion of oxygen. Examples of the conductive material include a conductive material containing nitrogen and a conductive material containing oxygen. Thus, a decrease in conductivity of the conductive layer 220 and the conductive layer 240 can be inhibited.

When a conductive material containing oxygen is used for the conductive layer 220 or the conductive layer 240, the conductive layer 220 or the conductive layer 240 can maintain its conductivity even after absorbing oxygen. It is also preferable that an insulating layer containing oxygen, such as hafnium oxide, be used as the insulating layer 210 because the conductive layer 220 can maintain its conductivity. For each of the conductive layers 220 and 240, ITO, ITSO, IZO (registered trademark), or the like is preferably used, for example.

FIG. 3 illustrates an example where the conductive layer 220 has a three-layer structure of a conductive layer 220al, a conductive layer 220a2 over the conductive layer 220al, and the conductive layer 220b over the conductive layer 220a2. In this case, for example, a conductive material that is not easily oxidized or a conductive material that has a function of inhibiting diffusion of oxygen is preferably used for the conductive layer 220a1, a conductive material that has high conductivity is preferably used for the conductive layer 220a2, and a conductive material that contains oxygen (preferably an oxide conductor) is preferably used for the conductive layer 220b. Specifically, titanium nitride is preferably used for the conductive layer 220al, tungsten is preferably used for the conductive layer 220a2, and an oxide conductor (e.g., ITO, ITSO, or IZO (registered trademark)) is preferably used for the conductive layer 220b. In this case, the titanium nitride is in contact with the insulating layer 210, and the oxide conductor is in contact with the oxide semiconductor layer 230. In addition, the oxide conductor is used for the layer closest to the channel formation region of the oxide semiconductor layer 230. Since the oxide conductor has a lower contact resistance with the oxide semiconductor layer 230 than tungsten, the current path between the source and the drain can be shortened and the on-state current of the transistor can be increased. Such a structure enables the conductive layer 220 to maintain its conductivity even when being in contact with the oxide semiconductor layer 230. In the case of using an oxide insulating layer as the insulating layer 210, the conductive layer 220 can be inhibited from being excessively oxidized by the insulating layer 210. When a metal material (here, tungsten) having higher conductivity than an oxide conductor and titanium nitride is used for the conductive layer 220a2, the conductivity of the conductive layer 220 can be increased.

FIG. 3 illustrates the example where the conductive layer 240 has a two-layer structure of the conductive layer 240a and the conductive layer 240b over the conductive layer 240a. In this case, for example, a conductive material containing oxygen is preferably used for the conductive layer 240b, and a material having higher conductivity than the material for the conductive layer 240b is preferably used for the conductive layer 240a. Specifically, for example, an oxide conductor (e.g., ITO, ITSO, or IZO (registered trademark)) is preferably used for the conductive layer 240b, and tungsten is preferably used for the conductive layer 240a. Alternatively, ruthenium, titanium nitride, tantalum nitride, or the like may be used for the conductive layer 240a.

In the conductive layer 240, the conductive layer 240b is mainly in contact with the oxide semiconductor layer 230. The use of an oxide conductor for the conductive layer 240b is preferable because the contact resistance with the oxide semiconductor layer 230 can be reduced. The use of a material having higher conductivity than the oxide conductor for the layer included in the conductive layer 240 is preferable because the conductivity of the conductive layer 240 can be increased.

Note that a conductive material containing oxygen can be used for the conductive layer 240a, and a material having higher conductivity than the material for the conductive layer 240a can be used for the conductive layer 240b. In this case, the oxide conductor is used for the layer of the conductive layer 240 which is closest to the channel formation region of the oxide semiconductor layer 230. Thus, the current path between the source and the drain can be shortened, so that the on-state current of the transistor can be increased.

The conductive layers 255 and 265 are each preferably formed using a material with high conductivity such as tungsten. In addition, a conductive material that is not easily oxidized, a conductive material that has a function of inhibiting diffusion of oxygen, or the like is preferably used for each of the conductive layers 255 and 265. As described above, examples of the conductive material include a conductive material containing nitrogen (e.g., titanium nitride or tantalum nitride) and a conductive material containing oxygen (e.g., ruthenium oxide). Thus, a decrease in conductivity of the conductive layers 255 and 265 can be inhibited.

It is particularly preferable to use, for the conductive layer 265, a conductive material containing oxygen and a metal element contained in the metal oxide where a channel is formed. Alternatively, a conductive material containing the above metal element and nitrogen (e.g., titanium nitride or tantalum nitride) may be used. One or more of an indium tin oxide, an indium oxide containing tungsten oxide, an indium zinc oxide containing tungsten oxide, an indium oxide containing titanium oxide, an indium tin oxide containing titanium oxide, an indium zinc oxide, and an indium tin oxide to which silicon is added may be used. An indium gallium zinc oxide containing nitrogen may be used. With the use of such a material, hydrogen contained in the metal oxide where a channel is formed can be captured in some cases. Hydrogen entering from a surrounding insulating layer or the like can also be captured in some cases.

FIG. 3 illustrates an example where the conductive layer 265 has a two-layer structure of the conductive layer 265a and the conductive layer 265b over the conductive layer 265a. In this case, for example, it is preferable to use titanium nitride for the conductive layer 265a and tungsten for the conductive layer 265b. Alternatively, it is preferable to use tantalum nitride for the conductive layer 265a and copper for the conductive layer 265b. With such a structure, the conductivity of the conductive layer 265 can be increased.

The conductive layer 265 may have a stacked-layer structure of three or more layers. The conductive layer 265 may have a three-layer structure of tantalum nitride, titanium nitride over the tantalum nitride, and tungsten over the titanium nitride, for example.

The conductive layer 265 functions as the gate wiring and thus preferably has high conductivity. The conductive layer 265 is preferably formed using tungsten. For example, a two-layer structure of titanium nitride and tungsten may be employed.

The conductive layer 255 is preferably formed using tungsten or tantalum nitride, for example.

### [Substrate]

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Another example is any of the above semiconductor substrates provided with an insulator region, such as a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided over the substrate include a capacitor, a resistor, a switching element, a light-emitting element, and a memory element.

### Structure Example 2 of Semiconductor Device

Structures of the semiconductor devices of other embodiments of the present invention will be described with reference to FIGS. 4A and 4B, FIGS. 5A and 5B, FIGS. 6A to 6D, FIGS. 7A to 7C, FIGS. 8A to 8E, FIGS. 9A and 9B, FIGS. 10A to 10E, FIGS. 11A and 11B, FIGS. 12A to 12E, FIGS. 13A and 13B, and FIGS. 14A to 14C2.

### [Transistor 200A]

FIG. 4A is a cross-sectional view of a semiconductor device including a transistor 200A.

FIG. 4A illustrates an example where the sidewall of the opening portion 290 has a tapered shape. When the sidewall of the opening portion 290 has a tapered shape, the coverage with the insulating layer 235, the oxide semiconductor layer 230, the insulating layer 250, and the like can be improved, so that defects such as voids can be reduced. In the case where the sidewall of the opening portion 290 has a tapered shape, a taper angle θ280 of the side surface of the insulating layer 280a in the opening portion 290 is preferably greater than or equal to 45° and less than 90°, for example. Specifically, the taper angle θ280 is preferably greater than or equal to 80° and less than 90°, in which case the semiconductor device can be miniaturized or highly integrated as described above. Alternatively, the taper angle θ280 is preferably greater than or equal to 45° or greater than or equal to 50° and less than 80°, less than or equal to 75°, less than or equal to 70°, less than or equal to 65°, or less than or equal to 60°, in which case the coverage with a film to be formed in the opening portion 290 is improved.

Alternatively, for example, the sidewall of the opening portion 290 may have an inverse tapered shape. In other words, the taper angle θ280 of the side surface of the insulating layer 280a in the opening portion 290 may be greater than 90°.

### [Transistors 200B, 200C, and 200D]

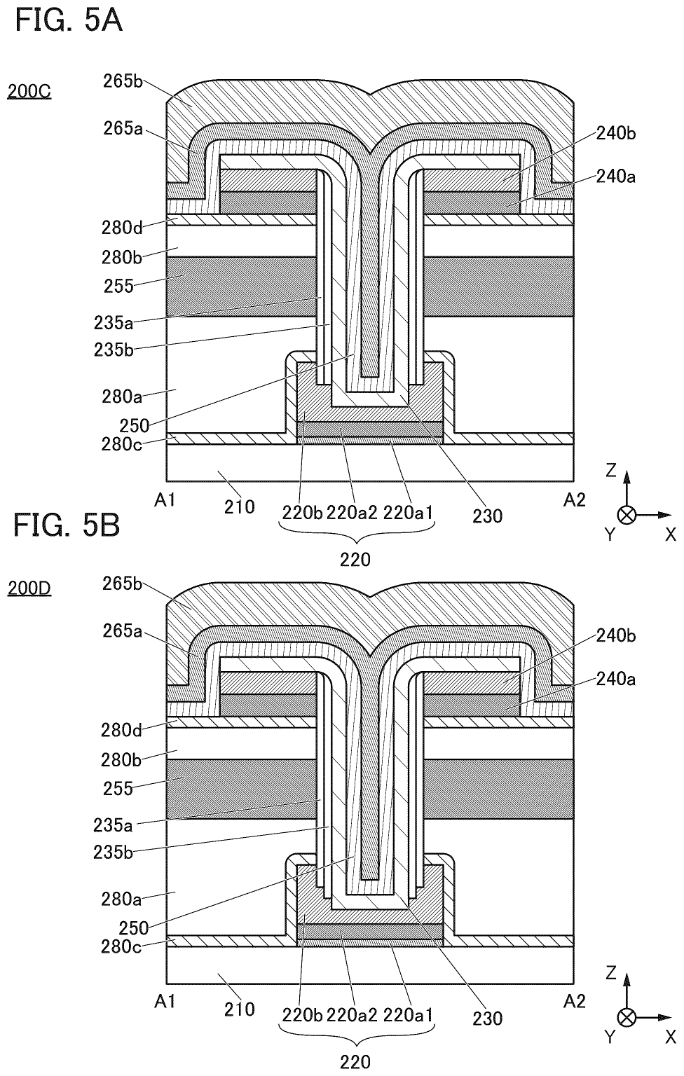

FIG. 4B is a cross-sectional view of a semiconductor device including a transistor 200B. FIG. 5A is a cross-sectional view of a semiconductor device including a transistor 200C. FIG. 5B is a cross-sectional view of a semiconductor device including a transistor 200D.

The transistors 200B, 200C, and 200D are different from the transistor 200 mainly in that the insulating layer 235 has a two-layer structure and an insulating layer 280c and an insulating layer 280d are provided.

The transistors 200B, 200C, and 200D each include an insulating layer 235a and an insulating layer 235b over the insulating layer 235a. The insulating layers 235a and 235b each function as a second gate insulating layer of the transistor.

One of the insulating layers 235a and 235b preferably includes an insulating layer including a region containing oxygen that is released by heating. The other of the insulating layers 235a and 235b preferably includes a barrier insulating layer against hydrogen.

Accordingly, oxygen can be supplied from the insulating layer 235a or the insulating layer 235b to the oxide semiconductor layer 230 and diffusion of hydrogen into the oxide semiconductor layer 230 can be inhibited, leading to higher reliability of the transistor.

For example, it is preferable that one of the insulating layers 235a and 235b be an oxide insulating layer and the other be a nitride insulating layer. Specifically, it is preferable that a silicon nitride film be used as the insulating layer 235a and a silicon oxide film be used as the insulating layer 235b. Alternatively, it is preferable that a silicon oxide film be used as the insulating layer 235a and a silicon nitride film be used as the insulating layer 235b.

The insulating layer 235 preferably includes a silicon oxide film with a thickness greater than 0 nm and less than or equal to 5 nm. The insulating layer 235 preferably includes a silicon nitride film with a thickness greater than 0 nm and less than or equal to 5 nm. The silicon oxide film and the silicon nitride film are each preferably formed by a PEALD method. Such a structure can prevent a gate leakage current from the conductive layer 255 in the transistor 200B. When including a silicon nitride film, the insulating layer 235 can have a function of blocking hydrogen.

In the example of the transistor 200B, the insulating layer 235a is provided in contact with the bottom and side surfaces of the depressed portion of the conductive layer 220b, and the insulating layer 235b is provided over the insulating layer 235a. For example, an insulating film to be the insulating layer 235a and an insulating film to be the insulating layer 235b are stacked, and then the two insulating films are processed, whereby the insulating layer 235a and the insulating layer 235b as illustrated in FIG. 4B can be formed. Thus, it can be said that the structure can be formed relatively easily.

In the example of the transistor 200C, the insulating layer 235a is provided in contact with the bottom and side surfaces of the depressed portion of the conductive layer 220b, and the insulating layer 235b is provided on an inner side of the insulating layer 235a to be in contact with the bottom portion of the depressed portion of the conductive layer 220b in the opening portion.

In the transistor 200D, the conductive layer 220b includes a first depressed portion, a second depressed portion positioned on an outer side of the first depressed portion, and a third depressed portion positioned on an outer side of the second depressed portion. The depth of the first depressed portion is greater than that of the second depressed portion, and the depth of the second depressed portion is greater than that of the third depressed portion. The third depressed portion is provided in the conductive layer 220b at the time of forming the opening portion 290, the second depressed portion is provided in the conductive layer 220b at the time of processing the insulating layer 235a, and then the first depressed portion is provided in the conductive layer 220b at the time of processing the insulating layer 235b. Thus, in FIG. 5B, the side surface of the first depressed portion is aligned with a surface of the insulating layer 235b on the oxide semiconductor layer 230 side, the side surface of the second depressed portion is aligned with a surface of the insulating layer 235a on the insulating layer 235b side, and the side surface of the third depressed portion is aligned with surfaces of the insulating layer 280a and the like on the opening portion 290 side.

In the example of the transistor 200D, the insulating layer 235a is provided in contact with the bottom and side surfaces of the third depressed portion of the conductive layer 220b, and the insulating layer 235b is provided in contact with the bottom and side surfaces of the second depressed portion of the conductive layer 220b.

For example, after the insulating layer 235a is provided on the sidewall of the opening portion, an insulating film to be the insulating layer 235b is formed and processing is performed, whereby the insulating layer 235a and the insulating layer 235b as illustrated in FIG. 5A or 5B can be formed. The contact area between the insulating layer 235a and the oxide semiconductor layer 230 can be smaller than that in the transistor 200B, and the insulating layer 235b can be in contact with the oxide semiconductor layer 230.

In the transistors 200B, 200C, and 200D, the insulating layers 280a and 280b are closer to the channel formation region of the oxide semiconductor layer 230 than the insulating layers 280c and 280d are. When an insulating layer containing oxygen is used as each of the insulating layers 280a and 280b, oxygen can be supplied to the oxide semiconductor layer 230.

The insulating layers 280a and 280b each preferably include a region having a higher oxygen content than at least one of the insulating layers 280c and 280d. When the insulating layers 280a and 280b each have a high oxygen content, an i-type region can be easily formed in the oxide semiconductor layer 230.

It is further preferable that a film from which oxygen is released by heating be used for each of the insulating layers 280a and 280b. When the insulating layers 280a and 280b release oxygen by being heated during the manufacturing process of the transistor, the oxygen can be supplied to the oxide semiconductor layer 230. The oxygen supply from the insulating layers 280a and 280b to the oxide semiconductor layer 230, particularly to the channel formation region of the oxide semiconductor layer 230, can reduce the amount of oxygen vacancies and V_{O}H in the oxide semiconductor layer 230, so that the transistor can have favorable electrical characteristics and high reliability.

In order to improve the electrical characteristics and reliability of the OS transistor, it is important to optimize the amount of oxygen supplied to the oxide semiconductor after the hydrogen concentration in the oxide semiconductor is sufficiently reduced.

In particular, when the channel length of the transistor is small, the influence of oxygen vacancies and V_{O}H in the channel formation region on the electrical characteristics and reliability of the channel formation region is especially large. Accordingly, when the amount of oxygen supplied to the oxide semiconductor layer 230 is optimized after the hydrogen concentration in the oxide semiconductor layer 230 is sufficiently reduced, a transistor with a small channel length, favorable electrical characteristics, and high reliability can be provided.

The insulating layers 280a and 280b are each preferably formed by a film formation method such as a sputtering method or a plasma-enhanced chemical vapor deposition (PECVD) method. It is particularly preferable to employ a sputtering method, in which a hydrogen gas does not need to be used as a deposition gas, to form a film having an extremely low hydrogen content. Therefore, supply of hydrogen to the oxide semiconductor layer 230 is inhibited and the electrical characteristics of the transistor can be stabilized.

In the case where a large amount of oxygen is supplied to the oxide semiconductor layer 230, heat treatment in an oxygen-containing atmosphere or plasma treatment in an oxygen-containing atmosphere is preferably performed after formation of the insulating layer 280a or 280b, for example. Alternatively, an oxide film may be formed over the top surface of the insulating layer 280a or 280b by a sputtering method in an oxygen atmosphere to supply oxygen. After that, the oxide film may be removed. Such treatment can supply oxygen to the insulating layer 280a or 280b and increase the amount of oxygen supplied to the oxide semiconductor layer 230.

An insulating layer suitable as the insulating layers 280a and 280b is preferably used as the insulating layer 235 (especially the insulating layer 235b in contact with the oxide semiconductor layer 230). Thus, oxygen can be supplied to the oxide semiconductor layer 230 efficiently.

A material with a low dielectric constant is preferably used for each of the insulating layers 280a and 280b. In that case, parasitic capacitance generated between wirings can be reduced. For example, silicon oxide or silicon oxynitride can be used for each of the insulating layers 280a and 280b.

As each of the insulating layers 280c and 280d, a barrier insulating layer against oxygen is preferably used. Thus, the conductive layers 220 and 240 can be inhibited from being oxidized and having an increased resistance.

As each of the insulating layers 280c and 280d, a barrier insulating layer against hydrogen may be used. This structure is preferable because diffusion of impurities such as hydrogen into the oxide semiconductor layer 230 can be inhibited.

In the transistors 200B, 200C, and 200D, a silicon oxide film is preferably used as each of the insulating layers 280a and 280b, and a silicon nitride film or an aluminum oxide film is preferably used as each of the insulating layers 280c and 280d.

### [Transistor 200E]

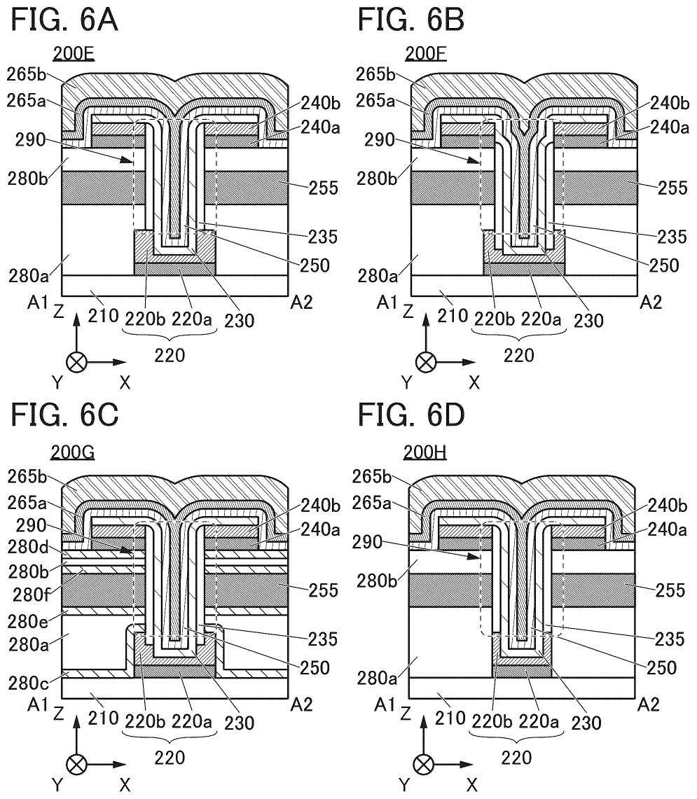

FIG. 6A is a cross-sectional view of a semiconductor device including a transistor 200E.

The transistor 200E is different from the transistor 200 mainly in that only one depressed portion is provided in the conductive layer 220b.

In the conductive layer 220b, a depressed portion can be formed in one or both of a step of forming the opening portion 290 and a step of forming the insulating layer 235. In the example of the transistor 200, a depressed portion is formed in the conductive layer 220b in both of the steps; by contrast, in the example of the transistor 200E, a depressed portion is formed in the conductive layer 220b not in the step of forming the opening portion 290 but in the step of forming the insulating layer 235.

In the transistor 200E, the insulating layer 235 is in contact with the side surface of the insulating layer 280a, the side surface of the conductive layer 255, the side surface of the insulating layer 280b, the side surface of the conductive layer 240a, the side surface of the conductive layer 240b, and the top surface of the conductive layer 220b in the opening portion 290. The oxide semiconductor layer 230 is in contact with the bottom and side surfaces of the depressed portion of the conductive layer 220b.

When a depressed portion is formed in the conductive layer 220b in at least one of the step of forming the opening portion 290 and the step of forming the insulating layer 235, the level of the bottom surface of the conductive layer 265a in the opening portion 290 can be made low; accordingly, a gate electric field can be easily applied to the channel formation region of the oxide semiconductor layer 230 and the electrical characteristics of the transistor 200 can be improved.

A depressed portion is preferably formed in the conductive layer 220b in the step of forming the insulating layer 235, in which case the oxide semiconductor layer 230 can be in contact with the bottom and side surfaces of the depressed portion of the conductive layer 220b, so that the contact area between the oxide semiconductor layer 230 and the conductive layer 220b is increased and accordingly the contact resistance between the oxide semiconductor layer 230 and the conductive layer 220b can be reduced.

### [Transistor 200F]

FIG. 6B is a cross-sectional view of a semiconductor device including a transistor 200F.

The transistor 200F is different from the transistor 200 mainly in that the insulating layer 235 does not cover the side surface of the conductive layer 240b.

The insulating layer 235 illustrated in FIG. 6B is in contact with the bottom and side surfaces of the depressed portion of the conductive layer 220, and is in contact with the side surfaces of the insulating layer 280a, the conductive layer 255, and the insulating layer 280b in the opening portion 290. The insulating layer 235 is in contact with part of the side surface of the conductive layer 240a and not in contact with the side surface of the conductive layer 240b. The insulating layer 235 functions as a second gate insulating layer. Thus, the insulating layer 235 covers at least the entire side surface of the conductive layer 255 in the opening portion 290 to electrically insulate the conductive layer 255 and the oxide semiconductor layer 230 from each other. The insulating layer 235 may be in contact with one or more of the side surfaces of the insulating layer 280a, the insulating layer 280b, the conductive layer 240a, and the conductive layer 240b in the opening portion 290, or may cover part or the whole of each side surface.

In the case where at least part of the side surface of the conductive layer 240b is not covered with the insulating layer 235, the uncovered part is in contact with the oxide semiconductor layer 230. This is preferable because the contact area between the oxide semiconductor layer 230 and the conductive layer 240 can be increased and the contact resistance therebetween can be reduced. Similarly, in the case where the insulating layer 235 does not cover the side surface of the conductive layer 240b and at least part of the side surface of the conductive layer 240a, the uncovered part is in contact with the oxide semiconductor layer 230. This is preferable because the contact area between the oxide semiconductor layer 230 and the conductive layer 240 can be increased and the contact resistance therebetween can be reduced.

### [Transistor 200G]

FIG. 6C is a cross-sectional view of a semiconductor device including a transistor 200G.

The transistor 200G is different from the transistor 200 mainly in including the insulating layer 280c, the insulating layer 280d, an insulating layer 280e, and an insulating layer 280f.

In the transistor 200G, a silicon oxide film is preferably used as each of the insulating layers 280a and 280b, and a silicon nitride film or an aluminum oxide film is preferably used as each of the insulating layers 280c, 280d, 280e, and 280f. A barrier insulating layer against hydrogen is preferably provided as each of the insulating layer 280c in contact with the top surface of the conductive layer 220, the insulating layer 280d in contact with the bottom surface of the conductive layer 240, the insulating layer 280e in contact with the bottom surface of the conductive layer 255, and the insulating layer 280f in contact with the top surface of the conductive layer 255, in which case diffusion of impurities such as hydrogen into the oxide semiconductor layer 230 can be inhibited.

For example, in the case where tungsten, tantalum nitride, or the like is used for the conductive layer 255, the conductive layer 255 might be oxidized when an oxide insulating layer is used as the insulating layer in contact with the conductive layer 255. Thus, a silicon nitride film is preferably used for each of the insulating layers 280e and 280f above and below the conductive layer 255. Accordingly, oxidation of the conductive layer 255 can be inhibited and a barrier insulating layer against hydrogen can be provided.

### [Transistor 200H]

FIG. 6D is a cross-sectional view of a semiconductor device including a transistor 200H.

The transistor 200H is different from the transistor 200 mainly in that the side surface of the conductive layer 220 is aligned with the side surfaces of the conductive layer 240, the insulating layer 280b, the conductive layer 255, and the insulating layer 280a in the opening portion 290.

The width of the conductive layer 220 in the cross-sectional view corresponds to the width of the opening portion 290. Such a structure is preferable because parasitic capacitance generated between the conductive layer 220 and the conductive layer 240 can be reduced.

### [Transistor 200I]

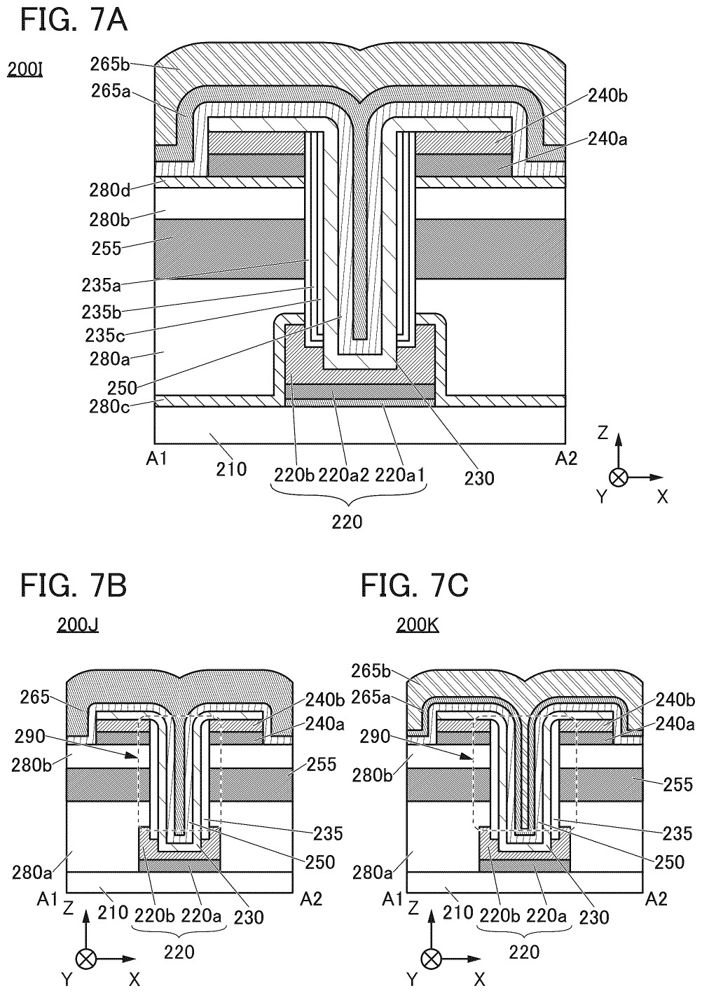

FIG. 7A is a cross-sectional view of a semiconductor device including a transistor 200I.

The transistor 200I is different from the transistor 200 mainly in that the insulating layer 235 has a three-layer structure.

The transistor 200I includes the insulating layer 235a, the insulating layer 235b over the insulating layer 235a, and an insulating layer 235c over the insulating layer 235b. The insulating layer 235a, the insulating layer 235b, and the insulating layer 235c function as a second gate insulating layer of the transistor 200I.

At least one of the insulating layers 235a, 235b, and 235c preferably includes an insulating layer including a region containing oxygen that is released by heating. At least one of the insulating layers 235a, 235b, and 235c preferably includes a barrier insulating layer against hydrogen.

Accordingly, oxygen can be supplied from at least one of the insulating layers 235a, 235b, and 235c to the oxide semiconductor layer 230 and diffusion of hydrogen into the oxide semiconductor layer 230 can be inhibited, leading to higher reliability of the transistor.

For example, it is preferable that a silicon nitride film be used as each of the insulating layers 235a and 235c and a silicon oxide film be used as the insulating layer 235b. Alternatively, it is preferable that a silicon oxide film be used as each of the insulating layers 235a and 235c and a silicon nitride film be used as the insulating layer 235b.

Note that the insulating layer 235 having a three-layer structure in the transistor 200I can be regarded as a variation example of the insulating layer 235 having a two-layer structure in the transistor 200B (FIG. 4B). In the case where the insulating layer 235 has a three-layer structure, the structure is not limited to that illustrated in the transistor 200I. For example, the insulating layer 235 having a two-layer structure in the transistor 200C (FIG. 5A) or the transistor 200D (FIG. 5B) can have a three-layer structure.

### [Transistors 200K and 200J]

FIG. 7B is a cross-sectional view of a semiconductor device including a transistor 200J. FIG. 7C is a cross-sectional view of a semiconductor device including a transistor 200K.

The transistor 200J is different from the transistor 200 mainly in not including the conductive layer 265a or 265b but including the conductive layer 265 having a single-layer structure.

Like the conductive layer 265 included in the transistor 200J, the conductive layer functioning as the gate electrode may have a single-layer structure. The conductive layer 265 is preferably provided to fill the opening portion 290.

The transistor 200K is different from the transistor 200 mainly in that both of the conductive layers 265a and 265b are positioned in the opening portion 290.

In the transistor 200K, the conductive layer 265b is positioned in the opening portion 290. As described above, not only the conductive layer 265a but also the conductive layer 265b is provided in the opening portion 290 in some cases depending on the diameter of the opening portion 290, the thickness of the conductive layer 265a, and the like.

### [Transistor 201]

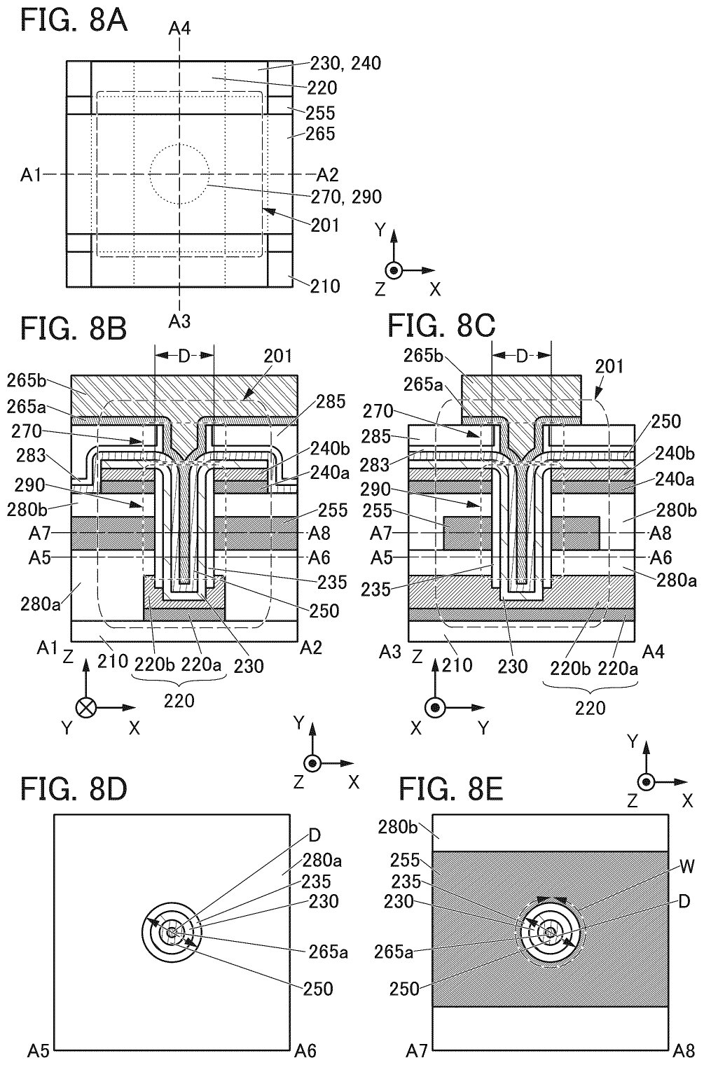

FIG. 8A is a plan view of a semiconductor device including a transistor 201. FIG. 8B is a cross-sectional view taken along dashed-dotted line A1-A2 in FIG. 8A. FIG. 8C is a cross-sectional view taken along dashed-dotted line A3-A4 in FIG. 8A. FIG. 8D is a cross-sectional view taken along dashed-dotted line A5-A6 in FIGS. 8B and 8C. FIG. 8E is a cross-sectional view taken along dashed-dotted line A7-A8 in FIGS. 8B and 8C. Since the structures in FIGS. 8D and 8E are similar to those in FIGS. 2D and 2E, the details thereof are not described.

The semiconductor device illustrated in FIGS. 8A to 8E includes the insulating layer 210 over a substrate (not illustrated), the transistor 201 over the insulating layer 210, the insulating layer 280a over the insulating layer 210, the insulating layer 280b over the insulating layer 280a, an insulating layer 283 over the insulating layer 250, and an insulating layer 285 over the insulating layer 283. The insulating layer 210, the insulating layer 280a, the insulating layer 280b, the insulating layer 283, and the insulating layer 285 function as interlayer films.

The transistor 201 includes the conductive layer 220a, the conductive layer 220b over the conductive layer 220a, the conductive layer 255 over the insulating layer 280a, the conductive layer 240a over the insulating layer 280b, the conductive layer 240b over the conductive layer 240a, the insulating layer 235, the oxide semiconductor layer 230, the insulating layer 250 over the oxide semiconductor layer 230, the conductive layer 265a over the insulating layers 250 and 285, and the conductive layer 265b over the conductive layer 265a.

Since the stacked-layer structure from the conductive layer 220a to the insulating layer 250 in the transistor 201 is similar to that in the transistor 200, the details thereof is not described.

As illustrated in FIGS. 8B and 8C, an opening portion 270 reaching the insulating layer 250 is provided in the insulating layer 283 in a position overlapping with the opening portion 290. The conductive layer 265a is placed to be positioned in the opening portion 270 at least partly. Furthermore, the conductive layer 265b may also be placed to be positioned in the opening portion 270 at least partly. The conductive layer 265a is in contact with the insulating layer 250 in the opening portion 270.

The conductive layer 265a is provided to fill at least part of the opening portion 290 and the opening portion 270.

In the transistor of one embodiment of the present invention, at least one layer included in the conductive layer 265 is provided in the opening portions 290 and 270. In the case where the conductive layer 265 has a stacked-layer structure, it becomes more difficult to place all the layers included in the conductive layer 265 in the opening portions 290 and 270 as the diameters of the opening portions 290 and 270 become smaller with progress of miniaturization of the transistor. FIGS. 8B and 8C illustrate an example where the conductive layer 265 has a two-layer structure, only the conductive layer 265a is provided in the opening portion 290, and the conductive layers 265a and 265b are provided in the opening portion 270. Note that both of the conductive layers 265a and 265b are positioned in the opening portion 290 in some cases depending on the diameter of the opening portion 290, the thickness of the conductive layer 265a, and the like. Only the conductive layer 265a is positioned in the opening portion 270 in some cases depending on the diameter of the opening portion 270, the thickness of the conductive layer 265a, the thickness of the conductive layer 265b, and the like.

Portions of the conductive layers 265a and 265b which do not overlap with the opening portion 290 are mainly positioned over the insulating layer 285. Thus, the conductive layer 265 mainly overlaps with the conductive layer 240 with the insulating layers 283 and 285 therebetween. This can increase the physical distance between the conductive layers 265 and 240, and reduce parasitic capacitance generated therebetween. Note that the conductive layers 240 and 265 may include a portion where they overlap with each other without the insulating layer 285 therebetween.

FIGS. 8B and 8C illustrate an example where the width of the opening portion 270 is smaller than the width D of the opening portion 290. The width of the opening portion 270 is preferably as small as possible because the region where the conductive layers 240 and 265 overlap with each other without the insulating layer 285 therebetween can be narrowed and parasitic capacitance generated between the conductive layers 240 and 265 can be reduced. For example, the width of the opening portion 270 is preferably smaller than or equal to that of the opening portion 290.

Note that the width of the opening portion 270 may be larger than that of the opening portion 290. For example, the width of the opening portion 270 is preferably smaller than that of the short-side width of the conductive layer 265 (the maximum width of the conductive layer 265a and the conductive layer 265b in FIG. 8C). For example, the maximum width of the conductive layer 265 is preferably smaller than or equal to the short-side width of the conductive layer 255 (the maximum width of the conductive layer 255 in the Y direction in FIG. 8E). Accordingly, the area of the portion where the conductive layers 240 and 265 overlap with each other without the insulating layer 285 therebetween can be sufficiently smaller than the area of the portion where the conductive layers 240 and 265 overlap with each other with the insulating layer 285 therebetween, so that parasitic capacitance generated between the conductive layers 240 and 265 can be reduced.

That is, the transistor 201 has a structure where parasitic capacitance generated between the other of the source electrode and the drain electrode and the gate wiring is reduced. Accordingly, the frequency characteristics of a circuit including the transistor can be improved.

Although this embodiment describes the example where the opening portion 270 has a circular shape in the plan view, the present invention is not limited thereto. The shape that can be employed for the opening portion 270 is similar to the above-described shape that can be employed for the opening portion 290.

The width of the opening portion 270 changes in the depth direction in some cases. Here, the maximum width of the opening portion 270 provided in the insulating layer 283 in a cross-sectional view is particularly used as the width of the opening portion 270.

As the insulating layer 283, a barrier insulating layer against hydrogen is preferably used. In this case, diffusion of hydrogen from above the insulating layer 283 into the oxide semiconductor layer 230 can be inhibited. A silicon nitride film and a silicon nitride oxide film can be suitably used for the insulating layer 283 because they release few impurities (e.g., water and hydrogen) and are less likely to transmit oxygen and hydrogen.

It is particularly preferable to use a silicon nitride film formed by a sputtering method as the insulating layer 283. A deposition gas in a sputtering method need not include molecules containing hydrogen; thus, the hydrogen concentration in the insulating layer 283 can be reduced.

When the insulating layer 283 is formed by a sputtering method, a high-density silicon nitride film can be obtained.

As the insulating layer 283, an insulating layer having a function of capturing or fixing hydrogen may be used. With such a structure, diffusion of hydrogen from above the insulating layer 283 into the oxide semiconductor layer 230 can be inhibited, and hydrogen contained in the oxide semiconductor layer 230 can be captured or fixed. Thus, the hydrogen concentration in the oxide semiconductor layer 230 can be reduced. For the insulating layer 283, aluminum oxide, hafnium oxide, hafnium silicate, or the like can be used.

The insulating layer 283 may have a stacked-layer structure of an insulating layer having a function of capturing or fixing hydrogen and a barrier insulating layer against hydrogen. For example, a stacked-layer film of aluminum oxide and silicon nitride over the aluminum oxide may be used for the insulating layer 283.

The insulating layer 285 functions as an interlayer film and thus is preferably formed using the above-described material with a low dielectric constant. For example, the insulating layer 285 preferably includes a silicon oxide film.

### [Transistor 201A]

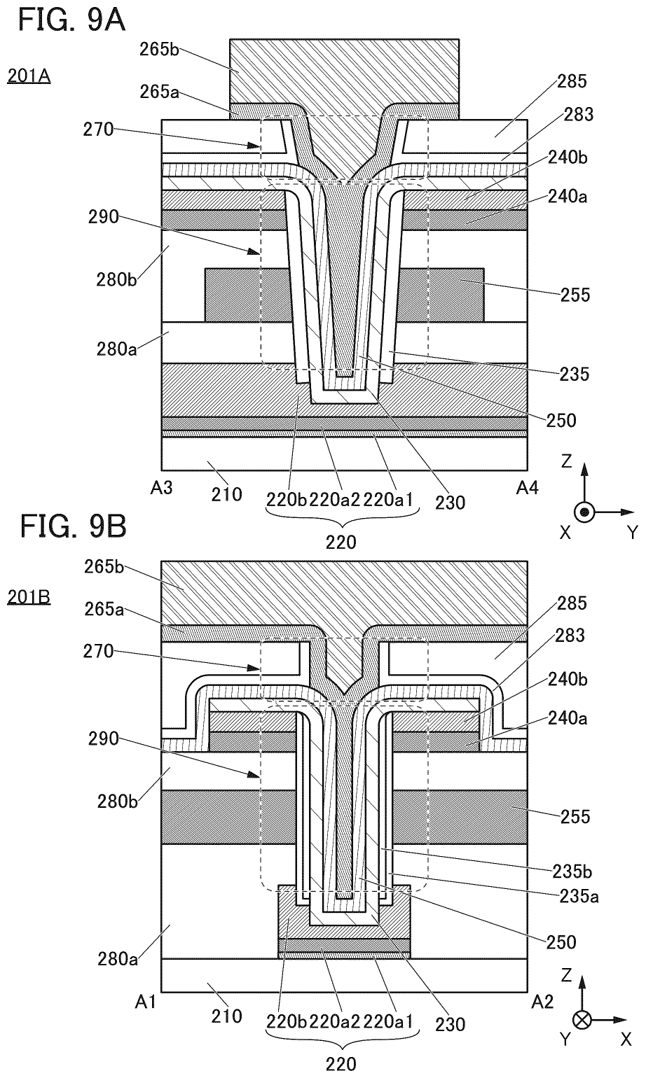

FIG. 9A is a cross-sectional view of a semiconductor device including a transistor 201A.

FIG. 9A illustrates an example where the sidewall of the opening portion 290 has a tapered shape. For the details of the case where the sidewall of the opening portion 290 has a tapered shape, the description of the transistor 200A (FIG. 4A) can be referred to.

### [Transistor 201B]

FIG. 9B is a cross-sectional view of a semiconductor device including a transistor 201B.

The transistor 201B is different from the transistor 201 mainly in that the insulating layer 235 has a two-layer structure. For the details of the case where the insulating layer 235 has a two-layer structure, the description of the transistor 200B (FIG. 4B) can be referred to.

The mode and details of the transistor 201 can be modified as in the case of the transistor 200. Specifically, the transistor 201 can have a structure similar to that of any of the transistors 200C to 200K.

### [Transistor 202]

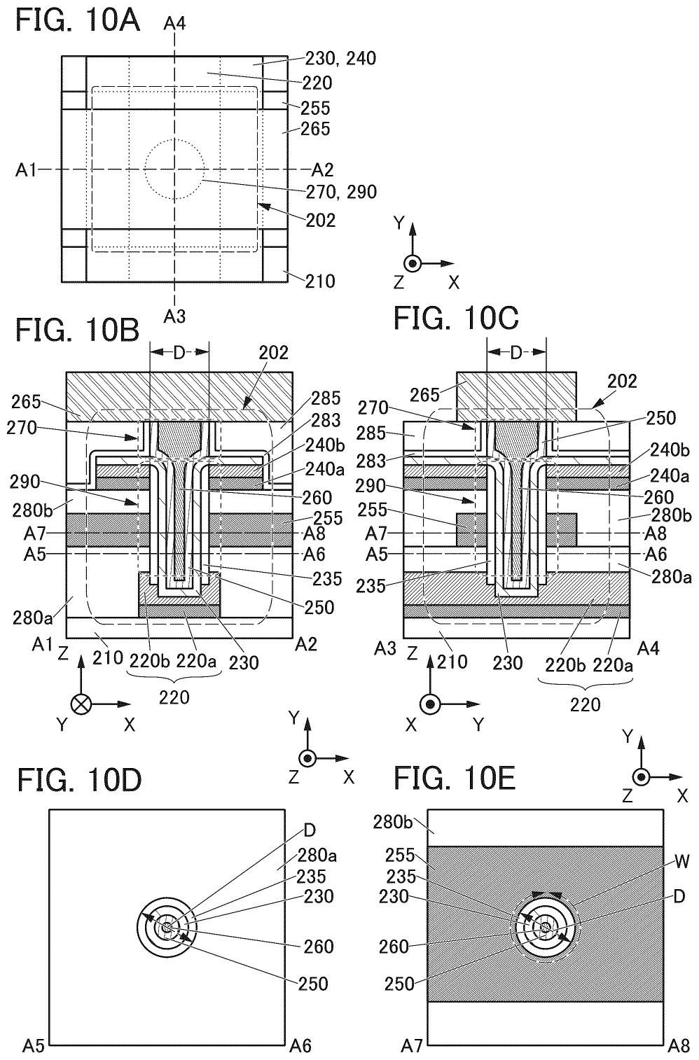

FIG. 10A is a plan view of a semiconductor device including a transistor 202. FIG. 10B is a cross-sectional view taken along dashed-dotted line A1-A2 in FIG. 10A. FIG. 10C is a cross-sectional view taken along dashed-dotted line A3-A4 in FIG. 10A. FIG. 10D is a cross-sectional view taken along dashed-dotted line A5-A6 in FIGS. 10B and 10C. FIG. 10E is a cross-sectional view taken along dashed-dotted line A7-A8 in FIGS. 10B and 10C. Since the structures in FIGS. 10D and 10E are similar to those in FIGS. 2D and 2E except that the conductive layer 265a is not provided but the conductive layer 260 is provided, the details thereof are not described.

The semiconductor device illustrated in FIGS. 10A to 10E includes the insulating layer 210 over a substrate (not illustrated), the transistor 202 over the insulating layer 210, the insulating layer 280a over the insulating layer 210, the insulating layer 280b over the insulating layer 280a, the insulating layer 283 over the insulating layer 250, the insulating layer 285 over the insulating layer 283, and the conductive layer 265 over the insulating layer 285. The insulating layer 210, the insulating layer 280a, the insulating layer 280b, the insulating layer 283, and the insulating layer 285 function as interlayer films.

The transistor 202 includes the conductive layer 220a, the conductive layer 220b over the conductive layer 220a, the conductive layer 255 over the insulating layer 280a, the conductive layer 240a over the insulating layer 280b, the conductive layer 240b over the conductive layer 240a, the insulating layer 235, the oxide semiconductor layer 230, the insulating layer 250 over the oxide semiconductor layer 230, and the conductive layer 260 over the insulating layer 250. Note that the conductive layer 265 may be regarded as a component of the transistor 202.

The conductive layer 260 functions as a gate electrode (a first gate electrode) of the transistor 202, and the conductive layer 265 functions as a gate wiring. The conductive layer 260 can be formed using a material that can be used for the conductive layer 265.

Since the stacked-layer structure from the conductive layer 220a to the insulating layer 230 in the transistor 202 is similar to that in the transistor 200, the details thereof is not described.

As illustrated in FIGS. 10B and 10C, the opening portion 270 reaching the oxide semiconductor layer 230 is provided in the insulating layer 283 in a position overlapping with the opening portion 290. At least part of the components of the transistor 202 is placed in the opening portion 270. Specifically, the insulating layer 250 and the conductive layer 260 are placed in the opening portion 270 at least partly. The insulating layer 250 is in contact with the oxide semiconductor layer 230 and the insulating layer 283 in the opening portion 270.

A portion of the insulating layer 250 which is placed in the opening portion 270 reflects the shape of the opening portion 270. Specifically, the insulating layer 250 is provided to cover the sidewall of the opening portion 270 (the side surface of the insulating layer 283). Then, the conductive layer 260 is provided to fill at least part of a depressed portion of the insulating layer 250 reflecting the shape of the opening portion 270.

Since the conductive layer 260 does not overlap with the top surface of the conductive layer 240 in the transistor 202, parasitic capacitance generated between the conductive layer 240 and the conductive layer 260 can be reduced. As illustrated in FIGS. 10B and 10C, the maximum width of the conductive layer 260 is smaller than the width D of the opening portion 290 in the cross-sectional view. As described above, the maximum width of the conductive layer 260 is preferably smaller than the width D of the opening portion 290, in which case parasitic capacitance generated between the conductive layer 260 and the conductive layer 240 can be reduced. Note that for example, as illustrated in FIG. 10B or FIG. 10C, the relation between the two widths in the semiconductor device of one embodiment of the present invention can be found in one cross section parallel to the Z direction.

FIGS. 10B and 10C illustrate an example where the width of the opening portion 270 corresponds to that of the opening portion 290 (is equal to the width D). The width of the opening portion 270 is preferably smaller than or equal to that of the opening portion 290. This is preferable because the conductive layer 260 does not overlap with the top surface of the conductive layer 240 and accordingly parasitic capacitance generated between the conductive layer 260 and the conductive layer 240 can be reduced.

Although this embodiment mainly describes the example where the conductive layer 260 does not overlap with the top surface of the conductive layer 240, the conductive layer 260 may include a portion overlapping with the top surface of the conductive layer 240. The overlapping portion is preferably as small as possible because parasitic capacitance generated between the conductive layer 260 and the conductive layer 240 can be reduced. For example, the width of the opening portion 270 is preferably smaller than the short-side width of the conductive layer 265 (the maximum width of the conductive layer 265 in FIG. 10C). The maximum width of the conductive layer 265 is, for example, preferably smaller than or equal to the short-side width of the conductive layer 255 (the maximum width of the conductive layer 255 in the Y direction in FIG. 10E).

The top surface of the conductive layer 260 is preferably level with or substantially level with the top surface of the insulating layer 285. The conductive layer 265 is provided over the insulating layer 285, the insulating layer 283, and the conductive layer 260, and is in contact with the top surface of the conductive layer 260. It can be said that the conductive layer 260 and the conductive layer 265 are electrically connected to each other. The insulating layer 283 and the insulating layer 285 are positioned between the conductive layer 265 and the conductive layer 240. This can increase the physical distance between the conductive layer 265 and the conductive layer 240, and reduce the parasitic capacitance generated therebetween.

That is, the transistor 202 has a structure where parasitic capacitance generated between the other of the source electrode and the drain electrode and the gate electrode and parasitic capacitance generated between the other of the source electrode and the drain electrode and the gate wiring are reduced. Accordingly, the frequency characteristics of a circuit using the transistor can be increased.

### [Transistor 202A]

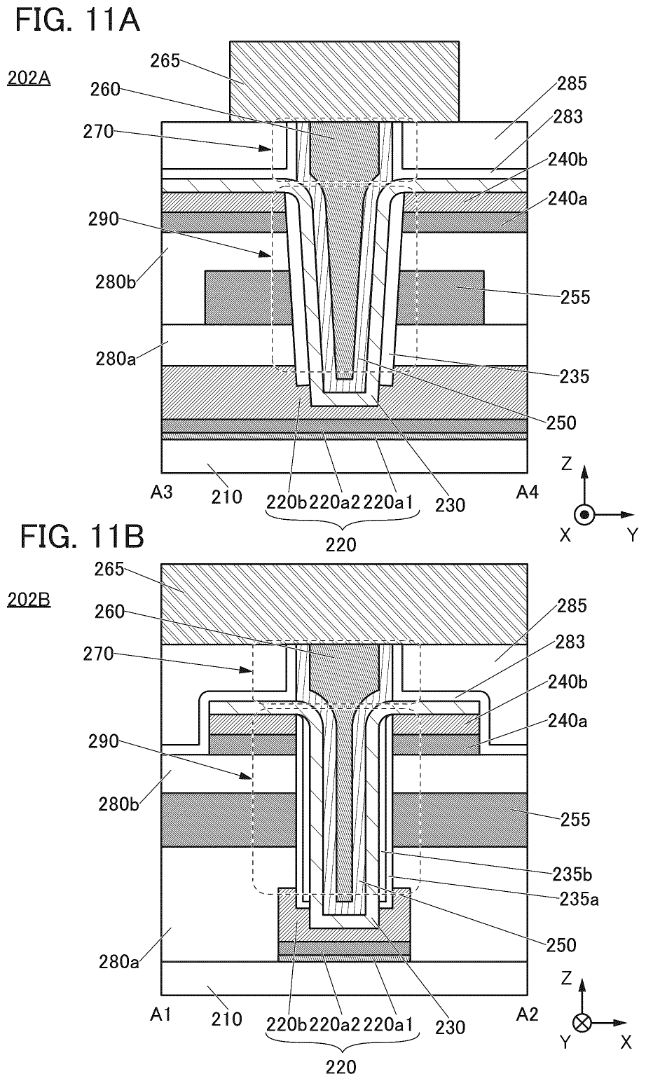

FIG. 11A is a cross-sectional view of a semiconductor device including a transistor 202A.

FIG. 11A illustrates an example where the sidewall of the opening portion 290 has a tapered shape. For the details of the case where the sidewall of the opening portion 290 has a tapered shape, the description of the transistor 200A (FIG. 4A) can be referred to.

### [Transistor 202B]

FIG. 11B is a cross-sectional view of a semiconductor device including a transistor 202B.

The transistor 202B is different from the transistor 202 mainly in that the insulating layer 235 has a two-layer structure. For the details of the case where the insulating layer 235 has a two-layer structure, the description of the transistor 200B (FIG. 4B) can be referred to.

The mode and details of the transistor 202 can be modified as in the case of the transistor 200. Specifically, the transistor 202 can have a structure similar to that of any of the transistors 200C to 200K.

### [Transistor 203]

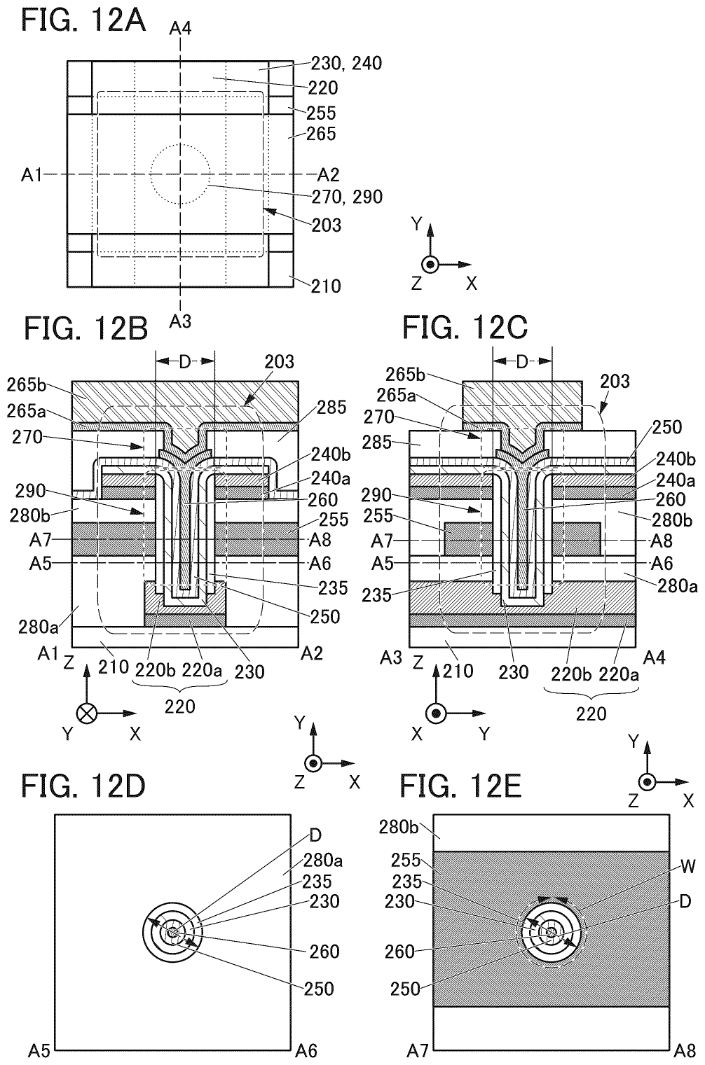

FIG. 12A is a plan view of a semiconductor device including a transistor 203. FIG. 12B is a cross-sectional view taken along dashed-dotted line A1-A2 in FIG. 12A. FIG. 12C is a cross-sectional view taken along dashed-dotted line A3-A4 in FIG. 12A. FIG. 12D is a cross-sectional view taken along dashed-dotted line A5-A6 in FIGS. 12B and 12C. FIG. 12E is a cross-sectional view taken along dashed-dotted line A7-A8 in FIGS. 12B and 12C. Since the structures in FIGS. 12D and 12E are similar to those in FIGS. 2D and 2E except that the conductive layer 265a is not provided but the conductive layer 260 is provided, the details thereof are not described.

The semiconductor device illustrated in FIGS. 12A to 12E includes the insulating layer 210 over a substrate (not illustrated), the transistor 203 over the insulating layer 210, the insulating layer 280a over the insulating layer 210, the insulating layer 280b over the insulating layer 280a, the insulating layer 285 over the insulating layer 250, the conductive layer 265a over the insulating layer 285, and the conductive layer 265b over the conductive layer 265a. The insulating layer 210, the insulating layer 280a, the insulating layer 280b, and the insulating layer 285 function as interlayer films.

The transistor 203 includes the conductive layer 220a, the conductive layer 220b over the conductive layer 220a, the conductive layer 255 over the insulating layer 280a, the conductive layer 240a over the insulating layer 280b, the conductive layer 240b over the conductive layer 240a, the insulating layer 235, the oxide semiconductor layer 230, the insulating layer 250 over the oxide semiconductor layer 230, and the conductive layer 260 over the insulating layer 250. Note that the conductive layer 265a and the conductive layer 265b may each be regarded as a component of the transistor 203.

The conductive layer 260 functions as a gate electrode (a first gate electrode) of the transistor 203, and the conductive layer 265a and the conductive layer 265b function as a gate wiring. The conductive layer 260 can be formed using a material that can be used for the conductive layer 265.

Since the stacked-layer structure from the conductive layer 220a to the insulating layer 250 in the transistor 203 is similar to that in the transistor 200, the details thereof are not described.

As illustrated in FIGS. 12B and 12C, the transistor 203 includes the conductive layer 260 over the insulating layer 250. The conductive layer 260 is provided to fill the opening portion 290. The conductive layer 260 included in the transistor 203 can be referred to as a conductive layer having a shape changed from that of the conductive layer 265a included in the transistor 200. The conductive layer 260 extends in neither the X direction nor the Y direction. The width of the conductive layer 260 is preferably small in both the X direction and the Y direction. Thus, the area of a region of the conductive layer 260 overlapping with the top surface of the conductive layer 240 can be reduced, so that parasitic capacitance generated between the conductive layer 260 and the conductive layer 240 can be reduced.

FIGS. 12B and 12C illustrate an example where the maximum width of the conductive layer 260 is smaller than the width D of the opening portion 290. In this manner, the maximum width of the conductive layer 260 is preferably smaller than or equal to the width of the opening portion 290.

Note that the maximum width of the conductive layer 260 may be larger than the width of the opening portion 290. For example, the maximum width of the conductive layer 260 is preferably smaller than or equal to the short-side width of the conductive layer 265 (the maximum width of the conductive layer 265a and the conductive layer 265b in FIG. 12C). The maximum width of the conductive layer 260 is, for example, preferably smaller than or equal to the short-side width of the conductive layer 255 (the maximum width of the conductive layer 255 in the Y direction in FIG. 12E). Thus, the area of the portion where the conductive layer 260 and the conductive layer 240 overlap with each other can be sufficiently small, and accordingly parasitic capacitance generated between the conductive layer 260 and the conductive layer 240 can be reduced.

As illustrated in FIGS. 12B and 12C, the opening portion 270 reaching the conductive layer 260 is provided in the insulating layer 285 in a position overlapping with the opening portion 290. The conductive layer 265a is placed to be positioned in the opening portion 270 at least partly. Furthermore, the conductive layer 265b may also be placed to be positioned in the opening portion 270 at least partly. The conductive layer 265a is in contact with the conductive layer 260 in the opening portion 270. It can be said that the conductive layer 260 and the conductive layer 265 are electrically connected to each other.

The conductive layer 265a is provided to fill at least part of the opening portion 270. The conductive layer 265b may be provided to fill part of the opening portion 270.

In the transistor of one embodiment of the present invention, at least one layer included in the conductive layer 265 is provided in the opening portion 270. In the case where the conductive layer 265 has a stacked-layer structure, it becomes more difficult to place all the layers included in the conductive layer 265 in the opening portion 270 as the diameter of the opening portion 270 becomes smaller with progress of miniaturization of the transistor. FIGS. 12B and 12C illustrate an example where the conductive layer 265 has a two-layer structure, and the conductive layer 265a and the conductive layer 265b are provided in the opening portion 270. Note that only the conductive layer 265a is positioned in the opening portion 270 in some cases depending on the diameter of the opening portion 270, the thickness of the conductive layer 265a, the thickness of the conductive layer 265b, and the like.

Portions of the conductive layers 265a and 265b which do not overlap with the opening portion 290 are mainly positioned over the insulating layer 285. Thus, the conductive layer 265 mainly overlaps with the conductive layer 240 with the insulating layer 285 therebetween. This can increase the physical distance between the conductive layers 265 and 240, and reduce parasitic capacitance generated therebetween. Note that the conductive layers 240 and 265 may include a portion where they overlap with each other without the insulating layer 285 therebetween.

FIGS. 12B and 12C illustrate an example where the width of the opening portion 270 is smaller than the width D of the opening portion 290. The width of the opening portion 270 is preferably as small as possible because the region where the conductive layers 240 and 265 overlap with each other without the insulating layer 285 therebetween can be narrowed and parasitic capacitance generated between the conductive layers 240 and 265 can be reduced. For example, the width of the opening portion 270 is preferably smaller than or equal to that of the opening portion 290.

Note that the width of the opening portion 270 may be larger than that of the opening portion 290. For example, the width of the opening portion 270 is preferably smaller than the short-side width of the conductive layer 265 (the maximum width of the conductive layer 265a and the conductive layer 265b in FIG. 12C). The maximum width of the conductive layer 265 is, for example, preferably smaller than or equal to the short-side width of the conductive layer 255 (the maximum width of the conductive layer 255 in the Y direction in FIG. 12E). Accordingly, the area of the portion where the conductive layers 240 and 265 overlap with each other without the insulating layer 285 therebetween can be sufficiently smaller than the area of the portion where the conductive layers 240 and 265 overlap with each other with the insulating layer 285 therebetween, so that parasitic capacitance generated between the conductive layers 240 and 265 can be reduced.

That is, the transistor 203 has a structure where parasitic capacitance generated between the other of the source electrode and the drain electrode and the gate wiring is reduced. Accordingly, the frequency characteristics of a circuit using the transistor can be increased.

### [Transistor 203A]

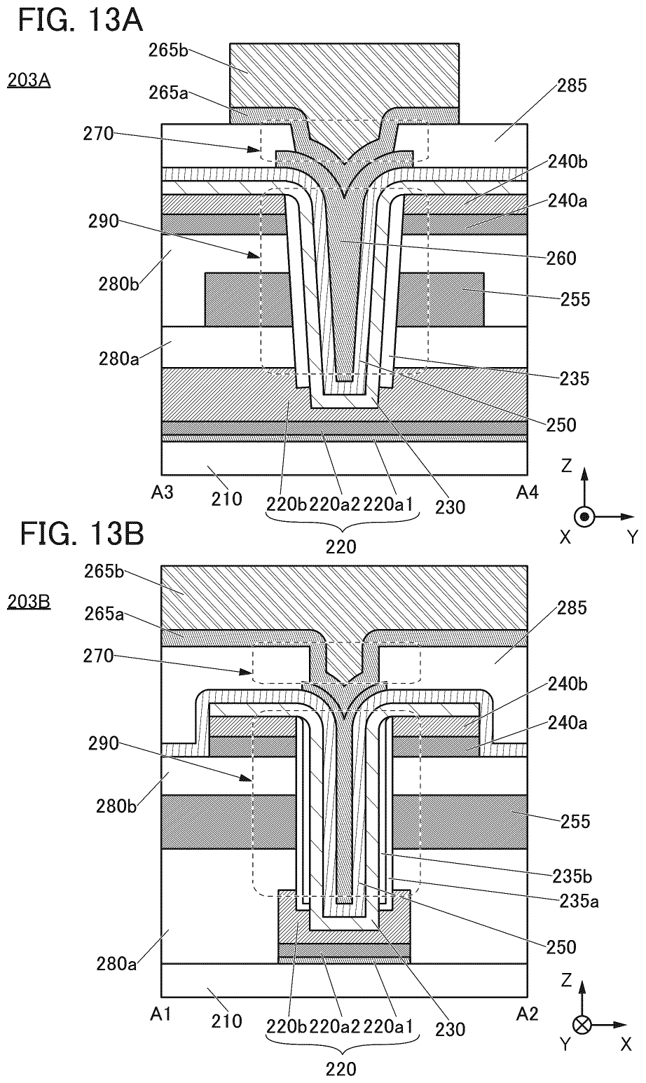

FIG. 13A is a cross-sectional view of a semiconductor device including a transistor 203A.

FIG. 13A illustrates an example where the sidewall of the opening portion 290 has a tapered shape. For the details of the case where the sidewall of the opening portion 290 has a tapered shape, the description of the transistor 200A (FIG. 4A) can be referred to.

### [Transistor 203B]

FIG. 13B is a cross-sectional view of a semiconductor device including a transistor 203B.

The transistor 203B is different from the transistor 203 mainly in that the insulating layer 235 has a two-layer structure. For the details of the case where the insulating layer 235 has a two-layer structure, the description of the transistor 200B (FIG. 4B) can be referred to.

The mode and details of the transistor 203 can be modified as in the case of the transistor 200. Specifically, the transistor 203 can have a structure similar to that of any of the transistors 200C to 200K.

### [Transistors 203C and 203D]

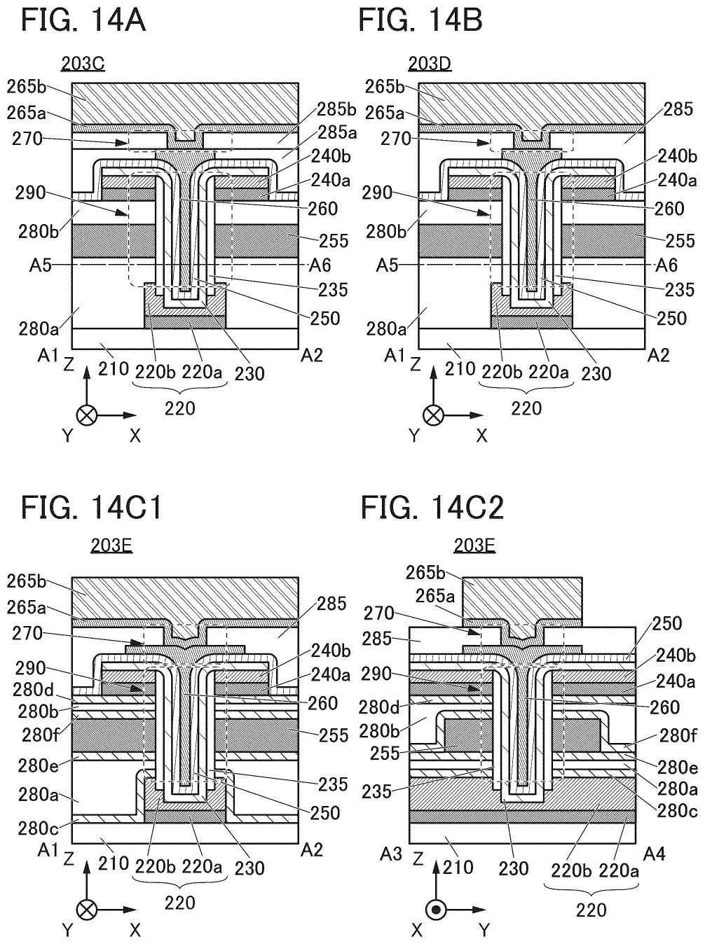

FIG. 14A is a cross-sectional view of a semiconductor device including a transistor 203C. FIG. 14B is a cross-sectional view of a semiconductor device including a transistor 203D.

The transistor 203C is different from the transistor 203 mainly in that an insulating layer 285a and an insulating layer 285b are provided instead of the insulating layer 285.

The transistor 203C and the transistor 203D are different from the transistor 203 mainly in that the top surface of the conductive layer 260 is flat.

As described above, the top surface of the conductive layer 260 may be planarized. The top surface of the conductive layer 260 is preferably level with or substantially level with the top surface of the insulating layer 285a.

### [Transistor 203E]

FIGS. 14C1 and 14C2 are cross-sectional views of a semiconductor device including a transistor 203E.

The transistor 203E is different from the transistor 203 mainly in that the conductive layer 260 includes a portion overlapping with the top surface of the conductive layer 240b.

As described above, the conductive layer 260 may include a portion overlapping with the conductive layer 240. Meanwhile, it is preferable that the conductive layer 265 functioning as a gate wiring be additionally provided and the insulating layer 285 be provided between the conductive layers 265 and 240. This can increase the physical distance between the conductive layers 265 and 240, and reduce parasitic capacitance generated between the gate wiring and the conductive layer 240.

### [Region Containing Halogen Element and Region Containing First Element]

In the semiconductor device of one embodiment of the present invention, at least one of the side surface of the insulating layer 280a on the opening portion 290 side and the vicinity thereof, the side surface of the insulating layer 280b on the opening portion 290 side and the vicinity thereof, the insulating layer 235, and the oxide semiconductor layer 230 may include a region containing a halogen element.

The halogen element is preferably one or more selected from chlorine, fluorine, bromine, and iodine, and further preferably chlorine or fluorine. In terms of substitution for oxygen, fluorine having higher electronegativity than oxygen is preferably used.

When the insulating layer 280a, the insulating layer 280b, or the insulating layer 235 contains a halogen element, the halogen element can be supplied to the oxide semiconductor layer 230. The halogen element (X) has a function of generating an electron serving as a carrier by entering an oxygen vacancy (Vo) in the oxide semiconductor layer 230 to form a defect (VoX). For example, in the case where chlorine (Cl) is used as the halogen element, Cl exists stably in a state of VoCl in the oxide semiconductor layer 230 (particularly at and near the interface between the insulating layer 235 and the oxide semiconductor layer 230). At this time, Cl can be in the state of VoCl by not only entering an existing Vo but also substituting for oxygen.

In contrast, oxygen substituted by Cl (also referred to as excess oxygen) has a function of trapping electrons. Furthermore, carrier trap by oxygen takes precedence over carrier generation by VoCl. Thus, a negative charge (also referred to as negative fixed charge) is formed at and near the interface between the insulating layer 235 and the oxide semiconductor layer 230. When a negative charge exists in the channel formation region, the threshold voltage of the transistor can be shifted positively. Thus, even when the transistor has a fine structure or an extremely small channel length, the transistor can be normally off.

As described above, the transistor of one embodiment of the present invention can be normally off not only by control of the threshold voltage with a back gate but also by the use of a halogen element.

In the semiconductor device of one embodiment of the present invention, the source region and the drain region of the oxide semiconductor layer 230 preferably contain an impurity element. A first element is preferably used as the impurity element. Alternatively, the first element and hydrogen are each preferably used as the impurity element. It is particularly preferable that the oxide semiconductor layer 230 contain the impurity element in the above-described region 230n⁺ (see FIG. 3).

Note that at least one of the conductive layers 240a, 240b, 220a, and 220b may also contain the impurity element.

As the first element, it is preferable to use one or more of boron, aluminum, indium, carbon, silicon, germanium, tin, phosphorus, arsenic, antimony, magnesium, calcium, titanium, copper, zinc, tungsten, molybdenum, tantalum, hafnium, cerium, and a noble gas (helium, neon, argon, krypton, xenon, and the like).

The first element is not limited to the above elements, and one or more of first transition elements (3d transition elements or 3d transition metals), second transition elements (4d transition elements or 4d transition metals), third transition elements (5d transition elements or 5d transition metals), alkaline earth metal elements, and rare earth elements can be used.

When the first element is supplied to the source region and the drain region, the first element deprives these regions of oxygen, for example, and accordingly generates an oxygen vacancy therein. Then, the oxygen vacancy is bonded to hydrogen in the film, so that a carrier is generated and the resistances of the source region and the drain region can be reduced. Accordingly, the sheet resistance of the oxide semiconductor layer 230, the contact resistance between the oxide semiconductor layer 230 and the conductive layer 220, and the contact resistance between the oxide semiconductor layer 230 and the conductive layer 240 can be reduced. Thus, the on-state current of the transistor can be increased. The increased on-state current can reduce the operation voltage of the transistor. This can reduce the power consumption of the semiconductor device.

In the case where an element that is easily bonded to oxygen is used as the first element, the first element exists in a state of being bonded to oxygen in the semiconductor layer. Furthermore, when an element that is stabilized by being bonded to oxygen is used as the first element, the first element in the semiconductor layer exists stably in an oxidized state and thus is not easily released by heat or the like applied during the manufacturing process of the semiconductor device, thereby enabling a low-resistance region that is stable in a low-electric-resistance state. Therefore, as the first element, it is preferable to use an element an oxide of which can exist as a solid at 25° C. and 1 atmospheric pressure. Specifically, a typical non-metallic element other than hydrogen, a typical metal element, and a transition element (transition metal) are preferable as the first element, and boron, phosphorus, magnesium, aluminum, and silicon are particularly preferable as the first element.

Thus, boron, phosphorus, magnesium, aluminum, or silicon is preferably used as the first element. In particular, boron or phosphorus is preferably used as the first element.

Furthermore, hydrogen has a function of being bonded to an oxygen vacancy in addition to the function of generating an oxygen vacancy, and thus is suitable as the impurity element.

When the first element and hydrogen are each used as the impurity element, the electric resistances of the source and drain regions of the oxide semiconductor layer 230 are easily reduced and a low-electric-resistance state can be kept stably.

Both the first element and hydrogen are preferably supplied because ions generated from the source gases can be added without mass separation and thus the productivity can be increased. For example, when a B₂H₆ gas is used, boron and hydrogen can be supplied as the impurity element. As another example, when a PH₃ gas is used, phosphorus and hydrogen can be supplied as the impurity element. Note that the method for supplying the impurity element is not limited thereto. For example, a specific element may be added after a source gas is ionized and then the ion is subjected to mass separation. For example, boron may be added after mass separation of an ionized B₂H₆ gas.

Note that the impurity element is supplied also to the channel formation region of the oxide semiconductor layer 230 in some cases. Alternatively, the above impurity element contained in the region 230n⁺ or the region 230-sometimes partly diffuses into the channel formation region (the region 230i) due to the influence of heat applied during the manufacturing process, for example.

In manufacturing the semiconductor device of one embodiment of the present invention, an impurity element is preferably added to the source and drain regions of the oxide semiconductor layer 230 more easily than to the channel formation region. Thus, the impurity element is preferably added from a direction perpendicular or substantially perpendicular to the top surface of the substrate. At this time, in the oxide semiconductor layer 230, the addition amount of the impurity element is smaller in a surface inclined to the top surface of the substrate than in a surface parallel or substantially parallel to the top surface of the substrate. That is, in the oxide semiconductor layer 230, the addition amount of the impurity element is larger in the source and drain regions than in the channel formation region. Thus, the resistances of the source and drain regions can be reduced preferentially.

### <Manufacturing Method Example of Semiconductor Device>

Next, a method for manufacturing the semiconductor device of one embodiment of the present invention is described with reference to FIGS. 15A1 to 15E, FIGS. 16A to 16C, FIGS. 17A to 17F, FIGS. 18A to 18F, and FIGS. 19A to 19D. Note that as for a material and a formation method of each component, portions similar to those described in the above embodiment are not described in some cases.

Note that thin films included in the semiconductor device (e.g., insulating films, semiconductor films, and conductive films) can be formed by any of a sputtering method, a chemical vapor deposition (CVD) method, a vacuum evaporation method, a pulsed laser deposition (PLD) method, an atomic layer deposition (ALD) method, and the like.

Examples of the sputtering method include an RF sputtering method in which a high-frequency power source is used for a sputtering power source, a DC sputtering method in which a DC power source is used, and a pulsed DC sputtering method in which a voltage is applied to an electrode while being changed in a pulsed manner. The RF sputtering method is mainly used in the case where an insulating film is formed, and the DC sputtering method is mainly used in the case where a metal conductive film is formed. The pulsed DC sputtering method is mainly used in the case where a film of a compound such as an oxide, a nitride, or a carbide is formed by a reactive sputtering method.

Note that CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature by a PECVD method. A thermal CVD method does not use plasma and thus causes less plasma damage to an object. A wiring, an electrode, an element (e.g., a transistor or a capacitor), or the like included in a semiconductor device might be charged up by receiving charges from plasma, for example. In that case, accumulated charges might break the wiring, electrode, element, or the like included in the semiconductor device. A thermal CVD method, which does not use plasma, does not cause such plasma damage, and thus can increase the yield of the semiconductor device. A thermal CVD method yields a film with few defects because of no plasma damage during deposition.

As the ALD method, a thermal ALD method, in which a precursor and a reactant react with each other only by a thermal energy, a PEALD method, in which a reactant excited by plasma is used, or the like can be used.

Note that some precursors used in the ALD method contain an element such as carbon or chlorine. Thus, a film formed by the ALD method sometimes contains an element such as carbon or chlorine in a larger quantity than a film formed by another film formation method. Note that these elements can be quantified by XPS or SIMS. The formation method of a metal oxide of one embodiment of the present invention, which employs an ALD method and one or both of a deposition condition with a high substrate temperature and impurity removal treatment, might form a film with smaller amounts of carbon and chlorine than a method employing an ALD method and neither the condition nor the treatment.

Unlike in a film formation method in which particles ejected from a target or the like are deposited, in an ALD method, a film is formed by reaction at a surface of an object to be processed. Thus, an ALD method is less likely to be influenced by the shape of an object and thus enable favorable step coverage. In particular, an ALD method allows excellent step coverage and excellent thickness uniformity and can be suitably used to cover a surface of an opening portion with a high aspect ratio, for example.

A CVD method and an ALD method differ from a sputtering method in which particles ejected from a target or the like are deposited. Thus, a CVD method and an ALD method are less likely to be influenced by the shape of an object and thus enable favorable step coverage. In particular, an ALD method allows excellent step coverage and excellent thickness uniformity and can be suitably used to cover a surface of an opening portion with a high aspect ratio, for example. Note that an ALD method has a relatively low deposition rate; hence, in some cases, an ALD method is preferably combined with another deposition method with a high deposition rate, such as a CVD method.

By a CVD method, a film with a certain composition can be formed by adjusting the flow rate ratio of the source gases. For example, a CVD method enables formation of a film whose composition is gradually changed by changing the flow rate ratio of the source gases during deposition. In the case where a film is formed while the flow rate ratio of the source gases is changed, as compared with the case where a film is formed using a plurality of deposition chambers, the time taken for the deposition can be shortened because the time taken for transfer and pressure adjustment is omitted. Hence, the productivity of the semiconductor device can be improved in some cases.

An ALD method, in which a plurality of different kinds of precursors are introduced at a time, enables formation of a film with a desired composition. In the case where a plurality of different kinds of precursors are introduced, the cycle number of precursor deposition is controlled, whereby a film with a desired composition can be formed.

Alternatively, thin films included in the semiconductor device (e.g., insulating films, semiconductor films, and conductive films) can be formed by a wet process such as a spin coating method, a dip coating method, a spray coating method, an inkjet method, dispensing, screen printing, offset printing, doctor blade coating, slit coating, roll coating, curtain coating, or knife coating.

In processing thin films included in the semiconductor device, a photolithography method or the like can be employed. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of photolithography methods. In one of the methods, a resist mask is formed over a thin film to be processed, the thin film is processed by etching or the like, and then the resist mask is removed. In the other method, a photosensitive thin film is formed and then processed into a desired shape by exposure and development.

As light for exposure in a photolithography method, it is possible to use light with the i-line (wavelength: 365 nm), light with the g-line (wavelength: 436 nm), light with the h-line (wavelength: 405 nm), or light in which the i-line, the g-line, and the h-line are mixed. Alternatively, ultraviolet light, KrF laser light, ArF laser light, or the like can be used. Exposure may be performed by liquid immersion exposure technique. As the light for exposure, extreme ultraviolet (EUV) light or X-rays may also be used. Furthermore, instead of the light for exposure, an electron beam can be used. It is preferable to use EUV, X-rays, or an electron beam because extremely minute processing can be performed. Note that a photomask is not needed when exposure is performed by scanning with a beam such as an electron beam.

For etching of thin films, a dry etching method, a wet etching method, a sandblast method, or the like can be used.

### [Manufacturing Method Example of Transistor 200]

An example of a method for manufacturing the semiconductor device including the transistor 200 (see FIGS. 2A1 to 2E and FIG. 3) is described with reference to FIGS. 15A1 to 15E and FIGS. 16A to 16C.

First, as illustrated in FIGS. 15A1 and 15A2, the insulating layer 210 is formed over a substrate (not illustrated), the conductive layer 220a is formed over the insulating layer 210, the conductive layer 220b is formed over the conductive layer 220a, the insulating layer 280a is formed over the conductive layer 220b, and the conductive layer 255 is formed over the insulating layer 280a.

Note that planarization treatment is preferably performed after formation of the insulating layer 280a to planarize the top surface of the insulating layer 280a. As the planarization treatment, planarization treatment using a chemical mechanical polishing (CMP) method (also referred to as CMP treatment) is suitable. Alternatively, planarization treatment using etching (also referred to as etch back treatment) may be performed. The planarization treatment performed on the insulating layer 280a can planarize the formation surface of the conductive layer 255, thereby inhibiting disconnection of the conductive layer 255. Note that the planarization treatment is not necessarily performed, in which case the manufacturing cost can be reduced.

Next, as illustrated in FIG. 15B, the insulating layer 280b is formed over the conductive layer 255, the conductive layer 240a is formed over the insulating layer 280b, and the conductive layer 240b is formed over the conductive layer 240a.

Next, as illustrated in FIG. 15C, the opening portion 290 is formed in the conductive layer 240b, the conductive layer 240a, the insulating layer 280b, the conductive layer 255, and the insulating layer 280a in a position overlapping with the conductive layer 220a. At this time, a depressed portion is preferably provided in the conductive layer 220b in a position overlapping with the opening portion 290. By formation of the opening portion 290, the bottom and side surfaces of the depressed portion of the conductive layer 220b are preferably exposed.

For microfabrication and a small transistor size, in forming the opening portion 290, part of the conductive layer 220b, part of the conductive layer 240a, part of the conductive layer 240b, part of the conductive layer 255, part of the insulating layer 280a, and part of the insulating layer 280b are preferably processed using anisotropic etching. It is particularly preferable to use a dry etching method because it is suitable for microfabrication. The opening portion 290 may be formed under processing conditions different between layers. Note that the side surface of the depressed portion of the conductive layer 220b, and the side surfaces of the conductive layer 240a, the conductive layer 240b, the conductive layer 255, the insulating layer 280a, and the insulating layer 280b in the opening portion 290 may have different inclinations depending on the materials, processing conditions, and the like for the conductive layer 220b, the conductive layer 240a, the conductive layer 240b, the conductive layer 255, the insulating layer 280a, and the insulating layer 280b.

In the formation step of the opening portion 290 or the like, a region containing a halogen element is sometimes provided in at least one of the bottom and side surfaces of the depressed portion of the conductive layer 220b, the side surface of the insulating layer 280a, the side surface of the insulating layer 280b, the side surface of the insulating layer 255, the side surface of the conductive layer 240a, and the top and side surfaces of the conductive layer 240b. Examples of the region include a region containing fluorine, a region containing chlorine, and a region containing fluorine and chlorine. In some cases, a halogen element derived from an etching gas used in dry etching remains in the region, for example.

Next, heat treatment may be performed. The heat treatment is performed, for example, at higher than or equal to 250° C. and lower than or equal to 650° C., preferably higher than or equal to 300° C. and lower than or equal to 500° C., further preferably higher than or equal to 320° C. and lower than or equal to 450° C.

Note that the heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under a reduced pressure.

Alternatively, the heat treatment may be performed in such a manner that heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen. By the above-described heat treatment, impurities such as water contained in the insulating layer 280a, the insulating layer 280b, and the like can be reduced before formation of the semiconductor layer 230.

The gas used in the above heat treatment is preferably highly purified. For example, the amount of moisture contained in the gas used in the above heat treatment is preferably less than or equal to 1 ppb, further preferably less than or equal to 0.1 ppb, still further preferably less than or equal to 0.05 ppb. The heat treatment using a highly purified gas can, for example, prevent entry of moisture into the insulating layer 280a, the insulating layer 280b, and the like as much as possible.

Next, as illustrated in FIG. 15D, the insulating layer 235 is formed to cover the opening portion 290. The insulating layer 235 is provided in contact with the bottom and side surfaces of the depressed portion of the conductive layer 220b, the side surface of the insulating layer 280a, the side surface of the conductive layer 255, the side surface of the insulating layer 280b, the side surface of the conductive layer 240a, and the top and side surfaces of the conductive layer 240b.

The insulating layer 235 is provided in the opening portion 290, and thus is preferably formed by a CVD method or an ALD method, further preferably formed by an ALD method. In such a case, the insulating layer 235 can be provided with good coverage.

Next, as illustrated in FIG. 15E, the insulating layer 235 is processed to expose the top surface of the conductive layer 240b and expose the conductive layer 220b in the opening portion 290. In the opening portion 290, the bottom surface of the depressed portion of the conductive layer 220b is preferably exposed.

When the insulating layer 235 is processed by anisotropic etching, a region of the insulating layer 235 which is positioned on the top surface of the conductive layer 240b and a region of the insulating layer 235 which is positioned on the bottom surface of the opening portion 290 are removed, so that the insulating layer 235 can remain only on the side surface of the opening portion 290. The insulating layer 235 is preferably processed by anisotropic etching using a dry etching method.

Note that as illustrated in FIG. 15E, part of the conductive layer 220b may be removed at the time of processing the insulating layer 235 to provide a depressed portion in the conductive layer 220b.

Next, as illustrated in FIG. 16A, the oxide semiconductor layer 230 is formed to cover the opening portion 290. The oxide semiconductor layer 230 is provided in contact with the bottom and side surfaces of the depressed portion of the conductive layer 220b, the insulating layer 235, and the top surface of the conductive layer 240b.

The oxide semiconductor layer 230 can be formed by a sputtering method, a CVD method, an MBE method, a PLD method, or an ALD method, for example.

The formed oxide semiconductor layer 230 is preferably a film having as uniform thickness as possible along the bottom and side surfaces of the depressed portion of the conductive layer 220b, the insulating layer 235, and the top surface of the conductive layer 240b. The use of an ALD method allows formation of a thin film with good controllability. Therefore, the oxide semiconductor layer 230 is preferably formed by an ALD method.

In addition, when the oxide semiconductor layer 230 has high crystallinity, diffusion of impurities in the oxide semiconductor layer 230 is inhibited, leading to a small variation in electrical characteristics and high reliability of the transistor. The oxide semiconductor layer 230 is preferably formed by a sputtering method, in which case a layer with high crystallinity can be obtained easily as compared with the case of using an ALD method.

In the case where the oxide semiconductor layer 230 is formed by a sputtering method, oxygen or a mixed gas of oxygen and a noble gas is used as a sputtering gas. An increase in the proportion of oxygen in the sputtering gas can increase the amount of excess oxygen contained in the oxide film to be formed. Moreover, when the oxide films are formed by a sputtering method, a target of the In-M-Zn oxide can be used, for example.

In the case where the oxide semiconductor layer 230 is formed by a sputtering method and the proportion of oxygen in the sputtering gas is higher than 30% and lower than or equal to 100%, preferably higher than or equal to 70% and lower than or equal to 100%, an oxygen-excess oxide semiconductor is formed. A transistor including an oxygen-excess oxide semiconductor in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in a channel formation region can have relatively high field-effect mobility. In addition, when the oxide semiconductor layer is formed while the substrate is being heated, the crystallinity of the oxide semiconductor layer can be improved.

For a manufacturing method of the oxide semiconductor layer, description in Embodiment 3 can also be referred to.

Next, heat treatment is preferably performed. The heat treatment is preferably performed in a temperature range where the oxide semiconductor layer 230 does not become polycrystal. The heat treatment temperature is, for example, preferably higher than or equal to 100° C. and lower than or equal to 650° C., further preferably higher than or equal to 250° C. and lower than or equal to 600° C., still further preferably higher than or equal to 350° C. and lower than or equal to 550° C. For the details of the heat treatment, the above description can be referred to.

The gas used in the above heat treatment is preferably highly purified. The heat treatment using a highly purified gas can, for example, prevent entry of moisture or the like into the oxide semiconductor layer 230 as much as possible.

In this embodiment, heat treatment at 450° C. for an hour is performed with a flow rate ratio of a nitrogen gas to an oxygen gas being 4:1. With the heat treatment using the above-described oxygen gas, impurities such as carbon, water, and hydrogen in the oxide semiconductor layer 230 can be reduced. Impurities in the film are reduced in the above manner, whereby the crystallinity of the oxide semiconductor layer 230 can be improved and a dense structure can be obtained. Accordingly, the crystal region in the oxide semiconductor layer 230 can be increased, and an in-plane variation in the crystal region in the oxide semiconductor layer 230 can be reduced. Thus, an in-plane variation in electrical characteristics of the transistor can be reduced.

In the case where at least one of the insulating layers 280a, 280b, and 235 contains oxygen, the oxygen is preferably supplied from the insulating layer containing the oxygen to the channel formation region of the oxide semiconductor layer 230 by heat treatment. Accordingly, oxygen vacancies and V_{O}H can be reduced.

In this manner, oxygen (also referred to as excess oxygen) that is released by heating from the insulating layer in contact with or in the vicinity of the oxide semiconductor layer 230 is supplied to the oxide semiconductor layer 230 in some cases. Since excess oxygen has a function of trapping electrons, a negative charge is likely to be formed. Accordingly, the threshold voltage of the transistor can be shifted positively to achieve a normally-off transistor.

Next, as illustrated in FIG. 16B, the oxide semiconductor layer 230, the conductive layer 240a, and the conductive layer 240b are processed into island shapes so that part of the top surface of the insulating layer 280b is exposed. The oxide semiconductor layer 230, the conductive layer 240a, and the conductive layer 240b can be processed using the same mask. This is preferable because the number of masks required for manufacturing the semiconductor device can be reduced.

Next, as illustrated in FIG. 16C, the insulating layer 250 is formed to cover the opening portion 290, and the conductive layer 265a is formed over the insulating layer 250. Furthermore, the conductive layer 265b is formed over the conductive layer 265a. The insulating layer 250 is provided in contact with the oxide semiconductor layer 230. The conductive layer 265a is preferably provided to fill the opening portion 290. Note that the conductive layer 265b is also provided in the opening portion 290 in some cases depending on the diameter of the opening portion 290, the thickness of the conductive layer 265a, and the like.

The insulating layer 250 and the conductive layer 265a are each formed in the opening portion 290 having a high aspect ratio. Thus, the insulating layer 250 and the conductive layer 265a are preferably formed by a film formation method with favorable coverage, further preferably formed by a CVD method, an ALD method, or the like.

In this manner, the transistor 200 can be manufactured.

### [Manufacturing Method Example of Transistor 201]

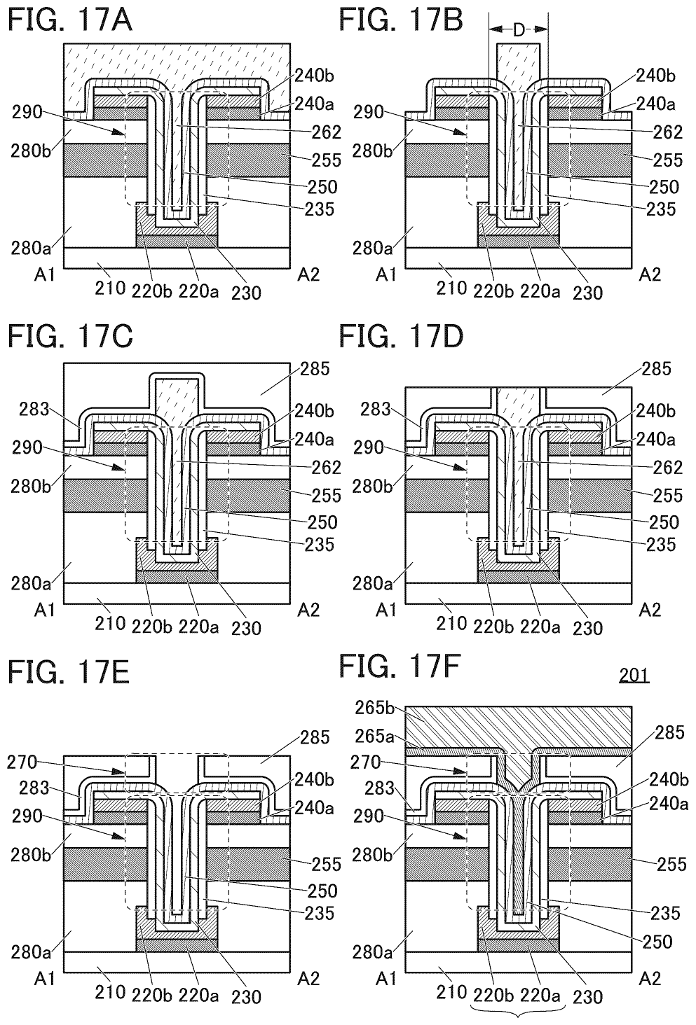

An example of a method for manufacturing the semiconductor device including the transistor 201 (see FIGS. 8A to 8E) will be described with reference to FIGS. 17A to 17F. For steps similar to those of the manufacturing method example of the transistor 200, the detailed description is omitted.

First, the steps of FIGS. 15A1 to 16B are performed as in the manufacturing method example of the transistor 200. Next, as illustrated in FIG. 17A, the insulating layer 250 is formed to cover the insulating layer 280b, the conductive layer 240a, the conductive layer 240b, and the oxide semiconductor layer 230.

After that, a sacrificial layer 262 is formed over the insulating layer 250. As the sacrificial layer 262, a spin on carbon (SOC) film and a spin on glass (SOG) film are suitable. The sacrificial layer 262 preferably has a two-layer structure of an SOC film and an SOG film over the SOC film, for example.

The sacrificial layer 262 is preferably provided over and in contact with the insulating layer 250, in which case damage to the oxide semiconductor layer 230 can be reduced in the manufacturing process of the semiconductor device as compared with the case where the sacrificial layer 262 is provided over and in contact with the oxide semiconductor layer 230. Meanwhile, in the case where the sacrificial layer 262 is provided over and in contact with the oxide semiconductor layer 230 as in a manufacturing method of the transistor 202 to be described later, damage to the insulating layer 250 can be reduced in the manufacturing process of the semiconductor device, which is preferable. Note that in the case where the insulating layer 250 has a stacked-layer structure, some of the layers constituting the insulating layer 250 may be formed before formation of the sacrificial layer 262, and the other layer(s) may be formed after removal of the sacrificial layer 262.

Next, as illustrated in FIG. 17B, part of the sacrificial layer 262 is removed. A gate electrode (the conductive layer 265a and the conductive layer 265b) is provided in a later step in a region where the sacrificial layer 262 remains. Thus, the sacrificial layer 262 preferably overlaps with the top surface of the conductive layer 240b only in a small area, further preferably does not overlap with the top surface of the conductive layer 240b. As illustrated in FIG. 17B, the maximum width of the sacrificial layer 262 is preferably smaller than the width D of the opening portion 290 in a cross-sectional view.

Next, as illustrated in FIG. 17C, the insulating layer 283 is formed to cover the insulating layer 250 and the sacrificial layer 262, and the insulating layer 285 is formed over the insulating layer 283.

When the insulating layer 285 is made thick, the distance between the conductive layer 240b and the conductive layer 265a can be increased, so that parasitic capacitance generated between the conductive layer 240b and the gate electrode (or gate wiring) can be reduced.

A silicon oxide film is preferably formed by a sputtering method as the insulating layer 285, for example.

Here, in the case where the insulating layer 283 is not provided, the sacrificial layer 262 is exposed to plasma containing oxygen in forming a silicon oxide film by a sputtering method as the insulating layer 285, so that part or the whole of the sacrificial layer 262 is etched in some cases. As described above, depending on the formation method of the insulating layer 285, the sacrificial layer 262 might be shrunk or disappear. For this reason, the insulating layer formed over the sacrificial layer 262 preferably has not a single-layer structure of the insulating layer 285 but a stacked-layer structure of the insulating layer 283 and the insulating layer 285. This can produce effects of widening the range of choices of the materials for the sacrificial layer 262 and the insulating layer 285, lowering the difficulty of manufacturing the semiconductor device, and the like.

In the case where an oxide film is used as the insulating layer 283, the oxide film is preferably formed by a method other than a sputtering method, e.g., an ALD method. For example, an aluminum oxide film or a hafnium oxide film is preferably formed as the insulating layer 283 by an ALD method. Alternatively, a nitride film (e.g., a silicon nitride film) is preferably used as the insulating layer 283. Thus, the sacrificial layer 262 can be inhibited from being unintentionally processed in forming the insulating layer 283 and the insulating layer 285.

The insulating layer 283 is preferably formed by a CVD method or an ALD method, further preferably formed by an ALD method. In such a case, the insulating layer 283 can be provided on the side surface of the sacrificial layer 262, for example, with good coverage.

Subsequently, as illustrated in FIG. 17D, planarization treatment is performed to expose the top surface of the sacrificial layer 262 and planarize the top surfaces of the sacrificial layer 262, the insulating layer 283, and the insulating layer 285. As the planarization treatment, CMP treatment is suitable. At least part of the insulating layer 283 and part of the insulating layer 285 are removed by the planarization treatment. Part of the sacrificial layer 262 may further be removed.

Then, as illustrated in FIG. 17E, the sacrificial layer 262 is removed. There is no particular limitation on the method for removing the sacrificial layer 262. For example, the sacrificial layer 262 can be removed by dry etching. Here, as illustrated in FIG. 17E, the insulating layer 283 can be regarded as including the opening portion 270 in a position overlapping with the opening portion 290.

Next, as illustrated in FIG. 17F, the conductive layer 265a is formed to cover the opening portion 270 and the opening portion 290. The conductive layer 265a is provided in contact with the insulating layer 250 and the insulating layer 283 in the opening portion 270 and the opening portion 290. The conductive layer 265a is preferably provided to fill the opening portion 290. Furthermore, the conductive layer 265b is formed over the conductive layer 265a. Here, an example where the conductive layer 265b is provided in the opening portion 270 is illustrated.

The conductive layer 265a and the conductive layer 265b are each formed in one or both of the opening portion 290 and the opening portion 270 that have a high aspect ratio. Thus, the conductive layer 265a and the conductive layer 265b are preferably formed by a film formation method with favorable coverage, further preferably formed by a CVD method, an ALD method, or the like.

Note that the conductive layer 265b is also provided in the opening portion 290 in some cases depending on the diameter of the opening portion 270, the diameter of the opening portion 290, the thickness of the conductive layer 265a, the thickness of the conductive layer 265b, and the like. In another case, the conductive layer 265a fills the opening portion 270, and the conductive layer 265b is not provided in the opening portion 270.

In this manner, the transistor 201 can be manufactured.

### [Manufacturing Method Example of Transistor 202]

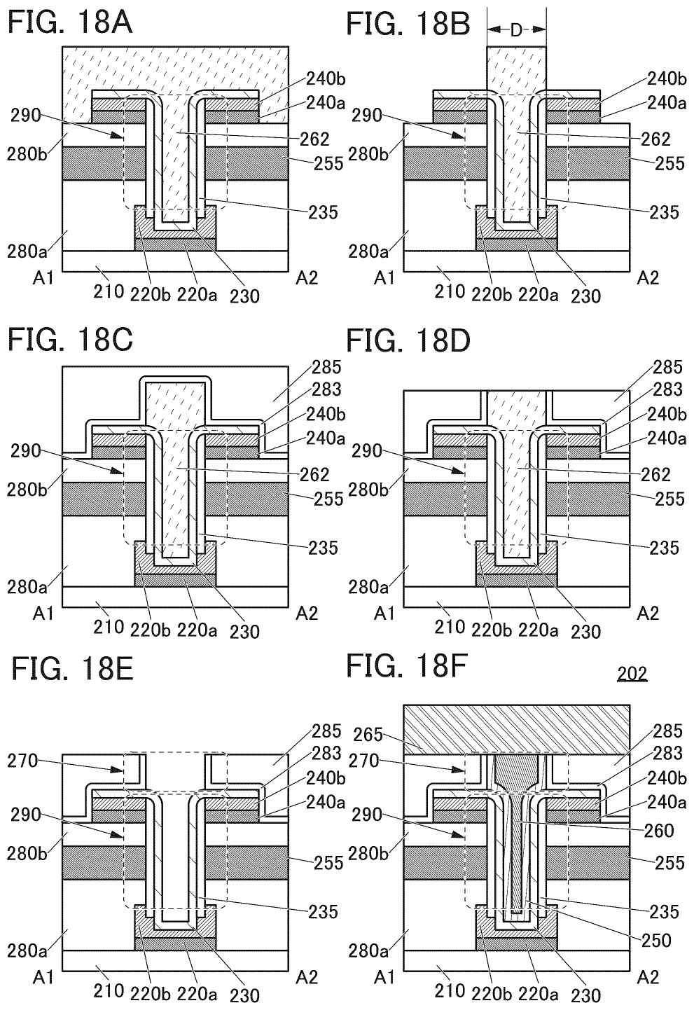

An example of a method for manufacturing the semiconductor device including the above-described transistor 202 (see FIGS. 10A to 10E) will be described with reference to FIGS. 18A to 18F. For steps similar to those of the manufacturing method examples of the transistors 200 and 201, the detailed description is omitted.

First, the steps of FIGS. 15A1 to 16B are performed as in the manufacturing method example of the transistor 200. Next, as illustrated in FIG. 18A, the sacrificial layer 262 is formed to cover the insulating layer 280b, the conductive layer 240a, the conductive layer 240b, and the oxide semiconductor layer 230.

Next, as illustrated in FIG. 18B, part of the sacrificial layer 262 is removed. In a region where the sacrificial layer 262 remains, a gate insulating layer and a gate electrode (the insulating layer 250 and the conductive layer 260) are provided in a later step. Thus, the sacrificial layer 262 preferably overlaps with the top surface of the conductive layer 240b only in a small area, further preferably does not overlap with the top surface of the conductive layer 240b. In a cross-sectional view, the width of the sacrificial layer 262 is preferably less than the sum of the width D of the opening portion 290 and twice the thickness of the insulating layer 250 to be formed later. FIG. 18B illustrates an example where the width of the sacrificial layer 262 corresponds to the width D of the opening portion 290.

Next, as illustrated in FIG. 18C, the insulating layer 283 is formed to cover the insulating layer 280b, the conductive layer 240a, the conductive layer 240b, the oxide semiconductor layer 230, and the sacrificial layer 262, and the insulating layer 285 is formed over the insulating layer 283.

When the insulating layer 285 is made thick, the distance between the conductive layer 240b and the gate wiring (the conductive layer 265) can be increased, so that parasitic capacitance generated therebetween can be reduced.

Subsequently, as illustrated in FIG. 18D, planarization treatment is performed to expose the top surface of the sacrificial layer 262 and planarize the top surfaces of the sacrificial layer 262, the insulating layer 283, and the insulating layer 285.

Then, as illustrated in FIG. 18E, the sacrificial layer 262 is removed.

Next, as illustrated in FIG. 18F, the insulating layer 250 is formed to cover the opening portion 270 and the opening portion 290, and the conductive layer 260 is formed over the insulating layer 250. Next, planarization treatment is performed to expose the top surfaces of the insulating layers 283 and 285 and planarize the top surfaces of the conductive layer 260, the insulating layer 250, the insulating layer 283, and the insulating layer 285.

The insulating layer 250 is provided in contact with the oxide semiconductor layer 230 and the insulating layer 283.

The insulating layer 250 and the conductive layer 260 are each formed in the opening portion 290 and the opening portion 270 having a high aspect ratio. Thus, the insulating layer 250 and the conductive layer 260 are preferably formed by a film formation method with favorable coverage, further preferably formed by a CVD method, an ALD method, or the like.

As the planarization treatment, CMP treatment is suitable. In the planarization treatment, at least portions of the conductive layer 260 and the insulating layer 250 overlapping with the top surface of the insulating layer 285 are removed. Thus, a portion of the conductive layer 260 overlapping with the top surface of the conductive layer 240 can be removed, so that generation of parasitic capacitance between the conductive layer 260 and the conductive layer 240 can be inhibited.

By removing the portion of the conductive layer 260 overlapping with the top surface of the conductive layer 240 by the CMP treatment, an increase in the number of masks can be suppressed as compared with the case of using dry etching, for example.

As illustrated in FIG. 18F, the top surface of the insulating layer 285 and the top surface of the conductive layer 260 are preferably level with each other. Alternatively, one of the top surface of the insulating layer 285 and the top surface of the conductive layer 260 may be higher than the other. Owing to the difference in polishing rate between the materials for the insulating layer 285 and the conductive layer 260, the top surface levels of the two layers can be controlled.

Next, as illustrated in FIG. 18F, the conductive layer 265 is formed over the insulating layer 250, the insulating layer 283, the insulating layer 285, and the conductive layer 260.

The insulating layer 283 and the insulating layer 285 are positioned between the conductive layer 265 and the conductive layer 240b. This can increase the physical distance between the conductive layer 265 and the conductive layer 240b, and reduce parasitic capacitance generated therebetween.

Through the above steps, the semiconductor device of one embodiment of the present invention can be manufactured.

### [Manufacturing Method Example of Transistor 203]

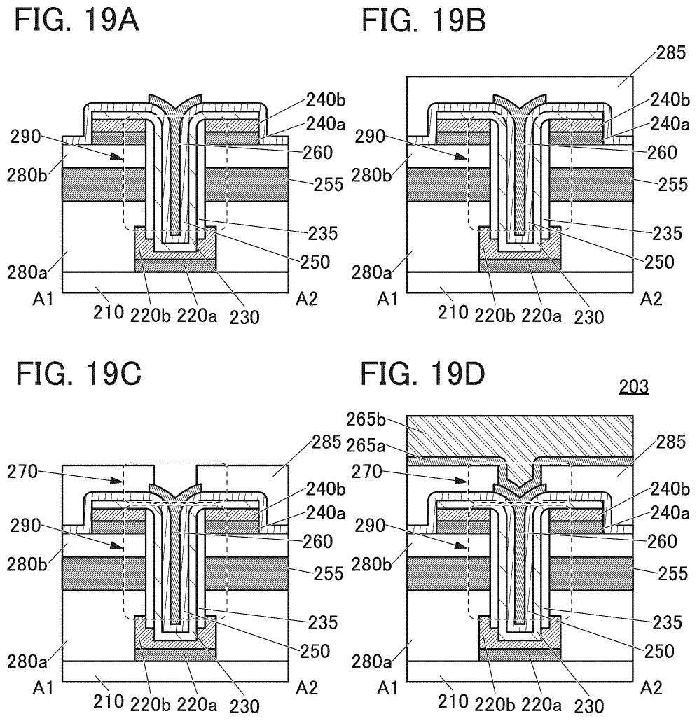

An example of a method for manufacturing the semiconductor device including the above-described transistor 203 (see FIGS. 12A and 12E) will be described with reference to FIGS. 19A to 19D. For steps similar to those of the manufacturing method example of the transistor 200, the detailed description is omitted.

First, the steps of FIGS. 15A1 to 16B are performed as in the manufacturing method example of the transistor 200. Next, as illustrated in FIG. 19A, the insulating layer 250 is formed to cover the insulating layer 280b, the conductive layer 240a, the conductive layer 240b, and the oxide semiconductor layer 230, and the conductive layer 260 is formed over the insulating layer 250.

The insulating layer 250 and the conductive layer 260 are each formed in the opening portion 290 having a high aspect ratio. Thus, the insulating layer 250 and the conductive layer 260 are preferably formed by a film formation method with favorable coverage, further preferably formed by a CVD method, an ALD method, or the like.

The conductive layer 260 preferably overlaps with the top surface of the conductive layer 240b only in a small area, further preferably does not overlap with the top surface of the conductive layer 240b. Thus, parasitic capacitance generated between the conductive layer 260 and the conductive layer 240b can be reduced. Note that as in the transistor 203E (see FIGS. 14C1 and 14C2), the conductive layer 260 may include a portion overlapping with the top surface of the conductive layer 240b.

Next, as illustrated in FIG. 19B, the insulating layer 285 is formed to cover the insulating layer 250 and the conductive layer 260.

When the insulating layer 285 is made thick, the distance between the conductive layer 240b and the conductive layer 265a can be increased, so that parasitic capacitance generated between the conductive layer 240b and the gate wiring can be reduced.

A silicon oxide film is preferably formed by a sputtering method as the insulating layer 285, for example.

Next, as illustrated in FIG. 19C, the opening portion 270 reaching the conductive layer 260 is formed in the insulating layer 285.

Next, as illustrated in FIG. 19D, the conductive layer 265a is formed to cover the opening portion 270, and the conductive layer 265b is formed over the conductive layer 265a. The conductive layer 265a is provided in contact with the conductive layer 260 in the opening portion 270. The conductive layer 265a and the conductive layer 265b are preferably provided to fill the opening portion 270.

The conductive layer 265a and the conductive layer 265b are formed in the opening portion 270 having a high aspect ratio. Thus, the conductive layer 265a and the conductive layer 265b are preferably formed by a film formation method with favorable coverage, further preferably formed by a CVD method, an ALD method, or the like.

Note that the conductive layer 265a fills the opening portion 270 and the conductive layer 265b is not provided in the opening portion 270 in some cases depending on the diameter of the opening portion 270, the thickness of the conductive layer 265a, and the like.

In this manner, the transistor 203 can be manufactured.

### [Method for Adding Element]

As described above, a region containing a halogen element may be provided in at least one of the insulating layer 280a, the insulating layer 280b, the insulating layer 235, and the oxide semiconductor layer 230. A region containing the first element described above may be provided in the oxide semiconductor layer 230. A region containing the first element may be provided in at least one of the conductive layers 220a, 220b, 240a, and 240b.

For example, after the opening portion 290 illustrated in FIG. 15C is formed, a halogen element may be supplied to the side surfaces of the insulating layers 280a and 280b in the opening portion 290. Note that the halogen element may also be supplied to one or more of the conductive layers 240a, 240b, 255, 220a, and 220b.

Here, FIG. 15C illustrates an example where the sidewall of the opening portion 290 is perpendicular to the top surface of the substrate. In the semiconductor device of one embodiment of the present invention, the sidewall of the opening portion 290 is perpendicular or substantially perpendicular to the top surface of the substrate or has a tapered shape. Accordingly, when a halogen element is added perpendicularly or substantially perpendicularly to the top surface of the substrate, it is sometimes difficult to supply the halogen element uniformly to a desired region.

Thus, a halogen element is preferably added in a direction that is inclined to the top surface of the substrate at greater than 0° and less than 90°. Thus, the halogen element can be easily supplied to the side surfaces of the insulating layers 280a and 280b in the opening portion 290. The adding direction is not limited to one direction; the halogen element is preferably supplied step by step at different angles, in which case the halogen element can be supplied to a desired region more uniformly.

An element that can be used as the halogen element is as described above.

A plasma ion doping method or an ion implantation method can be suitably used for the supply of the halogen element. In the above methods, the concentration profile in the depth direction can be controlled with high accuracy by the acceleration voltage and the dose of ions, for example.

Note that when one or both of the substrate to be processed and the ion irradiation portion of the apparatus are inclined, for example, the angle at which the halogen element is added can be within the above range.

With the use of an ion implantation method in which a source gas is ionized and the ion is subjected to mass separation and then added, the purity of the halogen element to be supplied can be increased. Furthermore, with the use of a plasma ion doping method in which the source gas is ionized and the ion is added without mass separation, the productivity can be increased.

An ion implantation apparatus or an ion doping apparatus used for supplying the halogen element is used also in manufacturing a Si transistor such as an LTPS transistor, which is preferable because an apparatus for an existing LTPS manufacturing line can be used and new capital investment is not required. Thus, capital investment for manufacturing the semiconductor device can be reduced.

As the source gas of the halogen element, a gas containing the above-described halogen element can be used. As the gas, a gas of halogen alone or a halide gas can also be used. In the case where fluorine is supplied, an F₂ gas, a BF₃ gas, a C₄F₆ gas, a C₅F₆ gas, a C₄F₈ gas, a CF₄ gas, an SF₆ gas, a CHF₃ gas, a CH₂F₂ gas, a CH₃F gas, or the like can be typically used. In the case where chlorine is supplied, a Cl₂ gas, a BCl₃ gas, an SiCl₄ gas, or a CCl₄ gas can be typically used. A mixed gas in which the above source gas is diluted with hydrogen or a noble gas may be used. The ion source is not limited to a gas, and a solid or a liquid may be vaporized by heating.

The supply of the halogen element can be controlled by setting conditions such as the acceleration voltage and the dose in consideration of the composition, density, thickness, and the like of the insulating layers 280a and 280b.

Note that there is no limitation on the method for supplying the halogen element, and for example, plasma treatment, treatment using thermal diffusion by heating, or the like may be used. In the case of a plasma treatment method, a halogen element can be supplied in such a manner that plasma is generated in a gas atmosphere containing the halogen element to be supplied and plasma treatment is performed. A dry etching apparatus, an ashing apparatus, a plasma CVD apparatus, a high-density plasma CVD apparatus, or the like can be used to generate the plasma.

The step of supplying the halogen element may be performed while the substrate is heated. Thus, damage applied to the insulating layers 280a and 280b when the halogen element is added can be repaired. That is, the addition of the halogen element and the repair of damage due to the addition can be performed on the insulating layers 280a and 280b in parallel.

The substrate temperature in the step of supplying the halogen element is preferably higher than or equal to 150° C. and lower than the strain point of the substrate, further preferably higher than or equal to 200° C. and lower than or equal to 500° C., still further preferably higher than or equal to 200° C. and lower than or equal to 450° C., yet further preferably higher than or equal to 250° C. and lower than or equal to 400° C., yet still further preferably higher than or equal to 250° C. and lower than or equal to 350° C. or higher than or equal to 300° C. and lower than or equal to 400° C., yet still further preferably higher than or equal to 300° C. and lower than or equal to 350° C.

Alternatively, after the insulating layer 235 illustrated in FIG. 15D or FIG. 15E is formed, the halogen element may be supplied to the insulating layer 235 positioned in the opening portion 290.

After that, the oxide semiconductor layer 230 is formed while the substrate is heated, so that the halogen element can be supplied from the insulating layer 280a, 280b, or 235 to the oxide semiconductor layer 230 in some cases. In the heat treatment performed after formation of the oxide semiconductor layer 230, the halogen element can be supplied from the insulating layer 280a, 280b, or 235 to the oxide semiconductor layer 230 in some cases.

As described above, in the semiconductor device of one embodiment of the present invention, the halogen element is added to the insulating layer in contact with or in the vicinity of the oxide semiconductor layer 230, and then supplied from the insulating layer to the oxide semiconductor layer 230; thus, damage to the channel formation region of the oxide semiconductor layer 230 due to the element addition, decrease in crystallinity of the channel formation region due to the element addition, and the like can be inhibited. As a result, the reliability of the transistor can be increased.

Alternatively, after the oxide semiconductor layer 230 illustrated in FIG. 16A or FIG. 16B is formed, the halogen element may be supplied to the side surface of the oxide semiconductor layer 230 positioned in the opening portion 290.

After the opening portion 290 illustrated in FIG. 15C is formed, an impurity element may be supplied to the top surface of the conductive layer 220b and the top surface of the conductive layer 240b.

After that, the oxide semiconductor layer 230 is formed and heat treatment or the like is performed, whereby the impurity element can be supplied from the conductive layers 220b and 240b to the source and drain regions of the oxide semiconductor layer 230.

When the impurity element is supplied to the oxide semiconductor layer 230 through the conductive layer 220 or the conductive layer 240, decrease in crystallinity of the oxide semiconductor layer 230 can be inhibited as compared with the case where the impurity element is directly added to the oxide semiconductor layer 230. Thus, an increase in electric resistance due to decrease in crystallinity can be inhibited.

Note that the step of supplying the impurity element is preferably performed after the step in FIG. 15C but before the step of forming the conductive layer 265a in FIG. 16C. That is, the impurity element may be supplied to the oxide semiconductor layer 230 after formation of the oxide semiconductor layer 230. Alternatively, the impurity element may be added to the oxide semiconductor layer 230 through the insulating layer 250.

When the impurity element is added to the oxide semiconductor layer 230, the sheet resistance of the oxide semiconductor layer 230, the contact resistance between the oxide semiconductor layer 230 and the conductive layer 220, and the contact resistance between the oxide semiconductor layer 230 and the conductive layer 240 can be reduced.

The insulating layer 250 is formed over the oxide semiconductor layer 230 after the impurity element is directly added to the oxide semiconductor layer 230, whereby the insulating layer 250 can be inhibited from being damaged by addition of the impurity element.

When the impurity element is supplied to the oxide semiconductor layer 230 through the insulating layer 250, decrease in crystallinity of the oxide semiconductor layer 230 can be inhibited as compared with the case where the impurity element is directly added to the oxide semiconductor layer 230. Thus, an increase in electric resistance due to decrease in crystallinity can be inhibited.

When the insulating layer 250 is formed after the addition of the impurity element, the deposition chamber of the insulating layer 250 might be contaminated. Thus, the impurity element is preferably added after the formation of the insulating layer 250.

Here, the thickness of the insulating layer 250 in the direction where the impurity element is added is larger in a region along the side surface of the insulating layer 235 than in a region along the top surface of the conductive layer 220b or the top surface of the conductive layer 240b.

Thus, in the oxide semiconductor layer 230, the addition amount of the impurity element is larger in the region along the top surface of the conductive layer 220b or the top surface of the conductive layer 240b than in the region along the side surface of the insulating layer 235. In this manner, the impurity element can be inhibited from entering the channel formation region of the oxide semiconductor layer 230, so that the resistances of the source and drain regions can be reduced preferentially.

The impurity element is preferably added from a direction perpendicular or substantially perpendicular to the top surface of the substrate. At this time, in the oxide semiconductor layer 230, the addition amount of the impurity element is smaller in a surface inclined to the top surface of the substrate than in a surface parallel or substantially parallel to the top surface of the substrate. That is, in the oxide semiconductor layer 230, the addition amount of the impurity element is larger in the source and drain regions than in the channel formation region. Thus, the resistances of the source and drain regions can be reduced preferentially.

An element that can be used as the impurity element is as described above.

A plasma ion doping method or an ion implantation method can be suitably used for the supply of the impurity element. In the above methods, the concentration profile in the depth direction can be controlled with high accuracy by the acceleration voltage and the dose of ions, for example.

With the use of an ion implantation method in which the source gas is ionized and the ion is subjected to mass separation and then added, the purity of an impurity element to be supplied can be increased. In the case of using an ion implantation method, the above-described first element is preferably used as the impurity element, and boron or phosphorus is further preferably used. When an element that is stabilized by being bonded to oxygen is used as the impurity element, a low-resistance region that is stable in a low-electric-resistance state can be obtained.

Furthermore, with the use of a plasma ion doping method in which the source gas is ionized and the ion is added without mass separation, the productivity can be increased. In the case of using a plasma ion doping method, the first element and hydrogen are each preferably used as the impurity element, and hydrogen and boron or phosphorus are further preferably used. When hydrogen and an element that is stabilized by being bonded to oxygen are each used as the impurity element, the electric resistance of the low-resistance region is easily reduced and the low-electric-resistance state can be kept stable.

An ion implantation apparatus or an ion doping apparatus used for supplying the impurity element is preferably used also in manufacturing a Si transistor such as an LTPS transistor, in which case an apparatus for an existing LTPS manufacturing line can be used and new capital investment is not required. Thus, capital investment for manufacturing the semiconductor device can be reduced.

In the treatment for supplying the impurity element, the treatment conditions are preferably controlled such that the impurity element concentration in the oxide semiconductor layer 230 is higher in a portion overlapping with the top surface of the conductive layer 220b or the top surface of the conductive layer 240b than in the other regions. Thus, the impurity element at an optimal concentration can be supplied to the source and drain regions of the oxide semiconductor layer 230.

A gas containing the above impurity element can be used as a source gas of the impurity element. In the case where boron is supplied, a B₂H₆ gas, a BF₃ gas, or the like can be typically used. In the case where phosphorus is supplied, a PH₃ gas can be typically used. A mixed gas in which the above source gas is diluted with hydrogen or a noble gas may be used.

Alternatively, as the source gas, CH₄, N₂, NH₃, AlH₃, AlCl₃, SiH₄, Si₂H₆, F₂, HF, H₂, (C₅H₅)₂Mg, a noble gas, or the like can be used. The ion source is not limited to a gas, and a solid or a liquid may be vaporized by heating.

For example, boron and hydrogen are preferably supplied as the impurity element using a gas containing boron and hydrogen. This is preferable because the impurity element can be added without mass separation and the resistance of the oxide semiconductor layer 230 can be easily reduced, thereby improving both the productivity and characteristics of the semiconductor device.

Furthermore, the same source gas is preferably used in the step of supplying the halogen element and the step of supplying the impurity element, in which case the manufacturing cost can be reduced. For example, by ionization of a BF₃ gas and mass separation of the ion, fluorine can be supplied as the halogen element and boron can be supplied as the impurity element.

The supply of the impurity element can be controlled by setting the conditions such as the acceleration voltage and the dose in consideration of the composition, the density, the thickness, and the like of the oxide semiconductor layer 230.

Note that there is no limitation on the method for supplying the impurity element, and for example, plasma treatment, treatment using thermal diffusion by heating, or the like may be used. In the case of a plasma treatment method, an impurity element can be supplied in such a manner that plasma is generated in a gas atmosphere containing the impurity element to be supplied and plasma treatment is performed. A dry etching apparatus, an ashing apparatus, a plasma CVD apparatus, a high-density plasma CVD apparatus, or the like can be used to generate the plasma.

The step of supplying the impurity element is preferably performed while the substrate is heated. Thus, damage applied to the oxide semiconductor layer 230 when the impurity element is added can be repaired. That is, the addition of the impurity element and the repair of damage due to the addition can be performed on the oxide semiconductor layer 230 in parallel.

The substrate temperature in the step of supplying the impurity element is preferably higher than or equal to 150° C. and lower than the strain point of the substrate, further preferably higher than or equal to 200° C. and lower than or equal to 500° C., still further preferably higher than or equal to 200° C. and lower than or equal to 450° C., yet further preferably higher than or equal to 250° C. and lower than or equal to 400° C., yet still further preferably higher than or equal to 250° C. and lower than or equal to 350° C. or higher than or equal to 300° C. and lower than or equal to 400° C., yet still further preferably higher than or equal to 300° C. and lower than or equal to 350° C.

Heat treatment may be performed after the impurity element is supplied. By the heat treatment, damage to the oxide semiconductor layer 230 in the step of supplying the impurity element can be repaired.

When an element that is stabilized by being bonded to oxygen is used as the impurity element, the impurity element can be inhibited from being released by heat or the like applied during the manufacturing process of the semiconductor device. Thus, even when heat treatment is performed or a film formation step or the like is performed while the substrate is heated after the addition of the impurity element, the impurity element is not released and the low-electric-resistance state can be kept.

As described above, the semiconductor device of one embodiment of the present invention has a structure where a gate electric field is easily applied to the oxide semiconductor. As a result, the transistor can have favorable electric characteristics.

The semiconductor device of one embodiment of the present invention has a structure where parasitic capacitance generated between the gate electrode and the source electrode or the drain electrode and parasitic capacitance generated between the gate wiring and the source electrode or the drain electrode are reduced. Accordingly, the frequency characteristics of a circuit using the semiconductor device can be increased.

The transistor of one embodiment of the present invention includes a back gate. Thus, the transistor of one embodiment of the present invention can have all of high on-state characteristics, normally-off characteristics, and high reliability even when being miniaturized.

This embodiment can be combined with any of the other embodiments as appropriate.

### Embodiment 3

In this embodiment, an oxide semiconductor layer that can be used as a semiconductor layer of a transistor is described.

### [Oxide Semiconductor Layer]

An oxide semiconductor layer of one embodiment of the present invention preferably includes a metal oxide layer having crystallinity. Examples of the structure of a metal oxide having crystallinity include a c-axis aligned crystalline (CAAC) structure, a polycrystalline structure, and a nano-crystal (nc) structure. By using a metal oxide having crystallinity for the oxide semiconductor layer, the density of defect states in the oxide semiconductor layer can be reduced. This can improve the reliability of a transistor including the oxide semiconductor layer of one embodiment of the present invention, thereby improving the reliability of a semiconductor device including the transistor.

It is particularly preferable that the oxide semiconductor layer of one embodiment of the present invention include a metal oxide having a CAAC structure. The CAAC structure is a crystal structure where a plurality of microcrystals (typically a plurality of microcrystals having a hexagonal crystal structure) have c-axis alignment and are connected in the a-b plane without alignment. Furthermore, according to a cross-sectional image of an oxide semiconductor layer having the CAAC structure observed with a high-resolution transmission electron microscope (TEM), metal atoms are arranged in a layered manner in a crystal part. Thus, it can be said that the oxide semiconductor layer having the CAAC structure includes a layered crystal part. The metal atoms arranged in a layered manner can be observed as bright spots in the cross-sectional TEM image of the oxide semiconductor layer.

The CAAC structure is formed such that the c-axis is perpendicular or substantially perpendicular to a formation surface, for example. In the CAAC structure, metal atoms are arranged in a layered manner in a direction parallel or substantially parallel to the formation surface. In a region having the CAAC structure, an angle formed by the c-axis and the formation surface is preferably within 90°±20° (greater than or equal to 70° and less than or equal to) 110°, further preferably within 90°±15° (greater than or equal to 75° and less than or equal to) 105°, still further preferably within 90°±10° (greater than or equal to 80° and less than or equal to) 100°, yet still further preferably within 90°±5° (greater than or equal to 85° and less than or equal to) 95°.

The crystallinity of the oxide semiconductor layer can be analyzed by X-ray diffraction (XRD), TEM, or electron diffraction (ED), for example. Alternatively, these methods may be combined as appropriate to be employed for analysis.

When the oxide semiconductor layer having the CAAC structure is subjected to electron diffraction, spots indicating c-axis alignment (bright spots) are observed in the electron diffraction pattern. The c-axes of the CAAC structure are preferably aligned in a direction parallel to the normal vector of the formation surface of the oxide semiconductor layer or the normal vector of a surface of the oxide semiconductor layer.

A fast Fourier transform (FFT) pattern obtained by FFT processing on a TEM image reflects reciprocal lattice space information similar to that of an electron diffraction pattern.

When the cross-sectional TEM image of the oxide semiconductor layer having the CAAC structure is obtained and each region in the cross-sectional TEM image is subjected to FFT processing to form the FFT pattern, the crystal axis direction in each region can be calculated from the obtained FFT pattern. Specifically, the direction of a line segment connecting two spots that have high luminance and are at substantially the same distance from the center, among spots observed in the obtained FFT pattern, is referred to as a crystal axis direction. A region in which an angle formed by the crystal axis direction calculated from the FFT pattern and the formation surface is preferably within 90°±20° (greater than or equal to 70° and less than or equal to) 110°, further preferably within 90°±15° (greater than or equal to 75° and less than or equal to) 105°, still further preferably within 90°±10° (greater than or equal to 80° and less than or equal to) 100°, and yet still further preferably within 90°±5° (greater than or equal to 85° and less than or equal to) 95° can be regarded as having the CAAC structure.

When the oxide semiconductor layer having the CAAC structure is observed from the direction perpendicular to the formation surface using the TEM image, a triangular or hexagonal atomic arrangement and crystallinity are observed in the a-b plane. In a Voronoi diagram formed by analysis of the TEM image of the oxide semiconductor layer having the CAAC structure observed from the direction perpendicular to the formation surface, pentagonal, hexagonal, and heptagonal Voronoi regions are mainly observed, typically a hexagonal Voronoi region is observed. For example, the hexagonal Voronoi region accounts for higher than or equal to 30% and lower than 100% of the Voronoi regions observed in the Voronoi diagram.

A method for forming a Voronoi diagram is described. First, in TEM image analysis, FFT processing is performed, only information within a certain range is left by filtering, and then reverse fast Fourier transform is performed to obtain an FFT filtering image. Lattice points are extracted from the obtained FFT filtering image, and perpendicular bisectors of line segments each connecting adjacent lattice points are formed. A point at which three perpendicular bisectors intersect with each other is referred to as a Voronoi point, and a polygonal region surrounded by line segments connecting the Voronoi points is referred to as a Voronoi region. In the above manner, a Voronoi diagram can be formed.

Note that as the TEM observation range for forming a Voronoi diagram, a rectangular region that is 50 nm wide and 50 nm long can be observed, for example. Note that the observation range is not limited to this.

In addition, when distribution of hexagonal lattice orientations is analyzed using lattice points extracted by analysis of a plan-view TEM image, at a boundary between two structures with different hexagonal lattice orientations, the difference in hexagonal lattice orientation is small, the boundary is blurred, and the two structures are connected to be tangled with each other. That is, no clear boundary portion is observed in the CAAC structure.

Note that as the hexagonal lattice orientation, the orientation of a hexagon formed by six lattice points closest to each other can be calculated.

Note that there is no particular limitation on the crystallinity of a semiconductor material contained in the oxide semiconductor layer. For example, the oxide semiconductor layer sometimes contains one or more of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including a crystal region). When the oxide semiconductor layer has crystallinity, degradation of the transistor characteristics can be inhibited in some cases.

The metal oxide of one embodiment of the present invention preferably contains at least indium (In) or zinc (Zn), particularly preferably contains indium as its main component. Here, the metal oxide contains indium as its main component, and can further contain an element M. The metal oxide preferably contains two or three selected from indium, the element M, and zinc, and particularly preferably contains indium and zinc as its main components. Here, the metal oxide contains indium and zinc as its main components, and can further contain the element M. The element M is a metal element or metalloid element that has a high bonding energy with oxygen, such as a metal element or metalloid element whose bonding energy with oxygen is higher than that of In. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more of the above elements, further preferably one or more selected from aluminum, gallium, tin, and yttrium, still further preferably one or more selected from gallium and tin. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may refer to a metalloid element.

In the cross section of the oxide semiconductor layer observed using the TEM image, metal atoms arranged in a layered manner in a direction parallel or substantially parallel to the formation surface are observed. In a TEM image, a metal atom is observed as a bright spot. For example, in a metal oxide containing indium, indium atoms arranged in a layered manner are observed. As another example, in a metal oxide containing indium and zinc, indium atoms and zinc atoms arranged in a layered manner are observed.

As the metal oxide of one embodiment of the present invention, for example, an indium zinc oxide (In—Zn oxide), an indium tin oxide (In—Sn oxide), an indium titanium oxide (In—Ti oxide), an indium gallium oxide (In—Ga oxide), an indium gallium aluminum oxide (In—Ga—Al oxide), an indium gallium tin oxide (also referred to as In—Ga—Sn oxide or IGTO), a gallium zinc oxide (also referred to as Ga—Zn oxide or GZO), an aluminum zinc oxide (also referred to as Al—Zn oxide or AZO), an indium aluminum zinc oxide (also referred to as In—Al—Zn oxide or IAZO), an indium tin zinc oxide (In—Sn—Zn oxide), an indium titanium zinc oxide (In—Ti—Zn oxide), an indium gallium zinc oxide (also referred to as In—Ga—Zn oxide or IGZO), an indium gallium tin zinc oxide (also referred to as In—Ga—Sn—Zn oxide or IGZTO), or an indium gallium aluminum zinc oxide (also referred to as In—Ga—Al—Zn oxide, IGAZO, or IAGZO) can be used. Alternatively, an indium tin oxide containing silicon (also referred to as ITSO), a gallium tin oxide (Ga—Sn oxide), an aluminum tin oxide (Al—Sn oxide), or the like can be used. As the metal oxide of one embodiment of the present invention, an indium oxide can be used. Alternatively, as the metal oxide of one embodiment of the present invention, a gallium oxide, a zinc oxide, or the like can be used.

By increasing the proportion of the number of indium atoms in the total number of atoms of all the metal elements contained in the metal oxide, a high on-state current and high frequency characteristics of the transistor can be achieved.

Instead of indium, the metal oxide may contain one or more kinds of metal elements whose period number in the periodic table is large. Alternatively, in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, prascodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, changes in electrical characteristics of the transistor are reduced and the transistor can have high reliability.

By increasing the proportion of the number of element M atoms in the total number of atoms of all the metal elements contained in the metal oxide, oxygen vacancies can be prevented from being formed in the metal oxide. Accordingly, generation of carriers due to oxygen vacancies is inhibited, which makes the off-state current of the transistor low. Furthermore, changes in the electrical characteristics of the transistor are reduced and the transistor can have high reliability.

In the description of this embodiment, an In—Ga—Zn oxide is sometimes taken as an example of the metal oxide.

The oxide semiconductor layer of one embodiment of the present invention can be formed by forming metal oxides using two kinds of film formation methods. For example, the oxide semiconductor layer of one embodiment of the present invention can be formed by forming metal oxides by a first film formation method and a second film formation method. Note that the oxide semiconductor layer formed by two kinds of film formation methods may be referred to as a hybrid OS.

The oxide semiconductor layer of one embodiment of the present invention has crystallinity. The oxide semiconductor layer of one embodiment of the present invention preferably has the CAAC structure.

In the formation of the oxide semiconductor layer of one embodiment of the present invention, a metal oxide having crystallinity is formed by the first film formation method. The metal oxide formed at this time particularly preferably has the CAAC structure. A metal oxide formed by, for example, a sputtering method, is likely to have crystallinity.

In the case where a metal oxide is formed by the first film formation method, a mixed layer is sometimes formed at the interface between the metal oxide and a layer (formation surface) over which the metal oxide is formed. For example, in the case where a sputtering method is used as the first film formation method, the mixed layer is sometimes formed by particles ejected from a target or the like (also referred to as sputtered particles) or energy applied to the substrate side by sputtered particles or the like, for example. There is a concern that the mixed layer may hinder crystallization of the metal oxide.

For example, in the case where an insulating layer containing silicon, e.g., silicon oxide, is used as the formation surface and a metal oxide is formed over the silicon oxide by the first film formation method, silicon might enter the metal oxide. There is a concern that the entry of impurities such as silicon into the metal oxide may hinder crystallization of the metal oxide.

In view of the above, in one embodiment of the present invention, a metal oxide is formed by the second film formation method before a metal oxide is formed by the first film formation method. In other words, a metal oxide is formed by the second film formation method as a first layer, and then a metal oxide is formed by the first film formation method as a second layer over the first layer. In that case, the second film formation method preferably causes less damage to a formation surface than the first film formation method. When a film formation method that causes less damage to a formation surface is used as the second film formation method, formation of a mixed layer at an interface between the oxide semiconductor layer and a layer serving as the formation surface of the oxide semiconductor layer can be inhibited. Moreover, entry of impurities such as silicon into the second layer can be inhibited, which can increase the crystallinity. For example, an atomic layer deposition (ALD) method and a chemical vapor deposition (CVD) method are suitable as the second film formation method because they can reduce damages to a formation surface as compared with a sputtering method.

In addition, for example, a metal oxide having a microcrystalline structure or an amorphous structure that has lower crystallinity than the CAAC structure is sometimes formed as the first layer. Formation of the second layer having high crystallinity over the first layer having low crystallinity or the formation of the second layer followed by heat treatment can increase the crystallinity of the first layer with the second layer as a nucleus in some cases. Accordingly, the crystallinity can be increased in the whole oxide semiconductor layer including the vicinity of the interface with the formation surface in some cases.

In a preferred mode of the oxide semiconductor layer of one embodiment of the present invention, a metal oxide is formed over the formation surface by the second film formation method, and then a metal oxide is formed thereover by the first film formation method.

Examples of the first film formation method include a sputtering method and a PLD method.

Examples of the second film formation method include an ALD method, a plasma enhanced CVD (PECVD) method, a thermal CVD method, a photo CVD method, a metal organic CVD (MOCVD) method, and a molecular beam epitaxy (MBE) method. The MBE method is a film formation method in which a thin film having a crystal structure reflecting a crystal system of a substrate is grown, and is one of film formation methods that cause less damage to a formation surface. A wet method can be used as the second film formation method. The wet method is one of film formation methods that cause less damage to a formation surface. An example of the wet method is a spray coating method.

For example, the oxide semiconductor layer of one embodiment of the present invention can be formed in the following manner: a metal oxide is formed as the first layer by the second film formation method, and then a metal oxide is formed as the second layer by the first film formation method. Specifically, an ALD method can be used as the second film formation method, and a sputtering method can be used as the first film formation method. The metal oxide formed by the first film formation method preferably has the CAAC structure.

Furthermore, a third layer can be formed over the second layer. Since the second layer has high crystallinity, a crystal of the third layer can grow with a crystal of the second layer as a nucleus or a seed. Thus, the third layer can be crystallized even when a film formation method that easily gives crystallinity is not used as the film formation method of the third layer. Here, for example, when a film formation method that gives higher coverage than that of the second layer is used for formation of the third layer, the whole oxide semiconductor layer can have both high crystallinity and high coverage.

Furthermore, when influence of the formation surface on the second layer is reduced by provision of the first layer, the crystallinity of the second layer is increased to an extremely high level. Thus, the third layer whose crystal is grown with the second layer as a nucleus or a seed is also expected to have extremely high crystallinity.

Note that the third layer is the uppermost layer of the oxide semiconductor layer. In the case where the oxide semiconductor layer is used as a semiconductor layer of a transistor, the third layer is, for example, a layer in contact with a gate insulating layer. Increasing the crystallinity of the layer in contact with the gate insulating layer can increase the carrier mobility in an on state of the transistor.

The oxide semiconductor layer of one embodiment of the present invention can be formed in the following manner, for example: a metal oxide is formed as the first layer by the second film formation method, a metal oxide is formed as the second layer by the first film formation method, and a metal oxide is formed as the third layer by the second film formation method. Specifically, an ALD method can be used as the second film formation method, and a sputtering method can be used as the first film formation method. The metal oxide formed by the first film formation method preferably has the CAAC structure. The ALD method is a film formation method that gives higher coverage than a sputtering method, and when the ALD method is used as the film formation methods of the first layer and the third layer, the coverage with the oxide semiconductor layer can be improved. Thus, the oxide semiconductor layer can be formed to favorably cover a step, an opening portion, or the like with a high aspect ratio.

### [Formation Method of Oxide Semiconductor Layer]

The oxide semiconductor layer 230 can be formed in the following manner, for example: an oxide semiconductor 230a is formed over a layer 229 serving as the formation surface by an ALD method, an oxide semiconductor 230b is formed over the oxide semiconductor 230a by a sputtering method, and an oxide semiconductor 230c is formed over the oxide semiconductor 230b by an ALD method. Furthermore, heat treatment is preferably performed after formation of the oxide semiconductor layer 230. The heat treatment can increase the crystallinity of the oxide semiconductor layer 230. The heat treatment here is not limited to heating treatment. For example, heat applied in the formation process may be regarded as the heat treatment. The layer 229 is an insulating film and is, for example, a silicon oxide film, a silicon oxynitride film, a silicon nitride film, a silicon nitride oxide film, an aluminum oxide film, or a hafnium oxide film.

The oxide semiconductor layer 230 can be used as the oxide semiconductor layer 230 or the like included in each of the transistors described in Embodiment 2. The layer 229 corresponds to one or more of the conductive layer 220, the insulating layer 235, the conductive layer 240, and the like described in Embodiment 2.

The layer 229 does not necessarily have crystallinity. In the case where the layer 229 has crystallinity, the crystal structures of the layer 229 and the metal oxide included in the oxide semiconductor 230 may have poor lattice match.

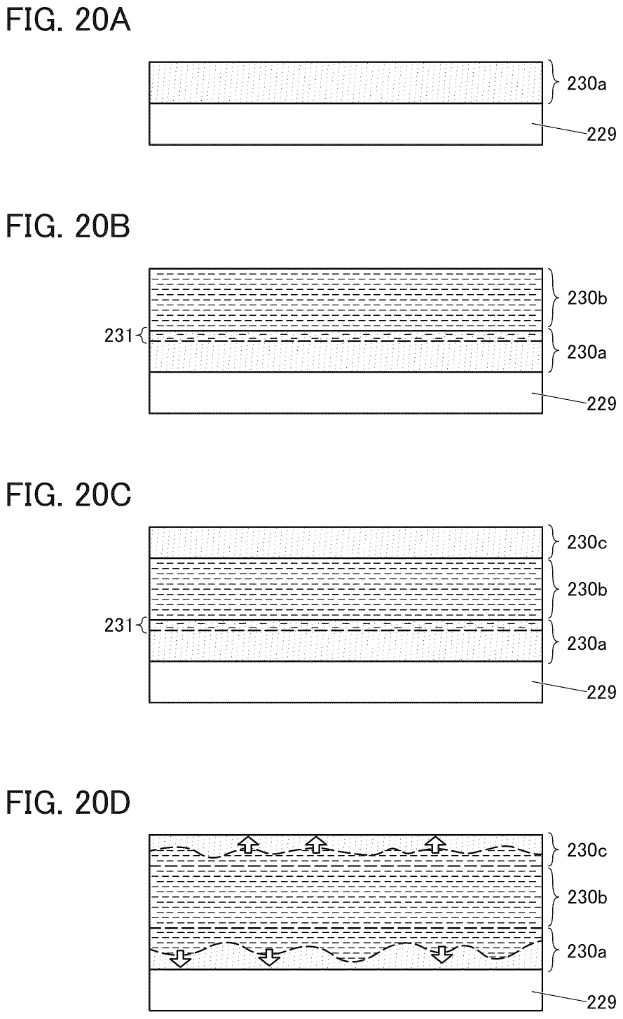

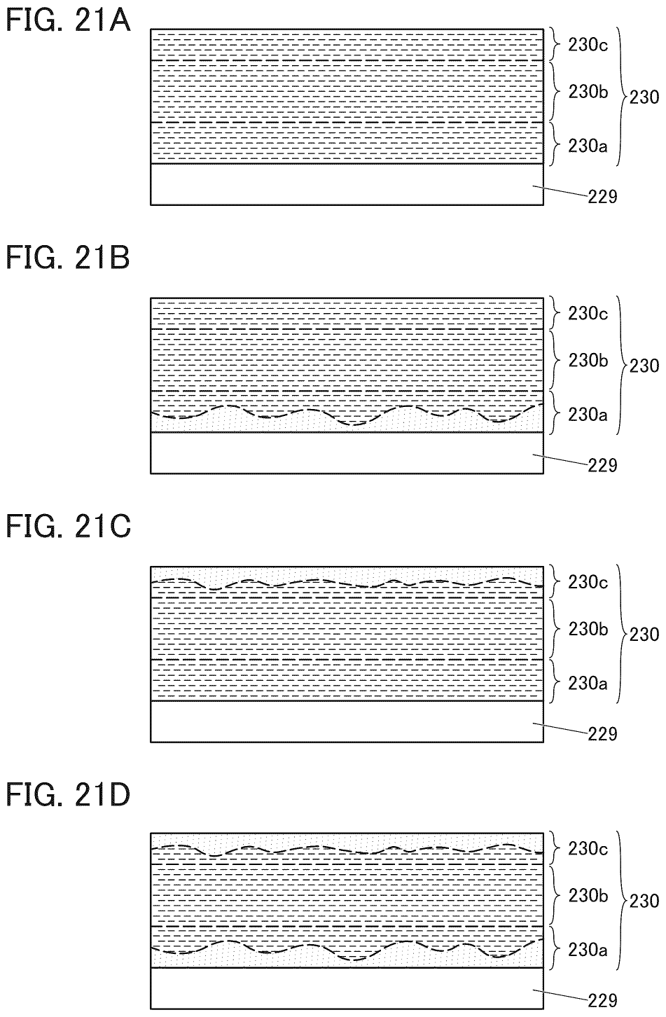

An example of the formation method of the oxide semiconductor layer 230 is described with reference to FIGS. 20A to 20D and FIGS. 21A to 21D.

First, the oxide semiconductor 230a is formed over the layer 229 (FIG. 20A). Next, the oxide semiconductor 230b is formed over the oxide semiconductor 230a (FIG. 20B).

The oxide semiconductor 230b is preferably formed by a sputtering method. In addition, the oxide semiconductor 230b preferably has a composition suitable for forming the CAAC structure.

The oxide semiconductor 230a is preferably formed by a film formation method that causes less damage to a formation surface than the film formation method of the oxide semiconductor 230b. Here, the oxide semiconductor 230a is formed by an ALD method.

In the case where a metal oxide film is formed by a sputtering method, damage to a formation surface might cause alloying of a component contained in the metal oxide film with a component contained in a layer serving as the formation surface. In the case where alloying is caused, it is difficult to increase the crystallinity of the alloyed region even when heat treatment described later is performed. When an oxide semiconductor layer including the alloyed region is used for a transistor, the initial characteristics or reliability of the transistor might be adversely affected. Thus, it is preferable to inhibit alloying of the component contained in the metal oxide film with the component contained in the layer serving as the formation surface.

In the formation method of the oxide semiconductor layer of one embodiment of the present invention, the oxide semiconductor 230a is formed over the layer 229, and then the oxide semiconductor 230b is formed thereover by a sputtering method. At this time, the oxide semiconductor 230a is preferably formed by a film formation method that causes less damage to a formation surface. The oxide semiconductor 230a is formed between the oxide semiconductor 230b and the layer 229 by a film formation method that causes less damage to a formation surface, thereby inhibiting alloying of the component contained in the oxide semiconductor layer 230 with the component contained in the layer 229 and further increasing the crystallinity of the oxide semiconductor layer 230.

The above structure enables the alloyed region to be thin or thin enough not to be observed. For example, the thickness of the alloyed region can be greater than or equal to 0 nm and less than or equal to 3 nm, preferably greater than or equal to 0 nm and less than or equal to 2 nm, further preferably greater than or equal to 0 nm and less than or equal to 1 nm, still further preferably greater than or equal to 0 nm and less than 0.3 nm. Note that FIGS. 20A and 20B each illustrate an example where the alloyed region is not formed between the layer 229 and the oxide semiconductor 230a.

Note that the thickness of the alloyed region can sometimes be calculated by performing SIMS or composition line analysis by energy dispersive X-ray spectroscopy (EDX) on the region and its vicinity.

For example, EDX line analysis is performed on the region and its vicinity with the direction perpendicular to the formation surface of the oxide semiconductor 230a regarded as the depth direction. Next, in profiles of quantitative values of elements in the depth direction obtained by the analysis, the depth at which the quantitative value of a metal that is the main component of the oxide semiconductor 230a and is not the main component of a layer (here, the layer 229) serving as the formation surface (the metal is In when the oxide semiconductor 230a contains In) becomes half is defined as a depth (position) of the interface between the region and the oxide semiconductor 230a. Furthermore, the depth at which the quantitative value of an element (e.g., Si) that is the main component of the layer serving as the formation surface and is not the main component of the oxide semiconductor 230a becomes half is defined as a depth (position) of the interface between the region and the layer serving as the formation surface. In the above manner, the thickness of the alloyed region can be calculated.

In the case where the thickness of the alloyed region in the oxide semiconductor layer of one embodiment of the present invention is observed by EDX analysis, the thickness is greater than or equal to 0 nm and less than or equal to 3.0 nm, preferably greater than or equal to 0 nm and less than or equal to 2.0 nm, further preferably greater than or equal to 0 nm and less than or equal to 1.0 nm, still further preferably greater than or equal to 0 nm and less than 0.3 nm, for example.

For example, in the case where SIMS analysis is performed on the oxide semiconductor layer 230 formed over the layer 229 that is formed using a silicon oxide layer, the depth at which the silicon concentration is 50% of the maximum silicon concentration in the layer 229 is defined as an interface, and the distance between the interface and the depth at which the silicon concentration decreases to 1.0×10²¹ atoms/cm³, preferably 5.0×10²⁰ atoms/cm³, further preferably 1.0×10²⁰ atoms/cm³ is defined as a thickness t_s2. The thickness t_s2 is preferably less than or equal to 3 nm, further preferably less than or equal to 2 nm.

Thinning the alloyed region enables the thickness t_s2 to be within the above range.

Note that thinning the alloyed region enables formation of the CAAC structure in the vicinity of the formation surface. Here, the vicinity of the formation surface refers to, for example, a region ranging from the formation surface of the oxide semiconductor layer 230 to greater than 0 nm and less than or equal to 3 nm, preferably greater than 0 nm and less than or equal to 2 nm, further preferably greater than or equal to 1 nm and less than or equal to 2 nm in a direction substantially perpendicular to the formation surface of the oxide semiconductor layer 230.

Note that the CAAC structure in the vicinity of the formation surface can be confirmed in TEM observation in some cases. For example, in cross-sectional observation of the oxide semiconductor 230 with a high-resolution TEM, bright spots arranged in a layered manner in a direction parallel to the formation surface are observed in the vicinity of the formation surface.

Note that when the oxide semiconductor 230a is formed by an ALD method, an oxide semiconductor layer having a microcrystalline structure or an amorphous structure that has lower crystallinity than the CAAC structure may be formed. That is, in the formation step illustrated in FIG. 20A, the oxide semiconductor 230a sometimes includes a region having lower crystallinity than the oxide semiconductor 230b.

After the oxide semiconductor 230a is formed by an ALD method, an In-M-Zn oxide is formed as the oxide semiconductor 230b over the oxide semiconductor 230a by a sputtering method.

When the oxide semiconductor 230b is formed by a sputtering method, a mixed layer 231 is formed on the surface of the oxide semiconductor 230a or in the vicinity of the surface. A fine crystal region is sometimes formed in the mixed layer 231 by, for example, sputtered particles or energy applied to the substrate side by sputtered particles or the like at the time of forming the oxide semiconductor 230b. In the subsequent heat treatment step, at least part of the oxide semiconductor 230a is crystallized with the mixed layer 231 or the fine crystal region formed in the mixed layer 231 as a nucleus in some cases.

As a target used in a sputtering method, an In-M-Zn oxide can be used. In the case where a metal oxide is formed by a sputtering method, oxygen or a mixed gas of oxygen and a noble gas can be used as a sputtering gas. An increase in the proportion of oxygen in the sputtering gas can increase the amount of excess oxygen contained in the oxide film to be formed.

In some cases, the crystallinity of the metal oxide layer can be increased as the proportion of a flow rate of an oxygen gas in the whole deposition gas (also referred to as oxygen flow rate ratio) used in formation is higher.

In the case where a metal oxide is formed by a sputtering method and the proportion of oxygen in the sputtering gas is higher than 30% and lower than or equal to 100%, preferably higher than or equal to 70% and lower than or equal to 100%, an oxygen-excess metal oxide is formed in some cases. A transistor including an oxygen-excess metal oxide in a channel formation region can have relatively high reliability. However, one embodiment of the present invention is not limited thereto. When the proportion of oxygen in the sputtering gas is higher than or equal to 1% and lower than or equal to 30%, preferably higher than or equal to 5% and lower than or equal to 20%, an oxygen-deficient metal oxide is formed. A transistor including an oxygen-deficient metal oxide in a channel formation region can have relatively high field-effect mobility.

In the formation of the oxide semiconductor 230b by a sputtering method, substrate heating is preferably performed. When the substrate temperature (stage temperature) at the time of forming the metal oxide is increased, the formed metal oxide can have high crystallinity in some cases. In the formation of the oxide semiconductor 230b by a sputtering method, the substrate heating temperature is preferably higher than or equal to 100° C. and lower than or equal to 400° C., further preferably higher than or equal to 200° C. and lower than or equal to 300° C., for example.

In the above manner, as illustrated in FIG. 20B, the oxide semiconductor 230a and the oxide semiconductor 230b over the oxide semiconductor 230a can be formed over the layer 229.

Next, the oxide semiconductor 230c is formed over the oxide semiconductor 230b (FIG. 20C). Here, the oxide semiconductor 230c is formed by an ALD method. For the formation of the oxide semiconductor 230c by an ALD method, the formation method of the oxide semiconductor 230a can be referred to.

When the oxide semiconductor 230c is formed over the oxide semiconductor 230b having the CAAC structure by an ALD method, the oxide semiconductor 230c may epitaxially grow with the oxide semiconductor 230b as a nucleus. Thus, at the time of forming the oxide semiconductor 230c, the oxide semiconductor 230c may include a region having the CAAC structure. The region having the CAAC structure is preferably formed throughout the oxide semiconductor 230c.

Next, a heat treatment step may be performed.

The heat treatment temperature can be higher than or equal to 100° C. and lower than or equal to 800° C., preferably higher than or equal to 250° C. and lower than or equal to 650° C., further preferably higher than or equal to 350° C. and lower than or equal to 550° C., for example. Typically, the temperature can be set to 400° C.±25° C. (greater than or equal to 375° C. and less than or equal to 425° C.). The treatment time can be shorter than or equal to 10 hours, longer than or equal to 1 minute and shorter than or equal to 5 hours, or longer than or equal to 1 minute and shorter than or equal to 2 hours. In the case of using an RTA apparatus, the treatment time can be longer than or equal to 1 second and shorter than or equal to 5 minutes, for example. By the heat treatment, the oxide semiconductor 230c (in other words, crystal molecules formed by an ALD method) is expected to repair the atomic-level space between crystal parts of the CAAC structure of the oxide semiconductor 230b.

There is no particular limitation on a heat treatment apparatus used for the heat treatment, and the apparatus may be provided with a device for heating an object to be processed by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas.

The heat treatment step increases the crystallinity of the region having the CAAC structure in the oxide semiconductor 230c in some cases. When the region is formed only below the oxide semiconductor 230c after the formation by an ALD method, the region may extend upward by the heat treatment step (FIG. 20D). That is, by the heat treatment, the region having the CAAC structure is formed throughout the oxide semiconductor 230c in some cases.

At least part of the oxide semiconductor 230a preferably has the CAAC structure by the heat treatment step (FIG. 20D). The CAAC structure is expected to be easily formed when the mixed layer 231 formed in the oxide semiconductor 230a in the formation of the oxide semiconductor 230b becomes a nucleus or a seed. The oxide semiconductor 230a preferably has a large CAAC region, and the CAAC region preferably extends to the vicinity of the layer 229.

Since the CAAC region extends from the upper portion to the lower portion of the oxide semiconductor 230a, the CAAC region can extend to the vicinity of the layer 229, regardless of the material and crystallinity of the layer 229. For example, even when the layer 229 has an amorphous structure, the oxide semiconductor 230a having high crystallinity can be formed. Thus, the formation method of the oxide semiconductor layer of one embodiment of the present invention is suitable for the case where a layer serving as the formation surface has an amorphous structure, in particular.

FIGS. 20A to 20D are cross-sectional views illustrating the formation method of a metal oxide of one embodiment of the present invention. FIGS. 20A to 20D can also be regarded as conceptual diagrams illustrating a formation model of the metal oxide of one embodiment of the present invention. As illustrated in FIGS. 20A to 20D, the crystallinity of each of the oxide semiconductors 230a and 230c is increased with the oxide semiconductor 230b as a nucleus or a seed. Specifically, the crystallinity of the oxide semiconductor 230a may be increased at the time of forming the oxide semiconductor 230b or by heat treatment after the formation of the oxide semiconductor 230c. In addition, the crystallinity of the oxide semiconductor 230c may be increased at the time of forming the oxide semiconductor 230c or by heat treatment after the formation of the oxide semiconductor 230c. Note that the heat treatment has an assisting function of increasing the crystallinity.

As described above, in the formation method of a metal oxide of one embodiment of the present invention, the crystallinity of the oxide semiconductors (here, the oxide semiconductors 230a and 230c) above and below the oxide semiconductor 230b can be increased with the oxide semiconductor 230b (i.e., CAAC) having high crystallinity as a nucleus or a seed. This can increase the crystallinity of the whole oxide semiconductor layer. In other words, the oxide semiconductor 230b serves as a nucleus or a seed to cause solid-phase growths of the oxide semiconductors above and below the oxide semiconductor 230b, so that the oxide semiconductor layer 230 with high crystallinity can be formed. An oxide semiconductor formed by such a film formation method, here, a CAAC film, may be referred to as an axial growth CAAC (Axial Growth CAAC or AG CAAC).

It is preferable that the region having the CAAC structure be formed widely throughout the oxide semiconductor layer 230. FIG. 21A illustrates a state where the oxide semiconductors 230a, 230b, and 230c are each crystallized. Crystals in the region having the CAAC structure in the oxide semiconductor 230a are connected to crystals in the region having the CAAC structure in the oxide semiconductor 230b. Crystals in the region having the CAAC structure in the oxide semiconductor 230c are connected to the crystals in the region having the CAAC structure in the oxide semiconductor 230b. As a result, a boundary between the oxide semiconductors 230a and 230b is not observed in some cases. In addition, a boundary between the oxide semiconductors 230b and 230c is not observed in some cases. The oxide semiconductor layer 230 may be expressed as one layer where the interfaces are not clearly observed. The oxide semiconductor layer 230 may be expressed as a single layer in some cases.

In cross-sectional observation with a high-resolution TEM, for example, bright spots arranged parallel to the formation surface are observed in the region having the CAAC structure in each of the oxide semiconductors 230a, 230b, and 230c. The c-axis of the CAAC structure included in each of the oxide semiconductors 230a, 230b, and 230c is preferably substantially parallel to the normal direction of the formation surface of the oxide semiconductor layer 230.

Part of the oxide semiconductor 230a or part of the oxide semiconductor 230c is not crystallized in some cases. An example illustrated in FIG. 21B illustrates a state where the vicinity of the interface between the oxide semiconductor 230a and the layer 229 is not crystallized. FIG. 21C illustrates a state where the vicinity of the surface of the oxide semiconductor 230c is not crystallized. FIG. 21D illustrates a state where the vicinity of the interface between the oxide semiconductor 230a and the layer 229 and the vicinity of the surface of the oxide semiconductor 230c are not crystallized.

Increasing the crystallinity of the oxide semiconductor layer can suppress an increase in electric resistance of the oxide semiconductor layer used as the semiconductor layer of the transistor or increase the initial characteristics (in particular, the on-state current) of the transistor; thus, the transistor can be expected to be suitable for high-speed driving. In addition, the transistor can have higher reliability and a higher on-state current.

The whole oxide semiconductor layer of one embodiment of the present invention has high crystallinity. Thus, the boundaries between the stacked films of the oxide semiconductors 230a, 230b, and 230c in the oxide semiconductor layer 230 are not observed in some cases. In particular, it is sometimes difficult to observe the boundaries between the stacked films after heat treatment. Whether the boundaries between the stacked films are present can be checked with a cross-sectional TEM or a cross-sectional STEM, for example.

As described above, a transistor including a metal oxide with a high In content percentage can have higher field-effect mobility. Meanwhile, an oxide semiconductor with a high In content percentage tends to be polycrystallized. The use of a metal oxide having a polycrystalline structure for a transistor adversely affects the initial characteristics or reliability of the transistor. In view of this, when an oxide semiconductor with a high In content percentage is used as one or both of the oxide semiconductors 230a and 230c, crystals reflecting the orientation of crystals included in the oxide semiconductor 230b are formed, so that polycrystallization can be inhibited.

It is preferable that crystals included in the oxide semiconductor 230b and crystals included in the oxide semiconductor 230a or 230c have a small lattice mismatch. Thus, the oxide semiconductor 230a or 230c can form crystals reflecting the orientation of crystals included in the oxide semiconductor 230b. In this case, for example, in high-resolution TEM cross-sectional observation of the oxide semiconductor 230, bright spots arranged in a layered manner in a direction parallel to the formation surface are observed in the oxide semiconductor 230a or 230c.

As long as crystals included in the oxide semiconductor 230b and crystals included in the oxide semiconductor 230a or 230c have a small lattice mismatch, there is no particular limitation on the crystal structure of the oxide semiconductor 230a or 230c. The oxide semiconductor 230a or 230c may have any of cubic, tetragonal, orthorhombic, hexagonal, monoclinic, and trigonal crystal structures.

### [Composition of Oxide Semiconductor Layer]

The oxide semiconductor 230a preferably has a composition different from that of the oxide semiconductor 230b. The oxide semiconductor 230c preferably has a composition different from that of the oxide semiconductor 230b. The oxide semiconductor 230a can have the same composition as the oxide semiconductor 230c. Alternatively, the oxide semiconductors 230a and 230c can have different compositions.

As described above, the oxide semiconductor 230b preferably has a composition suitable for forming the CAAC structure. The oxide semiconductor 230b can be formed by a sputtering method, for example. The oxide semiconductor 230b preferably contains zinc, for example. The oxide semiconductor 230b containing zinc can be a metal oxide having high crystallinity. The oxide semiconductor 230b preferably contains the element M in addition to zinc. When the oxide semiconductor 230b contains the element M, formation of oxygen vacancies in the metal oxide can be inhibited, for example. Thus, a transistor including the oxide semiconductor layer can have high reliability. As the oxide semiconductor 230b, it is possible to use, specifically, a metal oxide having an atomic ratio of In:M:Zn=1:1:1 or the neighborhood thereof, In:M:Zn=1:1:1.2 or the neighborhood thereof, In:M:Zn=1:1:0.5 or the neighborhood thereof, In:M:Zn=1:1:2 or the neighborhood thereof, In:M:Zn=4:2:3 or the neighborhood thereof, In:M:Zn=1:3:2 or the neighborhood thereof, or In:M:Zn=1:3:4 or the neighborhood thereof. Note that the neighborhood of the atomic ratio includes ±30% of an intended atomic ratio. It is preferable to use one or more of gallium, aluminum, and tin as the element M.

The oxide semiconductor 230b does not necessarily contain the element M. For example, an In—Zn oxide may be used. Specifically, an In—Zn oxide having an atomic ratio of In:Zn=1:1 or the neighborhood thereof, In:Zn=2:1 or the neighborhood thereof, or In:Zn=4:1 or the neighborhood thereof can be used. Alternatively, an indium oxide may be used. Furthermore, a slight amount of the element M may be contained. For example, an oxide having an atomic ratio of In:Ga:Zn=4:0.1:1 or the neighborhood thereof or In:Ga:Zn=2:0.1:1 or the neighborhood thereof can be used. As another example, an oxide having an atomic ratio of In:Sn:Zn=4:0.1:1 or the neighborhood thereof or In:Sn:Zn=2:0.1:1 or the neighborhood thereof can be used.

The oxide semiconductors 230a and 230c can each be a metal oxide with a high In proportion. The oxide semiconductors 230a and 230c can each be formed by an ALD method, for example. It is particularly preferable to use a metal oxide in which the In proportion is higher than the element M proportion. Using a metal oxide with a high In proportion for an oxide semiconductor layer of a transistor can achieve a high on-state current and high frequency characteristics of the transistor.

Alternatively, the oxide semiconductors 230a and 230c do not necessarily contain the element M. For example, an In—Zn oxide may be used. Specifically, an In—Zn oxide having an atomic ratio of In:Zn=1:1 or the neighborhood thereof, In:Zn=2:1 or the neighborhood thereof, or In:Zn=4:1 or the neighborhood thereof can be used. Alternatively, an indium oxide may be used. Furthermore, the oxide semiconductors 230a and 230c may contain a slight amount of the element M. Specifically, an oxide having an atomic ratio of In:Ga:Zn=4:0.1:1 or the neighborhood thereof, In:Ga:Zn=2:0.1:1 or the neighborhood thereof, In:Sn:Zn=4:0.1:1 or the neighborhood thereof, or In:Sn:Zn=2:0.1:1 or the neighborhood thereof can be used.

The oxide semiconductors 230a and 230c can each be a metal oxide with a higher In proportion than the oxide semiconductor 230b.

For example, as each of the oxide semiconductor 230a and 230c, a metal oxide with a higher Ga proportion than the oxide semiconductor 230b can also be used. For example, as each of the oxide semiconductors 230a and 230c, a metal oxide having an atomic ratio of In:Ga:Zn=1:1:1 or the neighborhood thereof, In:Ga:Zn=1:3:2 or the neighborhood thereof, or In:Ga:Zn=1:3:4 or the neighborhood thereof is preferably used. When the Ga proportion is increased, the band gap of each of the oxide semiconductors 230a and 230c can be larger than that of the oxide semiconductor 230b in some cases, for example. Accordingly, the oxide semiconductor 230b interposed between the oxide semiconductors 230a and 230c each having a large band gap functions as a current path (channel). When the oxide semiconductor 230b is interposed between the oxide semiconductors 230a and 230c, trap states at and near the interfaces with the oxide semiconductor 230b can be reduced. Accordingly, a buried-channel transistor where a channel is away from the interface with an insulating layer can be achieved, whereby the field-effect mobility can be increased. Furthermore, the influence of interface states that might be formed on the back channel side is reduced, so that light deterioration (e.g., light negative bias deterioration) of the transistor can be inhibited and the reliability of the transistor can be increased.

Alternatively, one of the oxide semiconductors 230a and 230c can be a metal oxide with a higher In proportion than the oxide semiconductor 230b, and the other can be a metal oxide with a higher Ga proportion than the oxide semiconductor 230b.

The oxide semiconductors 230a, 230b, and 230c may each include a stack of layers having the above compositions. For example, the oxide semiconductor 230c may have a structure where a metal oxide with a high Ga proportion is stacked over a metal oxide with a high In proportion.

Even when each of the oxide semiconductors 230a and 230c as a single layer has a composition that does not easily form the CAAC structure, the whole oxide semiconductor layer of one embodiment of the present invention, including the oxide semiconductors 230a and 230c, can have the CAAC structure owing to crystal growth caused with the oxide semiconductor 230b as a nucleus. Alternatively, the CAAC structure can be formed in a region including the whole oxide semiconductor 230b and at least part of the oxide semiconductor 230a and part of the oxide semiconductor 230c.

In particular, even when the oxide semiconductors 230a and 230c have a composition with a high In proportion, the oxide semiconductor layer 230 can have crystallinity suitable as the semiconductor layer of the transistor. The semiconductor layer of one embodiment of the present invention enables both high on-state characteristics and high reliability of a transistor, respectively by having the high In proportion and by having the CAAC structure with high crystallinity.

A metal oxide having the same composition as the oxide semiconductor 230b may be used as each of the oxide semiconductors 230a and 230c. By using the same composition, the oxide semiconductors easily have the CAAC structure after heat treatment in some cases.

The oxide semiconductor layer having the CAAC structure formed by the two kinds of film formation methods sometimes has one or more of a higher dielectric constant, higher film density, and higher film hardness than the oxide semiconductor layer having the CAAC structure formed by one kind of film formation method.

With the use of the oxide semiconductor layer having the CAAC structure formed by two kinds of film formation methods for a channel formation region of a transistor as described above, the transistor can have excellent characteristics (e.g., a high on-state current, high field-effect mobility, a low S value, high frequency characteristics (also referred to as f characteristics), or high reliability).

Analysis of the composition of the metal oxide used for the oxide semiconductor layer 230 can be performed by EDX, XPS, inductively coupled plasma-mass spectrometry (ICP-MS), or inductively coupled plasma-atomic emission spectrometry (ICP-AES). Alternatively, these methods may be combined as appropriate to be employed for analysis. As for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage. In some cases, the element M is difficult to quantize or the element M is not detected.

### [Oxide Semiconductor Layer of Transistor]

The oxide semiconductor layer of one embodiment of the present invention can be used as a semiconductor layer of a transistor.

The oxide semiconductor layer of one embodiment of the present invention has the CAAC structure. In an oxide semiconductor layer having the CAAC structure, metal atoms are arranged in a crystal part in a layered manner in a direction parallel or substantially parallel to the formation surface.

In the oxide semiconductor layer 230 of a semiconductor device of one embodiment of the present invention, metal atoms are arranged in a layered manner in a direction parallel or substantially parallel to the formation surface. This can also be expressed that “the a-b plane of the CAAC structure is provided to be parallel or substantially parallel to the formation surface”. Here, the oxide semiconductor layer 230 is provided along the sidewall of the opening portion 290 with the insulating layer 235, which is part of the formation surface, therebetween. Thus, in the oxide semiconductor layer 230, metal atoms are arranged in a layered manner in a direction parallel or substantially parallel to the sidewall of the opening portion 290. With such a structure, the a-b plane of the CAAC structure can be provided along a current flow direction in a channel of the transistor. Accordingly, the transistor can have a high on-state current.

In the case where the oxide semiconductor layer 230 is used as a semiconductor layer of a transistor, the thickness of the oxide semiconductor layer 230 is preferably greater than or equal to 3 nm and less than or equal to 200 nm, further preferably greater than or equal to 3 nm and less than or equal to 100 nm, still further preferably greater than or equal to 5 nm and less than or equal to 100 nm, yet further preferably greater than or equal to 10 nm and less than or equal to 100 nm, yet still further preferably greater than or equal to 10 nm and less than or equal to 70 nm, yet still further preferably greater than or equal to 15 nm and less than or equal to 70 nm, yet still further preferably greater than or equal to 15 nm and less than or equal to 50 nm, and yet still further preferably greater than or equal to 20 nm and less than or equal to 50 nm. In a transistor used for a miniaturized semiconductor device, the thickness of the oxide semiconductor layer 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm. The average thickness of the oxide semiconductor layer 230 in the channel formation region of the transistor is particularly preferably greater than or equal to 2 nm and less than or equal to 15 nm, for example.

The thickness of the oxide semiconductor 230b is preferably less than or equal to 200 nm, for example. When having a layer form, the oxide semiconductor 230b preferably has a thickness greater than or equal to 1 nm and less than or equal to 200 nm, further preferably greater than or equal to 1 nm and less than or equal to 100 nm, still further preferably greater than or equal to 2 nm and less than or equal to 100 nm.

Alternatively, when the oxide semiconductor 230b can function as a crystal nucleus, the oxide semiconductor 230b does not have a layer form but may be an aggregate of island-shaped regions. In such a case, for example, the island-shaped regions exist discretely in the oxide semiconductor 230b.

The thickness of each of the oxide semiconductors 230a and 230c is preferably greater than or equal to 0.5 nm and less than or equal to 50 nm, further preferably greater than or equal to 0.5 nm and less than or equal to 30 nm, still further preferably greater than or equal to 0.5 nm and less than or equal to 20 nm, yet still further preferably greater than or equal to 1 nm and less than or equal to 50 nm, yet still further preferably greater than or equal to 1 nm and less than or equal to 30 nm, yet still further preferably greater than or equal to 1 nm and less than or equal to 20 nm, and yet still further preferably greater than or equal to 2 nm and less than or equal to 20 nm. The thickness of the oxide semiconductor 230a is further preferably greater than or equal to 0.5 nm and less than or equal to 3.0 nm.

### [Impurities in Oxide Semiconductor]

The influence of impurities in the oxide semiconductor will be described here.

It is preferable that the channel formation region of the transistor including an oxide semiconductor in the semiconductor layer contain less oxygen vacancies or have a lower concentration of impurities such as hydrogen, nitrogen, or a metal element than the source region and the drain region. When oxygen vacancies (Vo) and impurities are in a channel formation region of an oxide semiconductor, the electrical characteristics easily vary and the reliability might worsen. In some cases, hydrogen in the vicinity of the oxygen vacancies forms V_{O}H and generates an electron serving as a carrier. Thus, when the channel formation region of the oxide semiconductor includes oxygen vacancies, the transistor tends to be normally on. Thus, V_{O}H is also preferably reduced in the channel formation region. Thus, the channel formation region of the transistor is a high-resistance region having a low carrier concentration. Accordingly, the channel formation region of the transistor can be regarded as an i-type (intrinsic) or substantially i-type region.

In order to obtain stable electrical characteristics of the transistor, reducing the impurity concentration in the oxide semiconductor is effective. In order to reduce the impurity concentration in the oxide semiconductor, the impurity concentration in a film that is adjacent to the oxide semiconductor is preferably reduced. Examples of the impurity include hydrogen, carbon, and nitrogen. Note that an impurity in an oxide semiconductor refers to, for example, elements other than the main components of the oxide semiconductor. For example, an element with a concentration of lower than 0.1 atomic % is an impurity.

When an oxide semiconductor contains silicon or carbon, which is a Group 14 element, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet still further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor including, as a semiconductor, an oxide semiconductor that contains nitrogen tends to be normally on. When nitrogen is contained in the oxide semiconductor, a trap state is sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet still further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom generates an electron serving as a carrier in some cases. Thus, a transistor including an oxide semiconductor that contains hydrogen tends to be normally on. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Accordingly, a transistor including an oxide semiconductor that contains an alkali metal or an alkaline earth metal tends to be normally on. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics.

### [C-Axis Alignment Proportion]

The oxide semiconductor layer of one embodiment of the present invention has the CAAC structure. The crystallinity degree of the oxide semiconductor layer of one embodiment of the present invention can be evaluated with the use of crystal orientation, for example.

The crystal orientation can be obtained from an FFT pattern obtained by performing FFT processing on a TEM image. Specifically, the crystal axis direction can be obtained using the FFT pattern. The FFT pattern obtained by the FFT processing reflects reciprocal lattice space information like an electron diffraction pattern.

When FFT processing is performed on each region in the TEM image of the oxide semiconductor layer, crystal orientation in each region can be obtained. For example, crystal orientation is obtained in each region in a certain area range, so that a map indicating crystal orientation can be formed. Specifically, two spots with high intensity are observed in the FFT pattern of the region including a layered crystal part. The crystal axis direction in the region can be obtained from the angle of a line segment connecting the two spots.

When the proportion of regions having c-axis alignment is calculated from the map indicating the crystal orientation, the c-axis alignment proportion can be calculated. Note that the region having c-axis alignment here is a region where the orientation is aligned with the c-axis or a region where the orientation is deviated from the c-axis by less than or equal to 20°, further preferably less than or equal to 15°, still further preferably less than or equal to 10°, yet still further preferably less than or equal to 5°. Here, the angle of the c-axis refers to an angle with respect to the formation surface.

In the oxide semiconductor layer of one embodiment of the present invention, the c-axis alignment proportion can be calculated using, for example, the above-described map indicating crystal orientation obtained through cross-sectional or plan-view TEM observation of the oxide semiconductor layer. A region subjected to FFT (also referred to as FFT window) can be a circle with a diameter of 1.0 nm, for example. Note that a region subjected to FFT is not limited to a circle.

In the case where analysis is performed using a cross-sectional TEM image, the cross-sectional TEM image observation range can be, for example, a region having a width of 100 nm in the horizontal direction with a direction perpendicular to the formation surface regarded as the vertical direction. Note that the observation range is not limited to this.

In the oxide semiconductor layer of one embodiment of the present invention, the c-axis alignment proportion is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Here, the c-axis alignment proportion is preferably calculated as the proportion of regions where the orientation is deviated from the c-axis by less than or equal to 20°, for example.

The c-axis alignment proportions of a region formed as the oxide semiconductor 230a, a region formed as the oxide semiconductor 230b, and a region formed as the oxide semiconductor 230c are Rc1, Rc2, and Rc3, respectively. Rc2 is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Furthermore, Rc3 is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Rc3/Rc1 is preferably greater than one. Furthermore, Rc2/Rc1 is preferably greater than one. Here, the c-axis alignment proportion is preferably calculated as the proportion of regions where the orientation is deviated from the c-axis by less than or equal to 20°, for example.

Note that boundaries between the oxide semiconductors 230a, 230b, and 230c are not clearly observed in some cases after the formation of the oxide semiconductor layer 230.

The oxide semiconductor layer 230 of one embodiment of the present invention can be divided into a first region, a second region, and a third region in this order from the layer 229. Each of the regions has a layer form.

Each of the first, second, and third regions has the CAAC structure. In addition, the c-axis alignment proportion of the third region is preferably higher than that of the first region. The c-axis alignment proportion of the second region is preferably higher than that of the first region. The c-axis alignment proportion of the third region is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. The c-axis alignment proportion of the second region is preferably higher than or equal to 50%, further preferably higher than or equal to 60%, still further preferably higher than or equal to 70%, yet still further preferably higher than or equal to 80%, yet still further preferably higher than or equal to 90%, yet still further preferably higher than or equal to 95%. Here, the c-axis alignment proportion is preferably calculated as the proportion of regions where the orientation is deviated from the c-axis by less than or equal to 20°, for example.

The first region is a region ranging from the top surface of the layer 229 to greater than or equal to 0 nm and less than or equal to 3 nm, and the third region is a region ranging from the top surface of the oxide semiconductor layer 230 to greater than or equal to 0 nm and less than or equal to 3 nm.

The layers of the regions have substantially the same thickness, for example.

This embodiment can be combined with any of the other embodiments as appropriate.

### Embodiment 4

In this embodiment, memory devices of embodiments of the present invention will be described with reference to FIGS. 22A to 22C, FIGS. 23A and 23B, FIGS. 24A and 24B, FIGS. 25A to 25C, FIGS. 26A and 26B, FIGS. 27A and 27B, FIG. 28, FIG. 29, FIG. 30, FIG. 31, FIG. 32, FIGS. 33A and 33B, FIG. 34, FIG. 35, FIGS. 36A and 36B, FIG. 37, and FIG. 38. The memory device of one embodiment of the present invention includes a memory cell. The memory cell includes a transistor and a capacitor.

### <Structure Example 1 of Memory Device>

A structure of a memory device including a transistor and a capacitor is described with reference to FIGS. 22A to 22C. FIG. 22A is a plan view of a memory device including the transistor 202 and a capacitor 100. FIG. 22B is a cross-sectional view taken along dashed-dotted line A1-A2 in FIG. 22A. FIG. 22C is a cross-sectional view taken along dashed-dotted line A3-A4 in FIG. 22A.

The memory device illustrated in FIGS. 22A to 22C includes an insulating layer 140 over a substrate (not illustrated), a conductive layer 110 over the insulating layer 140, a memory cell 150 over the conductive layer 110, an insulating layer 180 over the conductive layer 110, the insulating layer 280a, the insulating layer 280b, the insulating layer 283, the insulating layer 285, and the conductive layer 265 over the insulating layer 285. The insulating layer 140, the insulating layer 180, the insulating layer 280a, the insulating layer 280b, the insulating layer 283, and the insulating layer 285 function as interlayer films. The conductive layer 110 and the conductive layer 265 function as wirings.

The memory cell 150 includes the capacitor 100 over the conductive layer 110 and the transistor 202 over the capacitor 100.

The capacitor 100 includes a conductive layer 115 over the conductive layer 110, an insulating layer 130 over the conductive layer 115, and the conductive layer 220a over the insulating layer 130. The conductive layer 220a functions as one of a pair of electrodes (sometimes referred to as an upper electrode), the conductive layer 115 functions as the other of the pair of electrodes (sometimes referred to as a lower electrode), and the insulating layer 130 functions as a dielectric. That is, the capacitor 100 is a metal-insulator-metal (M1M) capacitor. Note that the conductive layer 220b can be regarded as part of the upper electrode of the capacitor 100.

As illustrated in FIGS. 22B and 22C, the opening portion 190 reaching the conductive layer 110 is provided in the insulating layer 180. At least part of the conductive layer 115 is placed in the opening portion 190. Note that the conductive layer 115 includes a region in contact with the top surface of the conductive layer 110 in the opening portion 190, a region in contact with the side surface of the insulating layer 180 in the opening portion 190, and a region in contact with at least part of the top surface of the insulating layer 180. The insulating layer 130 is placed to be positioned in the opening portion 190 at least partly. The conductive layer 220a is placed to be positioned in the opening portion 190 at least partly. Note that the conductive layer 220a is preferably provided to fill the opening portion 190 as illustrated in FIGS. 22B and 22C. Note that the films provided in the opening portion 190 are preferably formed by an ALD method. Thus, the coverage with the films can be improved. For example, the conductive layer 115, the insulating layer 130, and the conductive layer 220a are preferably formed by an ALD method.

The upper electrode and the lower electrode of the capacitor 100 face each other with the dielectric therebetween, along the side surface of the opening portion 190 as well as the bottom surface thereof; thus, the capacitance per unit area can be larger. Accordingly, the deeper the opening portion 190 is, the larger the capacitance of the capacitor 100 can be. Increasing the capacitance per unit area of the capacitor 100 in this manner allows stable reading operation of the memory device. This also allows further miniaturization or high integration of the memory device.

FIGS. 22B and 22C illustrate an example where the sidewall of the opening portion 190 is perpendicular to the top surface of the conductive layer 110. At this time, the opening portion 190 has a cylindrical shape. Such a structure enables miniaturization or high integration of the memory device.

The conductive layer 115 and the insulating layer 130 are stacked along the sidewall of the opening portion 190 and the top surface of the conductive layer 110. The conductive layer 220a is provided over the insulating layer 130 to fill the opening portion 190. The capacitor 100 having such a structure may be referred to as a trench-type capacitor or a trench capacitor.

The insulating layer 280a is provided over the capacitor 100. The insulating layer 280a includes a portion positioned over the insulating layer 130 and a portion positioned over the conductive layer 220b.

The transistor 202 includes the conductive layer 220a, the conductive layer 220b over the conductive layer 220a, the conductive layer 255 over the insulating layer 280a, the conductive layer 240 over the insulating layer 280b, the oxide semiconductor layer 230, the insulating layer 235 between the conductive layer 255 and the oxide semiconductor layer 230, the insulating layer 250 over the oxide semiconductor layer 230, and the conductive layer 260 over the insulating layer 250. The oxide semiconductor layer 230 functions as the semiconductor layer, the conductive layer 260 functions as the first gate electrode, the insulating layer 250 functions as the first gate insulating layer, the conductive layer 255 functions as the second gate electrode, the insulating layer 235 functions as the second gate insulating layer, the conductive layer 220a and the conductive layer 220b function as one of the source electrode and the drain electrode, and the conductive layer 240 functions as the other of the source electrode and the drain electrode.

The description in Embodiment 2 (FIGS. 10A to 10E) can be referred to for the transistor 202; thus, the detailed description thereof is omitted. The transistor included in the memory cell 150 is not limited to the transistor 202, and any of the transistors described as examples in Embodiment 2 can be used.

As illustrated in FIGS. 22A to 22C, the transistor 202 is provided to overlap with the capacitor 100. The opening portion 290 and the opening portion 270 where part of the components of the transistor 202 is provided each include a region overlapping with the opening portion 190 where part of the components of the capacitor 100 is provided. In particular, since the conductive layer 220a (and the conductive layer 220b) has a function of one of the source electrode and the drain electrode of the transistor 202 and a function of the upper electrode of the capacitor 100, the transistor 202 and the capacitor 100 share part of the structure. With such a structure, the transistor 202 and the capacitor 100 can be provided without an increase in the occupation area in a plan view. Thus, the occupation area of the memory cell 150 can be reduced, so that the memory cells 150 can be arranged densely and the storage capacity of the memory device can be increased. In other words, the memory device can be highly integrated. FIGS. 22B and 22C illustrate an example where the width of the opening portion 190 is smaller than the width of the opening portion 290 and the width of the opening portion 270. There is no particular limitation on the relation between the width of the opening portion 190 and the width of the opening portion 290 or the width of the opening portion 270. In view of miniaturization, the width of the opening portion 190 is preferably smaller than or equal to the width of the opening portion 290. Similarly, the width of the opening portion 190 is preferably smaller than or equal to the width of the opening portion 270.

When the transistor 202 is provided above the capacitor 100, the transistor 202 is not affected by thermal budget in manufacturing the capacitor 100. Thus, in the transistor 202, degradation of the electrical characteristics such as variation in threshold voltage or an increase in parasitic resistance, and an increase in variation in electrical characteristics due to the degradation of the electrical characteristics can be inhibited.

FIG. 40A is a circuit diagram of the memory device described in this embodiment. As illustrated in FIG. 40A, the structure illustrated in FIGS. 22A to 22C functions as a memory cell. The memory cell 951 includes a transistor M1 and a capacitor CA. Here, the transistor M1 corresponds to the transistor 202, and the capacitor CA corresponds to the capacitor 100.

One of a source and a drain of the transistor M1 is connected to one of a pair of electrodes of the capacitor CA. The other of the source and the drain of the transistor M1 is connected to a wiring BIL. A gate of the transistor M1 is connected to a wiring WOL. The other of the pair of electrodes of the capacitor CA is connected to a wiring CAL.

Here, the wiring BIL corresponds to the conductive layer 240, the wiring WOL corresponds to the conductive layer 265, and the wiring CAL corresponds to the conductive layer 110. As illustrated in FIGS. 22A to 22C, it is preferable that the conductive layer 265 be provided to extend in the X direction and the conductive layer 240 be provided to extend in the Y direction. With such a structure, the wiring BIL and the wiring WOL are provided to intersect with each other. Although the wiring CAL (the conductive layer 110) is provided in a plane shape in FIG. 22A, the present invention is not limited thereto. For example, the wiring CAL may be provided parallel to the wiring WOL (the conductive layer 265) or the wiring BIL (the conductive layer 240).

Note that the memory cell will be described in detail in a later embodiment.

### [Capacitor 100]

The capacitor 100 includes the conductive layer 115, the insulating layer 130, and the conductive layer 220a. The conductive layer 110 is provided below the conductive layer 115. The conductive layer 115 includes a region in contact with the conductive layer 110.

The conductive layer 110 is provided over the insulating layer 140. The conductive layer 110 functions as the wiring CAL and can be provided in a plane shape, for example. The conductive layer 110 can be formed as a single layer or stacked layers using the conductive material described in [Conductive layer] in Embodiment 2. For example, a conductive material with high conductivity such as tungsten can be used for the conductive layer 110. With the use of a conductive material with high conductivity, the conductivity of the conductive layer 110 can be improved and the wiring CAL can function sufficiently.

For the conductive layer 115, a single layer or stacked layers of a conductive material that is less likely to be oxidized, a conductive material having a function of inhibiting diffusion of oxygen, or the like is preferably used. For example, titanium nitride, indium tin oxide to which silicon is added, or the like may be used. Alternatively, a structure where titanium nitride is stacked over tungsten may be used, for example. Alternatively, a structure where tungsten is stacked over first titanium nitride and second titanium nitride is stacked over the tungsten may be used, for example. With such a structure, when an oxide is used for the insulating layer 130, the conductive layer 115 can be inhibited from being oxidized by the insulating layer 130. When an oxide is used for the insulating layer 180, the conductive layer 115 can be inhibited from being oxidized by the insulating layer 180.

The insulating layer 130 is provided over the conductive layer 115. The insulating layer 130 can be provided to be in contact with the top and side surfaces of the conductive layer 115. That is, the insulating layer 130 preferably covers the side end portion of the conductive layer 115. This can prevent a short circuit between the conductive layer 115 and the conductive layer 220a.

Alternatively, the side end portion of the insulating layer 130 and the side end portion of the conductive layer 115 may be aligned with each other. With such a structure, the insulating layer 130 and the conductive layer 115 can be formed using the same mask, so that the manufacturing process of the memory device can be simplified.

For the insulating layer 130, a material with a high dielectric constant (a high-k material) is preferably used. Using such a high-k material for the insulating layer 130 allows the insulating layer 130 to be thick enough to inhibit a leakage current and the capacitor 100 to have a sufficiently high capacitance.

The insulating layer 130 preferably has a stacked-layer structure using an insulating layer that contains a high-k material. A stacked-layer structure containing a material with a high dielectric constant (a high-k material) and a material with higher dielectric strength than the high-k material is preferably used. For example, as the insulating layer 130, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The stacking of such an insulating layer having relatively high dielectric strength, such as aluminum oxide, can increase the dielectric strength and inhibit electrostatic breakdown of the capacitor 100.

Alternatively, a material that can have ferroelectricity may be used for the insulating layer 130. Description in Embodiment 2 can also be referred to for the details of the material that can have ferroelectricity.

A metal oxide containing one or both of hafnium and zirconium is preferable as the insulating layer 130 because the metal oxide can have ferroelectricity even when being a thin film of several nanometers. The thickness of the insulating layer 130 is preferably less than or equal to 100 nm, further preferably less than or equal to 50 nm, still further preferably less than or equal to 20 nm, yet still further preferably less than or equal to 10 nm (typically greater than or equal to 2 nm and less than or equal to 9 nm). For example, the thickness is preferably greater than or equal to 8 nm and less than or equal to 12 nm. With the use of the ferroelectric layer that can have a small thickness, the capacitor 100 can be combined with a miniaturized semiconductor element such as a transistor to fabricate a semiconductor device.

A metal oxide containing one or both of hafnium and zirconium is preferable as the insulating layer 130 because the metal oxide can have ferroelectricity even with a minute area. For example, a ferroelectric layer can have ferroelectricity even with an area (occupied area) less than or equal to 100 μm², less than or equal to 10 μm², less than or equal to 1 μm², or less than or equal to 0.1 μm² in a plan view. Furthermore, even with an area of less than or equal to 10000 nm² or less than or equal to 1000 nm², a ferroelectric layer can have ferroelectricity in some cases. With a small-area ferroelectric layer, the area occupied by the capacitor 100 can be reduced.

The ferroelectric refers to an insulator having a property of causing internal polarization by application of an electric field from the outside and maintaining the polarization even after the electric field is made zero. Thus, with the use of a capacitor that contains this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 100, the memory device described in this embodiment functions as a ferroelectric memory.

The conductive layer 220a is provided in contact with part of the top surface of the insulating layer 130. The side end portion of the conductive layer 220a is preferably positioned inward from the side end portion of the conductive layer 115 in both the X direction and the Y direction. Note that in the structure where the insulating layer 130 covers the side end portion of the conductive layer 115, the side end portion of the conductive layer 220a may be positioned outward from the side end portion of the conductive layer 115.

The insulating layer 180 functions as an interlayer film and thus preferably has a low dielectric constant. In the case where a material with a low dielectric constant is used for an interlayer film, parasitic capacitance generated between wirings can be reduced. As the insulating layer 180, an insulating layer containing a material with a low dielectric constant can be used as a single layer or stacked layers. Silicon oxide and silicon oxynitride, which have thermal stability, are preferable.

Although the insulating layer 180 has a single-layer structure in FIGS. 22B and 22C, the present invention is not limited thereto. The insulating layer 180 may have a stacked-layer structure of two layers or three or more layers.

### <Structure Example 2 of Memory Device>

FIGS. 23A and 23B are cross-sectional views of a memory device including a transistor 200a and a transistor 202a.

The memory device illustrated in FIGS. 23A and 23B includes the insulating layer 140 over a substrate (not illustrated), the memory cell 150 over the insulating layer 140, an insulating layer 161a over the insulating layer 140, an insulating layer 161b, the insulating layer 280a, the insulating layer 280b, the insulating layer 283, the insulating layer 285, and the conductive layer 265 over the insulating layer 285. The insulating layer 140, the insulating layer 161a, the insulating layer 161b, the insulating layer 280a, the insulating layer 280b, the insulating layer 283, and the insulating layer 285 function as interlayer films. The conductive layer 265 functions as a wiring.

The memory cell 150 includes the transistor 200a over the insulating layer 140 and the transistor 202a over the transistor 200a.

The description of the transistor 200 in Embodiment 2 (FIGS. 2A1 to 2E and FIG. 3) can be referred to for the transistor 200a; thus, the detailed description thereof is omitted. The description of the transistor 202 in Embodiment 2 (FIG. 10) can be referred to for the transistor 202a; thus, the detailed description thereof is omitted. The transistors included in the memory cell 150 are not limited to the combination of the transistor 200 and the transistor 202, and one or more kinds of the transistors described in Embodiment 2 can be used.

A conductive layer 120a and a conductive layer 120b included in the transistor 200a can have structures similar to those usable for the conductive layer 220a and the conductive layer 220b, respectively. A conductive layer 145 can have a structure similar to that usable for the conductive layer 240. An insulating layer 131 can have a structure similar to that usable for the insulating layer 235. An oxide semiconductor layer 135 can have a structure similar to that usable for the oxide semiconductor layer 230. An insulating layer 151 can have a structure similar to that usable for the insulating layer 250. The insulating layer 161a and the insulating layer 161b can have structures similar to those usable for the insulating layer 280a and the insulating layer 280b, respectively.

In the memory cell 150 illustrated in FIGS. 23A and 23B, capacitance generated between the conductive layer 220a and the conductive layer 145 can be used; thus, data can be retained without formation of an additional capacitor. The shortest distance from the top surface of the conductive layer 145 to the conductive layer 220a is preferably shorter than the shortest distance from the top surface of the conductive layer 240 to the conductive layer 265. Accordingly, the capacitance generated between the conductive layer 220a and the conductive layer 145 can be increased. Moreover, parasitic capacitance generated between the conductive layer 240 and the conductive layer 265 can be reduced.

As illustrated in FIGS. 23A and 23B, the transistor 202a is provided to overlap with the transistor 200a. The opening portion 290 and the opening portion 270 where part of the components of the transistor 202a is provided each include a region overlapping with the opening portion 190 where part of the components of the transistor 200a is provided. In particular, since the conductive layer 220a and the conductive layer 220b have a function of one of the source electrode and the drain electrode of the transistor 202a and a function of the gate electrode of the transistor 200a, the transistor 202a and the transistor 200a share part of the structure. With such a structure, the transistor 202a and the transistor 200a can be provided without an increase in the occupation area in a plan view. Thus, the occupation area of the memory cell 150 can be reduced, so that the memory cells 150 can be arranged densely and the storage capacity of the memory device can be increased. In other words, the memory device can be highly integrated.

FIG. 40E is a circuit diagram of the memory device described in this embodiment. As illustrated in FIG. 40E, the structure illustrated in FIGS. 23A and 23B functions as a memory cell. The memory cell 955 includes a transistor M2 and a transistor M3. Here, the transistor M2 corresponds to the transistor 202a, and the transistor M3 corresponds to the transistor 200a.

One of a source and a drain of the transistor M2 is connected to a gate of the transistor M3. The other of the source and the drain of the transistor M2 is connected to a wiring WBL. A gate of the transistor M2 is connected to the wiring WOL. One of a source and a drain of the transistor M3 is connected to a wiring RBL. The other of the source and the drain of the transistor M3 is connected to a wiring SL.

Here, the wiring WBL corresponds to the conductive layer 240, and the wiring WOL corresponds to the conductive layer 265. As illustrated in FIGS. 23A and 23B, it is preferable that the conductive layer 265 be provided to extend in the X direction and the conductive layer 240 be provided to extend in the Y direction. With such a structure, the wiring WBL and the wiring WOL are provided to intersect with each other.

The transistor M2 does not necessarily include a back gate. Similarly, the transistor M3 does not necessarily include a back gate.

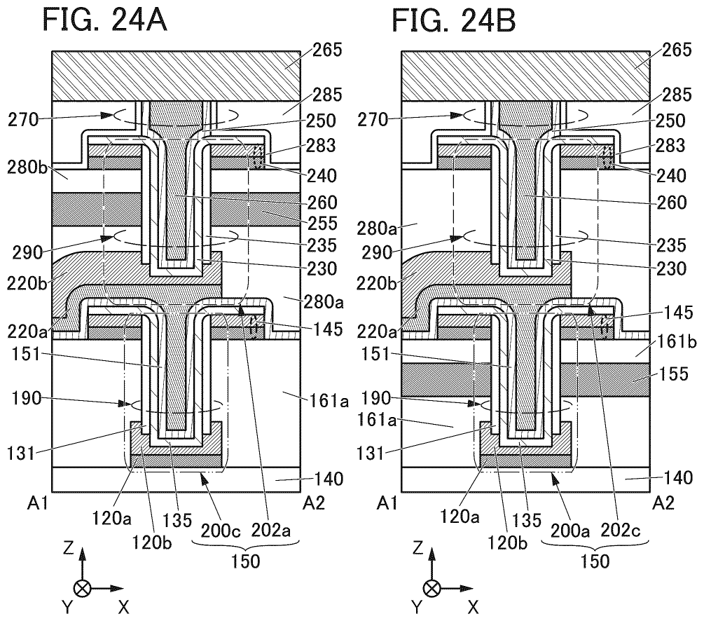

FIG. 24A illustrates an example where a transistor 200c not including a back gate is used as the transistor M3. The transistor 200c has a structure similar to that of the transistor 200a except that the conductive layer 155 and the insulating layer 161b are not provided. Furthermore, the transistor 200c does not necessarily include the insulating layer 131.

FIG. 24B illustrates an example where a transistor 202c not including a back gate is used as the transistor M2. The transistor 202c has a structure similar to that of the transistor 202a except that the conductive layer 255 and the insulating layer 280b are not provided. Furthermore, the transistor 202c does not necessarily include the insulating layer 235.

### Structure Example 1-2 of Memory Device

FIGS. 25A to 25C illustrate a structure of a memory device including a transistor and a capacitor. FIG. 25A is a plan view of a memory device including the transistor 203 and the capacitor 100. FIG. 25B is a cross-sectional view taken along dashed-dotted line A1-A2 in FIG. 25A. FIG. 25C is a cross-sectional view taken along dashed-dotted line A3-A4 in FIG. 25A.

The memory device illustrated in FIGS. 25A to 25C includes the insulating layer 140 over a substrate (not illustrated), the conductive layer 110 over the insulating layer 140, the memory cell 150 over the conductive layer 110, the insulating layer 180 over the conductive layer 110, the insulating layer 280a, the insulating layer 280b, the insulating layer 285, and the conductive layer 265 over the insulating layer 285. The insulating layer 140, the insulating layer 180, the insulating layer 280a, the insulating layer 280b, and the insulating layer 285 function as interlayer films. The conductive layer 110 and the conductive layer 265 function as wirings.

The memory cell 150 includes the capacitor 100 over the conductive layer 110 and the transistor 203 over the capacitor 100.

The capacitor 100 includes the conductive layer 115 over the conductive layer 110, the insulating layer 130 over the conductive layer 115, and the conductive layer 220a over the insulating layer 130. Detailed description of capacitor 100 is omitted because the above description can be referred to.

The insulating layer 280a is placed over the capacitor 100. The insulating layer 280a includes a portion positioned over the insulating layer 130 and a portion positioned over the conductive layer 220b.

The transistor 203 includes the conductive layer 220a, the conductive layer 220b over the conductive layer 220a, the conductive layer 255 over the insulating layer 280a, the conductive layer 240 over the insulating layer 280b, the oxide semiconductor layer 230, the insulating layer 235 between the conductive layer 255 and the oxide semiconductor layer 230, the insulating layer 250 over the oxide semiconductor layer 230, and the conductive layer 260 over the insulating layer 250. The oxide semiconductor layer 230 functions as the semiconductor layer, the conductive layer 260 functions as the first gate electrode, the insulating layer 250 functions as the first gate insulating layer, the conductive layer 255 functions as the second gate electrode, the insulating layer 235 functions as the second gate insulating layer, the conductive layer 220a and the conductive layer 220b function as one of the source electrode and the drain electrode, and the conductive layer 240 functions as the other of the source electrode and the drain electrode.

The description in Embodiment 2 (FIGS. 12A to 12E) can be referred to for the transistor 203; thus, the detailed description thereof is omitted.

As illustrated in FIGS. 25A to 25C, the transistor 203 is provided to overlap with the capacitor 100. The opening portion 290 where part of the components of the transistor 203 is provided includes a region overlapping with the opening portion 190 where part of the components of the capacitor 100 is provided. In particular, since the conductive layer 220a (and the conductive layer 220b) has a function of one of the source electrode and the drain electrode of the transistor 203 and a function of the upper electrode of the capacitor 100, the transistor 203 and the capacitor 100 share part of the structure. The opening portion 270 also includes a region overlapping with the opening portion 290 and the opening portion 190. With such a structure, the transistor 203 and the capacitor 100 can be provided without an increase in the occupation area in a plan view. Thus, the occupation area of the memory cell 150 can be reduced, so that the memory cells 150 can be arranged densely and the storage capacity of the memory device can be increased. In other words, the memory device can be highly integrated. FIGS. 25B and 25C illustrate an example where the width of the opening portion 190 is smaller than the width of the opening portion 290 and the width of the opening portion 270. There is no particular limitation on the relation between the width of the opening portion 190 and the width of the opening portion 290 or the width of the opening portion 270. In view of miniaturization, the width of the opening portion 190 is preferably smaller than or equal to the width of the opening portion 290. Similarly, the width of the opening portion 190 is preferably smaller than or equal to the width of the opening portion 270.

When the transistor 203 is provided above the capacitor 100, the transistor 203 is not affected by thermal budget in manufacturing the capacitor 100. Thus, in the transistor 203, degradation of the electrical characteristics such as variation in threshold voltage or an increase in parasitic resistance, and an increase in variation in electrical characteristics due to the degradation of the electrical characteristics can be inhibited.

FIG. 40A is a circuit diagram of the memory device described in this embodiment. As illustrated in FIG. 40A, the structure illustrated in FIGS. 25A to 25C functions as a memory cell. The memory cell 951 includes the transistor M1 and the capacitor CA. Here, the transistor M1 corresponds to the transistor 203, and the capacitor CA corresponds to the capacitor 100.

One of the source and the drain of the transistor M1 is connected to one of a pair of electrodes of the capacitor CA. The other of the source and the drain of the transistor M1 is connected to the wiring BIL. The gate of the transistor M1 is connected to the wiring WOL. The other of the pair of electrodes of the capacitor CA is connected to the wiring CAL.

Here, the wiring BIL corresponds to the conductive layer 240, the wiring WOL corresponds to the conductive layer 265, and the wiring CAL corresponds to the conductive layer 110. As illustrated in FIGS. 25A to 25C, it is preferable that the conductive layer 265 be provided to extend in the X direction and the conductive layer 240 be provided to extend in the Y direction. With such a structure, the wiring BIL and the wiring WOL are provided to intersect with each other. Although the wiring CAL (the conductive layer 110) is provided in a plane shape in FIG. 25A, the present invention is not limited thereto. For example, the wiring CAL may be provided parallel to the wiring WOL (the conductive layer 265) or the wiring BIL (the conductive layer 240).

### Structure Example 2-2 of Memory Device

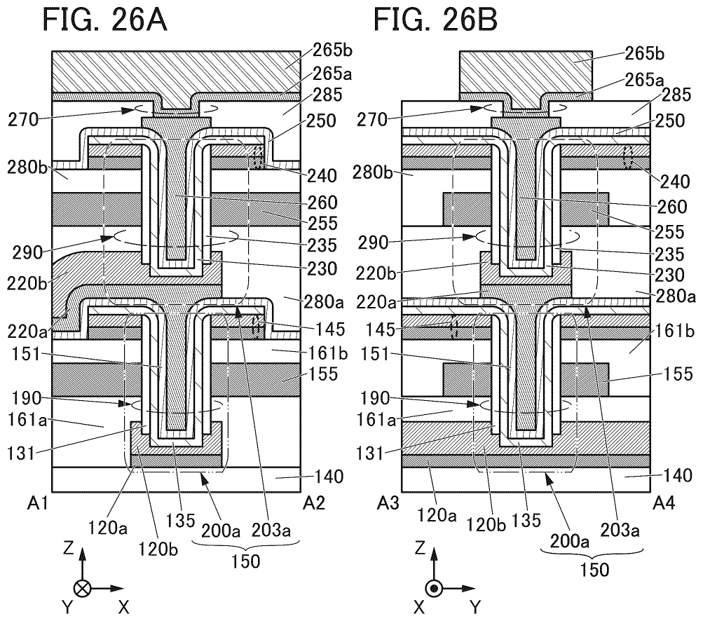

FIGS. 26A and 26B are cross-sectional views of a memory device including the transistor 200a and a transistor 203a.

The memory device illustrated in FIGS. 26A and 26B includes the insulating layer 140 over a substrate (not illustrated), the memory cell 150 over the insulating layer 140, the insulating layer 161a over the insulating layer 140, the insulating layer 161b, the insulating layer 280a, the insulating layer 280b, the insulating layer 285, and the conductive layer 265 over the insulating layer 285. The insulating layer 140, the insulating layer 161a, the insulating layer 161b, the insulating layer 280a, the insulating layer 280b, and the insulating layer 285 function as interlayer films. The conductive layer 265 functions as a wiring.

The memory cell 150 includes the transistor 200a over the insulating layer 140 and the transistor 203a over the transistor 200a.

The description of the transistor 200 in Embodiment 2 (FIGS. 2A1 to 2E and FIG. 3) can be referred to for the transistor 200a; thus, the detailed description thereof is omitted. The description of the transistor 203 in Embodiment 2 (FIGS. 12A to 12E) can be referred to for the transistor 203a; thus, the detailed description thereof is omitted. The transistors included in the memory cell 150 are not limited to the combination of the transistor 200 and the transistor 203, and one or more kinds of the transistors described in Embodiment 2 can be used.

The conductive layer 120a and the conductive layer 120b included in the transistor 200a can have structures similar to those usable for the conductive layer 220a and the conductive layer 220b, respectively. The conductive layer 145 can have a structure similar to that usable for the conductive layer 240. The insulating layer 131 can have a structure similar to that usable for the insulating layer 235. The oxide semiconductor layer 135 can have a structure similar to that usable for the oxide semiconductor layer 230. The insulating layer 151 can have a structure similar to that usable for the insulating layer 250. The insulating layer 161a and the insulating layer 161b can have structures similar to those usable for the insulating layer 280a and the insulating layer 280b, respectively.

In the memory cell 150 illustrated in FIGS. 26A and 26B, capacitance generated between the conductive layer 220a and the conductive layer 145 can be used; thus, data can be retained without formation of an additional capacitor. The shortest distance from the top surface of the conductive layer 145 to the conductive layer 220a is preferably shorter than the shortest distance from the top surface of the conductive layer 240 to the conductive layer 265. Accordingly, the capacitance generated between the conductive layer 220a and the conductive layer 145 can be increased. Moreover, parasitic capacitance generated between the conductive layer 240 and the conductive layer 265 can be reduced.

As illustrated in FIGS. 26A and 26B, the transistor 203a is provided to overlap with the transistor 200a. The opening portion 290 and the opening portion 270 where part of the components of the transistor 203a is provided each include a region overlapping with the opening portion 190 where part of the components of the transistor 200a is provided. In particular, since the conductive layer 220a and the conductive layer 220b have a function of one of the source electrode and the drain electrode of the transistor 203a and a function of the gate electrode of the transistor 200a, the transistor 203a and the transistor 200a share part of the structure. With such a structure, the transistor 203a and the transistor 200a can be provided without an increase in the occupation area in a plan view. Thus, the occupation area of the memory cell 150 can be reduced, so that the memory cells 150 can be arranged densely and the storage capacity of the memory device can be increased. In other words, the memory device can be highly integrated.

FIG. 40E is a circuit diagram of the memory device described in this embodiment. As illustrated in FIG. 40E, the structure illustrated in FIGS. 26A and 26B functions as a memory cell. The memory cell 955 includes the transistor M2 and the transistor M3. Here, the transistor M2 corresponds to the transistor 203a, and the transistor M3 corresponds to the transistor 200a.

One of the source and the drain of the transistor M2 is electrically connected to the gate of the transistor M3. The other of the source and the drain of the transistor M1 is connected to the wiring WBL. The gate of the transistor M2 is connected to the wiring WOL. One of the source and the drain of the transistor M3 is electrically connected to the wiring RBL. The other of the source and the drain of the transistor M3 is connected to the wiring SL.

Here, the wiring WBL corresponds to the conductive layer 240, and the wiring WOL corresponds to the conductive layer 265. As illustrated in FIGS. 26A and 26B, it is preferable that the conductive layer 265 be provided to extend in the X direction and the conductive layer 240 be provided to extend in the Y direction. With such a structure, the wiring WBL and the wiring WOL are provided to intersect with each other.

Alternatively, the transistor M2 does not necessarily include a back gate. Similarly, the transistor M3 does not necessarily include a back gate.

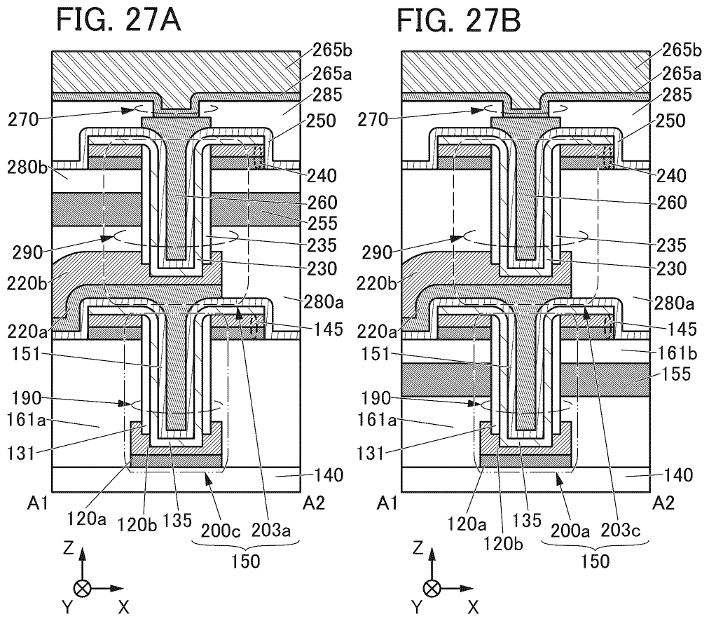

FIG. 27A illustrates an example where the transistor 200c not including a back gate is used as the transistor M3. The transistor 200c has a structure similar to that of the transistor 200a except that the conductive layer 155 and the insulating layer 161b are not provided. Furthermore, the transistor 200c does not necessarily include the insulating layer 131.

FIG. 27B illustrates an example where the transistor 203c not including a back gate is used as the transistor M2. The transistor 203c has a structure similar to that of the transistor 203a except that the conductive layer 255 and the insulating layer 280b are not provided. Furthermore, the transistor 203c does not necessarily include the insulating layer 235.

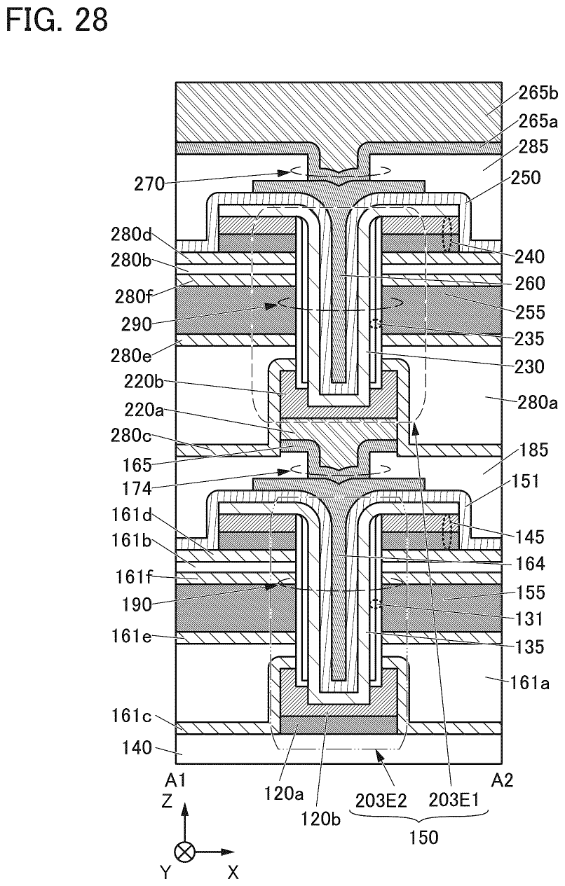

FIG. 28 is a cross-sectional view of a memory device including a transistor 200E1 and a transistor 200E2.

The memory device illustrated in FIG. 28 includes the insulating layer 140 over a substrate (not illustrated), the memory cell 150 over the insulating layer 140, the insulating layer 161c over the insulating layer 140, the insulating layer 161a over the insulating layer 161c, an insulating layer 161e over the insulating layer 161a, an insulating layer 161f, the insulating layer 161b over the insulating layer 161f, an insulating layer 161d over the insulating layer 161b, an insulating layer 185, the insulating layer 280c over the insulating layer 185, the insulating layer 280a over the insulating layer 280c, the insulating layer 280e over the insulating layer 280a, the insulating layer 280f, the insulating layer 280b over the insulating layer 280f, the insulating layer 280d over the insulating layer 280b, the insulating layer 285, the conductive layer 265a over the insulating layer 285, and the conductive layer 265b over the conductive layer 265a. The insulating layer 140, the insulating layers 161a to 161f, the insulating layer 185, the insulating layers 280a to 280f, and the insulating layer 285 function as interlayer films. The conductive layer 265a and the conductive layer 265b function as wirings.

The memory cell 150 includes a transistor 203E2 over the insulating layer 140 and a transistor 203E1 over the transistor 203E2.

The description of the transistor 203E in Embodiment 2 (FIGS. 14C1 and 14C2) can be referred to for the transistor 203E1 and the transistor 203E2; thus, the detailed description thereof is omitted.

The conductive layer 120a and the conductive layer 120b included in the transistor 203E2 can have structures similar to those usable for the conductive layer 220a and the conductive layer 220b, respectively. The conductive layer 145 can have a structure similar to that usable for the conductive layer 240. A conductive layer 164 can have a structure similar to that usable for the conductive layer 260. The insulating layer 131 can have a structure similar to that usable for the insulating layer 235. The oxide semiconductor layer 135 can have a structure similar to that usable for the oxide semiconductor layer 230. The insulating layer 151 can have a structure similar to that usable for the insulating layer 250. The insulating layer 161a to the insulating layer 161f can have structures similar to those usable for the insulating layer 280a to the insulating layer 280f, respectively. Note that FIG. 28 illustrates an example where the insulating layer 235 and the insulating layer 131 each have a two-layer structure. For the insulating layer 235 having a two-layer structure, the description of the transistor 200B (FIG. 4B) can be referred to, for example.

In the memory cell 150 illustrated in FIG. 28, capacitance generated between the conductive layer 164 and the conductive layer 145 can be used; thus, data can be retained without formation of an additional capacitor.

As illustrated in FIG. 28, the transistor 203E1 is provided to overlap with the transistor 203E2. The opening portion 290 where part of the components of the transistor 203E1 is provided includes a region overlapping with the opening portion 190 where part of the components of the transistor 203E2 is provided. An opening portion 174 that connects the transistor 203E1 to the transistor 203E2 and the opening portion 270 that connects the transistor 203E1 to the conductive layer 265a functioning as the wiring each include a region overlapping with the opening portion 290 and the opening portion 190. Since the conductive layer 164, the conductive layer 220a, and the conductive layer 220b have a function of one of a source electrode and a drain electrode of the transistor 203E1 and a function of a gate electrode of the transistor 203E2, the transistor 203E1 and the transistor 203E2 share part of the structure. With such a structure, the transistor 203E1 and the transistor 203E2 can be provided without an increase in the occupation area in a plan view. Thus, the occupation area of the memory cell 150 can be reduced, so that the memory cells 150 can be arranged densely and the storage capacity of the memory device can be increased. In other words, the memory device can be highly integrated.

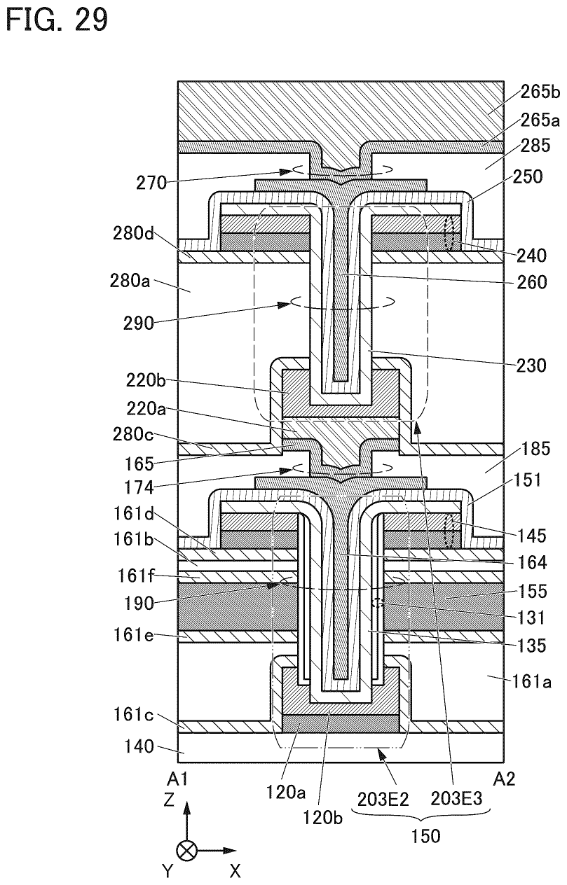

FIG. 29 illustrates an example where the memory cell 150 includes a transistor 203E3 not including a back gate instead of the transistor 203E1 illustrated in FIG. 28. The transistor 203E3 has a structure similar to that of the transistor 203E1 except that the conductive layer 255, the insulating layer 235, the insulating layer 280b, the insulating layer 280e, and the insulating layer 280f are not provided.

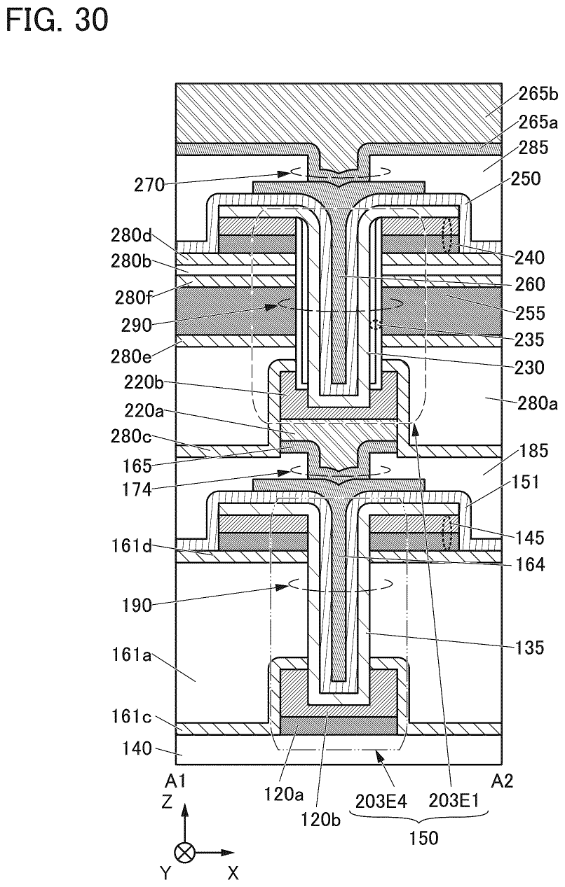

FIG. 30 illustrates an example where the memory cell 150 includes a transistor 203E4 not including a back gate instead of the transistor 203E2 illustrated in FIG. 28. The transistor 203E4 has a structure similar to that of the transistor 203E2 except that the conductive layer 155, the insulating layer 131, the insulating layer 161b, the insulating layer 161e, and the insulating layer 161f are not provided.

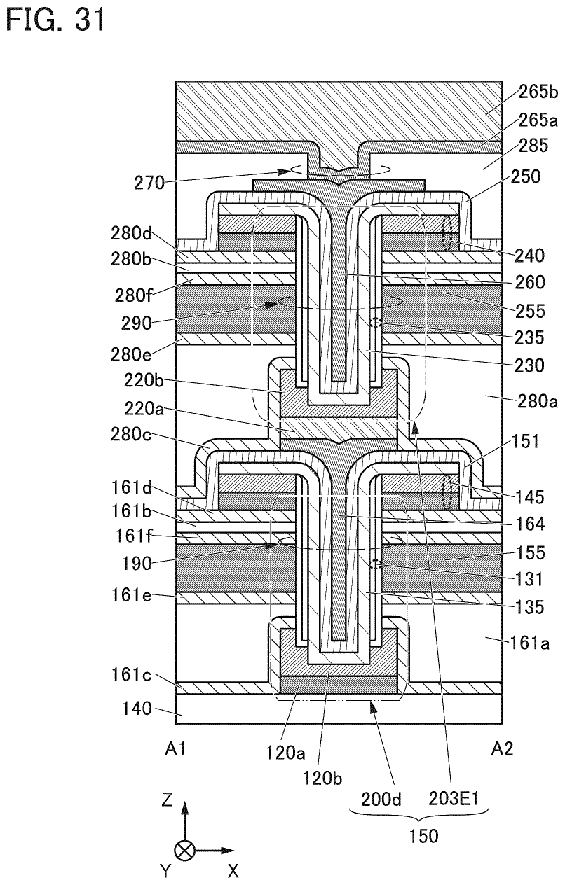

FIG. 31 illustrates an example where the memory cell 150 includes a transistor 200d instead of the transistor 203E2 illustrated in FIG. 28.

The description of the transistor 200G in Embodiment 2 (FIG. 6C) can be referred to for the transistor 200d; thus, the detailed description thereof is omitted.

In the memory cell 150 illustrated in FIG. 31, the conductive layer 164 and the conductive layer 220a are in contact with each other. The conductive layer 164, the conductive layer 220a, and the conductive layer 220b can be formed using the same mask. Unlike the memory cell 150 illustrated in FIG. 28, the memory cell 150 illustrated in FIG. 31 includes neither the insulating layer 185 nor the conductive layer 165, and thus can be manufactured through a simplified process.

FIG. 32 is a cross-sectional view of a memory device including the transistor 200e, the transistor 203E1, and a capacitor 100A.

The memory device illustrated in FIG. 32 includes the insulating layer 140 over a substrate (not illustrated), the memory cell 150 over the insulating layer 140, the insulating layer 161c over the insulating layer 140, the insulating layer 161a over the insulating layer 161c, the insulating layer 161e over the insulating layer 161a, the insulating layer 161f, the insulating layer 161b over the insulating layer 161f, the insulating layer 161d over the insulating layer 161b, the insulating layer 185, the insulating layer 180a over the insulating layer 185, the insulating layer 180b over the insulating layer 180a, the insulating layer 280c over the insulating layer 180b, the insulating layer 280a over the insulating layer 280c, the insulating layer 280e over the insulating layer 280a, the insulating layer 280f, the insulating layer 280b over the insulating layer 280f, the insulating layer 280d over the insulating layer 280b, the insulating layer 285, the conductive layer 265a over the insulating layer 285, and the conductive layer 265b over the conductive layer 265a. The insulating layer 140, the insulating layers 161a to 161f, the insulating layer 180a, the insulating layer 180b, the insulating layer 185, the insulating layers 280a to 280f, and the insulating layer 285 function as interlayer films. The conductive layers 265a and 265b function as wirings.

The memory cell 150 includes the transistor 200e over the insulating layer 140, the capacitor 100A over the transistor 200e, and the transistor 203E1 over the capacitor 100A.

The description of the transistor 200 in Embodiment 2 (FIGS. 2A1 to 2E and FIG. 3) can be referred to for the transistor 200e; thus, the detailed description thereof is omitted. The description of the transistor 203 (FIG. 12) in Embodiment 2 can be referred to for the transistor 203E1; thus, the detailed description thereof is omitted. The above description of the capacitor 100 can be referred to for the capacitor 100A; thus, the detailed description thereof is omitted. For the conductive layers 165a and 165b, any of materials that can be used for the conductive layer 115 can be used. Any of the above-described materials that can be used for the conductive layer included in the semiconductor device can also be used.

The conductive layer 115 is electrically connected to the conductive layer 164 through a conductive layer 110a and a conductive layer 110b that are embedded in the insulating layer 185. The conductive layer 115 is electrically connected to the conductive layer 220a1 through a conductive layer 166a and a conductive layer 166b that are embedded in the insulating layer 180b. Accordingly, the source or the drain of the transistor 203E1, one electrode of the capacitor 100A, and the gate of the transistor 200e are electrically connected to each other.

As illustrated in FIG. 32, the transistor 203E1 is provided to overlap with the capacitor 100A and the transistor 200e. With such a structure, the transistor 203E1, the capacitor 100A, and the transistor 200e can be provided without an increase in the occupation area in a plan view. Thus, the occupation area of the memory cell 150 can be reduced, so that the memory cells 150 can be arranged densely and the storage capacity of the memory device can be increased. In other words, the memory device can be highly integrated.

FIG. 40C is a circuit diagram of the memory device described in this embodiment. As illustrated in FIG. 40C, the structure illustrated in FIG. 32 functions as a memory cell. The memory cell 953 includes the transistor M2, the transistor M3, and a capacitor CB. Here, the transistor M2 corresponds to the transistor 203E1, the transistor M3 corresponds to the transistor 200e, and the capacitor CB corresponds to the capacitor 100A.

One of the source and the drain of the transistor M2 is connected to a first terminal of the capacitor CB, the other of the source and the drain of the transistor M2 is connected to the wiring WBL, and the gate of the transistor M2 is connected to the wiring WOL. A second terminal of the capacitor CB is connected to the wiring CAL. One of the source and the drain of the transistor M3 is connected to the wiring RBL, the other of the source and the drain of the transistor M3 is connected to the wiring SL, and the gate of the transistor M3 is connected to the first terminal of the capacitor CB.

Here, the wiring WBL corresponds to the conductive layer 240, and the wiring WOL corresponds to the conductive layer 265. It is preferable that the conductive layer 265 be provided to extend in the X direction and the conductive layer 240 be provided to extend in the Y direction. With such a structure, the wiring WBL and the wiring WOL are provided to intersect with each other.

The transistor M2 does not necessarily include a back gate. Similarly, the transistor M3 does not necessarily include a back gate.

### <Structure Example 3 of Memory Device>

The memory cell 150 including the transistor 202 and the capacitor 100 described in this embodiment can be used as a memory cell of the memory device. Similarly, the memory cell 150 including the transistor 203 and the capacitor 100 described in this embodiment can be used as a memory cell of the memory device. The transistors 202 and 203 are each a transistor in which a channel is formed in a semiconductor layer including an oxide semiconductor. Since the transistors 202 and 203 each have a low off-state current, a memory device including the transistors 202 and 203 can retain stored data for a long time. In other words, such a memory device does not require refresh operation or has an extremely low frequency of refresh operation, leading to a sufficient reduction in power consumption. The transistors 202 and 203 each have high frequency characteristics and thus enable the memory device to perform reading and writing at high speed.

The memory cells 150 are arranged in a matrix three-dimensionally, whereby a memory cell array can be formed.

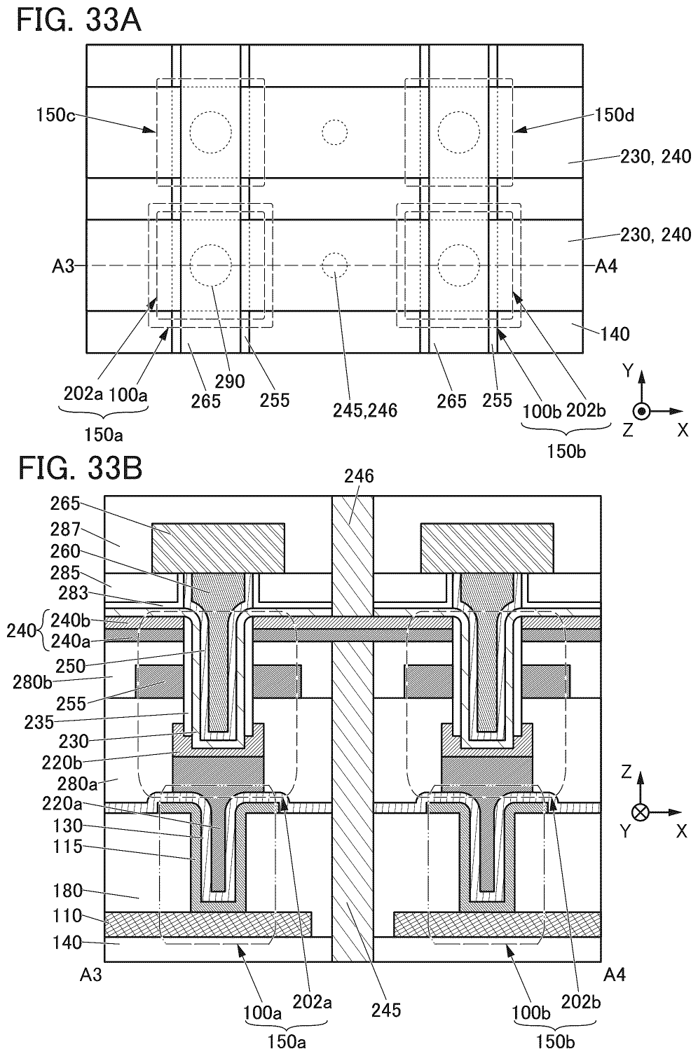

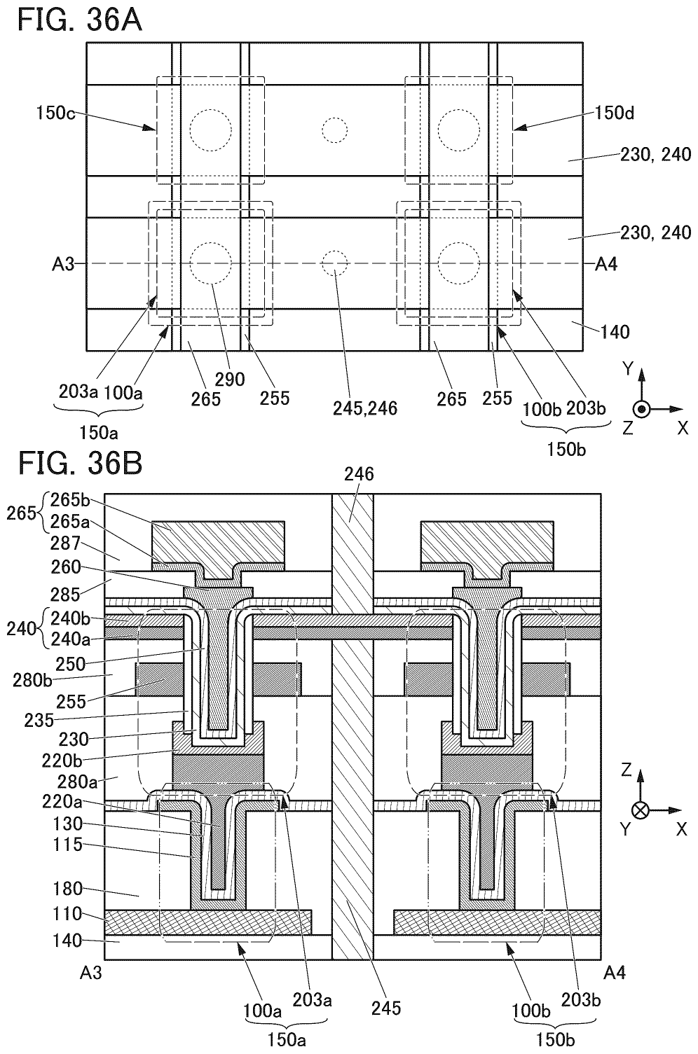

FIGS. 33A and 36A are plan views of a memory device. FIGS. 33A and 36A each illustrate an example where 2×2 memory cells (a memory cell 150a to a memory cell 150d) are arranged in the X direction and the Y direction.

FIG. 33B is a cross-sectional view taken along dashed-dotted line A3-A4 in FIG. 33A. In FIGS. 33A and 33B, two memory cells (the memory cells 150a and 150b in FIG. 33B) are connected to a common wiring (a conductive layer 246).

FIG. 36B is a cross-sectional view taken along dashed-dotted line A3-A4 in FIG. 36A. In FIGS. 36A and 36B, two memory cells (the memory cells 150a and 150b in FIG. 36B) are connected to a common wiring (the conductive layer 246).

FIG. 40B is a circuit diagram corresponding to two memory cells. As illustrated in FIG. 40B, a memory device 952 includes two memory cells; one of the memory cells includes the transistor M1 and a capacitor CA1, and the other of the memory cells includes the transistor M2 and a capacitor CA2. For example, in the case where FIG. 40B corresponds to FIG. 33B, the transistor M1 corresponds to the transistor 202a, the capacitor CA1 corresponds to the capacitor 100a, the transistor M2 corresponds to the transistor 202b, and the capacitor CA2 corresponds to the capacitor 100b. For example, in the case where FIG. 40B corresponds to FIG. 36B, the transistor M1 corresponds to the transistor 203a, the capacitor CA1 corresponds to the capacitor 100a, the transistor M2 corresponds to the transistor 203b, and the capacitor CA2 corresponds to the capacitor 100b.

One of the source and the drain of the transistor M1 is connected to one of a pair of electrodes of the capacitor CA1. The other of the source and the drain of the transistor M1 is connected to the wiring BIL. The gate of the transistor M1 is connected to a wiring WOL1. The other of the pair of electrodes of the capacitor CA1 is connected to the wiring CAL. One of the source and the drain of the transistor M2 is connected to one of a pair of electrodes of the capacitor CA2. The other of the source and the drain of the transistor M2 is connected to the wiring BIL. The gate of the transistor M2 is connected to a wiring WOL2. The other of the pair of electrodes of the capacitor CA2 is connected to the wiring CAL.

Here, the wiring BIL corresponds to the conductive layer 240, the wiring WOL1 corresponds to the conductive layer 265, the wiring WOL2 corresponds to another conductive layer 265, and the wiring CAL corresponds to the conductive layer 110.

The memory cells 150a and 150b illustrated in FIGS. 33A and 33B each have a structure similar to that of the memory cell 150. The memory cell 150a includes the capacitor 100a and the transistor 202a, and the memory cell 150b includes the capacitor 100b and the transistor 202b. The memory cells 150c and 150d illustrated in FIG. 33A each have a structure similar to that of the memory cell 150. Thus, in the memory device illustrated in FIGS. 33A and 33B, components having the same functions as the components of the memory device illustrated in FIGS. 22A to 22C are denoted by the same reference numerals. The description of the memory cell 150 in <Structure example 1 of memory device> can be referred to for the details of the memory cells 150a to 150d.

The memory cells 150a and 150b illustrated in FIGS. 36A and 36B each have a structure similar to that of the memory cell 150. The memory cell 150a includes the capacitor 100a and the transistor 203a, and the memory cell 150b includes the capacitor 100b and the transistor 203b. The memory cells 150c and 150d illustrated in FIG. 36A each have a structure similar to that of the memory cell 150. Thus, in the memory device illustrated in FIGS. 36A and 36B, components having the same functions as the components of the memory device illustrated in FIGS. 25A to 25C are denoted by the same reference numerals. The description of the memory cell 150 in <Structure example 1-2 of memory device> can be referred to for the details of the memory cells 150a to 150d.

As illustrated in FIGS. 33A, 33B, 36A, and 36B, the conductive layer 265 functioning as the wiring WOL is provided in each of the memory cells 150a and 150b. As illustrated in FIGS. 33A and 36A, one conductive layer 265 is shared by the memory cells 150a and 150c, and another conductive layer 265 is shared by the memory cells 150b and 150d. One conductive layer 240 functioning as part of the wiring BIL is shared by the memory cells 150a and 150b. That is, the conductive layer 240 is in contact with the oxide semiconductor layer 230 of the memory cell 150a and the oxide semiconductor layer 230 of the memory cell 150b. Another conductive layer 240 is shared by the memory cells 150c and 150d.

FIGS. 33B and 36B each illustrate an example where the conductive layer 240 has a two-layer structure of the conductive layer 240a and the conductive layer 240b over the conductive layer 240a.

Here, the memory device illustrated in FIGS. 33A and 33B includes the conductive layers 245 and 246 functioning as plugs (also can be referred to as connection electrodes) electrically connected to the memory cells 150a and 150b. The conductive layer 245 is placed in an opening portion formed in the insulating layers 140, 180, 130, 280a, and 280b, and is in contact with the bottom surface of the conductive layer 240a. The conductive layer 246 is placed in an opening portion formed in the insulating layer 287, the insulating layer 285, the insulating layer 283, and the oxide semiconductor layer 230, and is in contact with the top surface of the conductive layer 240b. Note that a conductive material that can be used for the conductive layer 240, for example, can be used for the conductive layers 245 and 246.

The memory device illustrated in FIGS. 36A and 36B includes the conductive layers 245 and 246 functioning as plugs (also can be referred to as connection electrodes) electrically connected to the memory cells 150a and 150b. The conductive layer 245 is placed in an opening portion formed in the insulating layers 140, 180, 130, 280a, and 280b, and is in contact with the bottom surface of the conductive layer 240a. The conductive layer 246 is placed in an opening portion formed in the insulating layer 287, the insulating layer 285, and the oxide semiconductor layer 230, and is in contact with the top surface of the conductive layer 240b.

The conductive layer 246 can be in contact with the top surface of the conductive layer 240a. Alternatively, the conductive layer 246 can be in contact with the top surface of the oxide semiconductor layer 230. That is, the conductive layer 240b may include an opening portion in a position overlapping with the conductive layer 246. The oxide semiconductor layer 230 does not necessarily include an opening portion in a position overlapping with the conductive layer 246. As a connection portion between the memory cell and the plug, a layer having a low contact resistance with the conductive layer 246 among the layers included in the conductive layer 240 and the oxide semiconductor layer 230 is preferably in contact with the conductive layer 246.

Similarly, the conductive layer 245 can be in contact with the bottom surface of the conductive layer 240b or the bottom surface of the oxide semiconductor layer 230. That is, the conductive layer 240a may include an opening portion in a position overlapping with the conductive layer 246. Among the layers included in the conductive layer 240 and the oxide semiconductor layer 230, a layer having a low contact resistance with the conductive layer 245 is preferably in contact with the conductive layer 245.

Among the layers included in the conductive layer 240 and the oxide semiconductor layer 230, a layer with a low wiring resistance is preferably in contact with the conductive layers 245 and 246.

The insulating layer 287 functions as an interlayer film and thus preferably has a low dielectric constant. In the case where a material with a low dielectric constant is used for an interlayer film, parasitic capacitance generated between wirings can be reduced.

The concentration of impurities such as water and hydrogen in the insulating layer 287 is preferably reduced. This can inhibit entry of impurities such as water and hydrogen into the channel formation region of the oxide semiconductor layer 230.

The conductive layers 245 and 246 each function as a plug or a wiring for electrically connecting the memory cells 150a and 150b to a wiring, an electrode, a terminal, or a circuit element such as a switch, a transistor, a capacitor, an inductor, a resistor, or a diode. For example, the conductive layer 245 can be electrically connected to a sense amplifier (not illustrated) provided below the memory device illustrated in FIG. 33B or 36B, and the conductive layer 246 can be electrically connected to a similar memory device (not illustrated) provided above the memory device illustrated in FIG. 33B or 36B. In this case, the conductive layers 245 and 246 function as part of the wiring BIL. When the memory device or the like is provided above or below the memory device illustrated in FIG. 33B or 36B in this manner, the storage capacity per unit area can be increased.

The memory cells 150a and 150b have a line-symmetric structure with a perpendicular bisector of the dashed-dotted line A3-A4 as the symmetric axis. Thus, the transistors 202a and 202b are also placed symmetrically with the conductive layers 245 and 246 therebetween. Note that in FIG. 33B, the conductive layer 240 has a function of the other of the source electrode and the drain electrode of the transistor 202a and the other of the source electrode and the drain electrode of the transistor 202b. The transistors 202a and 202b share the conductive layers 245 and 246 functioning as plugs. Similarly, the transistors 203a and 203b are also placed symmetrically with the conductive layers 245 and 246 therebetween. In FIG. 36B, the conductive layer 240 has a function of the other of the source electrode and the drain electrode of the transistor 203a and a function of the other of the source electrode and the drain electrode of the transistor 203b. The transistors 203a and 203b share the conductive layers 245 and 246 functioning as plugs. With the above connection structure between the two transistors and the plugs, a memory device that can be miniaturized or highly integrated can be provided.

Note that the conductive layer 110 functioning as the wiring CAL may be provided in each of the memory cells 150a and 150b or may be provided in common to the memory cells 150a and 150b. However, as illustrated in FIGS. 33B and 36B, the conductive layer 110 is provided to be apart from the conductive layer 245 so that the conductive layers 110 and 245 are not short-circuited.

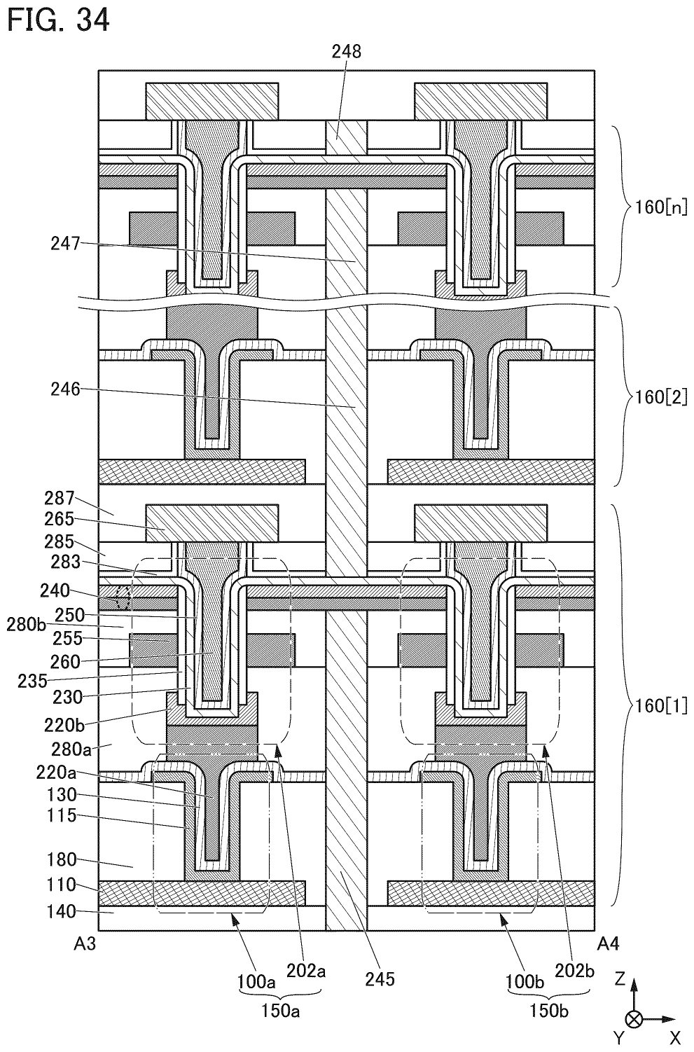

FIG. 34 illustrates an example where four memory cells illustrated in FIG. 33A are stacked in n layers (n is an integer greater than or equal to 3) in the Z direction. FIG. 34 is a cross-sectional view taken along dashed-dotted line A3-A4 in FIG. 33A.

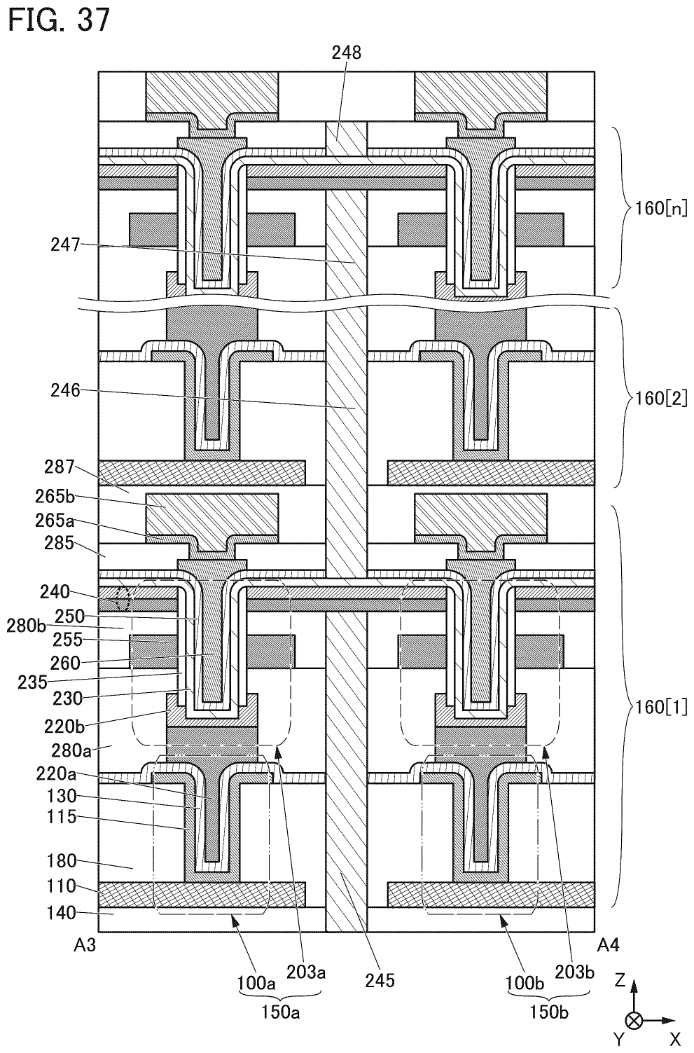

FIG. 37 illustrates an example where four memory cells illustrated in FIG. 36A are stacked in n layers (n is an integer greater than or equal to 3) in the Z direction. FIG. 37 is a cross-sectional view taken along dashed-dotted line A3-A4 in FIG. 36A.

The memory devices illustrated in FIGS. 34 and 37 each include n memory layers 160. Specifically, a memory layer 160[2] is provided over a memory layer 160[1], (n−2) memory layers are provided over the memory layer 160[2], and a memory layer 160[n] is provided in the uppermost stage. There is no particular limitation on the number of memory cells included in one memory layer 160, and two or more memory cells can be included. Through the conductive layer 245, the conductive layer 246, a conductive layer 247, a conductive layer 248, and the like, memory cells included in the n memory layers 160 are electrically connected to a sense amplifier (not illustrated) provided below the n memory layers 160.

FIGS. 34 and 37 each illustrate an example where the conductive layer 245 is in contact with the bottom surface of the conductive layer 240 and the conductive layer 246 is in contact with the top surface of the oxide semiconductor layer 230. As described above, a connection portion between the plug such as the conductive layer 245 or the conductive layer 246 and each memory cell can have any of a variety of modes and is not limited to the structures in FIGS. 34 and 37.

When a plurality of memory cells are stacked as illustrated in FIGS. 34 and 37, the cells can be provided in an integrated manner without increasing the area occupied by the memory cell array. That is, a 3D memory cell array can be formed.

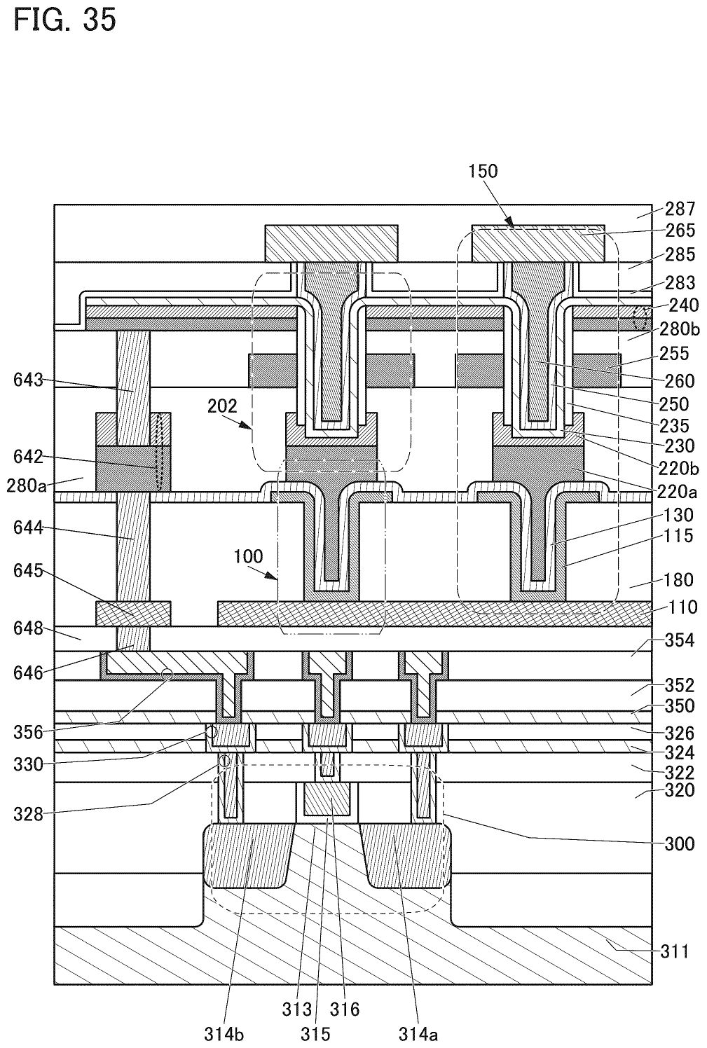

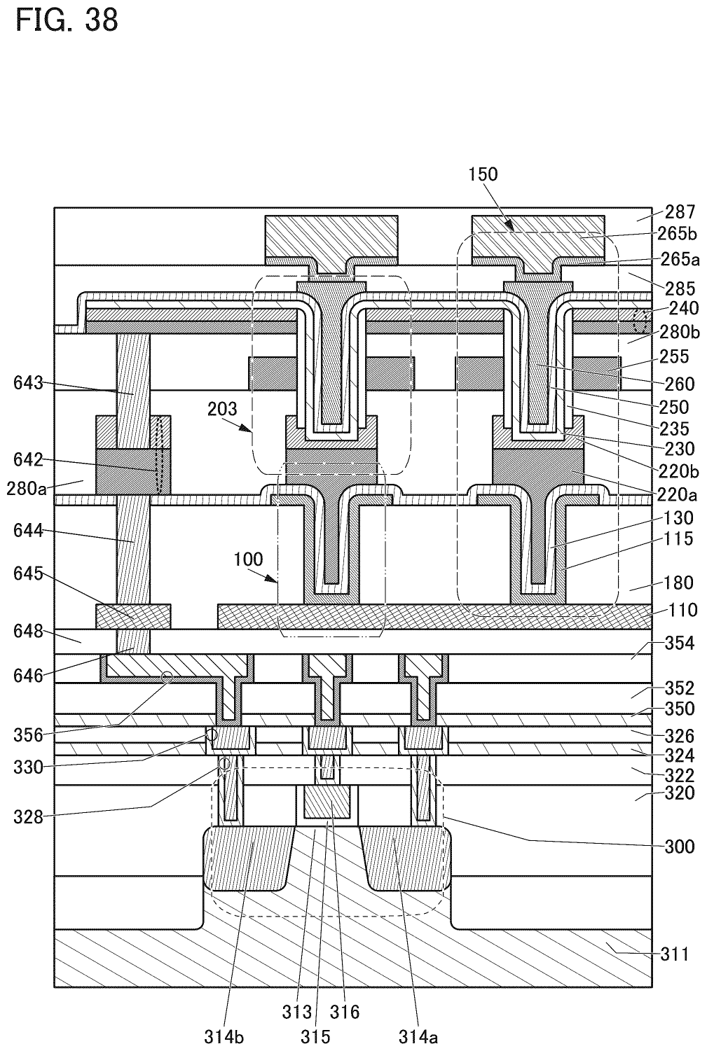

FIGS. 35 and 38 each illustrate a cross-sectional structure example of a memory device in which a layer including a memory cell is stacked over a layer including a driver circuit provided with a sense amplifier.

In FIG. 35, the memory cell 150 (the transistor 202 and the capacitor 100) is provided above a transistor 300. In FIG. 38, the memory cell 150 (the transistor 203 and the capacitor 100) is provided above the transistor 300.

The transistor 300 is one of the transistors included in the sense amplifier.

The description of the memory cell 150 in <Structure example 1 of memory device> and <Structure example 1-2 of memory device> can be referred to for the memory cell 150 illustrated in FIGS. 35 and 38.

When the sense amplifier is provided to overlap with the memory cell 150 as illustrated in FIGS. 35 and 38, the bit line can be shortened. Accordingly, the bit line capacitance can be reduced and the memory device can be driven at high speed.

The memory device illustrated in FIGS. 35 and 38 can correspond to a semiconductor device 900 described in Embodiment 5. Specifically, the transistor 300 corresponds to a transistor included in a sense amplifier 927 in the semiconductor device 900. The memory cell 150 corresponds to a memory cell 950.

The transistor 300 is provided on a substrate 311 and includes a conductive layer 316 functioning as a gate, an insulating layer 315 functioning as a gate insulating layer, a semiconductor region 313 that is a part of the substrate 311, and a low-resistance region 314a and a low-resistance region 314b functioning as a source region and a drain region. The transistor 300 can be a p-channel transistor or an n-channel transistor. The substrate 311 preferably includes a silicon-based semiconductor, specifically, single crystal silicon.

In the transistor 300 illustrated in FIGS. 35 and 38, the semiconductor region 313 (part of the substrate 311) in which a channel is formed has a projecting shape. Furthermore, the conductive layer 316 is provided to cover the side and top surfaces of the semiconductor region 313 with the insulating layer 315 therebetween. Note that the conductive layer 316 may be formed using a material for adjusting the work function. The transistor 300 having such a structure is also referred to as a FIN transistor because the projecting portion of the semiconductor substrate is utilized. Note that an insulating layer serving as a mask for forming the projecting portion may be provided in contact with the top of the projecting portion. Although the case where the projecting portion is formed by processing part of the semiconductor substrate is described here, a semiconductor film having a projecting shape may be formed by processing an SOI substrate.

Note that the transistor 300 illustrated in FIGS. 35 and 38 is just an example and is not limited to having the structure illustrated therein; an appropriate transistor can be used in accordance with a circuit structure or a driving method.

Wiring layers including an interlayer film, a wiring, a plug, and the like may be provided between the structure bodies. A plurality of wiring layers can be provided in accordance with the design. Here, a plurality of conductive layers functioning as plugs or wirings are collectively denoted by the same reference numeral in some cases. Furthermore, in this specification and the like, a wiring and a plug electrically connected to the wiring may be a single component. That is, in some cases, part of a conductive layer functions as a wiring or part of a conductive layer functions as a plug.

For example, an insulating layer 320, an insulating layer 322, an insulating layer 324, and an insulating layer 326 are stacked over the transistor 300 in this order as interlayer insulating films. A conductive layer 328 is embedded in the insulating layer 320 and the insulating layer 322, and a conductive layer 330 is embedded in the insulating layer 324 and the insulating layer 326. Note that the conductive layer 328 and the conductive layer 330 each function as a plug or a wiring.

The insulating layer functioning as an interlayer film may function as a planarization film that covers a roughness thereunder. For example, the top surface of the insulating layer 322 may be planarized by planarization treatment using a CMP method or the like to improve the planarity.

A wiring layer may be provided over the insulating layer 326 and the conductive layer 330. For example, in FIGS. 35 and 38, an insulating layer 350, an insulating layer 352, and an insulating layer 354 are stacked in this order. Furthermore, a conductive layer 356 is formed in the insulating layers 350, 352, and 354. The conductive layer 356 functions as a plug or a wiring.

As the insulating layer 352, the insulating layer 354, and the like functioning as interlayer films, the above-described insulating layer that can be used for the semiconductor device or the memory device can be used.

As the conductive layer functioning as a plug or a wiring, such as the conductive layer 328, the conductive layer 330, and the conductive layer 356, a conductive material that can be used for the conductive layer 240 can be used. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

The conductive layer 240 included in the transistor 202 is electrically connected to the low-resistance region 314b functioning as the source region or the drain region of the transistor 300 through a conductive layer 643, a conductive layer 642, a conductive layer 644, a conductive layer 645, a conductive layer 646, the conductive layer 356, the conductive layer 330, and the conductive layer 328. The same applies to the conductive layer 240 included in the transistor 203.

The conductive layer 643 is embedded in the insulating layer 280b. The conductive layer 642 is provided over the insulating layer 130 and is embedded in the insulating layer 280a. The conductive layers 642, 220a, and 220b can be formed using the same material in the same step. The conductive layer 644 is embedded in the insulating layers 180 and 130. The conductive layer 645 is embedded in the insulating layer 180. The conductive layers 645 and 110 can be formed using the same material in the same step. The conductive layer 646 is embedded in an insulating layer 648. The transistor 300 and the conductive layer 110 are electrically insulated from each other by the insulating layer 648.

This embodiment can be combined with any of the other embodiments as appropriate.

### Embodiment 5

In this embodiment, the semiconductor device 900 of one embodiment of the present invention will be described. The semiconductor device 900 can function as a memory device.

FIG. 39 is a block diagram illustrating a structure example of the semiconductor device 900. The semiconductor device 900 illustrated in FIG. 39 includes a driver circuit 910 and a memory array 920. The memory array 920 includes at least one memory cell 950. FIG. 39 illustrates an example where the memory array 920 includes a plurality of memory cells 950 arranged in a matrix.

The memory device (e.g., the memory device 150) described in Embodiment 4 can be used for the memory cell 950.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and a sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply potential is V_{DD} and a low power supply potential is GND (ground potential). In addition, V_{HM} is a high power supply potential used for setting a word line to high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 39 but can be more than one. In that case, a power switch is provided for each power domain.

Structure examples of other memory cells each of which can be used as the memory cell 950 are described with reference to FIGS. 40A to 40G.

In the following description, the expression “two components are connected to each other” includes the case where the two components are electrically connected through a circuit element (a transistor, a switch, a diode, a resistor, or the like). The term “electrical connection” means a possibility that a current flows between two components. Note that the case where two components are connected through a switch or a transistor is included as electrical connection because a current can flow when the components are in an on state.

### [DOSRAM]

FIG. 40A illustrates a circuit structure example of a memory cell for a DRAM. In this specification and the like, a DRAM using an OS transistor is referred to as a dynamic oxide semiconductor random access memory (DOSRAM). A memory cell 951 includes the transistor M1 and the capacitor CA.

Note that the transistor M1 may include a front gate (sometimes simply referred to as a gate) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to a wiring BIL. The gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and data reading, a low-level potential (sometimes referred to as a reference potential) is preferably applied to the wiring CAL.

Data writing and data reading are performed in such a manner that a high-level potential is applied to the wiring WOL to turn on the transistor M1 and establish electrical continuity between the wiring BIL and the first terminal of the capacitor CA (make a state where a current can flow therethrough).

The memory cell that can be used as the memory cell 950 is not limited to the memory cell 951, and the circuit structure can be changed. For example, the memory cell 951 does not necessarily include the capacitor CA or the wiring CAL, and the first terminal of the transistor M1 may be in an electrically floating state.

Note that an OS transistor is preferably used as the transistor M1. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cell 951.

As illustrated in FIG. 40B, one wiring BIL can be provided to be shared by two or more memory cells of DRAM.

### [NOSRAM]

FIG. 40C illustrates a circuit structure example of a gain-cell memory cell including two transistors and one capacitor. A memory cell 953 includes the transistor M2, the transistor M3, and the capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to the wiring WBL. The gate of the transistor M2 is connected to the wiring WOL. A second terminal of the capacitor CB is connected to the wiring CAL. A first terminal of the transistor M3 is connected to the wiring RBL. A second terminal of the transistor M3 is connected to the wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (sometimes referred to as a ground potential) is preferably applied to the wiring CAL.

Data writing is performed in such a manner that a high-level potential is applied to the wiring WOL to turn on the transistor M2 and establish electrical continuity between the wiring WBL and the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

As another example, one wiring BIL may be provided instead of the wiring WBL and the wiring RBL. A circuit structure example of the memory cell is illustrated in FIG. 40D. In the memory cell 954, one wiring BIL is provided instead of the wiring WBL and the wiring RBL in the memory cell 953, and the second terminal of the transistor M2 and the first terminal of the transistor M3 are electrically connected to the wiring BIL. In other words, one wiring BIL operates as the write bit line and the read bit line in the memory cell 954.

The memory cell 955 illustrated in FIG. 40E is an example where the capacitor CB and the wiring CAL in the memory cell 953 are omitted. The memory cell 956 illustrated in FIG. 40F is an example where the capacitor CB and the wiring CAL in the memory cell 954 are omitted. Such structures enable high integration of the memory cell.

Note that an OS transistor is preferably used as at least the transistor M2. In particular, an OS transistor is preferably used as each of the transistors M2 and M3.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

When the OS transistor is used as the transistor M3, the memory cell can be configured with the transistors having the same conductivity type.

FIG. 40G illustrates an example of a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is electrically connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed in such a manner that a high-level potential is applied to the wiring WOL to turn on the transistor M4 and establish electrical continuity between the wiring BIL and the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than the OS transistor depending on the crystal state of silicon used in a semiconductor layer, for example.

When OS transistors are used as the transistors M5 and M6, the memory cell can be configured with the transistors having the same conductivity type.

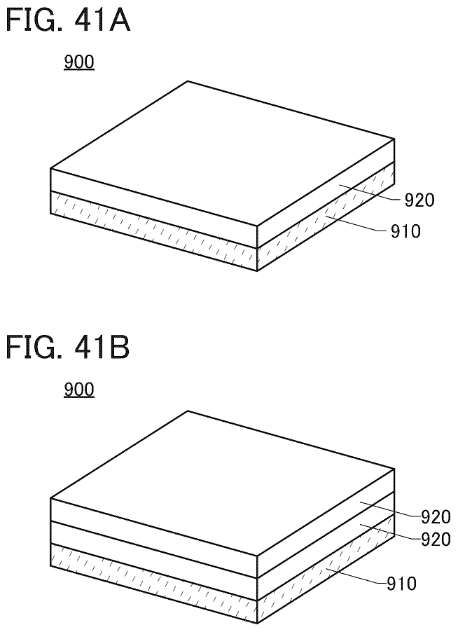

The driver circuit 910 and the memory array 920 included in the semiconductor device 900 may be provided on the same plane. Alternatively, as illustrated in FIG. 41A, the driver circuit 910 and the memory array 920 may be provided to overlap each other. Overlapping the driver circuit 910 and the memory array 920 can shorten a signal propagation distance. As illustrated in FIG. 41B, a plurality of memory arrays 920 may be stacked over the driver circuit 910.

Next, description is made on an example of an arithmetic processing device that can include the semiconductor device, such as the memory device described above.

FIG. 42 is a block diagram of the arithmetic device 960. The arithmetic device 960 illustrated in FIG. 42 can be used for a central processing unit (CPU), for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 42 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 42 is only an example with a simplified configuration, and the actual arithmetic device 960 has a variety of configurations depending on the application. For example, what is called a multicore configuration is preferably employed in which a plurality of cores each including the arithmetic device 960 in FIG. 42 operate in parallel. The larger number of cores can further enhance the arithmetic performance. The number of cores is preferably larger; for example, the number is preferably 2, further preferably 4, still further preferably 8, still further preferably 12, yet still further preferably 16 or larger. For application requiring extremely high arithmetic performance, e.g., a server, it is preferable to employ the multicore configuration including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 42, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, a power supply potential is supplied to the memory cell in the register 996. When data retention by the capacitor is selected, the data is rewritten into the capacitor, and supply of the power supply potential to the memory cell in the register 996 can be stopped.

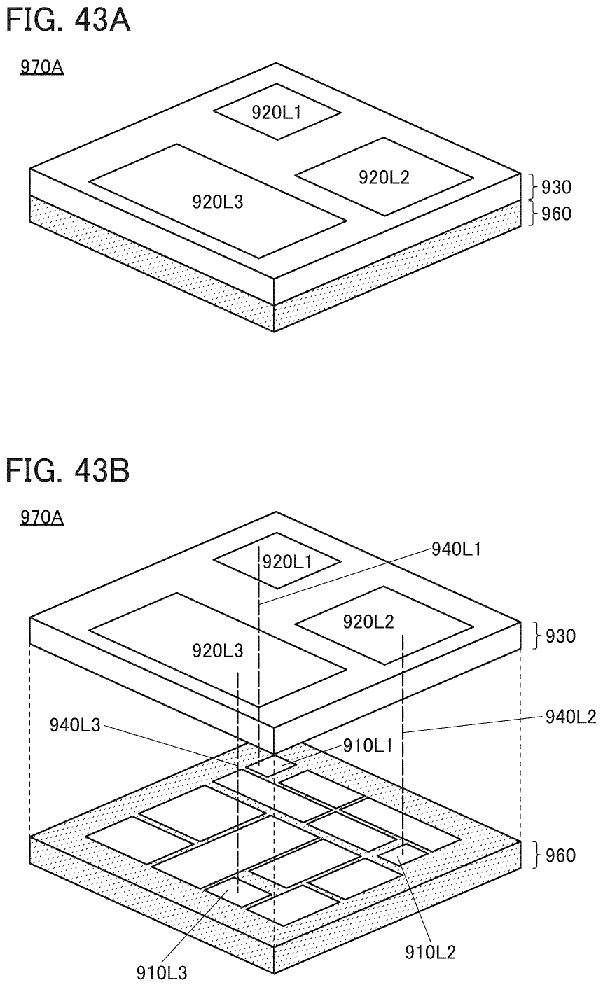

The memory array 920 and the arithmetic device 960 can be provided to overlap with each other. FIGS. 43A and 43B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 43B.

Overlapping the arithmetic device 960 and the layer 930 including the memory arrays can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 43B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

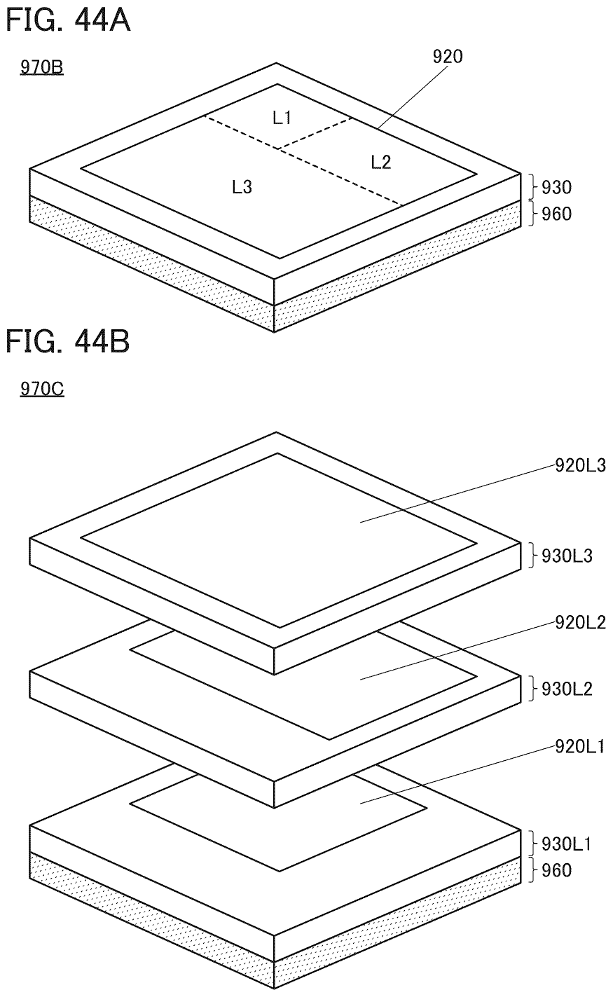

The layer 930 including one memory array 920 may be provided to overlap with the arithmetic device 960. FIG. 44A is a perspective view of a semiconductor device 970B.

In the semiconductor device 970B, one memory array 920 can be divided into a plurality of areas having different functions. FIG. 44A illustrates an example where a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 44B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

This embodiment can be combined with any of the other embodiments as appropriate.

### Embodiment 6

In this embodiment, application examples of the memory device of one embodiment of the present invention will be described.

In general, a variety of memory devices are used in semiconductor devices such as computers depending on the intended use. FIG. 45A illustrates the hierarchy of a variety of memory devices used in semiconductor devices. The memory devices at the upper levels require a higher operating speed, whereas the memory devices at the lower levels require a higher memory capacity and a higher memory density. FIG. 45A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may be further included.

A memory included as a register in an arithmetic processing device such as a CPU is used for temporary storage of arithmetic operation results, for example, and thus is very frequently accessed by the arithmetic processing device. Accordingly, rapid operation is more important than the memory capacity of the memory. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a low memory capacity than the main memory but a higher operating speed than the main memory. Data that is rewritten in the cache is duplicated, and the duplicated data is supplied to the main memory.

The main memory has a function of retaining a program and data that are read from the storage.

The storage has a function of retaining data that needs to be stored for a long time and programs used in an arithmetic processing device, for example. Therefore, the storage needs to have a high memory capacity and a high memory density rather than a high operating speed. For example, a high-capacity nonvolatile memory device such as a 3D NAND memory device can be used.

The memory device including an oxide semiconductor (the OS memory) of one embodiment of the present invention operates fast and can retain data for a long time. For example, the OS memory has features shown in Table 1.

TABLE 1

| | |
|---|---|
| Power | Reduced to 1/10 to 1/100 of Si LSI DRAMs and L3 |
| consumption | Caches currently used in servers and supercomputers |
| Switching | 10 times or more of currently used 2.5 V DRAMs |
| speed | (<1.7 ns at 1.8 V, −40° C. to 110° C.) |
| Memory | 10 to 100 times of currently used DRAMs |
| retention | (Operation temperature range is −40° C. to 110° C., which |
| time | is more severe than a condition of −20° C. to 85° C.) |

Utilizing the features of the OS memory shown in Table 1, the memory device of one embodiment of the present invention can be favorably used at both the level including the cache and the level including the main memory, as illustrated in FIG. 45A. The memory device of one embodiment of the present invention can also be used at the level including the storage.

FIG. 45B illustrates an example where a static random access memory (SRAM) is used as some levels of the caches and the OS memory of one embodiment of the present invention is used as the other level of the cache.

The lowest-level cache can be referred to as a last level cache (LLC). The LLC does not require a higher operation speed than a higher-level cache, but desirably has a high memory capacity. The OS memory of one embodiment of the present invention operates at high speed and can retain data for a long time, and thus can be suitably used as the LLC. Note that the OS memory of one embodiment of the present invention can also be used as a final level cache (FLC).

For example, as illustrated in FIG. 45B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 45B.

Note that in a supercomputer, a server using a supercomputer, or the like, the L3 cache and the DRAM that is a main memory consume a large amount of power, which is one factor of global warming. In FIG. 45A, an OS memory is used as both the L3 cache and the main memory. In FIG. 45B, an OS memory is used as the LLC. With use of the oxide semiconductor of one embodiment of the present invention for a memory device, the power consumption of a supercomputer can be reduced to be equivalent to that of a personal computer.

This embodiment can be combined with any of the other embodiments as appropriate.

### Embodiment 7

In this embodiment, a display device of one embodiment of the present invention will be described.

The semiconductor device of one embodiment of the present invention can be used for a display device or a module including the display device. Examples of the module including the display device include a module in which a connector such as a flexible printed circuit board (hereinafter referred to as an FPC) or a tape carrier package (TCP) is attached to the display device and a module which is mounted with an integrated circuit (IC) by a chip on glass (COG) method, a chip on film (COF) method, or the like.

That is, the display device in this embodiment may have a function of a touch panel. The display device can employ any of a variety of sensor elements that can sense proximity or touch of a sensing target such as a finger, for example.

For example, a variety of types such as a capacitive type, a resistive type, a surface acoustic wave type, an infrared type, an optical type, and a pressure-sensitive type can be used for the sensor.

Examples of the capacitive touch sensor include a surface capacitive touch sensor and a projected capacitive touch sensor. Examples of the projected capacitive touch sensor include a self-capacitive touch sensor and a mutual capacitive touch sensor. The use of a mutual capacitive touch sensor is preferable because multiple points can be detected simultaneously.

Examples of a touch panel include an out-cell touch panel, an on-cell touch panel, and an in-cell touch panel. An in-cell touch panel has a structure where an electrode included in a sensor element is provided on one or both of a substrate supporting a display element and a counter substrate.

### [Display Module]

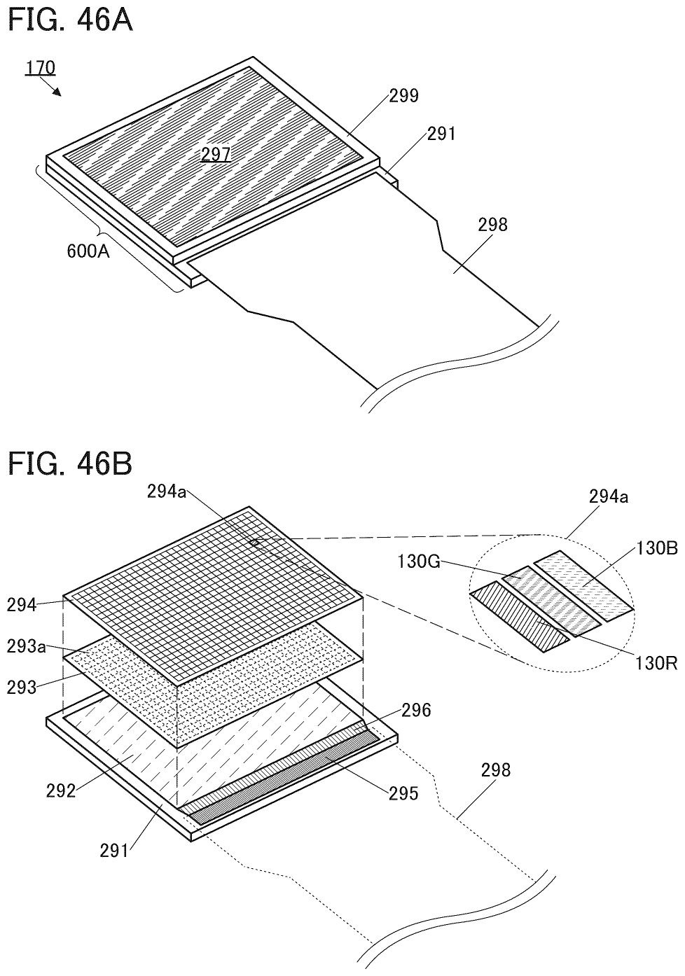

FIG. 46A is a perspective view of a display module 170. The display module 170 includes a display device 600A and an FPC 298. Note that the display device included in the display module 170 is not limited to the display device 600A and may be a display device 600B described later.

The display module 170 includes a substrate 291 and a substrate 299. The display module 170 includes a display portion 297. The display portion 297 is a region of the display module 170 where an image is displayed, and is a region where light emitted from pixels provided in a pixel portion 294 described later can be seen.

FIG. 46B is a perspective view schematically illustrating the structure on the substrate 291 side. Over the substrate 291, a circuit portion 292, a pixel circuit portion 293 over the circuit portion 292, and the pixel portion 294 over the pixel circuit portion 293 are stacked. In addition, a terminal portion 295 for connection to the FPC 298 is included in a portion over the substrate 291 that does not overlap with the pixel portion 294. The terminal portion 295 and the circuit portion 292 are electrically connected to each other through a wiring portion 296 formed of a plurality of wirings.

The semiconductor device of one embodiment of the present invention can be used for one or both of the circuit portion 292 and the pixel circuit portion 293.

The pixel portion 294 includes a plurality of pixels 294a arranged periodically. An enlarged view of one pixel 294a is illustrated on the right side in FIG. 46B. FIG. 46B illustrates an example where one pixel 294a includes a subpixel 130R emitting red light, a subpixel 130G emitting green light, and a subpixel 130B emitting blue light.

The subpixel includes a display element. Any of a variety of elements can be used as the display element, and a liquid crystal element or a light-emitting element can be used, for example. Alternatively, a micro electro mechanical systems (MEMS) shutter element, an optical interference type MEMS element, or a display element using a microcapsule method, an electrophoretic method, an electrowetting method, an Electronic Liquid Powder (registered trademark) method, or the like can be used. Alternatively, a quantum-dot LED (QLED) employing a light source and color conversion technology using quantum dot materials may be used.

As the light-emitting element, a self-luminous light-emitting element such as a light-emitting diode (LED), an organic LED (OLED), or a semiconductor laser can be used. Examples of the LED include a mini LED and a micro LED.

There is no particular limitation on the arrangement of pixels in the display device of one embodiment of the present invention, and a variety of arrangements can be employed. Examples of the arrangement of pixels include stripe arrangement, S-stripe arrangement, matrix arrangement, delta arrangement, Bayer arrangement, and PenTile arrangement. FIG. 46B illustrates an example where stripe arrangement is employed as the pixel arrangement.

The pixel circuit portion 293 includes a plurality of pixel circuits 293a arranged periodically.

One pixel circuit 293a is a circuit that controls driving of a plurality of elements included in one pixel 294a. One pixel circuit 293a can be provided with three circuits each of which controls light emission of one light-emitting element. For example, the pixel circuit 293a can include at least one selection transistor, one current control transistor (driving transistor), and a capacitor for one light-emitting element. In this case, a gate signal is input to a gate of the selection transistor, and a source signal is input to a source of the selection transistor. With such a structure, an active-matrix display device is achieved.

The circuit portion 292 includes a circuit for driving the pixel circuits 293a in the pixel circuit portion 293. For example, one or both of a gate line driver circuit and a source line driver circuit are preferably included. The circuit portion 292 may also include at least one of an arithmetic circuit, a memory circuit, a power supply circuit, and the like.

The FPC 298 functions as a wiring for supplying a video signal, a power supply potential, or the like to the circuit portion 292 from the outside. An IC may be mounted on the FPC 298.

The display module 170 can have a structure where one or both of the pixel circuit portion 293 and the circuit portion 292 are stacked below the pixel portion 294; thus, the aperture ratio (the effective display area ratio) of the display portion 297 can be significantly high. Furthermore, the pixels 294a can be arranged extremely densely and thus the display portion 297 can have an extremely high resolution.

Such a display module 170 has an extremely high resolution, and thus can be suitably used for a device for VR such as an HMD or a glasses-type device for AR. For example, even in the case of a structure where the display portion of the display module 170 is seen through a lens, pixels of the extremely-high-resolution display portion 297 included in the display module 170 are prevented from being seen when the display portion is enlarged by the lens, so that display providing a high sense of immersion can be performed. Without being limited thereto, the display module 170 can be suitably used for electronic devices including a relatively small display portion. For example, the display module 170 can be favorably used in a display portion of a wearable electronic device, such as a wrist watch.

### [Structure Example 1 of Display Device]

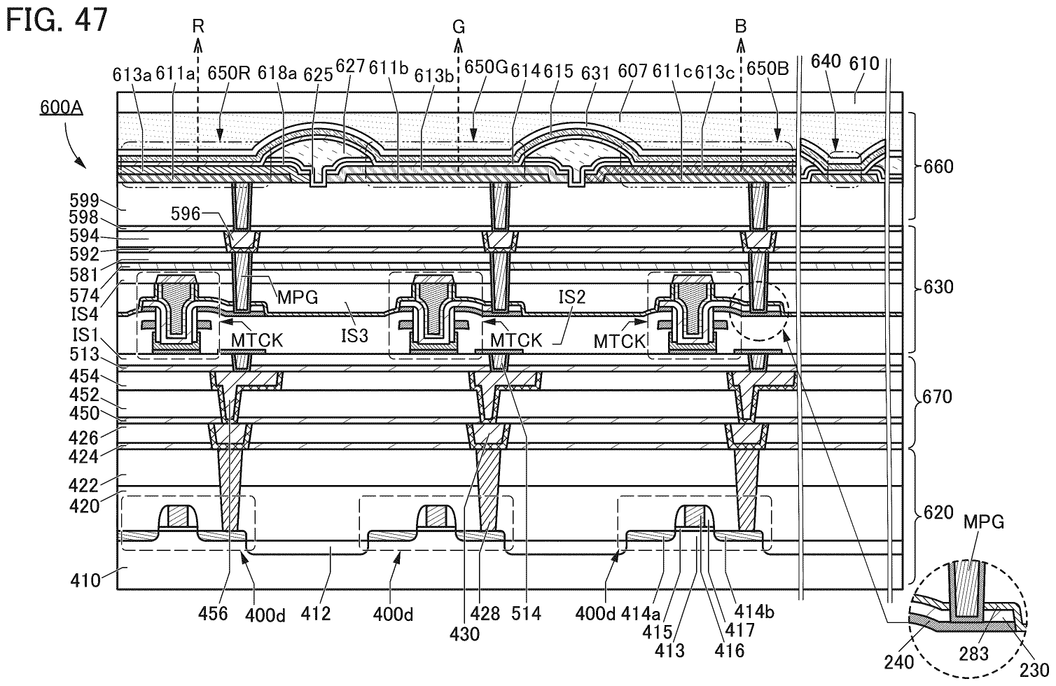

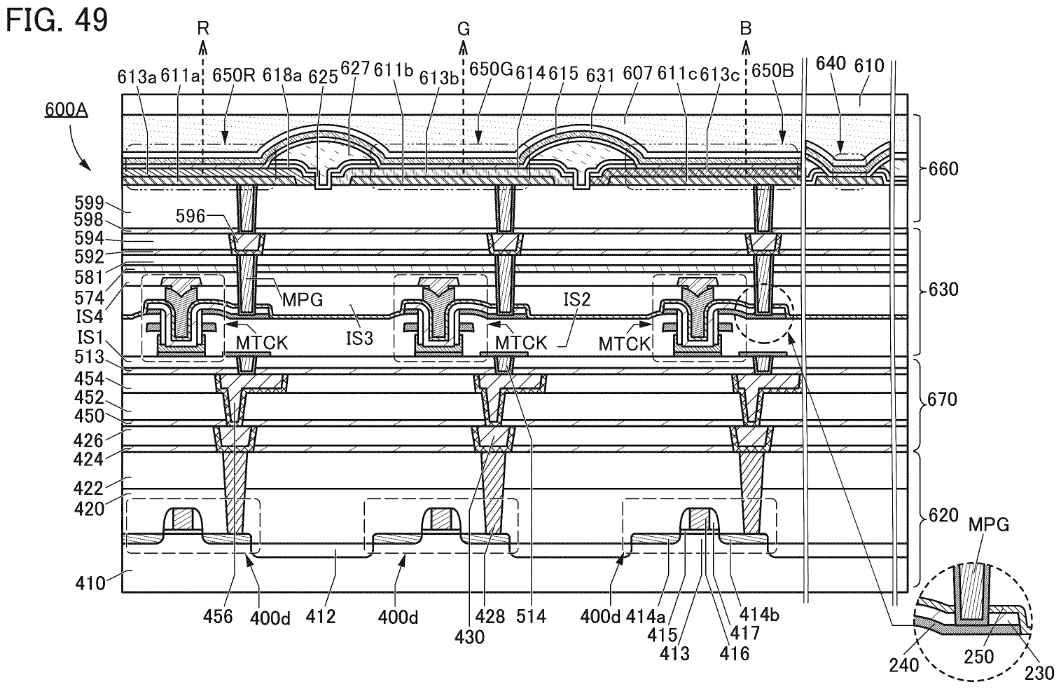

FIGS. 47 and 49 are cross-sectional views of the display device 600A. The display device 600A is an example of a display device having a metal maskless (MML) structure. In other words, the display device 600A includes a light-emitting element that is formed without using a fine metal mask.

An island-shaped light-emitting layer of the light-emitting element included in the display device having the MML structure is formed in such a manner that a light-emitting layer is formed on the entire surface and then the light-emitting layer is processed by a lithography method. Accordingly, a high-resolution display device or a display device with a high aperture ratio, which has been difficult to be formed so far, can be obtained. Moreover, light-emitting layers can be formed separately for the respective colors, enabling the display device to perform extremely clear display with high contrast and high display quality. For example, in the case where the display device includes three kinds of light-emitting elements, which are a light-emitting element emitting blue light, a light-emitting element emitting green light, and a light-emitting element emitting red light, three kinds of island-shaped light-emitting layers can be formed by forming a light-emitting layer and performing processing three times by photolithography.

A device having the MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. Furthermore, for processing by photolithography, an apparatus that is the same as or similar to that used for manufacturing a transistor can be used; thus, there is no need to introduce a special apparatus to manufacture the device having the MML structure. The MML structure can reduce the manufacturing cost as described above, and thus is suitable for mass production of the device.

A display device having the MML structure does not require a pseudo improvement in resolution by employing unique pixel arrangement such as PenTile arrangement; thus, the display device can achieve a high resolution (e.g., higher than or equal to 500 ppi, higher than or equal to 1000 ppi, higher than or equal to 2000 ppi, higher than or equal to 3000 ppi, or higher than or equal to 5000 ppi) while having what is called stripe arrangement where R, G, and B subpixels are arranged in one direction.

Moreover, providing a sacrificial layer over the light-emitting layer can reduce damage to the light-emitting layer in the manufacturing process of the display device, resulting in an increase in reliability of the light-emitting element. Note that the sacrificial layer may remain in the completed display device or may be removed in the manufacturing process. For example, a sacrificial layer 618a illustrated in FIGS. 47 to 50 is part of the sacrificial layer provided over the light-emitting layer.

Employing a film formation step using an area mask and a processing step using a resist mask enables a light-emitting element to be manufactured by a relatively easy process.

FIGS. 47 and 49 are schematic cross-sectional views of the display device 600A that is a display device (a semiconductor device) of one embodiment of the present invention. The display device 600A is provided with a pixel circuit, a driver circuit, and the like over a substrate 410. Note that in the display device 600A in FIGS. 47 and 49, a wiring layer 670 is illustrated in addition to an element layer 620, an element layer 630, and an element layer 660. The wiring layer 670 is a layer provided with a wiring.

A pixel circuit of the display device is preferably provided in the element layer 630. A driver circuit (one or both of a gate driver and a source driver) of the display device is preferably provided in the element layer 620. One or more of a variety of circuits such as an arithmetic circuit and a memory circuit may be provided in the element layer 620.

For example, the element layer 620 includes the substrate 410 on which a transistor 400d is formed. The wiring layer 670 is provided above the transistor 400d, and a wiring for electrically connecting the transistor 400d to a conductive layer, a transistor, or the like provided in the element layer 630 (a conductive layer 514 in FIGS. 47 and 49) is provided in the wiring layer 670. The element layer 630 and the element layer 660 are provided above the wiring layer 670, and the element layer 630 includes a transistor MTCK and the like, for example. FIG. 47 illustrates an example where the transistor 202 is used as the transistor MTCK. FIG. 49 illustrates an example where the transistor 203 is used as the transistor MTCK. The element layer 660 includes a light-emitting element 650 (a light-emitting element 650R, a light-emitting element 650G, and a light-emitting element 650B in FIGS. 47 and 49) and the like.

The transistor 400d is an example of a transistor included in the element layer 620. The transistor MTCK is an example of a transistor included in the element layer 630. The light-emitting element (the light-emitting element 650R, the light-emitting element 650G, and the light-emitting element 650B) is an example of a light-emitting element included in the element layer 660.

As the substrate 410, a semiconductor substrate (e.g., a single crystal substrate formed of silicon or germanium) can be used, for example. Besides such a semiconductor substrate, any of the following can be used as the substrate 410: a silicon on insulator (SOI) substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper or a base film including a fibrous material. In the description of this embodiment, the substrate 410 is a semiconductor substrate containing silicon as a material. Therefore, a transistor included in the element layer 620 can be a Si transistor.

The transistor 400d includes an element isolation layer 412, a conductive layer 416, an insulating layer 415, an insulating layer 417, a semiconductor region 413 that is part of the substrate 410, and low-resistance regions 414a and 414b functioning as source and drain regions. Thus, the transistor 400d is a Si transistor. Although FIGS. 47 and 49 illustrate the structure where one of the source and the drain of the transistor 400d is electrically connected to the conductive layer 514 provided in the element layer 630 through a conductive layer 428, a conductive layer 430, and a conductive layer 456, the electrical connection structure of the display device of one embodiment of the present invention is not limited thereto.

The transistor 400d can have a fin-type structure when, for example, the top surface of the semiconductor region 413 and the side surface thereof in the channel width direction are covered with the conductive layer 416 with the insulating layer 415 as a gate insulating layer therebetween. The effective channel width can be increased in the fin-type transistor 400d, so that the on-state characteristics of the transistor 400d can be improved. In addition, contribution of the electric field of the gate electrode can be increased, so that the off-state characteristics of the transistor 400d can be improved. The transistor 400d may have a planar structure instead of a fin-type structure.

Note that the transistor 400d can be a p-channel transistor or an n-channel transistor. Alternatively, a plurality of transistors 400d including both the p-channel transistor and the n-channel transistor may be used.

A region of the semiconductor region 413 where a channel is formed, a region in the vicinity thereof, and the low-resistance regions 414a and 414b functioning as the source and drain regions preferably include a silicon-based semiconductor, specifically, single crystal silicon. Alternatively, the above-described regions may be formed using germanium, silicon germanium, gallium arsenide, aluminum gallium arsenide, or gallium nitride, for example. Alternatively, the transistor 400d may contain silicon whose effective mass is adjusted by applying stress to the crystal lattice and thereby changing the lattice spacing. Alternatively, the transistor 400d may be a high-electron-mobility transistor (HEMT) containing gallium arsenide and aluminum gallium arsenide, for example.

For the conductive layer 416 functioning as the gate electrode, a semiconductor material such as silicon that contains an element imparting n-type conductivity (e.g., arsenic or phosphorus) or an element imparting p-type conductivity (e.g., boron or aluminum) can be used. For another example, for the conductive layer 416, a conductive material such as a metal material, an alloy material, or a metal oxide material can be used.

Note that a material for a conductive layer determines the work function; thus, selecting the material for the conductive layer can adjust the threshold voltage of a transistor. Specifically, one or both of titanium nitride and tantalum nitride are preferably used for the conductive layer. Furthermore, in order to ensure the conductivity and embeddability of the conductive layer, one or both of tungsten and aluminum are preferably stacked over the conductive layer. In particular, tungsten is preferable in terms of heat resistance.

The element isolation layer 412 is provided to separate a plurality of transistors on the substrate 410 from each other. The element isolation layer can be formed by a local oxidation of silicon (LOCOS) method, a shallow trench isolation (STI) method, or a mesa isolation method.

Over the transistor 400d illustrated in FIGS. 47 and 49, an insulating layer 420 and an insulating layer 422 are stacked in this order from the substrate 410 side.

For the insulating layers 420 and 422, one or more selected from silicon oxide, silicon oxynitride, silicon nitride oxide, silicon nitride, aluminum oxide, aluminum oxynitride, aluminum nitride oxide, and aluminum nitride can be used, for example.

The insulating layer 422 may function as a planarization film for eliminating a level difference caused by the transistor 400d or the like covered with the insulating layers 420 and 422. For example, the top surface of the insulating layer 422 may be planarized by planarization treatment using a CMP method or the like to improve the planarity.

The conductive layer 428 connected to the transistor MTCK and the like provided above the insulating layer 422 is embedded in the insulating layer 420 and the insulating layer 422. Note that the conductive layer 428 has a function of a plug or a wiring.

In the display device 600A, the wiring layer 670 is provided over the transistor 400d. The wiring layer 670 includes, for example, an insulating layer 424, an insulating layer 426, the conductive layer 430, an insulating layer 450, an insulating layer 452, an insulating layer 454, and the conductive layer 456.

For example, over the insulating layers 422 and 428, the insulating layers 424 and 426 are stacked in this order. An opening portion is formed in the insulating layers 424 and 426 in each region overlapping with the conductive layer 428. In addition, the conductive layer 430 is embedded in the opening portion.

The insulating layer 450, the insulating layer 452, and the insulating layer 454 are sequentially stacked over the insulating layer 426 and the conductive layer 430. An opening portion is formed in the insulating layers 450, 452, and 454 in each region overlapping with the conductive layer 430. The conductive layer 456 is embedded in the opening portion.

The conductive layers 430 and 456 each have a function of a plug or a wiring that is connected to the transistor 400d.

Note that for example, the insulating layers 424 and 450 are preferably formed using an insulating layer having a barrier property against at least one of hydrogen, oxygen, and water, like an insulating layer 592 described later. The insulating layers 426, 452, and 454 are preferably formed using an insulating layer having a relatively low dielectric constant to reduce the parasitic capacitance generated between wirings, like an insulating layer 594 described later. The insulating layers 426, 452, and 454 each have functions of an interlayer insulating film and a planarization film.

The conductive layer 456 preferably includes a conductive layer having a barrier property against at least one of hydrogen, oxygen, and water.

Note that as the conductive layer having a barrier property against hydrogen, tantalum nitride is preferably used, for example. By stacking tantalum nitride and tungsten, which has high conductivity, diffusion of hydrogen from the transistor 400d can be inhibited while the conductivity of a wiring is ensured. In this case, a tantalum nitride layer having a barrier property against hydrogen is preferably in contact with the insulating layer 450 having a barrier property against hydrogen.

An insulating layer 513 is provided above the insulating layer 454 and the conductive layer 456. An insulating layer IS1 is provided over the insulating layer 513. A conductive layer functioning as a plug or a wiring is embedded in the insulating layer IS1 and the insulating layer 513. Thus, the transistor 400d can be electrically connected to the conductive layer 514 provided in the element layer 630. Alternatively, a source or a drain of the transistor MTCK and the source or the drain of the transistor 400d may be electrically connected to each other.

The transistor MTCK is provided over the insulating layer IS1. An insulating layer IS4, an insulating layer 574, and an insulating layer 581 are stacked in this order over the transistor MTCK. A conductive layer MPG functioning as a plug or a wiring is embedded in the insulating layer IS3, the insulating layer IS4, the insulating layer 574, and the insulating layer 581. As illustrated in an enlarged view of a region surrounded by a dashed line in FIG. 47, the conductive layer MPG is preferably in direct contact with the conductive layer 240 through an opening portion provided in the insulating layer 283 and the oxide semiconductor layer 230. Similarly, as illustrated in an enlarged view of a region surrounded by a dashed line in FIG. 49, the conductive layer MPG is preferably in direct contact with the conductive layer 240 through an opening portion provided in the insulating layer 250 and the oxide semiconductor layer 230. The direct contact between the conductive layer MPG and the conductive layer 240 is preferable because the contact resistance therebetween can be reduced. Alternatively, the conductive layer MPG and the oxide semiconductor layer 230 may be in contact with each other and the conductive layer MPG and the conductive layer 240 may be electrically connected to each other through the oxide semiconductor layer 230.

The insulating layer 574 preferably has a function of inhibiting diffusion of impurities such as water and hydrogen (e.g., one or both of a hydrogen atom and a hydrogen molecule). In other words, the insulating layer 574 preferably functions as a barrier insulating film that inhibits entry of the impurities into transistor MTCK. The insulating layer 574 also preferably has a function of inhibiting diffusion of oxygen (e.g., one or both of an oxygen atom and an oxygen molecule). For example, the insulating layer 574 preferably has lower oxygen permeability than the insulating layer IS2, the insulating layer IS3, and the insulating layer IS4.

Thus, the insulating layer 574 preferably functions as a barrier insulating film that inhibits diffusion of impurities such as water and hydrogen. Accordingly, the insulating layer 574 is preferably formed using an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, or NO₂), and a copper atom (an insulating material through which the above impurities are less likely to pass). Alternatively, it is preferable to use an insulating material having a function of inhibiting diffusion of oxygen (e.g., one or both of an oxygen atom and an oxygen molecule) (an insulating material through which the above oxygen is less likely to pass).

For the insulating layer having a function of inhibiting passage of oxygen and impurities such as water and hydrogen, it is possible to use any of the materials that can be used for the insulating layer having a function of inhibiting passage of oxygen and impurities described in Embodiment 2.

In particular, aluminum oxide or silicon nitride is preferably used for the insulating layer 574. Accordingly, it is possible to inhibit diffusion of impurities such as water and hydrogen into the transistor MTCK from above the insulating layer 574. Alternatively, oxygen contained in the insulating layer IS3 and the like can be inhibited from diffusing above the insulating layer 574.

The insulating layer 581 is preferably a film functioning as an interlayer film and having a lower permittivity than the insulating layer 574. When a material with a low dielectric constant is used for an interlayer film, the parasitic capacitance generated between wirings can be reduced. For example, the dielectric constant of the insulating layer 581 is preferably lower than 4, further preferably lower than 3. For example, the dielectric constant of the insulating layer 581 is preferably 0.7 times or less that of the insulating layer 574, further preferably 0.6 times or less that of the insulating layer 574. When the insulating layer 581 is formed using a material with a low dielectric constant, the parasitic capacitance generated between wirings can be reduced.

The concentration of impurities such as water and hydrogen in the insulating layer 581 is preferably reduced. In that case, materials such as silicon oxide, silicon oxynitride, silicon nitride oxide, or silicon nitride can be used for the insulating layer 581. For example, silicon oxide to which fluorine is added, silicon oxide to which carbon is added, silicon oxide to which carbon and nitrogen are added, or porous silicon oxide can be used for the insulating layer 581. In particular, silicon oxide and silicon oxynitride are preferable because they are thermally stable. In particular, materials such as silicon oxide, silicon oxynitride, and porous silicon oxide are preferably used, in which case a region containing oxygen released by heating can be easily formed. Moreover, the insulating layer 581 can be formed using a resin. A material combined with any of the above materials as appropriate may be used for the insulating layer 581.

The insulating layer 592 and the insulating layer 594 are stacked in this order over the insulating layer 574 and the insulating layer 581.

For the insulating layer 592, it is preferable to use a barrier insulating layer which prevents diffusion of impurities such as water and hydrogen from the substrate 410 and the transistor MTCK into a region above the insulating layer 592 (e.g., the region including the light-emitting elements 650R, 650G, and 650B, and the like). Accordingly, the insulating layer 592 is preferably formed using an insulating material having a function of inhibiting diffusion of impurities such as a hydrogen atom, a hydrogen molecule, and a water molecule (an insulating material through which the above impurities are less likely to pass). Alternatively, depending on circumstances, the insulating layer 592 is preferably formed using an insulating material having a function of inhibiting diffusion of impurities such as a nitrogen atom, a nitrogen molecule, a nitrogen oxide molecule (e.g., N₂O, NO, or NO₂), and a copper atom (an insulating material through which the above impurities are less likely to pass). The insulating layer 592 preferably has a function of inhibiting diffusion of oxygen (e.g., at least one of an oxygen atom and an oxygen molecule).

For the film having a barrier property against hydrogen, for example, silicon nitride deposited by a CVD method can be used.

Like the insulating layer 581, the insulating layer 594 is preferably an interlayer film with a low permittivity. Thus, the insulating layer 594 can be formed using any of the materials that can be used for the insulating layer 581.

Note that the insulating layer 594 preferably has a lower permittivity than the insulating layer 592. For example, the dielectric constant of the insulating layer 594 is preferably lower than 4, further preferably lower than 3. For example, the dielectric constant of the insulating layer 594 is preferably 0.7 times or less that of the insulating layer 592, further preferably 0.6 times or less that of the insulating layer 592. When the insulating layer 594 is formed using a material with a low dielectric constant, the parasitic capacitance generated between wirings can be reduced.

The conductive layer MPG functioning as a plug or a wiring is embedded in the insulating layer IS3, the insulating layer IS4, the insulating layer 574, and the insulating layer 581, and a conductive layer 596 functioning as a plug or a wiring is embedded in the insulating layer 592 and the insulating layer 594. In particular, the conductive layer MPG and the conductive layer 596 are electrically connected to the light-emitting element or the like provided above the insulating layer 594. A plurality of conductive layers functioning as plugs or wirings are collectively denoted by the same reference numeral in some cases. In this specification and the like, a wiring and a plug connected to the wiring may be a single component. That is, in some cases, part of a conductive layer functions as a wiring or part of a conductive layer functions as a plug.

As a material for each of plugs and wirings (the conductors MPG, 428, 430, 456, 514, and 596), one or more conductive materials selected from a metal material, an alloy material, a metal nitride material, and a metal oxide material can be used in a single-layer structure or a stacked-layer structure. It is preferable to use a high-melting-point material that has both heat resistance and conductivity, such as tungsten or molybdenum, and it is particularly preferable to use tungsten. A low-resistance conductive material such as aluminum or copper is preferably used. The use of a low-resistance conductive material can reduce wiring resistance.

An insulating layer 598 and an insulating layer 599 are sequentially formed over the insulating layer 594 and the conductive layer 596.

For example, the insulating layer 598 is preferably formed using an insulating layer having a barrier property against one or more of hydrogen, oxygen, and water, like the insulating layer 592. The insulating layer 599 is preferably formed using an insulating layer having a relatively low dielectric constant to reduce the parasitic capacitance generated between wirings, like the insulating layer 594. The insulating layer 599 has functions of an interlayer insulating film and a planarization film.

The light-emitting element 650 and a connection portion 640 are formed over the insulating layer 599.

The connection portion 640 is referred to as a cathode contact portion in some cases, and is electrically connected to cathodes of the light-emitting element 650R, the light-emitting element 650G, and the light-emitting element 650B. In the connection portion 640 illustrated in FIGS. 47 and 49, a conductive layer formed using the same material in the same step as a conductive layer 611a to a conductive layer 611c is electrically connected to a common electrode 615 described later. Although FIGS. 47 and 49 each illustrate an example where the conductive layer is electrically connected to the common electrode 615 through a common layer 614 described later, the conductive layer and the common electrode 615 may be in direct contact with each other.

Note that the connection portion 640 may be provided to surround four sides of the display portion in a plan view or may be provided in the display portion (e.g., between adjacent light-emitting elements 650) (not illustrated).

The light-emitting element 650R includes the conductive layer 611a as a pixel electrode. Similarly, the light-emitting element 650G includes the conductive layer 611b as a pixel electrode, and the light-emitting element 650B includes the conductive layer 611c as a pixel electrode.

The conductive layer 611a, the conductive layer 611b, and the conductive layer 611c are connected to the conductive layer 596 embedded in the insulating layer 594 through a conductive layer (plug) embedded in the insulating layer 599.

The light-emitting element 650R includes a layer 613a, the common layer 614 over the layer 613a, and the common electrode 615 over the common layer 614. The light-emitting element 650G includes a layer 613b, the common layer 614 over the layer 613b, and the common electrode 615 over the common layer 614. The light-emitting element 650B includes a layer 613c, the common layer 614 over the layer 613c, and the common electrode 615 over the common layer 614.

For the pair of electrodes (the pixel electrode and the common electrode) of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include an indium tin oxide (also referred to as In—Sn oxide or ITO), an In—Si—Sn oxide (also referred to as ITSO), an indium zinc oxide (In—Zn oxide), and an In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The display device 600A employs an SBS structure. The SBS structure can optimize materials and structures of light-emitting elements and thus can extend freedom of choice of materials and structures, whereby the luminance and the reliability can be easily improved.

The display device 600A has a top-emission structure. The aperture ratio of pixels in a top-emission structure can be higher than that of pixels in a bottom-emission structure because a transistor and the like can be provided to overlap with a light-emitting region of a light-emitting element in the top-emission structure.

Note that the layer 613a is formed to cover the top and side surfaces of the conductive layer 611a. Similarly, the layer 613b is formed to cover the top and side surfaces of the conductive layer 611b. Similarly, the layer 613c is formed to cover the top and side surfaces of the conductive layer 611c. Accordingly, regions provided with the conductive layers 611a, 611b, and 611c can be entirely used as the light-emitting regions of the light-emitting elements 650R, 650G, and 650B, thereby increasing the aperture ratio of the pixels.

In the light-emitting element 650R, the layer 613a and the common layer 614 can be collectively referred to as an EL layer. Similarly, in the light-emitting element 650G, the layer 613b and the common layer 614 can be collectively referred to as an EL layer. Similarly, in the light-emitting element 650B, the layer 613c and the common layer 614 can be collectively referred to as an EL layer.

The EL layer includes at least a light-emitting layer. The light-emitting layer contains one or more kinds of light-emitting substances. As the light-emitting substance, a substance emitting light of blue, violet, bluish violet, green, yellowish green, yellow, orange, red, or the like is appropriately used. Alternatively, as the light-emitting substance, a substance emitting near-infrared light can be used.

Examples of a light-emitting substance contained in the light-emitting element include a substance exhibiting fluorescence (a fluorescent material), a substance exhibiting phosphorescence (a phosphorescent material), a substance exhibiting thermally activated delayed fluorescence (a thermally activated delayed fluorescent (TADF) material), and an inorganic compound (e.g., a quantum dot material).

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further contain one or both of a bipolar substance and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when a voltage is applied between the pair of electrodes. The tandem structure enables a light-emitting element capable of high-luminance light emission. Furthermore, the amount of current needed for obtaining a predetermined luminance can be smaller in the tandem structure than in the single structure; thus, the tandem structure enables higher reliability. The tandem structure can also be referred to as a stack structure.

When the light-emitting element has a microcavity structure, higher color purity can be achieved.

The layers 613a, 613b, and 613c are each processed into an island shape by a photolithography method. At each of end portions of the layers 613a, 613b, and 613c, an angle between the top surface and the side surface is approximately 90°. By contrast, for example, an organic film formed using a fine metal mask (FMM) tends to have a thickness that gradually decreases with decreasing distance to an end portion, and has the top surface forming a slope in an area extending greater than or equal to 1 μm and less than or equal to 10 μm from the end portion, for example; thus, such an organic film has a shape whose top surface and side surface cannot be easily distinguished from each other.

The top and side surfaces of each of the layers 613a, 613b, and 613c are clearly distinguished from each other. Accordingly, as for the layers 613a and 613b which are adjacent to each other, one of the side surfaces of the layer 613a and one of the side surfaces of the layer 613b face each other. This applies to a combination of any two of the layers 613a, 613b, and 613c.

The layers 613a, 613b, and 613c each include at least a light-emitting layer. Preferably, the layer 613a, the layer 613b, and the layer 613c include a red-light-emitting layer, a green-light-emitting layer, and a blue-light-emitting layer, respectively, for example. Other than the above colors, cyan, magenta, yellow, or white can be employed as colors of light emitted from the light-emitting layers.

The layers 613a, 613b, and 613c each preferably include a light-emitting layer and a carrier-transport layer (an electron-transport layer or a hole-transport layer) over the light-emitting layer. Since the surfaces of the layers 613a, 613b, and 613c are exposed in the manufacturing process of the display device in some cases, providing the carrier-transport layer over the light-emitting layer inhibits the light-emitting layer from being exposed on the outermost surface, so that damage to the light-emitting layer can be reduced. Thus, the reliability of the light-emitting element can be increased.

The common layer 614 includes, for example, an electron-injection layer or a hole-injection layer. Alternatively, the common layer 614 may be a stack of an electron-transport layer and an electron-injection layer, or may be a stack of a hole-transport layer and a hole-injection layer. The common layer 614 is shared by the light-emitting elements 650R, 650G, and 650B. Note that the common layer 614 is not necessarily provided, and the whole EL layer included in the light-emitting element may be provided in an island shape like the layer 613a, the layer 613b, and the layer 613c.

The common electrode 615 is shared by the light-emitting element 650R, the light-emitting element 650G, and the light-emitting element 650B. As illustrated in FIGS. 47 and 49, the common electrode 615 shared by the plurality of light-emitting elements is electrically connected to the conductive layer included in the connection portion 640.

An insulating layer 625 preferably has a function of a barrier insulating layer against at least one of water and oxygen. Alternatively, the insulating layer 625 preferably has a function of inhibiting diffusion of at least one of water and oxygen. Alternatively, the insulating layer 625 preferably has a function of capturing or fixing (also referred to as gettering) at least one of water and oxygen. When the insulating layer 625 has at least one of these functions, entry of impurities (typically, one or both of water and oxygen) that would diffuse into the light-emitting elements from the outside can be inhibited. With this structure, a highly reliable light-emitting element and a highly reliable display device can be provided.

As the insulating layer 625, the above-described barrier insulating layer against oxygen can be used, and aluminum oxide or silicon nitride is preferably used.

The insulating layer 625 preferably has a low impurity concentration. Accordingly, degradation of the EL layer, which is caused by entry of impurities into the EL layer from the insulating layer 625, can be inhibited. In addition, when the impurity concentration is reduced in the insulating layer 625, a barrier property against at least one of water and oxygen can be increased. For example, the insulating layer 625 preferably has a sufficiently low hydrogen concentration or a sufficiently low carbon concentration, and further preferably has both a sufficiently low hydrogen concentration and a sufficiently low carbon concentration.

As an insulating layer 627, an insulating layer containing an organic material can be favorably used. As the organic material, a photosensitive organic resin is preferably used, and for example, a photosensitive resin composite containing an acrylic resin can be used. Note that in this specification and the like, an acrylic resin refers to not only a polymethacrylic acid ester or a methacrylic resin, but also all the acrylic polymer in a broad sense in some cases.

An organic material that can be used for the insulating layer 627 is not limited to the above. For example, for the insulating layer 627, an acrylic resin, a polyimide resin, an epoxy resin, a polyamide resin, a polyimide-amide resin, a silicone resin, a siloxane resin, a benzocyclobutene-based resin, a phenol resin, or precursors of these resins can be used in some cases. An organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be used for the insulating layer 627 in some cases. A photoresist, which is a photosensitive resin, can be used for the insulating layer 627 in some cases. Examples of the photosensitive resin include positive-type materials and negative-type materials.

The insulating layer 627 may be formed using a material absorbing visible light. When the insulating layer 627 absorbs light emitted from the light-emitting element, light leakage (stray light) from the light-emitting element to an adjacent light-emitting element through the insulating layer 627 can be suppressed. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two or three or more colors is particularly preferable to enhance the effect of blocking visible light. In particular, mixing color filter materials of three or more colors enables the formation of a black or nearly black resin layer.

For example, the insulating layer 627 can be formed by a wet process such as spin coating, dipping, spray coating, ink-jetting, dispensing, screen printing, offset printing, doctor blade coating, slit coating, roll coating, curtain coating, or knife coating. Specifically, an organic insulating film that is to be the insulating layer 627 is preferably formed by spin coating.

The insulating layer 627 is formed at a temperature lower than the upper temperature limit of the EL layer. The typical substrate temperature in formation of layer 627 is higher than or equal to room temperature and lower than or equal to 200° C., preferably lower than or equal to 180° C., further preferably lower than or equal to 160° C., still further preferably lower than or equal to 150° C., yet still further preferably lower than or equal to 140° C.

Note that the side surface of the insulating layer 627 preferably has a tapered shape. When the end portion of the side surface of the insulating layer 627 has a forward tapered shape (with an angle less than 90°, preferably less than or equal to 60°, further preferably less than or equal to) 45°, the common layer 614 and the common electrode 615 that are provided over the end portion of the side surface of the insulating layer 627 can be formed with good coverage without disconnection, local thinning, or the like. Consequently, the in-plane uniformity of the common layer 614 and the common electrode 615 can be increased, so that the display quality of the display device can be improved.

In a cross-sectional view of the display device, the top surface of the insulating layer 627 preferably has a convex shape. The convex top surface of the insulating layer 627 preferably has a shape that expands gradually toward the center. When the insulating layer 627 has such a shape, the common layer 614 and the common electrode 615 can be formed with good coverage over the whole insulating layer 627.

The insulating layer 627 is formed in a region between two EL layers (e.g., a region between the layer 613a and the layer 613b). In that case, part of the insulating layer 627 is positioned between the side end portion of one of the two EL layers (e.g., the layer 613a) and the side end portion of the other of the two EL layers (e.g., the layer 613b).

One end portion of the insulating layer 627 preferably overlaps with the conductive layer 611a functioning as a pixel electrode, and the other end portion of the insulating layer 627 preferably overlaps with the conductive layer 611b functioning as a pixel electrode. Such a structure enables the end portion of the insulating layer 627 to be formed over a flat or substantially flat region of the layer 613a (the layer 613b). This makes it relatively easy to process the insulating layer 627 to have a tapered shape as described above.

By providing the insulating layer 627 and the like in the above manner, a disconnected portion and a locally thinned portion can be prevented from being formed in the common layer 614 and the common electrode 615 from a flat or substantially flat region of the layer 613a to a flat or substantially flat region of the layer 613b. Thus, a connection defect due to a disconnected portion and an increase in electric resistance due to a locally thinned portion can be inhibited from occurring in the common layer 614 and the common electrode 615 between the light-emitting elements.

In the display device of this embodiment, the distance between the light-emitting elements can be short. Specifically, the distance between the light-emitting elements, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display device in this embodiment includes a region where a distance between two adjacent island-shaped EL layers is less than or equal to 1 μm, preferably less than or equal to 0.5 μm (500 nm), further preferably less than or equal to 100 nm. Shortening the distance between the light-emitting elements in this manner enables a display device with a high resolution and a high aperture ratio to be provided.

A protective layer 631 is provided over the light-emitting element 650. The protective layer 631 functions as a passivation film for protecting the light-emitting element 650. Providing the protective layer 631 that covers the light-emitting element can prevent entry of impurities such as water and oxygen into the light-emitting element and increase the reliability of the light-emitting element 650. The protective layer 631 preferably has, for example, a single-layer structure or a stacked-layer structure at least including an inorganic insulating film. Examples of the inorganic insulating film include an oxide film or a nitride film such as a silicon oxide film, a silicon oxynitride film, a silicon nitride oxide film, a silicon nitride film, an aluminum oxide film, an aluminum oxynitride film, or a hafnium oxide film. Alternatively, a semiconductor material such as an indium gallium oxide or an indium gallium zinc oxide (IGZO) may be used for the protective layer 631. The protective layer 631 can be formed by an ALD method, a CVD method, a sputtering method, or the like. Although the protective layer 631 includes an inorganic insulating film in this example, the present invention is not limited thereto. For example, the protective layer 631 may have a stacked-layer structure of an inorganic insulating film and an organic insulating film.

The protective layer 631 and the substrate 610 are bonded to each other with an adhesive layer 607. A solid sealing structure, a hollow sealing structure, or the like can be employed to seal the light-emitting elements. In FIGS. 47 and 49, a solid sealing structure is employed, in which a space between the substrate 410 and the substrate 610 is filled with the adhesive layer 607. Alternatively, a hollow sealing structure may be employed, in which the space is filled with an inert gas (e.g., nitrogen or argon). In that case, the adhesive layer 607 may be provided not to overlap with the light-emitting element. Alternatively, the space may be filled with a resin other than the frame-like adhesive layer 607.

As the adhesive layer 607, any of a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, a polyvinyl chloride (PVC) resin, a polyvinyl butyral (PVB) resin, and an ethylene-vinyl acetate (EVA) resin. In particular, a material with low moisture permeability, such as an epoxy resin, is preferable. A two-component-mixture-type resin may be used. An adhesive sheet may be used.

The display device 600A is a top-emission display device. Light from the light-emitting element is emitted to the substrate 610 side. For this reason, a material having a high visible-light-transmitting property is preferably used for the substrate 610. For example, a substrate having a high visible-light-transmitting property can be selected as the substrate 610 among substrates usable as the substrate 410. The pixel electrode contains a material reflecting visible light, and the counter electrode (the common electrode 615) contains a material transmitting visible light.

Note that the display device of one embodiment of the present invention may be not a top-emission display device but a bottom-emission display device where light from the light-emitting element is emitted to the substrate 410 side. In that case, a substrate having a high visible-light-transmitting property is selected as the substrate 410.

### [Structure Example 2 of Display Device]

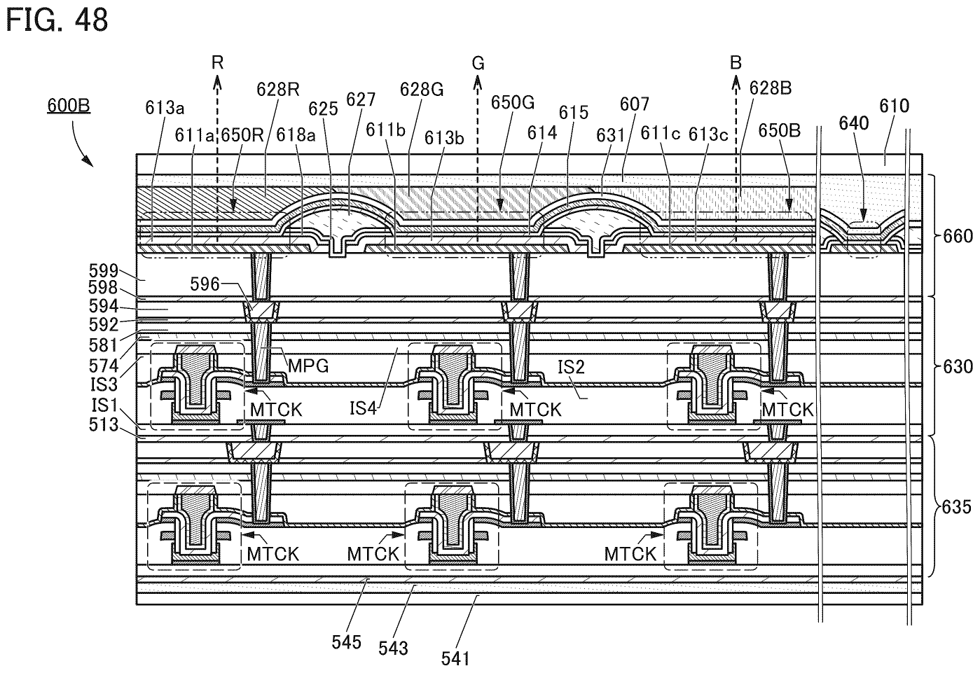

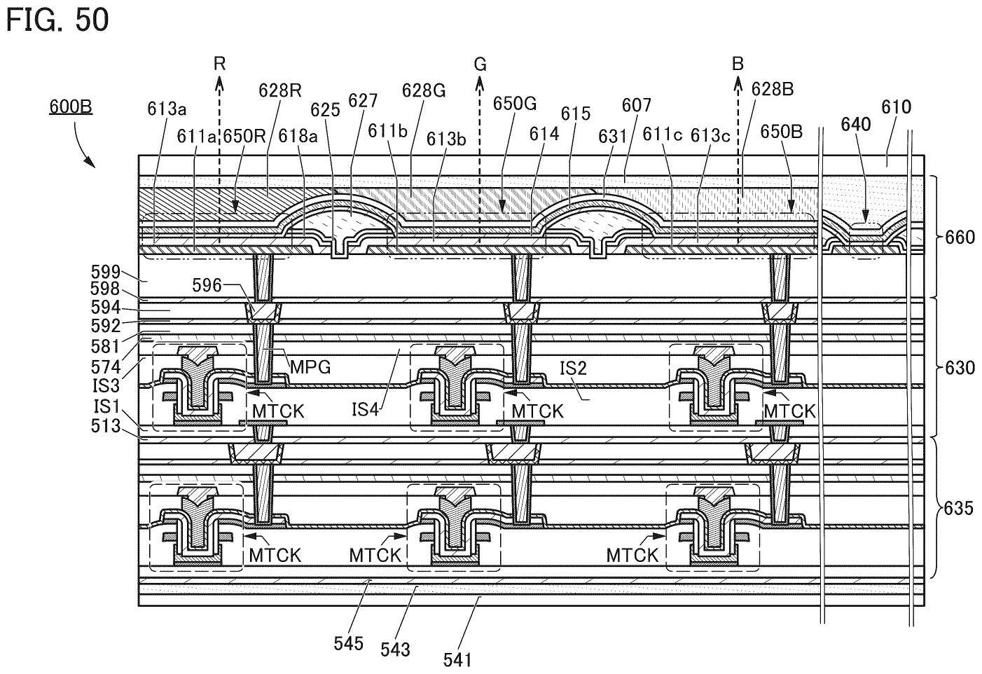

FIGS. 48 and 50 are cross-sectional views of the display device 600B.

The display device 600B can be a flexible display device when a flexible substrate is used as each of a substrate 541 and the substrate 610. The substrate 541 is bonded to an insulating layer 545 with an adhesive layer 543. The substrate 610 is bonded to the protective layer 631 with the adhesive layer 607.

The element layer 660 of the display device 600B is different from the element layer 660 of the display device 600A mainly in that the layer 613a, the layer 613b, and the layer 613c have the same structure and that a coloring layer 628R, a coloring layer 628G, and a coloring layer 628B are provided.

The layer 613a, the layer 613b, and the layer 613c are formed using the same material in the same step. The layer 613a, the layer 613b, and the layer 613c are isolated from each other. When the EL layer is provided in an island shape for each light-emitting element, a leakage current between adjacent light-emitting elements (sometimes referred to as horizontal-direction leakage current, horizontal leakage current, or lateral leakage current) can be inhibited. Accordingly, unintentional light emission due to crosstalk can be prevented, and color mixture between adjacent light-emitting elements can be inhibited, so that a display device with extremely high contrast can be obtained.

The light-emitting elements 650R, 650G, and 650B illustrated in FIGS. 48 and 50 emit white light, for example. White light emitted from the light-emitting elements 650R, 650G, and 650B passes through the coloring layers 628R, 628G, and 628B, whereby light of a desired color can be obtained.

In the case where the light-emitting element configured to emit white light has a microcavity structure, light with a specific wavelength (e.g., red, green, or blue) is sometimes intensified and emitted.

Light emitted from the light-emitting element 650R is extracted as red light to the outside of the display device 600B through the coloring layer 628R. Similarly, light emitted from the light-emitting element 650G is extracted as green light to the outside of the display device 600B through the coloring layer 628G. Light emitted from the light-emitting element 650B is extracted as blue light to the outside of the display device 600B through the coloring layer 628B.

A light-emitting element emitting white light preferably has a tandem structure.

Alternatively, the light-emitting elements 650R, 650G, and 650B illustrated in FIGS. 48 and 50 emit blue light, for example. In this case, the layers 613a, 613b, and 613c each include one or more light-emitting layers emitting blue light. In a subpixel emitting blue light, blue light emitted from the light-emitting element 650B can be extracted as it is. In each of the subpixel emitting red light and the subpixel emitting green light, a color conversion layer is provided between the light-emitting element 650R and the coloring layer 628R and between the light-emitting element 650G and the coloring layer 628G, so that blue light emitted from the light-emitting element 650R or 650G is converted into light with a longer wavelength, whereby red light or green light can be extracted. When light passing through the color conversion layer is extracted through the coloring layer, light other than light of a desired color can be absorbed by the coloring layer, and color purity of light emitted from a subpixel can be improved.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. Each coloring layer can be formed using one or more of a metal material, a resin material, a pigment, and a dye. Each coloring layer is formed in a desired position by a printing method, an ink-jet method, an etching method using a photolithography method, or the like.

The element layer 630 of the display device 600B has a structure similar to that of the element layer 630 of the display device 600A; thus, the detailed description thereof is omitted.

The display device 600B is different from the display device 600A in not including the element layer 620 but including an element layer 635. The element layer 635 has a structure similar to that of the element layer 630. FIG. 48 illustrates an example where the transistor 202 is used as the transistor MTCK included in the element layers 630 and 635. FIG. 50 illustrates an example where the transistor 203 is used as the transistor MTCK included in the element layers 630 and 635.

At least part of the transistor included in the element layer 635 is electrically connected to a conductive layer or a transistor included in the element layer 630 through a plug, a wiring, and the like. Note that the wiring layer 670 may be provided between the element layer 630 and the element layer 635.

One or both of a pixel circuit and a driver circuit of the display device are preferably provided in the element layer 635.

Although FIGS. 48 and 50 each illustrate an example where two element layers (the element layer 630 and the element layer 635) including OS transistors are stacked, the number of stacked element layers is not limited thereto, and three or more layers may be stacked. For example, in the case where three or more element layers including OS transistors are stacked, it is preferable that the lowermost layer be used for the driver circuit (one or both of the gate driver and the source driver) of the display device, the uppermost layer be used for the pixel circuit of the display device, and one or more layers between them be used for the pixel circuit or the driver circuit.

A Si transistor is typically formed on a single crystal Si wafer, and thus is difficult to have flexibility. Meanwhile, as illustrated in FIGS. 48 and 50, in the case where the display device is formed using only OS transistors without using a Si transistor, the display device can have flexibility through a relatively simple manufacturing process.

### [Structure Example of Light-Emitting Element]

Next, light-emitting elements that can be used for the display device of one embodiment of the present invention are described. Structure examples of a light-emitting element, which are different from the structures illustrated in FIGS. 47 to 50, are mainly described below.

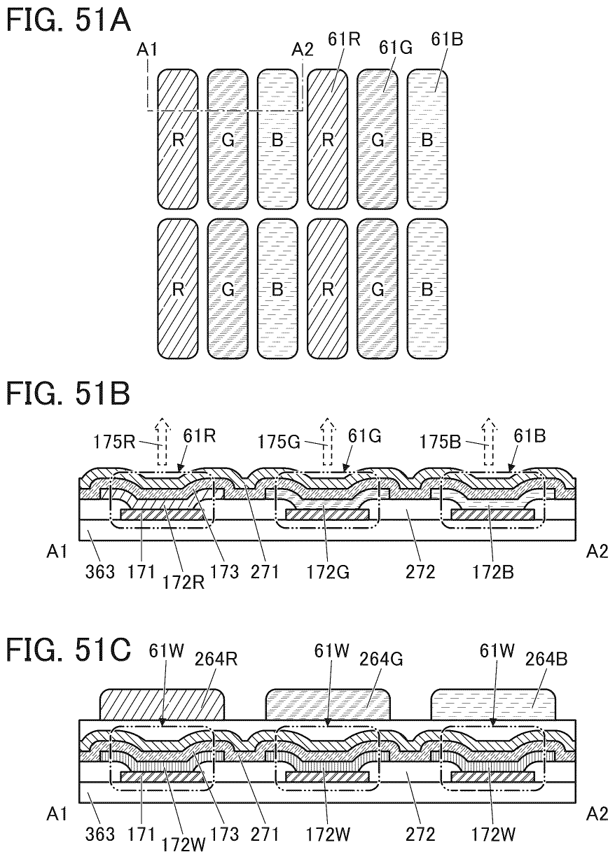

FIG. 51A is a schematic top view of part of a display portion including a plurality of light-emitting elements. The display portion includes a plurality of light-emitting elements 61R emitting red light, a plurality of light-emitting elements 61G emitting green light, and a plurality of light-emitting elements 61B emitting blue light. In FIG. 51A, light-emitting regions of the light-emitting elements are denoted by R, G, and B to easily differentiate the light-emitting elements. Although the structure illustrated in FIG. 51A has three emission colors of red (R), green (G), and blue (B), one embodiment of the present invention is not limited thereto. For example, the structure may have four or more colors.

FIG. 51B is a cross-sectional view taken along dashed-dotted line A1-A2 in FIG. 51A. The light-emitting elements 61R, 61G, and 61B illustrated in FIG. 51B are provided over an insulating layer 363, and include a conductive layer 171 functioning as a pixel electrode and a conductive layer 173 functioning as a common electrode. For the insulating layer 363, one or both of an inorganic insulating film and an organic insulating film can be used.

The light-emitting element 61R includes an EL layer 172R between the conductive layer 171 functioning as a pixel electrode and the conductive layer 173 functions as a common electrode. The EL layer 172R contains a light-emitting compound that emits light having a peak in a red wavelength range. An EL layer 172G included in the light-emitting element 61G contains a light-emitting compound that emits light having a peak in a green wavelength range. An EL layer 172B included in the light-emitting element 61B contains a light-emitting compound that emits light having a peak in a blue wavelength range.

The conductive layer 171 functioning as a pixel electrode is provided for each light-emitting element. The conductive layer 173 functioning as a common electrode is provided as a continuous layer shared by the light-emitting elements. A conductive film having a visible-light-transmitting property is used for either the conductive layer 171 functioning as a pixel electrode or the conductive layer 173 functioning as a common electrode, and a reflective conductive film is used for the other.

For example, in the case where the light-emitting element 61R has a top-emission structure, light 175R is emitted from the light-emitting element 61R to the conductive layer 173 side. In the case where the light-emitting element 61G has a top-emission structure, light 175G is emitted from the light-emitting element 61G to the conductive layer 173 side. In the case where the light-emitting element 61B has a top-emission structure, light 175B is emitted from the light-emitting element 61B to the conductive layer 173 side.

An insulating layer 272 is provided to cover an end portion of the conductive layer 171 functioning as a pixel electrode. An end portion of the insulating layer 272 is preferably tapered. For the insulating layer 272, one or both of an inorganic insulating film and an organic insulating film can be used.

The insulating layer 272 is provided to prevent an unintentional electric short-circuit between adjacent light-emitting elements and unintended light emission therefrom. The insulating layer 272 also has a function of preventing the contact of a metal mask with the conductive layer 171 in the case where the metal mask is used to form the EL layer.

The EL layers 172R, 172G, and 172B each include a region in contact with the top surface of the conductive layer 171 functioning as a pixel electrode and a region in contact with a surface of the insulating layer 272. End portions of the EL layers 172R, 172G, and 172B are positioned over the insulating layer 272.

As illustrated in FIG. 51B, there is a gap between the EL layers of two light-emitting elements with different emission colors. The EL layers 172R, 172G, and 172B are thus preferably provided not to be in contact with each other. This suitably prevents unintentional light emission (also referred to as crosstalk) from being caused by a current flowing through two adjacent EL layers. As a result, the contrast can be increased to achieve a display device with high display quality.

The EL layers 172R, 172G, and 172B can be formed separately by a vacuum evaporation method or the like using a shadow mask such as a metal mask. These layers may be formed separately by a photolithography method. The photolithography method achieves a display device with a high resolution, which is difficult to obtain in the case of using a metal mask.

A protective layer 271 is provided over the conductive layer 173 functioning as a common electrode to cover the light-emitting elements 61R, 61G, and 61B. The protective layer 271 has a function of preventing diffusion of impurities such as water into each light-emitting element from the above. For the material of the protective layer 271, the above-described material of the protective layer 631 can be referred to.

FIG. 51C illustrates a light-emitting element 61W emitting white light. The light-emitting element 61W includes an EL layer 172W emitting white light between the conductive layer 171 functioning as a pixel electrode and the conductive layer 173 functioning as a common electrode.

The EL layer 172W can have, for example, a stacked structure of two or more light-emitting layers that are selected so as to emit light of complementary colors. It is also possible to use a tandem EL layer in which a charge-generation layer is provided between light-emitting layers.

FIG. 51C illustrates three light-emitting elements 61W side by side. A coloring layer 264R is provided above the left light-emitting element 61W. The coloring layer 264R functions as a band path filter transmitting red light. Similarly, a coloring layer 264G transmitting green light is provided above the middle light-emitting element 61W, and a coloring layer 264B transmitting blue light is provided above the right light-emitting element 61W. This enables the display device to display a color image.

Here, the EL layer 172W is separated between two adjacent light-emitting elements 61W. This suitably prevents unintentional light emission from being caused by a current flowing through the EL layers 172W in the two adjacent light-emitting elements 61W. Particularly when the EL layer 172W is a stacked EL layer in which a charge-generation layer is provided between two light-emitting layers, the effect of crosstalk is more significant as the resolution increases, i.e., as the distance between adjacent pixels decreases, leading to lower contrast. Thus, the above structure can achieve a display device having both a high resolution and high contrast.

The EL layers 172W are preferably separated by a photolithography method. This can reduce the distance between light-emitting elements, achieving a display device with a higher aperture ratio than that formed using, for example, a shadow mask such as a metal mask.

This embodiment can be combined with any of the other embodiments as appropriate.

### Embodiment 8

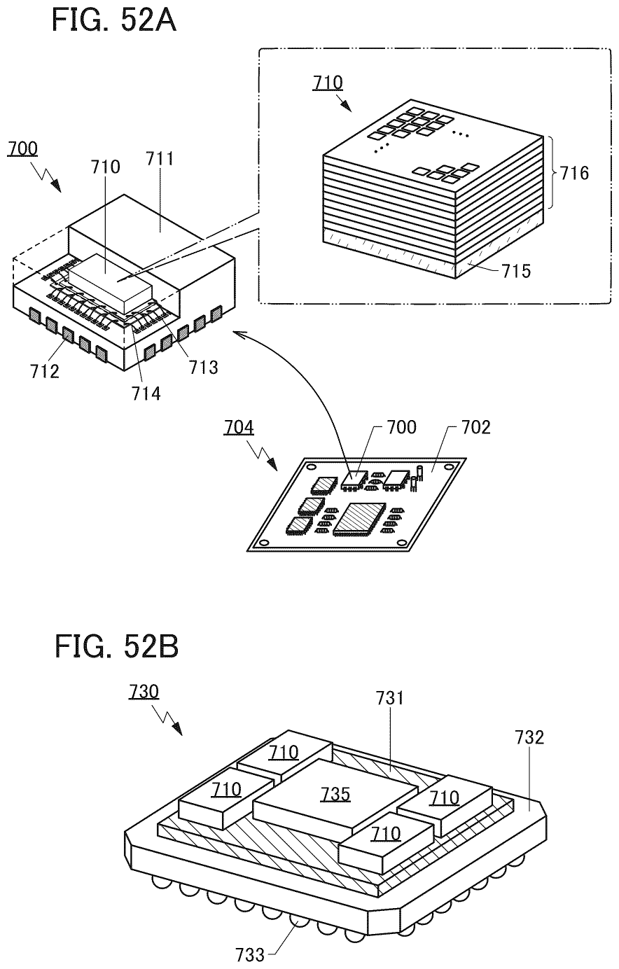

In this embodiment, application examples of the semiconductor device of one embodiment of the present invention are described with reference to FIGS. 52A and 52B, FIGS. 53A to 53E, FIGS. 54A to 54F, FIGS. 55A to 55G, and FIGS. 56A to 56F.

The semiconductor device of one embodiment of the present invention can be used for an electronic component, a large computer, a device for space, a data center (also referred to as DC), and a variety of electronic devices, for example. With the use of the semiconductor device of one embodiment of the present invention, an electronic component, a large computer, a device for space, a data center, and a variety of electronic devices can have lower power consumption and higher performance.

A display device including the semiconductor device of one embodiment of the present invention can be used for a display portion of any of a variety of electronic devices. The display device including the semiconductor device of one embodiment of the present invention can be easily increased in resolution and definition.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have a high resolution, and thus can be favorably used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display device having one or both of such a high definition and a high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

FIG. 52A is a perspective view of a substrate (a circuit board 704) provided with an electronic component 700. The electronic component 700 illustrated in FIG. 52A includes a semiconductor device 710 in a mold 711. FIG. 52A omits some components to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure where a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) technique and a bonding technique such as Cu-to-Cu direct bonding. The monolithic stacked-layer structure of the driver circuit layer 715 and the memory layer 716 enables, for example, what is called an on-chip memory structure where a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form as compared with the case where the memory layer 716 is formed with OS transistors. Therefore, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 52B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The electronic component 730 using the semiconductor device 710 as a high bandwidth memory (HBM) is illustrated as an example. The semiconductor device 735 can be used for an integrated circuit such as a CPU, a GPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are electrically connected with use of a silicon interposer, a TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 52B illustrates an example where the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Large Computer]

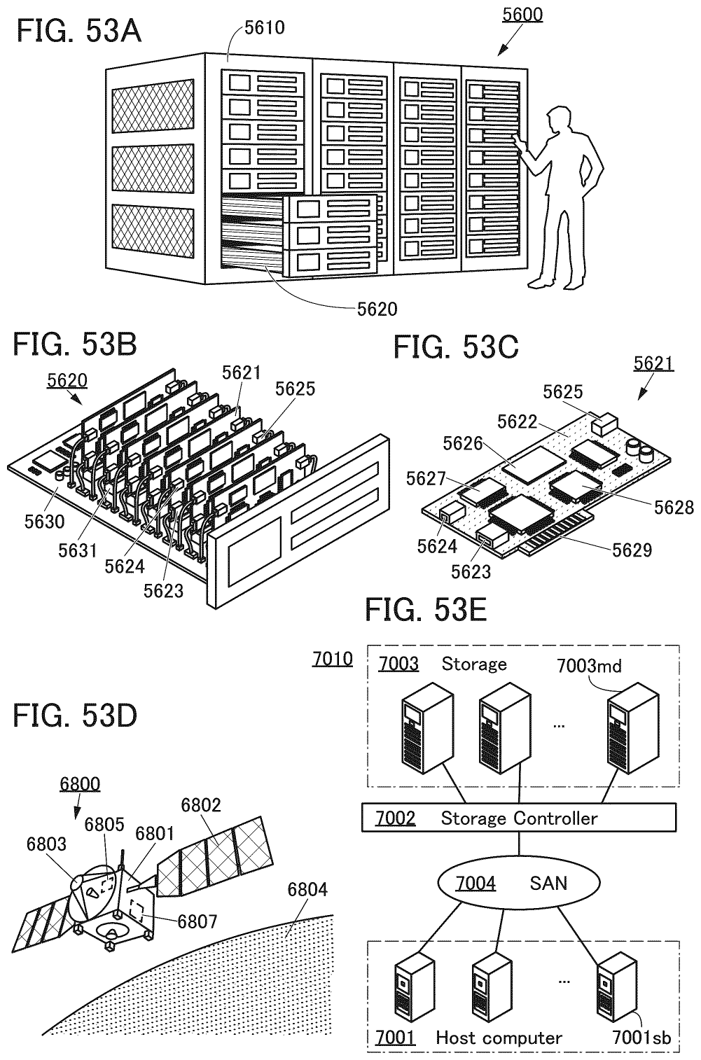

FIG. 53A is a perspective view of a large computer 5600. In the large computer 5600 illustrated in FIG. 53A, a plurality of rack mount computers 5620 are stored in a rack 5610. Note that the large computer 5600 may be referred to as a supercomputer.

The computer 5620 can have a structure illustrated in a perspective view in FIG. 53B, for example. In FIG. 53B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 53C is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 53C also illustrates semiconductor devices other than the semiconductor devices 5626, 5627, and 5628, and the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDM1 (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used as a device for space.

The semiconductor device of one embodiment of the present invention includes an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space. Specifically, the OS transistor can be used as a transistor in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification may include one or more of thermosphere, mesosphere, and stratosphere.

FIG. 53D illustrates an artificial satellite 6800 as an example of a device for space. The artificial satellite 6800 includes a body 6801, a solar panel 6802, an antenna 6803, a secondary battery 6805, and a control device 6807. In FIG. 53D, a planet 6804 in outer space is illustrated as an example.

Although not illustrated in FIG. 53D, a battery management system (also referred to as BMS) or a battery control circuit may be provided in the secondary battery 6805. The battery management system or the battery control circuit preferably uses the OS transistor, in which case low power consumption and high reliability are achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics due to radiation irradiation is smaller in an OS transistor than in a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, the OS transistor has advantageous effects over the Si transistor, such as a wide memory bandwidth and high radiation resistance.

### [Data Center]

The semiconductor device of one embodiment of the present invention can be suitably used for, for example, a storage system in a data center or the like. Long-term management of data, such as guarantee of data immutability, is required for the data center. The long-term management of data needs setting a storage and a server for retaining a huge amount of data, stable power supply for retaining data, cooling equipment for retaining data, an increase in building size, and the like.

With use of the semiconductor device of one embodiment of the present invention for a storage system in a data center, electric power used for retaining data can be reduced and a semiconductor device for retaining data can be downsized. Accordingly, downsizing of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

FIG. 53E illustrates a storage system that can be used in a data center. A storage system 7010 illustrated in FIG. 53E includes a plurality of servers 7001sb as a host 7001 (indicated as “Host Computer” in the diagram). The storage system 7010 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for storing and outputting data. The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

With a structure where an OS transistor is used as a transistor for storing data in the cache memory to retain a potential based on data, the frequency of refreshing can be decreased, so that power consumption can be reduced. Furthermore, downscaling is possible by stacking memory cell arrays.

### [Electronic Device]

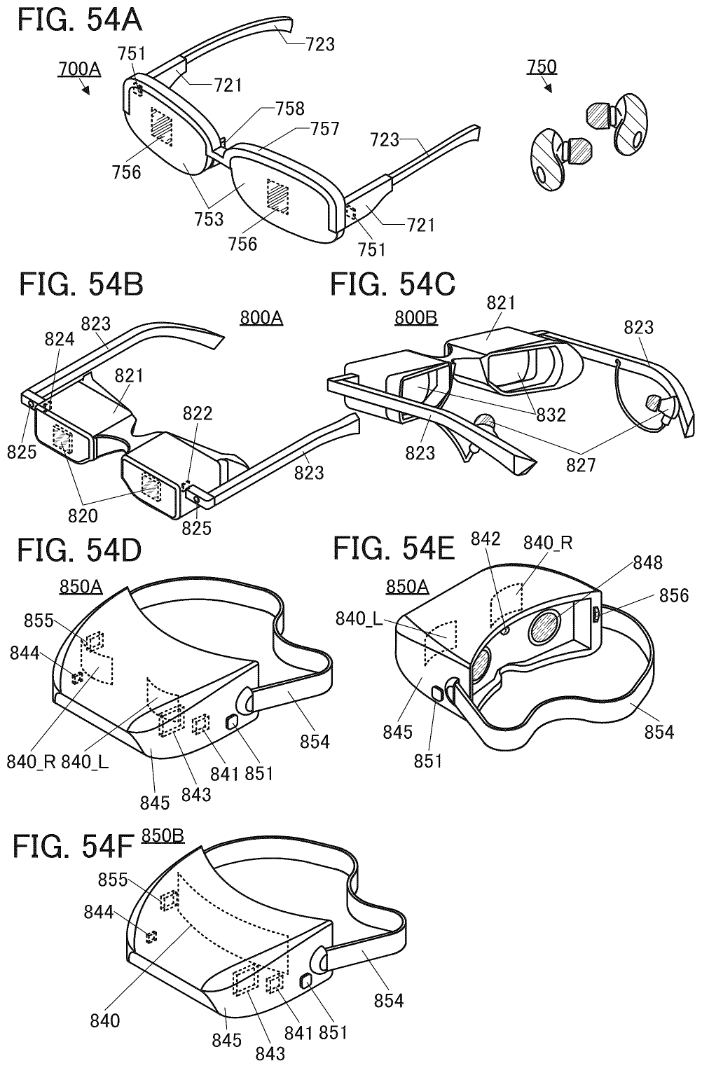

Examples of head-mounted wearable devices are described with reference to FIGS. 54A to 54F. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables the user to feel a higher level of immersion.

An electronic device 700A illustrated in FIG. 54A includes a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display device of one embodiment of the present invention can be used for the display panels 751. Thus, the electronic devices are capable of performing ultrahigh-resolution display. The semiconductor device of one embodiment of the present invention can be used for the control portion (not illustrated). In that case, power consumption of the electronic device can be reduced.

The electronic device 700A can project images displayed on the display panels 751 onto display regions 756 of the optical members 753. Since the optical members 753 have a light-transmitting property, the user can see images displayed on the display regions, which are superimposed on transmission images seen through the optical members 753. Accordingly, the electronic device 700A is ana electronic device capable of AR display.

In the electronic device 700A, a camera capable of capturing images of the front side may be provided as the image capturing portion. Furthermore, when the electronic device 700A is provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 700A is provided with a battery so that charging can be performed wirelessly and/or by wire.

A touch sensor module may be provided in the housing 721. The touch sensor module has a function of detecting a touch on the outer surface of the housing 721. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 721, the range of the operation can be increased.

An electronic device 800A illustrated in FIG. 54B and an electronic device 800B illustrated in FIG. 54C each include a pair of display portions 820, a housing 821, a communication portion 822, a pair of wearing portions 823, a control portion 824, a pair of image capturing portions 825, and a pair of lenses 832.

The display device of one embodiment of the present invention can be used for the display portions 820. Thus, the electronic devices are capable of performing ultrahigh-resolution display. Such electronic devices provide a high sense of immersion to the user. The semiconductor device of one embodiment of the present invention can be used for the control portion 824. In that case, power consumption of the electronic devices can be reduced.

The display portions 820 are positioned inside the housing 821 so as to be seen through the lenses 832. When the pair of display portions 820 display different images, three-dimensional display using parallax can be performed.

The electronic devices 800A and 800B can be regarded as electronic devices for VR. The user wearing the electronic device 800A or the electronic device 800B can see images displayed on the display portions 820 through the lenses 832.

The electronic devices 800A and 800B preferably include a mechanism for adjusting the lateral positions of the lenses 832 and the display portions 820 so that the lenses 832 and the display portions 820 are positioned optimally in accordance with the positions of the user's eyes. Moreover, the electronic devices 800A and 800B preferably include a mechanism for adjusting focus by changing the distance between the lenses 832 and the display portions 820.

The electronic device 800A or the electronic device 800B can be mounted on the user's head with the wearing portions 823. FIG. 54B and the like illustrate examples where the wearing portion 823 has a shape like a temple of glasses; however, one embodiment of the present invention is not limited thereto. The wearing portion 823 may have any shape with which the user can wear the electronic device, such as a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to cover a plurality of fields of view, such as a telescope field of view and a wide field of view.

Although an example where the image capturing portions 825 are provided is shown here, a range sensor (hereinafter also referred to as a sensing portion) capable of measuring a distance between the user and an object just needs to be provided. In other words, the image capturing portion 825 is one embodiment of the sensing portion. As the sensing portion, an image sensor or a range image sensor such as a light detection and ranging (LiDAR) sensor can be used, for example. By using images obtained by the camera and images obtained by the range image sensor, more information can be obtained and a gesture operation with higher accuracy is possible.

The electronic device 800A may include a vibration mechanism that functions as bone-conduction earphones. For example, at least one of the display portion 820, the housing 821, and the wearing portion 823 can include the vibration mechanism. Thus, without additionally requiring an audio device such as headphones, earphones, or a speaker, the user can enjoy images and sound only by wearing the electronic device 800A.

The electronic devices 800A and 800B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A in FIG. 54A has a function of transmitting information to the earphones 750 with the wireless communication function.

The electronic device may include an earphone portion. The electronic device 800B in FIG. 54C includes earphone portions 827. For example, the earphone portion 827 can be connected to the control portion 824 by wire. Part of a wiring that connects the earphone portion 827 and the control portion 824 may be positioned inside the housing 821 or the wearing portion 823. Alternatively, the earphone portions 827 and the wearing portions 823 may include magnets.

This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

FIGS. 54D and 54E are perspective views of a goggles-type electronic device 850A for VR. FIGS. 54D and 54E illustrate an example where a housing 845 includes a pair of curved display devices 840 (a display device 840_R and a display device 840_L). The electronic device 850A includes a motion detection portion 841, an eye-gaze detection portion 842, an arithmetic portion 843, a communication portion 844, lenses 848, an operation button 851, a wearing tool 854, a sensor 855, a dial 856, and the like.

When the two display devices 840 are provided, the user's eyes can see the respective display devices. This allows a high-resolution image to be displayed even when three-dimensional display using parallax or the like is performed. In addition, the display device 840 is curved around an arc with an approximate center at the user's eye. This keeps a certain distance between the user's eye and the display surface of the display device 840, enabling the user to see a more natural image. Even when having what is called viewing angle dependence where the luminance or chromaticity of light changes depending on a viewing angle, the display device 840 can have a structure where the user's eye is positioned in the normal direction of the display surface of the display device 840; accordingly, the influence of the viewing angle dependence particularly in the horizontal direction can be practically ignored, enabling display of a more realistic video.

As illustrated in FIG. 54E, the lenses 848 are positioned between the display devices 840 and the user's eyes. FIG. 54E illustrates an example where the dial 856 for changing the positions of the lenses for visibility adjustment is provided. Note that in the case where the electronic device 850A has an autofocus function, the dial 856 for visibility adjustment is not necessarily provided.

FIG. 54F illustrates a goggles-type electronic device 850B including one display device 840. Such a structure can reduce the number of components.

The display device 840 can display an image for the right eye and an image for the left eye side by side on a right region and a left region, respectively. Thus, a three-dimensional image using binocular parallax can be displayed. Note that the display device 840 may display two different images side by side using parallax, or may display two same images side by side without using parallax.

One image which can be seen with both eyes may be displayed on the entire display device 840. Thus, a panorama image can be displayed from end to end of the field of view, which can provide a higher sense of reality.

The display device of one embodiment of the present invention can be used as the display device 840. Since the display device of one embodiment of the present invention has an extremely high resolution, even when an image is magnified using the lenses 848, the pixels are not perceived by the user, and thus a more realistic image can be displayed.

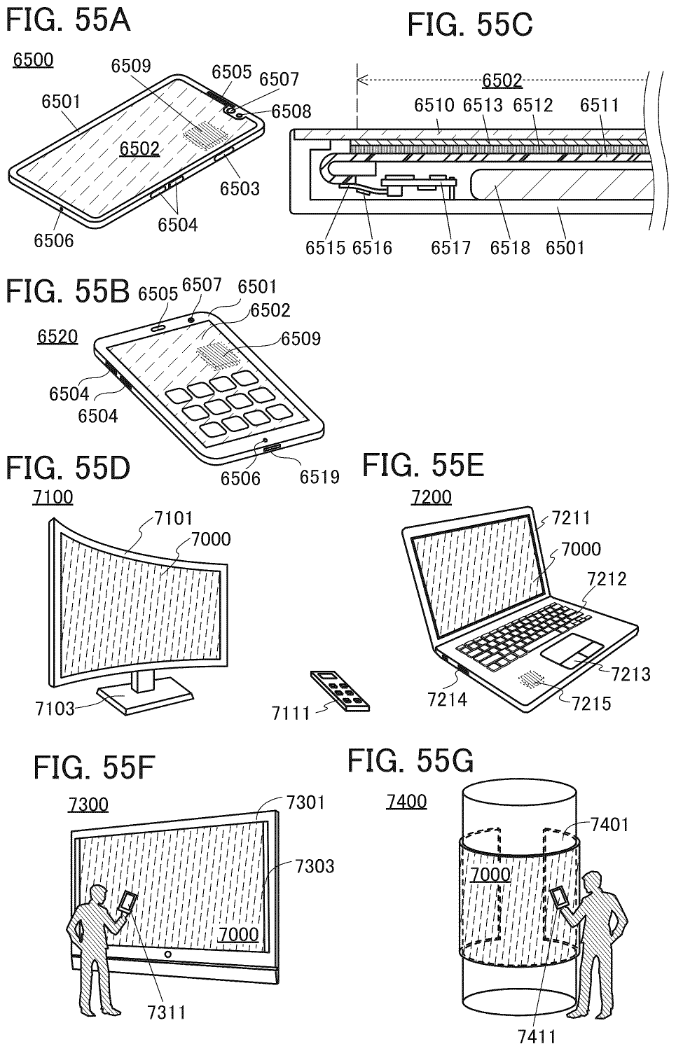

An electronic device 6500 in FIG. 55A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, a control device 6509, and the like.

An electronic device 6520 in FIG. 55B is a portable information terminal that can be used as a tablet terminal.

The electronic device 6520 includes the housing 6501, the display portion 6502, the buttons 6504, the speaker 6505, the microphone 6506, the camera 6507, the control device 6509, a connection terminal 6519, and the like.

In each of the electronic device 6500 and the electronic device 6520, the display portion 6502 has a touch panel function. Note that the control device 6509 includes, for example, one or more selected from a CPU, a GPU, and a memory device. The semiconductor device of one embodiment of the present invention can be used for one or both of the display portion 6502 and the control device 6509.

FIG. 55C is a schematic cross-sectional view including an end portion of the housing 6501 included in the electronic device 6500 or the electronic device 6520 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. In that case, an extremely lightweight electronic device can be obtained. Since the display panel 6511 is extremely thin, the battery 6518 with high capacity can be mounted without an increase in the thickness of the electronic device. An electronic device with a narrow bezel can be obtained when part of the display panel 6511 is folded back so that the portion connected to the FPC 6515 is provided on the back side of a pixel portion.

FIG. 55D illustrates an example of a television device. In a television device 7100, a display portion 7000 is incorporated in a housing 7101. Here, the housing 7101 is supported by a stand 7103.

The display device of one embodiment of the present invention can be used for the display portion 7000.

Operation of the television device 7100 illustrated in FIG. 55D can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 55E illustrates an example of a laptop personal computer. The laptop personal computer 7200 includes a housing 7211, a keyboard 7212, a pointing device 7213, an external connection port 7214, a control device 7215, and the like. The display portion 7000 is incorporated in the housing 7211. The control device 7215 includes, for example, one or more selected from a CPU, a GPU, and a memory device. The semiconductor device of one embodiment of the present invention can be used for one or both of the display portion 7000 and the control device 7215.

FIGS. 55F and 55G illustrate examples of digital signage.

Digital signage 7300 illustrated in FIG. 55F includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 55G is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIGS. 55F and 55G.

A larger area of the display portion 7000 can increase the amount of information that can be provided at a time. The display portion 7000 having a larger area attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 55F and 55G, it is preferable that the digital signage 7300 or the digital signage 7400 can work with an information terminal 7311 or an information terminal 7411, such as a smartphone of a user, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The semiconductor device and the display device of one embodiment of the present invention can be used around a driver's seat in a car, which is a vehicle.

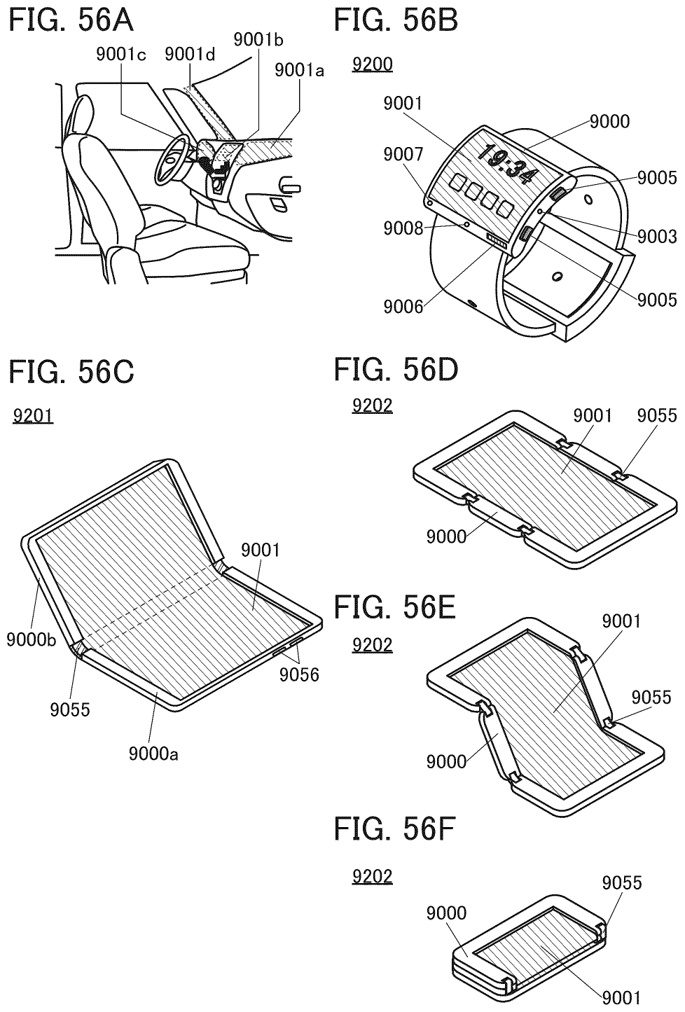

FIG. 56A illustrates the vicinity of a windshield inside a car. FIG. 56A illustrates a display panel 9001a, a display panel 9001b, and a display panel 9001c attached to a dashboard and a display panel 9001d attached to a pillar.

The display panels 9001a to 9001c can provide various kinds of information by displaying navigation data, a speedometer, a tachometer, a mileage, a fuel meter, a gearshift state, air-conditioning settings, and the like. Items displayed on the display panel, their layout, and the like can be changed as appropriate to suit the user's preferences, resulting in more sophisticated design. The display panels 9001a to 9001c can also be used as lighting devices.

The display panel 9001d can compensate for the view hindered by the pillar (blind areas) by displaying an image taken by an imaging unit provided for the car body. That is, displaying an image taken by the imaging unit provided on the outside of the car body leads to elimination of blind areas and enhancement of safety. Moreover, showing an image to compensate for the area that a driver cannot see makes it possible for the driver to confirm safety more easily and comfortably. The display panel 9001d can also be used as a lighting device.

FIG. 56B is a perspective view of a watch-type portable information terminal 9200. The portable information terminal 9200 can be used as a Smartwatch (registered trademark), for example. The display surface of the display portion 9001 is curved, and an image can be displayed on the curved display surface. Furthermore, for example, mutual communication between the portable information terminal 9200 and a headset capable of wireless communication can be performed, and thus hands-free calling is possible. With a connection terminal 9006, the portable information terminal 9200 can perform mutual data transmission with another information terminal and charging. Note that the charging operation may be performed by wireless power feeding.

The portable information terminal 9200 illustrated in FIG. 56B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

FIG. 56C is a perspective view of a foldable portable information terminal 9201. The portable information terminal 9201 includes a housing 9000a, a housing 9000b, the display portion 9001, and operation buttons 9056.

The housing 9000a and the housing 9000b are bonded to each other with a hinge 9055 that allows the display portion 9001 to be folded in half.

The display portion 9001 of the portable information terminal 9201 is supported by two housings (the housing 9000a and the housing 9000b) joined together with the hinge 9055. FIGS. 56D to 56F are perspective views illustrating a foldable portable information terminal 9202. FIG. 56D is a perspective view of an opened state of the portable information terminal 9202, FIG. 56F is a perspective view of a folded state thereof, and FIG. 56E is a perspective view of a state in the middle of change from one of FIG. 56D and FIG. 56F to the other. In this manner, the portable information terminal 9202 can be folded in three.

The display portion 9001 of the portable information terminal 9202 is supported by three housings 9000 joined together with the hinges 9055.

In FIGS. 56C to 56F, the display device of one embodiment of the present invention can be used for the display portion 9001. The display portion 9001 can be folded with a radius of curvature greater than or equal to 0.1 mm and less than or equal to 150 mm, for example.

The portable information terminals 9201 and 9202 are highly portable when folded. When the portable information terminals 9201 and 9202 are opened, a seamless large display region is highly browsable.

The use of the semiconductor device of one embodiment of the present invention for one or more selected from an electronic component, a large computer, a device for space, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

This embodiment can be combined with any of the other embodiments as appropriate.

### Example

In this example, memory circuits that can be used for a memory device of one embodiment of the present invention were fabricated and the writing characteristics thereof were evaluated.

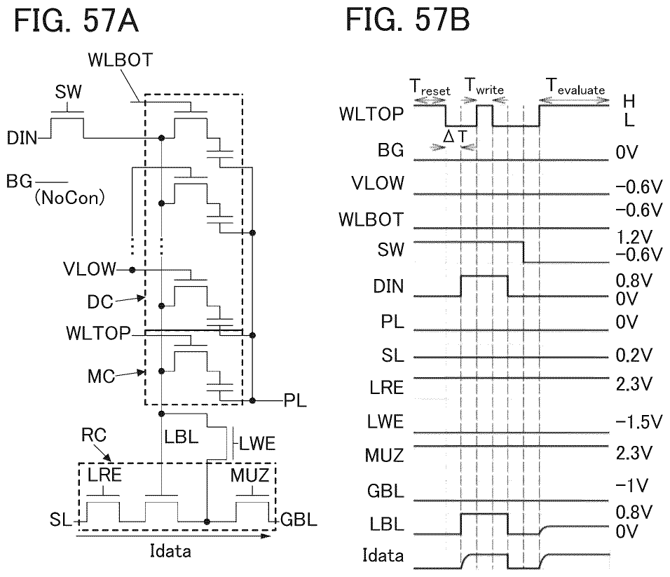

FIG. 57A is a circuit diagram of this example, and FIG. 57B is a timing chart of circuit operation.

A memory cell MC has what is called a 1Tr1C structure including one transistor and one capacitor. A target memory cell MC and 15 dummy cells DC are connected in parallel. A word line WLTOP is connected to a gate of the transistor of the memory cell MC, and a wiring VLOW constantly supplied with a low-level potential is connected to a gate of each transistor of the dummy cells DC. A bit line is connected to one of a source electrode and a drain electrode of each transistor of the memory cell MC and the dummy cells DC. The bit line is connected to a read circuit RC.

In the timing chart in FIG. 57B, a period Tᵣₑₛₑₜ corresponds to a reset period. A period T_{write} corresponds to a writing period, in which a high-level potential is supplied from the word line WLTOP to the gate of the transistor of the memory cell MC to turn on the transistor, so that a data potential (0.8 V) is written from a wiring DIN to the memory cell through the bit line. A period Tₑᵥₐₗᵤₐₜₑ corresponds to a reading period, in which a current I_{data} corresponding to the potential written to the memory cell MC flows to the read circuit RC. In this example, the current I_{data} was measured using different potentials supplied to the word line WLTOP and different periods T_{write}.

The other signals, potentials, and the like are as shown in the circuit diagram in FIG. 57A and the timing chart in FIG. 57B.

Here, a vertical transistor (VFET) that can be used in the memory device of one embodiment of the present invention was used as each transistor illustrated in FIG. 57A. In addition, a vertical capacitor (VC) that can be used in the memory device of one embodiment of the present invention was used as each capacitor. The memory cell MC and the dummy cells DC each employ a structure where the vertical transistor is stacked over the vertical capacitor. An oxide semiconductor was used for the semiconductor layer of the vertical transistor, in which the diameter of an opening portion was approximately 60 nm and the thickness of a spacer insulating layer was approximately 80 nm. In the vertical capacitor, the diameter of an opening portion was approximately 60 nm and the thickness of an spacer insulating layer was approximately 80 nm.

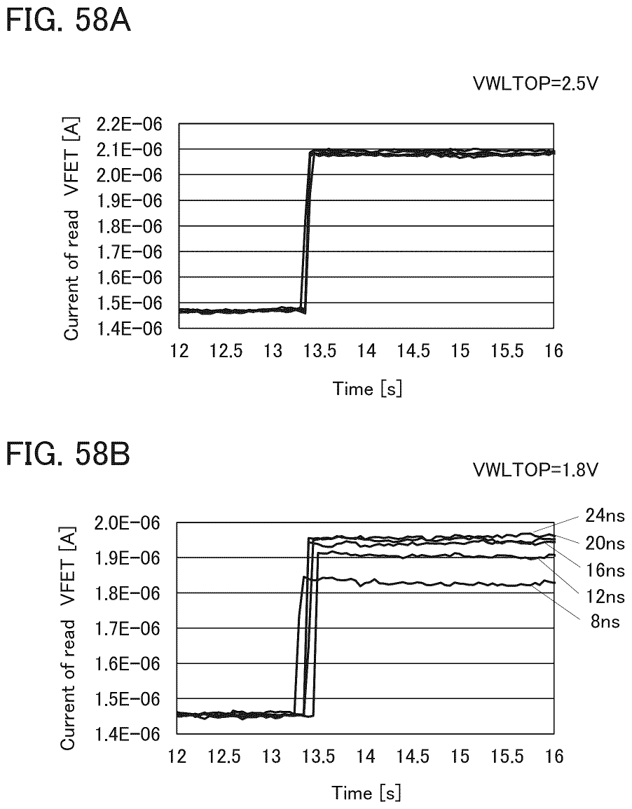

FIGS. 58A and 58B show measurement results of the current I_{data}. In each graph, the vertical axis represents a current of a read VFET and the horizontal axis represents time.

Voltages VWLTOP of the word line WLTOP were 2.5 V and 1.8 V. The periods T_{write} were 8 ns, 12 ns, 16 ns, 20 ns, and 24 ns.

FIG. 58A shows the results at the voltage VWLTOP of 2.5 V. The results show that the values measured using five different periods T_{write} substantially overlap with each other. From the results in FIG. 58A, with the shortest period T_{write} of 8 ns, for example, a voltage retained in the memory cell MC (voltage of a retention node) can be estimated to be 0.73 V. This is approximately 91% of the data potential 0.8 V and exceeds 80%, demonstrating that the writing operation is performed adequately.

FIG. 58B shows the results at the voltage VWLTOP of 1.8 V. The results confirm that the current values decrease when the period T_{write} is shorter than or equal to 12 ns. For example, when the period T_{write} is 16 ns, the voltage of the retention node of the memory cell MC can be estimated to be 0.68 V. This is approximately 85% of the data potential 0.8 V and exceeds 80%, demonstrating that the writing operation is performed adequately.

The above results confirm that the memory device of one embodiment of the present invention can perform high-speed writing and reading even at a low voltage by using a memory cell composed of a vertical transistor and a vertical capacitor.

This application is based on Japanese Patent Application Serial No. 2023-111782 filed with Japan Patent Office on Jul. 6, 2023, Japanese Patent Application Serial No. 2023-111783 filed with Japan Patent Office on Jul. 6, 2023, Japanese Patent Application Serial No. 2023-111802 filed with Japan Patent Office on Jul. 6, 2023, and Japanese Patent Application Serial No. 2023-131028 filed with Japan Patent Office on Aug. 10, 2023, the entire contents of which are hereby incorporated by reference.

What is claimed is:

1. A semiconductor device comprising:
an oxide semiconductor layer;
a first conductive layer;
a second conductive layer;
a third conductive layer;
a fourth conductive layer;
a first insulating layer;
a second insulating layer;
a third insulating layer; and
a fourth insulating layer,
wherein the first insulating layer is over the first conductive layer,
wherein the second conductive layer is over the first insulating layer,
wherein the second insulating layer is over the second conductive layer,
wherein the third conductive layer is over the second insulating layer,
wherein the first conductive layer comprises a first depressed portion,
wherein the first insulating layer, the second conductive layer, the second insulating layer, and the third conductive layer comprise a first opening portion in a position overlapping with the first depressed portion,
wherein the third insulating layer is in contact with at least a side surface of the second conductive layer in the first opening portion,
wherein the oxide semiconductor layer is in contact with a top surface of the third conductive layer and a bottom surface and a side surface of the first depressed portion, and is in contact with the third insulating layer in the first opening portion,
wherein the fourth insulating layer is on an inner side of the oxide semiconductor layer in the first opening portion,
wherein the fourth conductive layer is on an inner side of the fourth insulating layer in the first opening, and
wherein in a cross-sectional view, the oxide semiconductor layer comprises a region overlapping with the second conductive layer with the third insulating layer therebetween and overlapping with the fourth conductive layer with the fourth insulating layer therebetween.

2. The semiconductor device according to claim 1, further comprising a fifth insulating layer,
wherein the first conductive layer and the second insulating layer are over the fifth insulating layer, and
wherein the shortest distance from a top surface of the fifth insulating layer to a top surface of the first conductive layer in contact with the first insulating layer is longer than the shortest distance from the top surface of the fifth insulating layer to a bottom surface of the fourth insulating layer.

3. The semiconductor device according to claim 1, further comprising a fifth insulating layer,
wherein the first conductive layer and the fourth conductive layer are over the fifth insulating layer, and
wherein the shortest distance from a top surface of the fifth insulating layer to a top surface of the first conductive layer in contact with the first insulating layer is longer than or equal to the shortest distance from the top surface of the fifth insulating layer to a bottom surface of the fourth conductive layer.

4. The semiconductor device according to claim 1,
wherein the first conductive layer comprises a fifth conductive layer and a sixth conductive layer over the fifth conductive layer,
wherein the sixth conductive layer comprises a second depressed portion,
wherein the first opening portion overlaps with the second depressed portion, and
wherein the oxide semiconductor layer is in contact with a bottom surface and a side surface of the second depressed portion.

5. The semiconductor device according to claim 1, further comprising a sixth insulating layer,
wherein the fourth insulating layer covers a top surface and a side surface of the oxide semiconductor layer over the second insulating layer,
wherein the sixth insulating layer is over the fourth insulating layer and comprises a second opening portion in a position overlapping with the first opening portion, and
wherein the fourth conductive layer comprises a portion overlapping with the oxide semiconductor layer with the fourth insulating layer therebetween in the first opening portion, and a portion positioned in the second opening portion.

6. The semiconductor device according to claim 1, further comprising a sixth insulating layer,
wherein the sixth insulating layer is over the second insulating layer, covers a top surface and a side surface of the oxide semiconductor layer over the second insulating layer, and comprises a second opening portion in a position overlapping with the first opening portion,
wherein the fourth insulating layer comprises a portion positioned in the second opening portion, and
wherein the fourth conductive layer is on an inner side of the fourth insulating layer in the second opening portion.

7. The semiconductor device according to claim 1,
wherein the third insulating layer comprises a seventh insulating layer in contact with the oxide semiconductor layer and an eighth insulating layer positioned on an outer side of the seventh insulating layer in the first opening portion, and
wherein one of the seventh insulating layer and the eighth insulating layer is an oxide insulating layer and the other is a nitride insulating layer.

8. The semiconductor device according to claim 1, further comprising:
a fifth insulating layer; and
a fifth conductive layer,
wherein the fifth insulating layer is over the fourth insulating layer and comprises a second opening portion reaching the fourth conductive layer in a position overlapping with the first opening portion, and
wherein the fifth conductive layer is in contact with the fourth conductive layer in the second opening portion.

9. A semiconductor device comprising:
a first layer; and
a second layer over the first layer,
wherein the second layer comprises a first memory cell array and a second memory cell array,
wherein the first memory cell array comprises a plurality of first memory cells,
wherein the second memory cell array comprises a plurality of second memory cells,
wherein the first layer comprises a transistor comprising silicon in a channel formation region,
wherein the first memory cell and the second memory cell each comprise a vertical transistor,
wherein the vertical transistor comprises an oxide semiconductor in a channel formation region, and
wherein the first memory cell and the second memory cell have different structures.

10. A semiconductor device comprising:
a first layer;
a second layer over the first layer; and
a third layer over the second layer,
wherein the second layer comprises a first memory cell array,
wherein the third layer comprises a second memory cell array,
wherein the first memory cell array comprises a plurality of first memory cells,
wherein the second memory cell array comprises a plurality of second memory cells,
wherein the first layer comprises a transistor comprising silicon in a channel formation region,
wherein the first memory cell and the second memory cell each comprise a vertical transistor,
wherein the vertical transistor comprises an oxide semiconductor in a channel formation region, and
wherein the first memory cell and the second memory cell have different structures.

11. The semiconductor device according to claim 9,
wherein one of the first memory cell and the second memory cell retains data for a longer time than the other without being supplied with power.

12. The semiconductor device according to claim 10,
wherein one of the first memory cell and the second memory cell retains data for a longer time than the other without being supplied with power.

13. A semiconductor device comprising:
a first layer; and
a second layer over the first layer,
wherein the second layer comprises a first memory cell array and a second memory cell array,
wherein the first memory cell array comprises a plurality of first memory cells,
wherein the second memory cell array comprises a plurality of second memory cells,
wherein the first layer comprises a transistor comprising silicon in a channel formation region,
wherein the first memory cell is composed of one vertical transistor and one capacitor,
wherein the second memory cell is composed of two vertical transistors, and
wherein the vertical transistors included in the first memory cell and the second memory cell each comprise an oxide semiconductor in a channel formation region.

14. A semiconductor device comprising:
a first layer;
a second layer over the first layer; and
a third layer over the second layer,
wherein the second layer comprises a first memory cell array,
wherein the third layer comprises a second memory cell array,
wherein the first memory cell array comprises a plurality of first memory cells,
wherein the second memory cell array comprises a plurality of second memory cells,
wherein the first layer comprises a transistor comprising silicon in a channel formation region,
wherein one of the first memory cell and the second memory cell is composed of one vertical transistor and one capacitor, and the other is composed of two vertical transistors, and
wherein the vertical transistors included in the first memory cell and the second memory cell each comprise an oxide semiconductor in a channel formation region.
